(19) United States
(12) Patent Application Publication
(10) Pub. No.: US 2017/0285482 A1
(43) Pub. Date: Oct. 5, 2017

(54) ORGANIC PROCESSING LIQUID AND PATTERN FORMING METHOD

(71) Applicant: FUJIFILM Corporation, Tokyo (JP)

(72) Inventors: Toru TSUCHIHASHI, Haibara-gun (JP); Hideaki TSUBAKI, Haibara-gun (JP); Kei YAMAMOTO, Haibara-gun (JP)

(73) Assignee: FUJIFILM Corporation, Tokyo (JP)

(21) Appl. No.: 15/629,985

(22) Filed: Jun. 22, 2017

Related U.S. Application Data
(63) Continuation of application No. PCT/JP2015/085940, filed on Dec. 24, 2015.

(30) Foreign Application Priority Data
Dec. 26, 2014 (JP) 2014-265970
Mar. 17, 2015 (JP) 2015-053561
Jun. 2, 2015 (JP) 2015-112349
Nov. 30, 2015 (JP) 2015-234063

(51) Int. Cl. G03F 7/32; G03F 7/16; G03F 7/20; H01L 21/027; G03F 7/039; G03F 7/004; G03F 7/38; G03F 7/40; G03F 7/42; G03F 7/038

(52) U.S. Cl. CPC G03F 7/32; G03F 7/422; G03F 7/16; G03F 7/2004; G03F 7/038; G03F 7/039; G03F 7/0045; G03F 7/0046; G03F 7/168; G03F 7/38; G03F 7/40; G03F 7/2006; G03F 7/2041; H01L 21/0274; H01L 21/0275

(57) ABSTRACT

Disclosed herein are an organic processing liquid for resist film patterning which is capable of suppressing the occurrence of defects in resist patterns, and a pattern forming method. Provided is an organic processing liquid for resist film patterning, which is used to carry out at least one of developing or cleaning of a resist film obtained from an actinic ray-sensitive or radiation-sensitive composition, the liquid including an organic solvent, in which the content of an oxidant in the organic processing liquid is 10 mmol/L or less.

### CROSS-REFERENCE TO RELATED APPLICATIONS

This application is a Continuation of PCT International Application No. PCT/JP2015/085940 filed on Dec. 24, 2015, which claims priority under 35 U.S.C. §119(a) to Japanese Patent Application No. 2014-265970 filed on Dec. 26, 2014, Japanese Patent Application No. 2015-053561 filed on Mar. 17, 2015, Japanese Patent Application No. 2015-112349 filed on Jun. 2, 2015 and Japanese Patent Application No. 2015-234063 filed on Nov. 30, 2015. Each of the above applications is hereby expressly incorporated by reference, in its entirety, into the present application.

### BACKGROUND OF THE INVENTION

### 1. Field of the Invention

The present invention relates to an organic processing liquid for resist film patterning and a pattern forming method.

More specifically, the present invention relates to an organic processing liquid which is used for a production process of a semiconductor such as an IC, a production process of a circuit board of, for example, a liquid crystal or a thermal head, and other lithography processes of photofabrication, and a pattern forming method.

### 2. Description of the Related Art

In the process of producing a semiconductor device such as an integrated circuit (IC) or a large scale integrated circuit (LSI), microfabrication by lithography using a photoresist composition has been conventionally carried out. Recently, the integration degree of integrated circuits has been becoming higher and consequently the formation of an ultrafine pattern in the sub-micron or quarter-micron range has been required. To cope with this requirement, the exposure wavelength has also tended to become shorter, for example, from g line to i line, or further to KrF excimer laser light. Furthermore, at present, the development of lithography using electron beams, X-rays, or extreme ultraviolet (EUV) light in addition to excimer laser light is also proceeding.

In such lithography, a film is formed by using a photoresist composition (also referred to as an actinic ray-sensitive or radiation-sensitive composition or a chemically amplified resist composition), the resulting film is developed with a developer, and the post-development film is cleaned with a rinsing liquid.

For example, JP2014-112176A discloses that an organic processing liquid with an alkyl olefin content and a metal element concentration being equal to or less than a specific value is used as a developer or a rinsing liquid.

### SUMMARY OF THE INVENTION

The integration degree of integrated circuits has recently been becoming higher and consequently the formation of a fine pattern using a photoresist composition (actinic ray-sensitive or radiation-sensitive composition) has been required. In the formation of such a fine pattern, the foreign matter generated on the surface of a resist pattern becomes a defect, which is likely to cause performance degradation of the resist pattern.

The present inventors have conducted extensive studies on such a problem and identified that, in addition to specific olefins or specific metal elements contained in the developer or rinsing liquid as described in JP2014-112176A, the action of an oxidant contained in an organic solvent is particularly significant as a cause of the above-mentioned foreign matter.

The present invention has been made in view of the foregoing points. An object of the present invention is to provide an organic processing liquid for resist film patterning which is capable of suppressing the occurrence of resist pattern defects, and a pattern forming method.

As a result of extensive studies on the above-mentioned problems, the present inventors have found that the desired effect is achieved by setting the content of an oxidant contained in an organic processing liquid to a specific amount or less.

More specifically, the present inventors have found that the above-described object can be achieved by the following configurations.

(1) An organic processing liquid for resist film patterning, which is used to carry out at least one of developing or cleaning of a resist film obtained from an actinic ray-sensitive or radiation-sensitive composition, the liquid comprising an organic solvent,

in which the content of an oxidant in the organic processing liquid is 10 mmol/L or less.

(2) The organic processing liquid according to (1), in which the organic processing liquid is a developer.

(3) The organic processing liquid according to (2), in which the organic solvent includes an ester-based solvent.

(4) The organic processing liquid according to (3), in which the ester-based solvent includes isoamyl acetate.

(5) The organic processing liquid according to (2), in which the organic solvent includes a ketone-based solvent.

(6) The organic processing liquid according to any one of (2) to (5), further comprising a basic compound.

(7) The organic processing liquid according to (1), in which the organic processing liquid is a rinsing liquid.

(8) The organic processing liquid according to (7), in which the organic solvent includes a hydrocarbon-based solvent.

(9) The organic processing liquid according to (7) or (8), in which the organic solvent includes a ketone-based solvent.

(10) The organic processing liquid according to any one of (7) to (9), in which the organic solvent includes an ether-based solvent.

(11) The organic processing liquid according to (8), in which the hydrocarbon-based solvent includes undecane.

(12) The organic processing liquid according to any one of (1) to (11), further comprising an antioxidant.

(13) The organic processing liquid according to any one of (1) to (12), further comprising a surfactant.

(14) A pattern forming method, comprising:

a resist film forming step of forming a resist film using an actinic ray-sensitive or radiation-sensitive composition;

an exposure step of exposing the resist film; and

a treatment step of treating the exposed resist film with the organic processing liquid according to (1).

(15) The pattern forming method according to (14), in which the treatment step includes a development step of developing with a developer,

the developer is the organic processing liquid according to (1), and

the organic solvent includes isoamyl acetate.

(16) The pattern forming method according to (14) or (15), in which the treatment step includes a development step of developing with a developer,

the developer is the organic processing liquid according to (1), and

the organic processing liquid further contains a basic compound.

(17) The pattern forming method according to any one of (14) to (16), in which the treatment step includes a rinsing step of cleaning by a rinsing liquid,

the rinsing liquid is the organic processing liquid according to (1), and

the organic solvent includes a hydrocarbon-based solvent.

According to the present invention, it is possible to provide an organic processing liquid for resist film patterning, which is capable of reducing the occurrence of defects on surfaces of patterns to be formed, and a pattern forming method.

### DESCRIPTION OF THE PREFERRED EMBODIMENTS

Hereinafter, an example of embodiments for carrying out the present invention will be described.

The numerical value ranges shown with “to” as used herein means ranges including the numerical values indicated before and after “to” as the lower limit and the upper limit, respectively.

The term “actinic rays” or “radiation” as used herein indicates, for example, a bright line spectrum of mercury lamp, far ultraviolet rays represented by excimer laser light, extreme ultraviolet rays (EUV light), X-rays, or electron beams. The term “light” as used herein means actinic rays or radiation. Unless otherwise indicated, the term “exposure” as used herein includes not only exposure to a mercury lamp, far ultraviolet rays represented by excimer laser light, X-rays, extreme ultraviolet rays (EUV light), or the like but also lithography with particle beams such as electron beams (EB) and ion beams.

In the description of the present invention, when a group (atomic group) is denoted without specifying whether substituted or unsubstituted, the group includes both a group having no substituent and a group having a substituent. For example, an “alkyl group” includes not only an alkyl group having no substituent (unsubstituted alkyl group) but also an alkyl group having a substituent (substituted alkyl group).

[Organic Processing Liquid]

The organic processing liquid of the present invention is an organic processing liquid for resist film patterning, which is used to carry out at least one of developing or cleaning of a resist film obtained from an actinic ray-sensitive or radiation-sensitive composition and which contains an organic solvent. The content of an oxidant in the organic processing liquid of the present invention is 10 mmol/L or less.

According to the organic processing liquid of the present invention, it is possible to suppress the occurrence of defects in resist patterns. The details of this reason are not yet clear, but it is estimated as follows.

That is, due to a low content of an oxidant, the foregoing organic processing liquid, which is used as a developer and/or a rinsing liquid, is capable of inhibiting the reaction between the oxidant contained in the organic processing liquid and the components contained in the post-exposure film (resist film). As a result, it is presumed that it is possible to prevent generation of foreign matters on surfaces of resist patterns due to the reaction with the oxidant, and therefore the occurrence of resist pattern defects can be suppressed.

The content (concentration) of the oxidant in the organic processing liquid of the present invention is 10.0 mmol/L or less, preferably 2.5 mmol/L or less, and more preferably 1.0 mmol/L or less. Most preferably, the organic processing liquid of the present invention is substantially free of an oxidant.

In this way, by setting the content of the oxidant to 10.0 mmol/L or less, the occurrence of defects in resist patterns can be suppressed, for example, even if the organic processing liquid is used after being stored in a capped container (for example, the container described in JP2014-112176A) at room temperature (23° C.) for 6 months.

As used herein, the phrase “substantially free of” refers to that an oxidant is not detected (under the detection limit value) in the case of being measured by a method capable of measuring the content (concentration) of the oxidant (for example, a measurement method to be described hereinafter).

With respect to the lower limit of the content (concentration) of an oxidant, as described above, it is most preferred that the organic processing liquid of the present invention is substantially free of an oxidant. However, as will be described hereinafter, a treatment such as distillation to reduce the content of an oxidant results in an increased cost. Considering the cost or the like for industrial use, the content of an oxidant may be 0.01 mmol/L or more.

The oxidant in the present invention is primarily a component (more specifically, a peroxide) produced by oxidation of a component (in particular, an organic solvent to be described hereinafter) constituting the organic processing liquid.

The content of the oxidant (amount of peroxide) in the organic processing liquid of the present invention can be measured as follows. Hereinafter, although the method of measuring the amount of a peroxide as an example will be described in detail, other oxidants can also be measured by the same method.

First, 10 ml of the organic processing liquid is accurately collected in a 200 ml flask equipped with a stopper, and 25 ml of an acetic acid:chloroform (volume ratio of 3:2) solution is added thereto. Then, 1 ml of a saturated potassium iodide solution is added thereto, followed by mixing and allowing to stand for 10 minutes in the dark. Next, 30 ml of distilled water and 1 ml of a starch solution are added thereto, followed by titration with a 0.01 N sodium thiosulfate solution until the reaction solution became colorless.

Next, the above procedure is carried out with no addition of a sample, which is taken as a blank test.

The amount of peroxide is calculated according to the following equation.

Peroxide (mmol/L)=(A−B)×F/amount of sample (ml)×100÷2

A: Consumption of a 0.01 N sodium thiosulfate solution required for titration (ml)

B: Consumption of a 0.01 N sodium thiosulfate solution required for titration of blank test (ml)

F: Titer of a 0.01 N sodium thiosulfate solution

The peroxide detection limit according to the present analytical method is 0.01 mmol/L.

By subjecting the organic processing liquid of the present invention to, for example, nitrogen purging during storage of the organic processing liquid, or distillation of an organic solvent to be used, the content of the oxidant can be further reduced, or the over-time increase in the content of the oxidant can be further suppressed. Further, the over-time increase in the content of the oxidant can be further suppressed by adding an antioxidant (which will be described hereinafter) to the organic processing liquid.

The organic processing liquid of the present invention is preferably substantially free of an acid, an alkali, or a halogen-containing metal salt.

Examples of the acid include hydrochloric acid, nitric acid, and sulfuric acid. Examples of the alkali include sodium hydroxide and potassium hydroxide. Examples of the halogen-containing metal salt include sodium chloride and potassium chloride.

Note that the alkali limitedly refers to a substance that produces a hydroxide ion when it is dissolved in water, such as a hydroxide (salt) of an alkali metal and an alkaline earth metal, and corresponds to a base according to the Arrhenius definitions.

As described above, the organic processing liquid of the present invention preferably does not contain impurities such as a metal, a halogen-containing metal salt, an acid, and an alkali. More specifically, the content of impurities in the organic processing liquid of the present invention is preferably 1 ppm or less, more preferably 10 ppb or less, still more preferably 100 ppt or less, and particularly preferably 10 ppt or less. Most preferably, the organic processing liquid of the present invention is substantially free of impurities (under the detection limit of the measurement device).

Examples of the method for removing impurities such as metals from various materials include filtration using a filter, and a distillation purification process (in particular, thin film distillation, molecular distillation, or the like). Examples of the distillation purification process include those described in, for example, “<Factory Operation Series> Enlarged/Distillation, Jul. 31, 1992, Chemical Industry Co., Ltd., and “Chemical Engineering Handbook, Sep. 30, 2004, Asakura Shoten, pages 95 to 102”. These processes may be carried out in combination thereof.

The filter pore size is preferably 10 nm or less, more preferably 5 nm or less, and still more preferably 3 nm or less. The filter is preferably made of polytetrafluoroethylene, polyethylene, or nylon. Filter may be used after pre-cleaning with an organic solvent. The filter filtration process may be carried out using a plurality of types of filters connected in series or in parallel. In the case of using a plurality of types of filters, filters each having a different pore size and/or made of a different material may be used in combination thereof. Further, various materials may be filtered several times, and the process of filtering several times may be a circulation filtration process.

Further, examples of the method for reducing impurities, such as metals, contained in the organic processing liquid of the present invention include a method which selects raw materials having a low content of metals as the raw materials constituting various materials, a method which carries out filter filtration for raw materials constituting various materials, and a method which carries out distillation under the conditions that the contamination is suppressed as much as possible, for example, by lining the inside of an apparatus with Teflon (registered trademark). Preferred conditions for the filter filtration carried out for raw materials constituting various materials are the same as those described above.

In addition to filter filtration, it is also possible to remove impurities by using an adsorbent, or using filter filtration in combination with an adsorbent. A known adsorbent may be used as the adsorbent. For example, an inorganic adsorbent such as silica gel or zeolite, or an organic adsorbent such as activated carbon may be used.

The organic processing liquid of the present invention is usually used as a developer and/or a rinsing liquid. It is preferred that the organic processing liquid contains an organic solvent, and further contains an antioxidant and/or a surfactant. The organic solvent which is contained in the organic processing liquid, and the antioxidant and the surfactant which may be contained in the organic processing liquid will be described in detail in the description relating to a developer and a rinsing liquid to be described hereinafter.

Hereinafter, components which are contained in and components which may be contained in the developer and the rinsing liquid will be described in detail in the order of the developer and the rinsing liquid.

<Developer>

The developer, which is a kind of the organic processing liquid of the present invention, is used in a development step to be described hereinafter and can be an organic developer since it contains an organic solvent.

(Organic Solvent)

The vapor pressure of the organic solvent (or overall vapor pressure thereof in the case of a mixed solvent) at 20° C. is preferably 5 kPa or less, more preferably 3 kPa or less, and particularly preferably 2 kPa or less. By setting the vapor pressure of the organic solvent to 5 kPa or less, evaporation of the developer on a substrate or in a development cup is suppressed, the temperature uniformity in the wafer plane is improved, and as a result, the dimensional uniformity in the wafer plane is improved.

Various organic solvents are widely used as the organic solvent for use in the developer. For example, solvents such as an ester-based solvent, a ketone-based solvent, an alcohol-based solvent, an amide-based solvent, an ether-based solvent, and a hydrocarbon-based solvent may be used.

In the present invention, the ester-based solvent is a solvent having an ester group in the molecule, the ketone-based solvent is a solvent having a ketone group in the molecule, the alcohol-based solvent is a solvent having an alcoholic hydroxyl group in the molecule, the amide-based solvent is a solvent having an amide group in the molecule, and the ether-based solvent is a solvent having an ether bond in the molecule. Among these solvents, there is also a solvent having a plurality of the above-mentioned functional groups in one molecule, but in this case, such a solvent shall correspond to any solvent type containing the functional group possessed by the solvent. For example, it is assumed that diethylene glycol monomethyl ether shall also fall under any of an alcohol-based solvent and an ether-based solvent in the above-mentioned categories. The hydrocarbon-based solvent is a hydrocarbon-based solvent having no substituent.

In particular, preferred is a developer containing at least one solvent selected from a ketone-based solvent, an ester-based solvent, an alcohol-based solvent, and an ether-based solvent.

Examples of the ester-based solvent include methyl acetate, ethyl acetate, butyl acetate, isobutyl acetate, pentyl acetate, propyl acetate, isopropyl acetate, amyl acetate (pentyl acetate), isoamyl acetate (isopentyl acetate and 3-methylbutyl acetate), 2-methylbutyl acetate, 1-methylbutyl acetate, hexyl acetate, isohexyl acetate, heptyl acetate, octyl acetate, methoxyethyl acetate, ethoxyethyl acetate, propylene glycol monomethyl ether acetate (PGMEA; also known as 1-methoxy-2-acetoxypropane), ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monoethyl ether acetate, diethylene glycol monophenyl ether acetate, diethylene glycol monobutyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, butyl propionate, pentyl propionate, hexyl propionate, heptyl propionate, butyl butanoate, isobutyl butanoate, pentyl butanoate, hexyl butanoate, isobutyl isobutanoate, propyl pentanoate, isopropyl pentanoate, butyl pentanoate, pentyl pentanoate, ethyl hexanoate, propyl hexanoate, butyl hexanoate, isobutyl hexanoate, methyl heptanoate, ethyl heptanoate, propyl heptanoate, cyclohexyl acetate, cycloheptyl acetate, 2-ethylhexyl acetate, cyclopentyl propionate, 2-hydroxymethyl propionate, 2-hydroxyethyl propionate, methyl-3-methoxy propionate, ethyl-3-methoxy propionate, ethyl-3-ethoxy propionate, and propyl-3-methoxy propionate. Among these, preferred is butyl acetate, amyl acetate, isoamyl acetate, 2-methylbutyl acetate, 1-methylbutyl acetate, hexyl acetate, pentyl propionate, hexyl propionate, heptyl propionate, or butyl butanoate, and particularly preferred is isoamyl acetate.

Examples of the ketone-based solvent include 1-octanone, 2-octanone, 1-nonanone, 2-nonanone, acetone, 2-heptanone, 4-heptanone, 1-hexanone, 2-hexanone, diisobutyl ketone, cyclohexanone, methylcyclohexanone, phenyl acetone, methyl ethyl ketone, methyl isobutyl ketone, acetylacetone, acetonylacetone, ionone, diacetonyl alcohol, acetyl carbinol, acetophenone, methyl naphthyl ketone, isophorone, propylene carbonate, and γ-butyrolactone, among which preferred is 2-heptanone.

Examples of the alcohol-based solvent include an alcohol (monohydric alcohol), such as methanol, ethanol, 1-propanol, isopropanol, 1-butanol, 2-butanol, 3-methyl-1-butanol, tert-butyl alcohol, 1-pentanol, 2-pentanol, 1-hexanol, 1-heptanol, 1-octanol, 1-decanol, 2-hexanol, 2-heptanol, 2-octanol, 3-hexanol, 3-heptanol, 3-octanol, 4-octanol, 3-methyl-3-pentanol, cyclopentanol, 2,3-dimethyl-2-butanol, 3,3-dimethyl-2-butanol, 2-methyl-2-pentanol, 2-methyl-3-pentanol, 3-methyl-2-pentanol, 3-methyl-3-pentanol, 4-methyl-2-pentanol, 4-methyl-3-pentanol, cyclohexanol, 5-methyl-2-hexanol, 4-methyl-2-hexanol, 4,5-dimethyl-2-hexanol, 6-methyl-2-heptanol, 7-methyl-2-octanol, 8-methyl-2-nonanol, 9-methyl-2-decanol, or 3-methoxy-1-butanol; a glycol-based solvent, such as ethylene glycol, diethylene glycol, or triethylene glycol; and a glycol ether-based solvent containing a hydroxyl group, such as ethylene glycol monomethyl ether, propylene glycol monomethyl ether (PGME; also known as 1-methoxy-2-propanol), diethylene glycol monomethyl ether, triethylene glycol monoethyl ether, methoxymethyl butanol, ethylene glycol monoethyl ether, ethylene glycol monopropyl ether, ethylene glycol monobutyl ether, propylene glycol monoethyl ether, propylene glycol monopropyl ether, propylene glycol monobutyl ether, or propylene glycol monophenyl ether. Among these, preferred is a glycol ether-based solvent.

Examples of the ether-based solvent include, in addition to the glycol ether-based solvent containing a hydroxyl group, a glycol ether-based solvent containing no hydroxyl group, such as propylene glycol dimethyl ether, propylene glycol diethyl ether, dipropylene glycol dimethyl ether, dipropylene glycol diethyl ether, diethylene glycol dimethyl ether, or diethylene glycol diethyl ether; an aromatic ether-based solvent such as anisole or phenetole; a cycloaliphatic ether-based solvent such as dioxane, tetrahydrofuran, tetrahydropyran, perfluoro-2-butyl tetrahydrofuran, perfluorotetrahydrofuran, 1,4-dioxane, cyclopentyl isopropyl ether, cyclopentyl sec-butyl ether, cyclopentyl tert-butyl ether, cyclohexyl isopropyl ether, cyclohexyl sec-butyl ether, or cyclohexyl tert-butyl ether; an acyclic aliphatic ether-based solvent having a linear alkyl group, such as di-n-propyl ether, di-n-butyl ether, di-n-pentyl ether, or di-n-hexyl ether; and an acyclic aliphatic ether-based solvent having a branched alkyl group, such as diisohexyl ether, methylisopentyl ether, ethylisopentyl ether, propylisopentyl ether, diisopentyl ether, methylisobutyl ether, ethylisobutyl ether, propylisobutyl ether, diisobutyl ether, diisopropyl ether, ethylisopropyl ether, methylisopropyl ether, or diisohexyl ether. Preferred is a glycol ether-based solvent, or an aromatic ether-based solvent such as anisole.

Examples of the amide-based solvent include N-methyl-2-pyrrolidone, N,N-dimethylacetamide, N,N-dimethylformamide, hexamethylphosphoric triamide, and 1,3-dimethyl-2-imidazolidinone.

Examples of the hydrocarbon-based solvent include an aliphatic hydrocarbon-based solvent such as pentane, hexane, octane, nonane, decane, dodecane, undecane, hexadecane, 2,2,4-trimethylpentane, 2,2,3-trimethylhexane, perfluorohexane, or perfluoroheptane; and an aromatic hydrocarbon-based solvent such as toluene, xylene, ethylbenzene, propylbenzene, 1-methylpropylbenzene, 2-methylpropylbenzene, dimethylbenzene, diethylbenzene, ethylmethylbenzene, trimethylbenzene, ethyldimethylbenzene, or dipropylbenzene.

The aliphatic hydrocarbon-based solvent, which is a hydrocarbon-based solvent, may be a mixture of compounds having the same number of carbon atoms and a different structure. For example, in the case of using decane as the aliphatic hydrocarbon-based solvent, 2-methylnonane, 2,2-dimethyloctane, 4-ethyloctane, isooctane, and the like, which are compounds having the same number of carbon atoms and a different structure, may be included in the aliphatic hydrocarbon-based solvent.

The compounds having the same number of carbon atoms and a different structure may be included alone, or may be included as a plurality of compounds as described above.

From the viewpoint of being capable of suppressing swelling of a resist film in the case of using extreme ultraviolet (EUV) light and electron beams (EB) in an exposure step to be described hereinafter, the developer to be used is preferably an ester-based solvent having 7 or more carbon atoms (preferably 7 to 14 carbon atoms, more preferably 7 to 12 carbon atoms, and still more preferably 7 to 10 carbon atoms), and having 2 or less heteroatoms.

The heteroatom in the ester-based solvent is an atom other than a carbon atom and a hydrogen atom, and examples thereof include an oxygen atom, a nitrogen atom, and a sulfur atom. The number of heteroatoms is preferably 2 or less.

Preferred examples of the ester-based solvent having 7 or more carbon atoms and having 2 or less heteroatoms include amyl acetate, isoamyl acetate, 2-methylbutyl acetate, 1-methylbutyl acetate, hexyl acetate, pentyl propionate, hexyl propionate, heptyl propionate, and butyl butanoate, among which it is particularly preferred to use isoamyl acetate.

In the case of using extreme ultraviolet (EUV) light and electron beams (EB) in an exposure step to be described hereinafter, the developer to be used may be a mixed solvent of the above-mentioned ester-based solvent and the above-mentioned hydrocarbon-based solvent or a mixed solvent of the above-mentioned ketone-based solvent and the above-mentioned hydrocarbon-based solvent in place of the above-mentioned ester-based solvent having 7 or more carbon atoms and having 2 or less heteroatoms. Also in this case, it is effective in suppressing swelling of a resist film.

In the case where an ester-based solvent and a hydrocarbon-based solvent are used in combination, it is preferred to use isoamyl acetate as the ester-based solvent. From the viewpoint of preparing the solubility of a resist film, the hydrocarbon-based solvent to be used is preferably a saturated hydrocarbon-based solvent (for example, octane, nonane, decane, dodecane, undecane, or hexadecane).

In the case where a ketone-based solvent and a hydrocarbon-based solvent are used in combination, it is preferred to use 2-heptanone as the ketone-based solvent. From the viewpoint of preparing the solubility of a resist film, the hydrocarbon-based solvent to be used is preferably a saturated hydrocarbon-based solvent (for example, octane, nonane, decane, dodecane, undecane, or hexadecane).

In the case where the above-mentioned mixed solvent is used, the content of the hydrocarbon-based solvent depends on solvent solubility of a resist film and is not particularly limited. Therefore, the necessary amount of the hydrocarbon-based solvent may be determined by appropriately preparing such a mixed solvent.

The above-mentioned organic solvent may be used as a mixture of a plurality of solvents, or may be used in admixture with water or a solvent other than those described above. However, in order to fully achieve the effect of the present invention, it is preferred that the moisture content of the whole developer is less than 10 mass %, and it is more preferable that the developer is substantially free of water.

The concentration of the organic solvent (total concentration of solvents in the case of mixing a plurality of solvents) in the developer is preferably 50 mass % or more, more preferably 50 to 100 mass %, still more preferably 85 to 90 mass %, and particularly preferably 95 to 100 mass %. Most preferred is the case consisting of substantially only an organic solvent. The case consisting of substantially only an organic solvent is intended to include a case containing a trace amount of a surfactant, an antioxidant, a stabilizer, an anti-foaming agent, or the like.

The organic solvent used as a developer may be suitably, for example, an ester-based solvent. As the ester-based solvent, it is more preferred to use a solvent represented by General Formula (S1) to be described hereinafter or a solvent represented by General Formula (S2) to be described hereinafter, it is still more preferred to use a solvent represented by General Formula (S1), it is particularly preferred to use alkyl acetate, and it is most preferred to use butyl acetate, pentyl acetate, or isopentyl acetate.

R—C(═O)—O—R′ General Formula (S1)

In General Formula (S1), R and R′ each independently represent a hydrogen atom, an alkyl group, a cycloalkyl group, an alkoxyl group, an alkoxycarbonyl group, a carboxyl group, a hydroxyl group, a cyano group, or a halogen atom. R and R′ may be bonded to each other to form a ring.

The number of carbon atoms in the alkyl group, alkoxyl group, or alkoxycarbonyl group for R and R′ is preferably in the range of 1 to 15, and the number of carbon atoms in the cycloalkyl group is preferably 3 to 15.

R and R′ are preferably a hydrogen atom or an alkyl group. The alkyl group, cycloalkyl group, alkoxyl group, or alkoxycarbonyl group for R and R′, and the ring formed by bonding of R and R′ to each other may be substituted with a hydroxyl group, a group containing a carbonyl group (for example, an acyl group, an aldehyde group, or an alkoxycarbonyl group), a cyano group, or the like.

Examples of the solvent represented by General Formula (S1) include methyl acetate, butyl acetate, ethyl acetate, isopropyl acetate, amyl acetate, isoamyl acetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, 2-hydroxymethyl propionate, and 2-hydroxyethyl propionate.

Among these, R and R′ are preferably an unsubstituted alkyl group.

The solvent represented by General Formula (S1) is preferably alkyl acetate, more preferably butyl acetate, amyl acetate (pentyl acetate), or isoamyl acetate (isopentyl acetate), and still more preferably isoamyl acetate.

The solvent represented by General Formula (S1) may be used in combination with one or more other organic solvents. The solvent used in combination in this case is not particularly limited as long as it can be mixed without separation into the solvent represented by General Formula (S1). The solvents represented by General Formula (S1) may be used in combination thereof. Alternatively, the solvent represented by General Formula (S1) may be used in admixture with another solvent selected from an ester-based solvent, a ketone-based solvent, an alcohol-based solvent, an amide-based solvent, an ether-based solvent, and a hydrocarbon-based solvent. One or more types of solvents may be used as the solvent used in combination, but the solvent used in combination is preferably one type in order to obtain stable performance. In the case where one type of a solvent used in combination is mixed and used, the mixing ratio of the solvent represented by General Formula (S1) and the solvent used in combination therewith is usually 20:80 to 99:1, preferably 50:50 to 97:3, more preferably 60:40 to 95:5, and most preferably 60:40 to 90:10 by mass ratio.

As the organic solvent used as a developer, a glycol ether-based solvent may be used. The glycol ether-based solvent to be used may be a solvent represented by the following General Formula (S2).

R″—C(═O)—O—R′″—O—R″″ General Formula (S2)

In General Formula (S2),

R″ and R″″ each independently represent a hydrogen atom, an alkyl group, a cycloalkyl group, an alkoxyl group, an alkoxycarbonyl group, a carboxyl group, a hydroxyl group, a cyano group, or a halogen atom. R″ and R″″ may be bonded to each other to form a ring.

R″ and R″″ are preferably a hydrogen atom or an alkyl group. The number of carbon atoms in the alkyl group, alkoxyl group, or alkoxycarbonyl group for R″ and R″″ is preferably in the range of 1 to 15, and the number of carbon atoms in the cycloalkyl group is preferably 3 to 15.

R′″ represents an alkylene group or a cycloalkylene group. R′″ is preferably an alkylene group. The number of carbon atoms in the alkylene group for R′″ is preferably in the range of 1 to 10. The number of carbon atoms in the cycloalkylene group for R′″ is preferably in the range of 3 to 10.

The alkyl group, cycloalkyl group, alkoxyl group, or alkoxycarbonyl group for R″ and R″″, the alkylene group or cycloalkylene group for R′″, and the ring formed by bonding of R″ and R″″ to each other may be substituted with a hydroxyl group, a group containing a carbonyl group (for example, an acyl group, an aldehyde group, or an alkoxycarbonyl group), a cyano group, or the like.

In General Formula (S2), the alkylene group for R′″ may have an ether bond in the alkylene chain.

Examples of the solvent represented by General Formula (S2) include propylene glycol monomethyl ether acetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, propylene glycol monoethyl ether acetate, propylene glycol monopropyl ether acetate, methyl-3-methoxypropionate, ethyl-3-methoxypropionate, ethyl-3-ethoxypropionate, propyl-3-methoxypropionate, methoxyethyl acetate, ethoxyethyl acetate, 2-methoxybutyl acetate, 3-methoxybutyl acetate, 4-methoxybutyl acetate, 3-methyl-3-methoxybutyl acetate, 3-ethyl-3-methoxybutyl acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, and 4-methyl-4-methoxypentyl acetate, among which preferred is propylene glycol monomethyl ether acetate.

Among these, it is preferred that R″ and R″″ are an unsubstituted alkyl group and R′″ is an unsubstituted alkylene group, it is more preferred that R″ and R″″ are any one of a methyl group and an ethyl group, and it is still more preferred that R″ and R″″ are a methyl group.

The solvent represented by General Formula (S2) may be used in combination with one or more other organic solvents. The solvent used in combination in this case is not particularly limited as long as it can be mixed without separation into the solvent represented by General Formula (S2). The solvents represented by General Formula (S2) may be used in combination. Alternatively, the solvent represented by General Formula (S2) may be used in admixture with another solvent selected from an ester-based solvent, a ketone-based solvent, an alcohol-based solvent, an amide-based solvent, an ether-based solvent, and a hydrocarbon-based solvent. One or more types of solvents may be used as the solvent used in combination, but the solvent used in combination is preferably one type in order to obtain stable performance. In the case where one type of a solvent used in combination is mixed and used, the mixing ratio of the solvent represented by General Formula (S2) and the solvent used in combination therewith is usually 20:80 to 99:1, preferably 50:50 to 97:3, more preferably 60:40 to 95:5, and most preferably 60:40 to 90:10 by mass ratio.

The organic solvent used as a developer may also be suitably, for example, an ether-based solvent.

Examples of the ether-based solvent that can be used include the above-mentioned ether-based solvents, among which preferred is an ether-based solvent containing one or more aromatic rings, more preferred is a solvent represented by the following General Formula (S3), and most preferred is anisole.

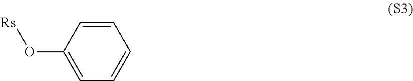

In General Formula (S3),

Rs represents an alkyl group. The alkyl group is preferably an alkyl group having 1 to 4 carbon atoms, more preferably a methyl group or an ethyl group, and most preferably a methyl group.

As the organic solvent contained in the developer of the present invention, it is possible to use an organic solvent used in an actinic ray-sensitive or radiation-sensitive composition to be described hereinafter.

(Surfactant)

The developer preferably contains a surfactant, which improves the wettability of a resist film and allows the development to proceed more effectively.

The surfactant to be used may be the same as the surfactant used in an actinic ray-sensitive or radiation-sensitive composition to be described hereinafter.

The content of the surfactant is usually 0.001 to 5 mass %, preferably 0.005 to 2 mass %, and still more preferably 0.01 to 0.5 mass %, with respect to the total mass of the developer.

(Antioxidant)

It is preferred that the developer contains an antioxidant so that the generation of an oxidant over time can be suppressed and the content of the oxidant can be further reduced.

A known antioxidant may be used as the antioxidant. In the case where the antioxidant is used for semiconductor applications, an amine-based antioxidant or a phenol-based antioxidant is preferably used.

Examples of the amine-based antioxidant include a naphthylamine-based antioxidant such as 1-naphthylamine, phenyl-1-naphthylamine, p-octylphenyl-1-naphthylamine, p-nonylphenyl-1-naphthylamine, p-dodecylphenyl-1-naphthylamine, or phenyl-2-naphthylamine; a phenylenediamine-based antioxidant such as N,N′-diisopropyl-p-phenylenediamine, N,N′-diisobutyl-p-phenylenediamine, N,N′-diphenyl-p-phenylenediamine, N,N′-di-β-naphthyl-p-phenylenediamine, N-phenyl-N′-isopropyl-p-phenylenediamine, N-cyclohexyl-N′-phenyl-p-phenylenediamine, N-1,3-dimethylbutyl-N′-phenyl-p-phenylenediamine, dioctyl-p-phenylenediamine, phenylhexyl-p-phenylenediamine, or phenyloctyl-p-phenylenediamine; a diphenylamine-based antioxidant such as dipyridylamine, diphenylamine, p,p′-di-n-butyldiphenylamine, p,p′-di-t-butyldiphenylamine, p,p′-di-t-pentyldiphenylamine, p,p′-dioctyldiphenylamine, p,p′-dinonyldiphenylamine, p,p′-didecyldiphenylamine, p,p′-didodecyldiphenylamine, p,p′-distyryldiphenylamine, p,p′-dimethoxydiphenylamine, 4,4′-bis(4-α,α-dimethylbenzoyl)diphenylamine, p-isopropoxydiphenylamine, or dipyridyl amine; and a phenothiazine-based antioxidant such as phenothiazine, N-methylphenothiazine, N-ethylphenothiazine, 3,7-dioctylphenothiazine, phenothiazine carboxylic acid ester, or phenoselenazine.

Examples of the phenol-based antioxidant include 2,6-ditertiarybutylphenol (hereinafter, tertiary butyl is simply referred to as t-butyl), 2,6-di-t-butyl-p-cresol, 2,6-di-t-butyl-4-methylphenol, 2,6-di-t-butyl-4-ethylphenol, 2,4-dimethyl-6-t-butylphenol, 4,4′-methylene bis(2,6-di-t-butylphenol), 4,4′-bis(2,6-di-t-butylphenol), 4,4′-bis(2-methyl-6-t-butylphenol), 2,2′-methylene bis(4-methyl-6-t-butylphenol), 2,2′-methylene bis(4-ethyl-6-t-butylphenol), 4,4′-butylidene bis(3-methyl-6-t-butylphenol), 4,4′-isopropylidene bis(2,6-di-t-butylphenol), 2,2′-methylene bis(4-methyl-6-cyclohexylphenol), 2,2′-methylene bis(4-methyl-6-nonylphenol), 2,2′-isobutylidene bis(4,6-dimethylphenol), 2,6-bis(2′-hydroxy-3′-t-butyl-5′-methylbenzyl)-4-methylphenol, 3-t-butyl-4-hydroxyanisole, 2-t-butyl-4-hydroxyanisole, octyl 3-(4-hydroxy-3,5-di-t-butylphenyl)propionate, stearyl 3-(4-hydroxy-3,5-di-t-butylphenyl)propionate, oleyl 3-(4-hydroxy-3,5-di-t-butylphenyl)propionate, dodecyl 3-(4-hydroxy-3,5-di-t-butylphenyl)propionate, decyl 3-(4-hydroxy-3,5-di-t-butylphenyl)propionate, octyl 3-(4-hydroxy-3,5-di-t-butylphenyl)propionate, tetrakis {3-(4-hydroxy-3,5-di-t-butylphenyl)propionyloxymethyl}methane, 3-(4-hydroxy-3,5-di-t-butylphenyl) propionic acid glycerin monoester, ester of 3-(4-hydroxy-3,5-di-t-butylphenyl) propionic acid and glycerin monooleyl ether, 3-(4-hydroxy-3,5-di-t-butylphenyl) propionic acid butylene glycol diester, 3-(4-hydroxy-3,5-di-t-butylphenyl) propionic acid thiodiglycol diester, 4,4′-thiobis(3-methyl-6-t-butylphenol), 4,4′-thiobis(2-methyl-6-t-butylphenol), 2,2′-thiobis(4-methyl-6-t-butylphenol), 2,6-di-t-butyl-α-dimethylamino-p-cresol, 2,6-di-t-butyl-4-(N,N′-dimethylaminomethylphenol), bis(3,5-di-t-butyl-4-hydroxybenzyl)sulfide, tris{(3,5-di-t-butyl-4-hydroxyphenyl)propionyl-oxyethyl}isocyanurate, tris(3,5-di-t-butyl-4-hydroxyphenyl)isocyanurate, 1,3,5-tris(3,5-di-t-butyl-4-hydroxybenzyl)isocyanurate, bis{2-methyl-4-(3-n-alkylthiopropionyloxy)-5-t-butylphenyl}sulfide, 1,3,5-tris(4-t-butyl-3-hydroxy-2,6-dimethylbenzyl)isocyanurate, tetraphthaloyl-di(2,6-dimethyl-4-t-butyl-3-hydroxybenzylsulfide), 6-(4-hydroxy-3,5-di-t-butylanilino)-2,4-bis(octylthio)-1,3,5-triazine, 2,2-thio-{diethyl-bis-3-(3,5-di-t-butyl-4-hydroxyphenyl)}propionate, N,N′-hexamethylene bis(3,5-di-t-butyl-4-hydroxy-hydrocinnamate), 3,9-bis[1,1-dimethyl-2-{β-(3-t-butyl-4-hydroxy-5-methylphenyl)propionyloxy}ethyl]-2,4,8,10-tetraoxaspiro[5,5]undecane, 1,1,3-tris(2-methyl-4-hydroxy-5-t-butylphenyl)butane, 1,3,5-trimethyl-2,4,6-tris(3,5-di-t-butyl-4-hydroxybenzyl)benzene, and bis{3,3′-bis-(4′-hydroxy-3′-t-butylphenyl)butyric acid}glycol ester.

The content of the antioxidant is not particularly limited, but it is preferably 0.0001 to 1 mass %, more preferably 0.0001 to 0.1 mass %, and still more preferably 0.0001 to 0.01 mass %, with respect to the total mass of the developer. If the content of the antioxidant is 0.0001 mass % or more, a superior antioxidant effect is obtained. If the content of the antioxidant is 1 mass % or less, there is a tendency that generation of development residues can be suppressed.

The developer of the present invention preferably contains a basic compound. Specific examples of the basic compound include the compounds exemplified as a basic compound that can be contained in an actinic ray-sensitive or radiation-sensitive composition to be described hereinafter.

Among the basic compounds which may be included in the developer of the present invention, the following nitrogen-containing compound may be preferably used.

In the case where the nitrogen-containing compound is contained in the developer, the nitrogen-containing compound can interact with polar groups generated in a resist film by the action of an acid to thereby further improve the insolubility of the exposed portion in an organic solvent. Here, the interaction between the nitrogen-containing compound and the polar groups refers to an action in which the nitrogen-containing compound and the polar groups react to form a salt, an ionic bond, or the like.

The nitrogen-containing compound is preferably a compound represented by Formula (1).

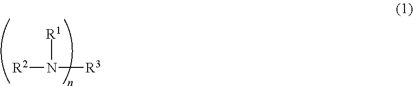

In Formula (1), R¹ and R² are each independently a hydrogen atom, a hydroxyl group, a formyl group, an alkoxy group, an alkoxycarbonyl group, a chain-like hydrocarbon group having 1 to 30 carbon atoms, an alicyclic hydrocarbon group having 3 to 30 carbon atoms, an aromatic hydrocarbon group having 6 to 14 carbon atoms, or a group formed by combining two or more of these groups. R³ is a hydrogen atom, a hydroxyl group, a formyl group, an alkoxy group, an alkoxycarbonyl group, an n-valent chain-like hydrocarbon group having 1 to 30 carbon atoms, an n-valent alicyclic hydrocarbon group having 3 to 30 carbon atoms, an n-valent aromatic hydrocarbon group having 6 to 14 carbon atoms, or an n-valent group formed by combining two or more of these groups. n is an integer of 1 or more. However, when n is 2 or more, a plurality of R¹'s and R²'s may be respectively the same or different from one another. In addition, any two of R¹ to R³, taken together with the nitrogen atom to which each is bonded, may form a ring structure.

Examples of the chain-like hydrocarbon group having 1 to 30 carbon atoms represented by R¹ and R² include a methyl group, an ethyl group, an n-propyl group, an i-propyl group, an n-butyl group, a 2-methylpropyl group, a 1-methylpropyl group, and a t-butyl group.

Examples of the alicyclic hydrocarbon group having 3 to 30 carbon atoms represented by R¹ and R² include a cyclopropyl group, a cyclopentyl group, a cyclohexyl group, an adamantyl group, and a norbornyl group.

Examples of the aromatic hydrocarbon group having 6 to 14 carbon atoms represented by R¹ and R² include a phenyl group, a tolyl group, and a naphthyl group.

Examples of the group formed by combining two or more of those groups represented by R¹ and R² include aralkyl groups having 6 to 12 carbon atoms, such as a benzyl group, a phenethyl group, a naphthylmethyl group, and a naphthylethyl group.

Examples of the n-valent chain-like hydrocarbon group having 1 to 30 carbon atoms represented by R³ include groups formed by removing an (n−1) number of hydrogen atoms from the same groups as those groups exemplified as the chain-like hydrocarbon group having 1 to 30 carbon atoms represented by R¹ and R².

Examples of the alicyclic hydrocarbon group having 3 to 30 carbon atoms represented by R³ include groups formed by removing an (n−1) number of hydrogen atoms from the same groups as those groups exemplified as the cyclic hydrocarbon group having 3 to 30 carbon atoms represented by R¹ and R².

Examples of the aromatic hydrocarbon group having 6 to 14 carbon atoms represented by R³ include groups formed by removing an (n−1) number of hydrogen atoms from the same groups as those groups exemplified as the aromatic hydrocarbon group having 6 to 14 carbon atoms represented by R¹ and R².

Examples of the group formed by combining two or more of those groups represented by R³ include groups formed by removing an (n−1) number of hydrogen atoms from the same groups as those groups exemplified as the group formed by combining two or more of those groups represented by R¹ and R².

The groups represented by R¹ to R³ may be substituted. Specific examples of the substituent include a methyl group, an ethyl group, a propyl group, an n-butyl group, a t-butyl group, a hydroxyl group, a carboxy group, a halogen atom, and an alkoxy group. Examples of the halogen atom include a fluorine atom, a chlorine atom, and a bromine atom. Examples of the alkoxy group include a methoxy group, an ethoxy group, a propoxy group, and a butoxy group.

Examples of the compound represented by Formula (1) include a (cyclo)alkylamine compound, a nitrogen-containing heterocyclic compound, an amide group-containing compound, and a urea compound.

Examples of the (cyclo)alkylamine compound include a compound having one nitrogen atom, a compound having two nitrogen atoms, and a compound having three or more nitrogen atoms.

Examples of the (cyclo)alkylamine compound having one nitrogen atom include mono(cyclo)alkylamines such as n-hexylamine, n-heptylamine, n-octylamine, n-nonylamine, 1-aminodecane, and cyclohexylamine; di(cyclo)alkylamines such as di-n-butylamine, di-n-pentylamine, di-n-hexylamine, di-n-heptylamine, di-n-octylamine, di-n-nonylamine, di-n-decylamine, cyclohexylmethylamine, and dicyclohexylamine; tri(cyclo)alkylamines such as triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, cyclohexyldimethylamine, methyldicyclohexylamine, and tricyclohexylamine; substituted alkylamines such as triethanolamine; and aromatic amines such as aniline, N-methylaniline, N,N-dimethylaniline, 2-methylaniline, 3-methylaniline, 4-methylaniline, N,N-dibutylaniline, 4-nitroaniline, diphenylamine, triphenylamine, naphthylamine, 2,4,6-tri-tert-butyl-N-methylaniline, N-phenyldiethanolamine, 2,6-diisopropylaniline, 2-(4-aminophenyl)-2-(3-hydroxyphenyl)propane, and 2-(4-aminophenyl)-2-(4-hydroxyphenyl)propane.

Examples of the (cyclo)alkylamine compound having two nitrogen atoms include ethylenediamine, tetramethylethylenediamine, tetramethylenediamine, hexamethylenediamine, 4,4′-diaminodiphenylmethane, 4,4′-diaminodiphenylether, 4,4′-diaminobenzophenone, 4,4′-diaminodiphenylamine, 2,2-bis(4-aminophenyl)propane, 2-(3-aminophenyl)-2-(4-aminophenyl)propane, 1,4-bis[1-(4-aminophenyl)-1-methylethyl]benzene, 1,3-bis[1-(4-aminophenyl)-1-methylethyl]benzene, bis(2-dimethylaminoethyl)ether, bis(2-diethylaminoethyl)ether, 1-(2-hydroxyethyl)-2-imidazolidinone, 2-quinoxalinol, and N,N,N′,N′-tetrakis(2-hydroxypropyl)ethylenediamine.

Examples of the (cyclo)alkylamine compound having three or more nitrogen atoms include polymers such as polyethyleneimine, polyallylamine, and 2-dimethylaminoethylacrylamide.

Examples of the nitrogen-containing heterocyclic compound include a nitrogen-containing aromatic heterocyclic compound and a nitrogen-containing aliphatic heterocyclic compound.

Examples of the nitrogen-containing aromatic heterocyclic compound include imidazoles such as imidazole, 4-methylimidazole, 4-methyl-2-phenylimidazole, benzimidazole, 2-phenylbenzimidazole, 1-benzyl-2-methylimidazole, and 1-benzyl-2-methyl-1H-imidazole; and pyridines such as pyridine, 2-methylpyridine, 4-methylpyridine, 2-ethylpyridine, 4-ethylpyridine, 2-phenylpyridine, 4-phenylpyridine, 2-methyl-4-phenylpyridine, nicotine, nicotinic acid, nicotinic acid amide, quinoline, 4-hydroxyquinoline, 8-oxyquinoline, acridine, and 2,2′:6′,2″-terpyridine.

Examples of the nitrogen-containing aliphatic heterocyclic compound include piperazines such as piperazine and 1-(2-hydroxyethyl)piperazine; pyrazine, pyrazole, pyridazine, quinoxaline, purine, pyrrolidine, proline, piperidine, piperidineethanol, 3-piperidino-1,2-propanediol, morpholine, 4-methylmorpholine, 1-(4-morpholinyl)ethanol, 4-acetylmorpholine, 3-(N-morpholino)-1,2-propanediol, 1,4-dimethylpiperazine, and 1,4-diazabicyclo[2.2.2]octane.

Examples of the amide group-containing compound include N-t-butoxycarbonyl group-containing amino compounds such as N-t-butoxycarbonyldi-n-octylamine, N-t-butoxycarbonyldi-n-nonylamine, N-t-butoxycarbonyldi-n-decylamine, N-t-butoxycarbonyldicyclohexylamine, N-t-butoxycarbonyl-1-adamantylamine, N-t-butoxycarbonyl-2-adamantylamine, N-t-butoxycarbonyl-N-methyl-1-adamantylamine, (S)-(−)-1-(t-butoxycarbonyl)-2-pyrrolidinemethanol, (R)-(+)-1-(t-butoxycarbonyl)-2-pyrrolidinemethanol, N-t-butoxycarbonyl-4-hydroxypiperidine, N-t-butoxycarbonylpyrrolidine, N-t-butoxycarbonylpiperazine, N,N-di-t-butoxycarbonyl-1-adamantylamine, N,N-di-t-butoxycarbonyl-N-methyl-1-adamantylamine, N-t-butoxycarbonyl-4,4′-diaminodiphenylmethane, N,N′-di-t-butoxycarbonyl hexamethylenediamine, N,N,N′,N′-tetra-t-butoxycarbonyl hexamethylenediamine, N,N′-di-t-butoxycarbonyl-1,7-diaminoheptane, N,N′-di-t-butoxycarbonyl-1,8-diaminooctane, N,N′-di-t-butoxycarbonyl-1,9-diaminononane, N,N′-di-t-butoxycarbonyl-1,10-diaminodecane, N,N′-di-t-butoxycarbonyl-1,12-diaminododecane, N,N′-di-t-butoxycarbonyl-4,4′-diaminodiphenylmethane, N-t-butoxycarbonylbenzimidazole, N-t-butoxycarbonyl-2-methylbenzimidazole, and N-t-butoxycarbonyl-2-phenylbenzimidazole; formamide, N-methylformamide, N,N-dimethylformamide, acetamide, N-methylacetamide, N,N-dimethylacetamide, propionamide, benzamide, pyrrolidone, N-methylpyrrolidone, N-acetyl-1-adamantylamine, and tris(2-hydroxyethyl) isocyanurate.

Examples of the urea compound include urea, methylurea, 1,1-dimethylurea, 1,3-dimethylurea, 1,1,3,3-tetramethylurea, 1,3-diphenylurea, and tri-n-butylthiourea.

Among the above-mentioned nitrogen-containing compounds, a nitrogen-containing compound having an SP value of 18 or less is preferably used from the viewpoint of suppressing development defects. This is because the nitrogen-containing compound having an SP value of 18 or less has a good affinity with a rinsing liquid used in a rinsing process to be described hereinafter and is therefore capable of suppressing the occurrence of development defects such as precipitation.

The SP value of the nitrogen-containing compound used in the present invention is calculated using the Fedors method described in “Properties of Polymers, 2^{nd} edition, 1976”. The calculation formula used and the parameters of each substituent are shown below.

SP value (Fedors method)=[(sum of cohesive energies of individual substituents)/(sum of volumes of individual substituents)]^{0.5}

TABLE 1

| | Cohesive | | | Cohesive | |
|---|---|---|---|---|---|
| | energy | Volume | Sub- | energy | Volume |
| Substituent | (J/mol) | (cm³/mol) | stituent | (J/mol) | (cm³/mol) |
| CH₃ | 4,710 | 33.5 | CN | 25530 | 24 |
| CH₂ | 4,940 | 16.1 | OH | 29800 | 10 |
| CH | 3,430 | −1 | CHO | 21350 | 22.3 |
| C | 1,470 | −19.2 | COOH | 27630 | 28.5 |
| CH₂═ | 4,310 | 28.5 | —O— | 3350 | 3.8 |
| ═CH— | 4,310 | 13.5 | CO | 17370 | 10.8 |
| ═C< | 4,310 | −5.5 | COO | 18000 | 18 |
| Ph | 31,940 | 71.4 | 5 or | 1050 | 16 |
| | | | more- | | |
| | | | membered | | |
| | | | ring | | |
| NH₂ | 12,560 | 19.2 | | | |
| NH | 8,370 | 4.5 | | | |
| N< | 4,190 | −9 | | | |

Fedors substituent constants extracted (Properties of Polymers, 2^{nd} edition, pp 138 to 140)

Preferred is a (cyclo)alkylamine compound or nitrogen-containing aliphatic heterocyclic compound satisfying the above-mentioned conditions (SP value), and more preferred is 1-aminodecane, di-n-octylamine, tri-n-octylamine, or tetramethylethylenediamine. SP values and the like of these nitrogen-containing aliphatic heterocyclic compounds are shown in the following table.

TABLE 2

| | | | | | | SP |
|---|---|---|---|---|---|---|
| | CH₃ | CH₂ | NH₂ | NH | N | value |
| 1-aminodecane | 1 | 9 | 1 | | | 17.7 |
| di-n-octylamine | 2 | 14 | | 1 | | 17.1 |
| tri-n-octylamine | 3 | 21 | | | 1 | 16.9 |
| tetramethylethylene- | 4 | 2 | | | 2 | 15.8 |
| diamine | | | | | | |

The content of the basic compound (preferably, nitrogen-containing compound) in the developer is not particularly limited, but it is preferably 10 mass % or less and more preferably 0.5 to 5 mass %, with respect to the total amount of the developer, from the viewpoint of a superior effect of the present invention.

In the present invention, the above-mentioned nitrogen-containing compounds may be used alone or in combination of two or more compounds having a different chemical structure.

<Rinsing Liquid>

The rinsing liquid which is a kind of the organic processing liquid of the present invention is used in a rinsing step to be described hereinafter, and can also be an organic rinsing liquid since it contains an organic solvent. This rinsing liquid is used in “cleaning” of a resist film (that is, “rinsing” of the resist film) using the organic processing liquid of the present invention.

The vapor pressure of the rinsing liquid (overall vapor pressure thereof in the case of being a mixed solvent) at 20° C. is preferably 0.05 kPa or more and 5 kPa or less, more preferably 0.1 kPa or more and 5 kPa or less, and most preferably 0.12 kPa or more and 3 kPa or less. When the vapor pressure of the rinsing liquid is set to 0.05 kPa or more and 5 kPa or less, temperature uniformity in the wafer plane is improved, the swelling due to permeation of the rinsing liquid is further suppressed, and the dimensional uniformity in the wafer plane is improved.

(Organic Solvent)

Various organic solvents are used as the organic solvent to be contained in the rinsing liquid of the present invention. It is preferred to use at least one organic solvent selected from the group consisting of a hydrocarbon-based solvent, a ketone-based solvent, an ester-based solvent, an alcohol-based solvent, an amide-based solvent, and an ether-based solvent.

Specific examples of these organic solvents are the same as the organic solvents described in the section <Developer>.

With regard to the organic solvent contained in the rinsing liquid, in the case of using EUV light (extreme ultraviolet) or EB (electron beam) in an exposure step to be described hereinafter, it is preferred to use a hydrocarbon-based solvent among the above-mentioned organic solvents and it is more preferred to use an aliphatic hydrocarbon-based solvent. From the viewpoint of the effect being more improved, the aliphatic hydrocarbon-based solvent used in the rinsing liquid is preferably an aliphatic hydrocarbon-based solvent having 5 or more carbon atoms (for example, pentane, hexane, octane, decane, undecane, dodecane, or hexadecane), more preferably an aliphatic hydrocarbon-based solvent having 8 or more carbon atoms, and still more preferably an aliphatic hydrocarbon-based solvent having 10 or more carbon atoms.

The upper limit of the number of carbon atoms of the aliphatic hydrocarbon-based solvent is not particularly limited, but it may be, for example, 16 or less, preferably 14 or less, and more preferably 12 or less.

Among the aliphatic hydrocarbon-based solvents, particularly preferred is decane, undecane or dodecane, and most preferred is undecane.

Thus, by using a hydrocarbon-based solvent (especially an aliphatic hydrocarbon-based solvent) as the organic solvent contained in the rinsing liquid, the developer which has been slightly impregnated into the resist film after the development is washed away to further exert the effects of further suppressing the swelling and suppressing the pattern collapse.

It is preferred to use at least one selected from the group consisting of the above-mentioned ester-based solvent and the above-mentioned ketone-based solvent as the organic solvent contained in the rinsing liquid, from the viewpoint that it is particularly effective to reduce post-development residues.

In the case where the rinsing liquid contains at least one selected from the group consisting of an ester-based solvent and a ketone-based solvent, it is preferred to contain at least one solvent selected from the group consisting of butyl acetate, isopentyl acetate, n-pentyl acetate, 3-ethoxyethyl propionate (EEP, ethyl-3-ethoxypropionate), diisobutyl ketone, and 2-heptanone as a main component, and it is particularly preferred to contain at least one solvent selected from the group consisting of butyl acetate and 2-heptanone as a main component.

Further, in the case where the rinsing liquid contains at least one selected from the group consisting of an ester-based solvent and a ketone-based solvent, it is preferred to contain a solvent selected from the group consisting of an ester-based solvent, a glycol ether-based solvent, a ketone-based solvent, and an alcohol-based solvent as a minor component, among which preferred is a solvent selected from the group consisting of propylene glycol monomethyl ether acetate (PGMEA), propylene glycol monomethyl ether (PGME), ethyl acetate, ethyl lactate, 3-methoxymethyl propionate, cyclohexanone, methyl ethyl ketone, γ-butyrolactone, propanol, 3-methoxy-1-butanol, N-methylpyrrolidone, and propylene carbonate.

Among these, in the case of using an ester-based solvent as the organic solvent, it is preferred to use two or more ester-based solvents from the viewpoint of the above-mentioned effects being further exerted. A specific example of this case is a case where an ester-based solvent (preferably, butyl acetate) is used as a main component and another ester-based solvent (preferably, propylene glycol monomethyl ether acetate (PGMEA)) whose chemical structure is different from that of the main component ester-based solvent is used as a minor component.

In the case of using an ester-based solvent as the organic solvent, a glycol ether-based solvent in addition to an ester-based solvent (one or two or more types) may be used from the viewpoint of the above-mentioned effects being further exerted. A specific example of this case is a case where an ester-based solvent (preferably, butyl acetate) is used as a main component and a glycol ether-based solvent (preferably, propylene glycol monomethyl ether (PGME)) is used as a minor component.

In the case of using a ketone-based solvent as the organic solvent, an ester-based solvent and/or a glycol ether-based solvent in addition to a ketone-based solvent (one or two or more types) may be used from the viewpoint of the above-mentioned effects being further exerted. A specific example of this case is a case where a ketone-based solvent (preferably, 2-heptanone) is used as a main component and an ester-based solvent (preferably, propylene glycol monomethyl ether acetate (PGMEA)) and/or a glycol ether-based solvent (preferably, propylene glycol monomethyl ether (PGME)) is used as a minor component.

In the case of using a ketone-based solvent as the organic solvent, at least one of the above-mentioned hydrocarbon-based solvent or the above-mentioned ether-based solvent may be used in addition to a ketone-based solvent (one or two or more types).

The above-mentioned ether-based solvent may also be suitably used as the organic solvent contained in the rinsing liquid. The ether-based solvents may be used alone or in combination of two or more thereof.

From the viewpoint of in-plane uniformity of a wafer, the ether-based solvent is preferably an acyclic aliphatic ether-based solvent having 8 to 12 carbon atoms, and more preferably an acyclic aliphatic ether-based solvent having a branched alkyl group having 8 to 12 carbon atoms. Particularly preferred are diisobutyl ether, diisopentyl ether, and diisohexyl ether.

In the case of using an ether-based solvent as the organic solvent, at least one selected from the group consisting of the above-mentioned hydrocarbon-based solvent, the above-mentioned ester-based solvent, the above-mentioned ketone-based solvent, and the above-mentioned alcohol-based solvent may be used in addition to an ether-based solvent (one or two or more types).

As used herein, the term “main component” refers to that the content with respect to the total mass of the organic solvent is 50 to 100 mass %, preferably 70 to 100 mass %, more preferably 80 to 100 mass %, still more preferably 90 to 100 mass %, and particularly preferably 95 to 100 mass %.

Further, in the case of containing a minor component, the content of the minor component is preferably 0.1 to 20 mass %, more preferably 0.5 to 10 mass %, and still more preferably 1 to 5 mass %, with respect to the total mass of the main component (100 mass %).

A plurality of organic solvents may be mixed, or the organic solvent may be used in admixture with an organic solvent other than those described above. The above-mentioned solvent may be mixed with water, but the moisture content in the rinsing liquid is usually 60 mass % or less, preferably 30 mass % or less, still more preferably 10 mass % or less, and most preferably 5 mass % or less. By setting the moisture content to 60 mass % or less, good rinsing properties can be obtained.

The rinsing liquid preferably contains a surfactant. Thereby, the wettability to a resist film is improved, and the cleaning effects tend to be further improved.

As the surfactant, use can be made of the same surfactants as those used in an actinic ray-sensitive or radiation-sensitive composition to be described hereinafter.

The content of the surfactant is usually 0.001 to 5 mass %, preferably 0.005 to 2 mass %, and still more preferably 0.01 to 0.5 mass %, with respect to the total mass of the rinsing liquid.

The rinsing liquid preferably contains an antioxidant. Thereby, generation of an oxidant over time can be suppressed, and the content of the oxidant can be further reduced. Specific examples and the content of the antioxidant are as described in the section <Developer>.

[Pattern Forming Method]

The pattern forming method of the present invention includes a resist film forming step of forming a resist film using an actinic ray-sensitive or radiation-sensitive composition, an exposure step of exposing the resist film, and a treatment step of treating the exposed resist film with the above-mentioned organic processing liquid (organic processing liquid in which the content of an oxidant is 10 mmol/L or less).

According to the pattern forming method of the present invention, the occurrence of defects in resist patterns can be suppressed since the above-mentioned organic processing liquid is used.

Hereinafter, individual steps in the pattern forming method of the present invention will be described. As an example of the treatment step, each of a development step and a rinsing step will be described.

Hereinafter, the actinic ray-sensitive or radiation-sensitive composition used in the pattern forming method of the present invention is also referred to as a “composition of the present invention” or “resist composition of the present invention”.

<Resist Film Forming Step>

The resist film forming step is a step of forming a resist film using the resist composition of the present invention and can be carried out by, for example, the following method.

To form a resist film (actinic ray-sensitive or radiation-sensitive composition film) on a substrate using the resist composition of the present invention, individual components to be described hereinafter are dissolved in a solvent to prepare the resist composition of the present invention which is then subjected to filtration if necessary and is applied onto the substrate. The filter is preferably a filter made of polytetrafluoroethylene, polyethylene or nylon and having a pore size of 0.1 micron or less, more preferably 0.05 micron or less, and still more preferably 0.03 micron or less.

The resist composition of the present invention is applied onto a substrate (for example, silicon or silicon dioxide-coated) used in the production of an integrated circuit element, by a suitable application method such as a spinner. This is followed by drying to form a resist film. If necessary, various underlying films (an inorganic film, an organic film, and an antireflection film) may be formed on the underlayer of the resist film.

As the drying method, a method of drying by heating is generally used. The heating may be carried out by a means provided in a conventional exposure/development machine, and may also be carried out using a hot plate or the like. The heating temperature is preferably 80° C. to 150° C., more preferably 80° C. to 140° C., and still more preferably 80° C. to 130° C. The heating time is preferably 30 to 1000 seconds, more preferably 60 to 800 seconds, and still more preferably 60 to 600 seconds.

The film thickness of the resist film is generally 200 nm or less and preferably 100 nm or less.

For example, in order to resolve a 1:1 line and space pattern having a size of 30 nm or less, the film thickness of the resist film to be formed is preferably 50 nm or less. If the film thickness is 50 nm or less, pattern collapse becomes less likely to occur when applying a development step to be described hereinafter, and therefore a superior resolution performance is obtained.

The film thickness is more preferably in the range of 15 nm to 45 nm. If the film thickness is 15 nm or more, a sufficient etching resistance is obtained. The film thickness is still more preferably in the range of 15 nm to 40 nm. If the film thickness is within this range, it is possible to satisfy an etching resistance and a superior resolution performance at the same time.

In the pattern forming method of the present invention, a topcoat may be formed on the upper layer of the resist film. It is preferred that the topcoat is not mixed with the resist film and can be uniformly coated on the upper layer of the resist film.

The topcoat is not particularly limited. A conventionally known topcoat may be formed by a conventionally known method. For example, the topcoat may be formed on the basis of the description in paragraphs [0072] to [0082] of JP2014-059543A.

In the case of using a developer containing an organic solvent in the development step, for example, it is preferred to form a topcoat containing a basic compound as described in JP2013-61648A on a resist film. Specific examples of the basic compound which may be contained in the topcoat will be described later as a basic compound (E).

The topcoat preferably contains a compound containing at least one group or bond selected from the group consisting of an ether bond, a thioether bond, a hydroxyl group, a thiol group, a carbonyl bond and an ester bond (hereinafter, also referred to as “compound (A2)”).

In one embodiment of the present invention, the compound (A2) preferably has two or more groups or bonds selected from the foregoing group, and more preferably has three or more groups or bonds selected from the foregoing group, and still more preferably has four or more groups or bonds selected from the foregoing group. In this case, the groups or bonds selected from the group consisting of an ether bond, a thioether bond, a hydroxyl group, a thiol group, a carbonyl bond and an ester bond, which are present in plurality in the compound (A2), may be the same or different from one another.

In one embodiment of the present invention, the compound (A2) preferably has a molecular weight of 3000 or less, more preferably 2500 or less, still more preferably 2000 or less, and particularly preferably 1500 or less.

Further, in one embodiment of the present invention, the number of carbon atoms contained in the compound (A2) is preferably 8 or more, more preferably 9 or more, and still more preferably 10 or more.

Further, in one embodiment of the present invention, the number of carbon atoms contained in the compound (A2) is preferably 30 or less, more preferably 20 or less, and still more preferably 15 or less.

Further, in one embodiment of the present invention, the compound (A2) is preferably a compound having a boiling point of 200° C. or higher, more preferably a compound having a boiling point of 220° C. or higher, and still more preferably a compound having a boiling point of 240° C. or higher.

Further, in one embodiment of the present invention, the compound (A2) is preferably a compound having an ether bond, more preferably a compound having two or more ether bonds, still more preferably a compound having three or more ether bonds, and even more preferably a compound having four or more ether bonds.

In one embodiment of the present invention, the compound (A2) more preferably contains a repeating unit containing an oxyalkylene structure represented by the following General Formula (1).

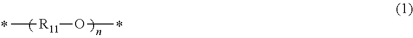

In the formula,

R₁₁ represents an alkylene group which may have a substituent,

n represents an integer of 2 or more, and

* represents a bond.

The number of carbon atoms in the alkylene group represented by R₁₁ in General Formula (1) is not particularly limited, but it is preferably 1 to 15, more preferably 1 to 5, still more preferably 2 or 3, and particularly preferably 2. In the case where this alkylene group has a substituent, the substituent is not particularly limited and is preferably, for example, an alkyl group (preferably having 1 to 10 carbon atoms).

n is preferably an integer of 2 to 20. n is more preferably 10 or less for the reason that the depth of focus (DOF) becomes larger.

The average value of n is preferably 20 or less, more preferably 2 to 10, still more preferably 2 to 8, and particularly preferably 4 to 6 for the reason that DOF becomes larger. Here, the “average value of n” refers to a value of n determined so that the weight-average molecular weight of the compound (A2) is measured by Gel Permeation Chromatography (GPC) and the general formula matches the obtained weight-average molecular weight. In the case where n is not an integer, the value shall be rounded off.

A plurality of R₁₁'s may be the same or different from one another.

Further, the compound having a partial structure represented by General Formula (1) is preferably a compound represented by the following General Formula (1-1) for the reason that DOF becomes larger.

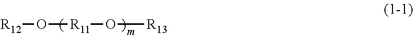

In the formula, the definition, specific examples and preferred embodiments of R₁₁ are the same as R₁₁ in the above-mentioned General Formula (1).

R₁₂ and R₁₃ each independently represent a hydrogen atom or an alkyl group. The number of carbon atoms in the alkyl group is not particularly limited, but it is preferably 1 to 15. R₁₂ and R₁₃ may be bonded to each other to form a ring.

m represents an integer of 1 or more. m is preferably an integer of 1 to 20. For the reason that DOF becomes larger, m is more preferably 10 or less.

For the reason that DOF becomes larger, the average value of m is preferably 20 or less, more preferably 1 to 10, still more preferably 1 to 8, and particularly preferably 4 to 6. Here, the “average value of m” has the same definition as in the above-mentioned “average value of n”.

In the case where m is 2 or more, a plurality of R₁₁'s may be the same or different from one another.

In one embodiment of the present invention, the compound having a partial structure represented by General Formula (1) is preferably an alkylene glycol containing at least two ether bonds.

The compound (A2) may be a commercially available product or may be synthesized by a known method.

Specific examples of the compound (A2) include the following compounds, but the present invention is not limited thereto.

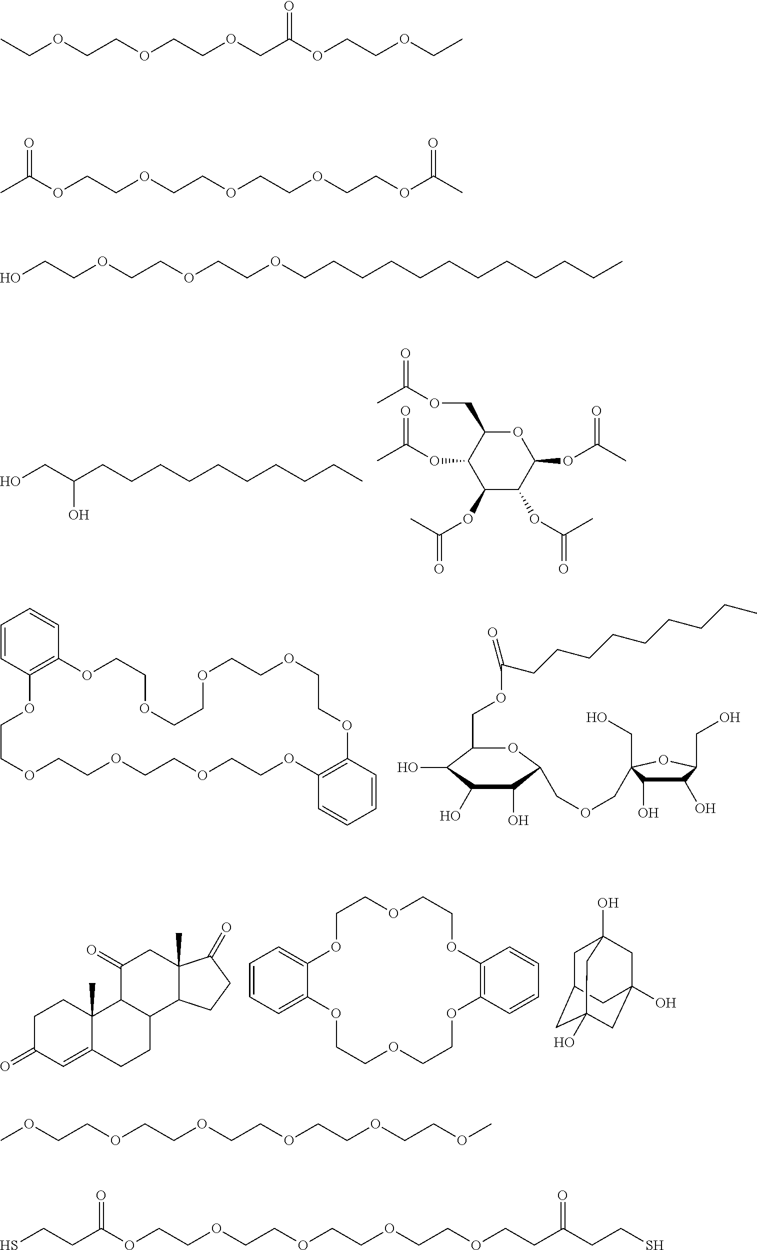

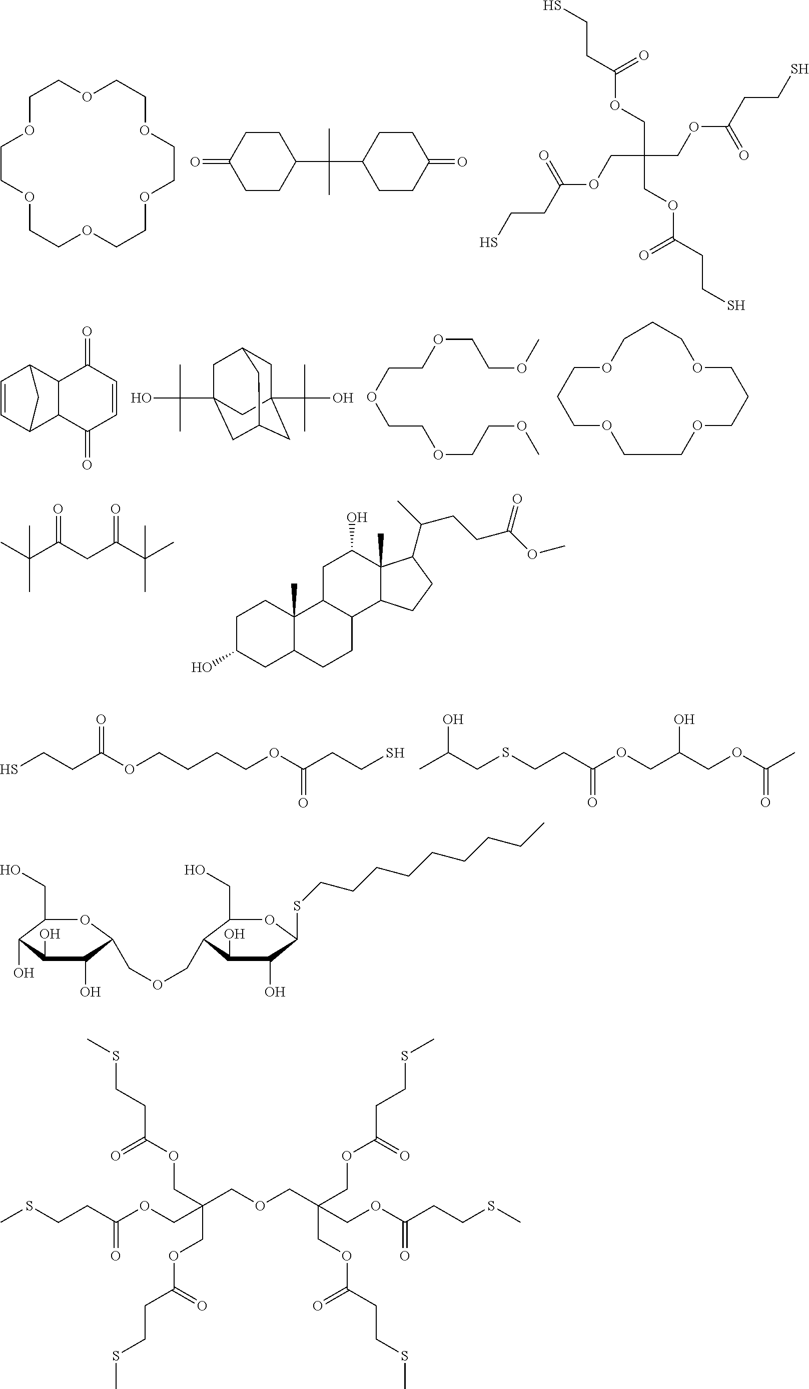

The content of the compound (A2) is preferably 0.1 to 30 mass %, more preferably 1 to 25 mass %, still more preferably 2 to 20 mass %, and particularly preferably 3 to 18 mass %, based on the total solid contents in the topcoat.

<Exposure Step>

The exposure step is a step of exposing the resist film and may be carried out by, for example, the following method.

The resist film formed as described above is irradiated with actinic rays or radiation through a predetermined mask. In irradiation of electron beams, maskless lithography (direct lithography) is common.

The actinic rays or radiation is not particularly limited and may be, for example, a KrF excimer laser, an ArF excimer laser, an extreme ultraviolet (EUV) light, or electron beams (EB). The exposure may be an immersion exposure.

<Baking>

In the pattern forming method of the present invention, it is preferred to carry out baking (heating) after the exposure and before the development. The baking accelerates the reaction of the exposed portion, so that the sensitivity and pattern shape become better.

The heating temperature is preferably 80° C. to 150° C., more preferably 80° C. to 140° C., and still more preferably 80° C. to 130° C.

The heating time is preferably 30 to 1000 seconds, more preferably 60 to 800 seconds, and still more preferably 60 to 600 seconds.

The heating may be carried out by means provided in a conventional exposure/development machine. The heating may also be carried out using a hot plate or the like.

<Development Step>

The development step is a step of developing the exposed resist film with a developer.

As the developing method, use can be made of, for example, a method in which a substrate is dipped in a bath filled with a developer for a given period of time (dip method), a method in which a developer is puddled on the surface of a substrate by its surface tension and allowed to stand still for a given period of time to thereby effect development (puddle method), a method in which a developer is sprayed onto the surface of a substrate (spray method), or a method in which a developer is continuously ejected onto a substrate spinning at a given speed while scanning a developer discharge nozzle at a given speed (dynamic dispense method).

Further, after the step of carrying out the development, a step of stopping the development may be carried while replacing the solvent with another solvent.

The development time is not particularly limited as long as it is a period of time for which the resin of the unexposed portion is sufficiently soluble. The development time is usually 10 to 300 seconds and preferably 20 to 120 seconds.

The temperature of the developer is preferably 0° C. to 50° C. and more preferably 15° C. to 35° C.

As the developer used in the development step, it is preferred to use the above-mentioned organic processing liquid. The details of the developer are as described above. In addition to the development using an organic processing liquid, development with an alkaline developer may also be carried out (so-called double development).

<Rinsing Step>

The rinsing step is a step of cleaning (rinsing) by a rinsing liquid after the development step.

In the rinsing step, the wafer subjected to development is subjected to a cleaning treatment by using the above-mentioned rinsing liquid.

The method of cleaning treatment is not particularly limited, but it is possible to employ, for example, a method of continuously ejecting a rinsing liquid on a substrate spinning at a given speed (spin ejection method), a method of dipping a substrate in a bath filled with a rinsing liquid for a given period of time (dip method), or a method of spraying a rinsing liquid on a substrate surface (spray method), and among them, it is preferred that the cleaning treatment is carried out by the spin coating method and after the cleaning, the substrate is spun at a rotation speed of 2,000 rpm to 4,000 rpm to remove the rinsing liquid from the substrate.

The rinsing time is not particularly limited, but it is usually 10 seconds to 300 seconds, preferably 10 seconds to 180 seconds, and most preferably 20 seconds to 120 seconds.

The temperature of the rinsing liquid is preferably 0° C. to 50° C. and more preferably 15° C. to 35° C.

Further, a treatment of removing the developer or rinsing liquid adhering on the pattern by a supercritical fluid may be carried out after the development treatment or rinsing treatment.

In addition, after treatments of the development treatment or rinsing treatment or treatment with a supercritical fluid, a heat treatment may be carried out to remove the solvent remaining in the pattern. The heating temperature is not particularly limited as long as a good resist pattern can be obtained, and it is usually 40° C. to 160° C. The heating temperature is preferably 50° C. to 150° C. and most preferably 50° C. to 110° C. The heating time is not particularly limited as long as a good resist pattern can be obtained, and it is usually 15 to 300 seconds and preferably 15 to 180 seconds.

It is preferred to use the above-mentioned organic processing liquid as the rinsing liquid. The details of the rinsing liquid are as described above.

In the pattern forming method of the present invention, at least one of the developer or the rinsing liquid is the above-mentioned organic processing liquid, but it is preferred that both of the developer and the rinsing liquid are an organic processing liquid.

Preferred embodiments of the developer and the rinsing liquid used in the pattern forming method of the present invention are as described above, but a combination of the developer and the rinsing liquid will be described as a more preferred embodiment.

A first aspect is a combination of using an ester-based solvent as the organic solvent contained in the developer and using a hydrocarbon-based solvent as the organic solvent contained in the rinsing liquid.

The present aspect is preferable in that swelling of a resist pattern is further suppressed and pattern collapse is further suppressed. Because of such features, the present aspect is suitable for the formation of a fine pattern and is particularly suitable in the case where extreme ultraviolet (EUV) light or electron beams (EB) are used in the exposure step.

In the first aspect, it is preferred to use the above-mentioned ester-based solvent having 7 or more carbon atoms and having 2 or less heteroatoms as the ester-based solvent contained in the developer. The ester-based solvents may be used alone or in combination of two or more thereof. A preferred embodiment of the ester-based solvent having 7 or more carbon atoms and having 2 or less heteroatoms is as described in the section <Developer>.

In the first aspect, it is preferred to use the above-mentioned aliphatic hydrocarbon-based solvent as the hydrocarbon-based solvent contained in the rinsing liquid. A preferred embodiment of the aliphatic hydrocarbon-based solvent is as described in the section <Rinsing liquid>.

In the first aspect, a mixed solvent of the above-mentioned ester-based solvent and the above-mentioned hydrocarbon-based solvent may be used as the ester-based solvent contained in the developer in place of the above-mentioned ester-based solvent having 7 or more carbon atoms and having 2 or less heteroatoms. A preferred specific example of the case of using a mixed solvent of an ester-based solvent and a hydrocarbon-based solvent as the developer is as described in the section <Developer>.

In the first aspect, a mixed solvent of the above-mentioned ketone-based solvent and the above-mentioned hydrocarbon-based solvent may be used in place of the ester-based solvent contained in the developer. A preferred specific example of the case of using a mixed solvent of a ketone-based solvent and a hydrocarbon-based solvent is as described in the section <Developer>.

A second aspect is a combination of using an ester-based solvent as the organic solvent contained in the developer and using at least one selected from an ester-based solvent and a ketone-based solvent as the organic solvent contained in the rinsing liquid.

The present aspect is effective for the reduction of residues after the development.

As the ester-based solvent contained in the developer, it is preferred to use butyl acetate, amyl acetate, isoamyl acetate, 2-methylbutyl acetate, 1-methylbutyl acetate, hexyl acetate, pentyl propionate, hexyl propionate, heptyl propionate, or butyl butanoate, and it is more preferred to use butyl acetate or isoamyl acetate. The ester-based solvents may be used alone or in combination of two or more thereof.

In the case where the rinsing liquid contains at least one selected from the group consisting of an ester-based solvent and a ketone-based solvent, it is preferred to contain at least one solvent selected from the group consisting of butyl acetate, isopentyl acetate, n-pentyl acetate, 3-ethoxyethyl propionate (EEP, ethyl-3-ethoxypropionate), and 2-heptanone as a main component, and it is particularly preferred to contain at least one solvent selected from the group consisting of butyl acetate and 2-heptanone as a main component.

Further, in the case where the rinsing liquid contains at least one selected from the group consisting of an ester-based solvent and a ketone-based solvent, it is preferred to contain a solvent selected from the group consisting of an ester-based solvent, a glycol ether-based solvent, a ketone-based solvent, and an alcohol-based solvent as a minor component, among which preferred is a solvent selected from the group consisting of propylene glycol monomethyl ether acetate (PGMEA), propylene glycol monomethyl ether (PGME), ethyl acetate, ethyl lactate, 3-methoxymethyl propionate, cyclohexanone, methyl ethyl ketone, γ-butyrolactone, propanol, 3-methoxy-1-butanol, N-methylpyrrolidone, and propylene carbonate.

Among these, in the case of using an ester-based solvent as the organic solvent of the rinsing liquid, it is preferred to use two or more ester-based solvents from the viewpoint of the above-mentioned effects being further exerted. A specific example of this case is a case where an ester-based solvent (preferably, butyl acetate) is used as a main component and another ester-based solvent (preferably, propylene glycol monomethyl ether acetate (PGMEA)) whose chemical structure is different from that of the main component ester-based solvent is used as a minor component.

Further, in the case of using an ester-based solvent as the organic solvent of the rinsing liquid, a glycol ether-based solvent in addition to an ester-based solvent (one or two or more types) may be used from the viewpoint of the above-mentioned effects being further exerted. A specific example of this case is a case where an ester-based solvent (preferably, butyl acetate) is used as a main component and a glycol ether-based solvent (preferably, propylene glycol monomethyl ether (PGME)) is used as a minor component.

In the case of using a ketone-based solvent as the organic solvent of the rinsing liquid, an ester-based solvent and/or a glycol ether-based solvent in addition to the ketone-based solvent (one or two or more types) may be used from the viewpoint of the above-mentioned effects being further exerted. A specific example of this case is a case where a ketone-based solvent (preferably, 2-heptanone) is used as a main component and an ester-based solvent (preferably, propylene glycol monomethyl ether acetate (PGMEA)) and/or a glycol ether-based solvent (preferably, propylene glycol monomethyl ether (PGME)) is used as a minor component.

The preferred contents of the main component and the minor component are as described above.

A third aspect is a combination of using one containing a basic compound as the developer and using a hydrocarbon-based solvent as the organic solvent contained in the rinsing liquid.

According to the present aspect, the pattern shape is excellent since the insolubility of the exposed portion with respect to an organic solvent can be further improved. In addition, the occurrence of scum can be reduced by compatibilization of the basic compound contained in the developer with the hydrocarbon-based solvent contained in the rinsing liquid.

A nitrogen-containing compound may be preferably used as the basic compound contained in the developer. A preferred embodiment of the nitrogen-containing compound is as described above. The basic compounds may be used alone or in combination of two or more thereof.

It is preferred to use the above-mentioned aliphatic hydrocarbon-based solvent as the hydrocarbon-based solvent contained in the rinsing liquid. A preferred embodiment of the aliphatic hydrocarbon-based solvent is as described in the section <Rinsing liquid>. The hydrocarbon-based solvents may be used alone or in combination of two or more thereof.

Further, the third aspect and the first aspect may be combined.

Generally, the developer and the rinsing liquid are stored in a waste liquid tank through a pipe after use. At that time, when a hydrocarbon-based solvent is used as the rinsing liquid, the resist dissolved in the developer is precipitated and adheres to the rear surface of the wafer, the side surface of the pipe or the like, thus resulting in contamination of the device.

In order to solve the above problem, there is a method of passing a solvent in which the resist dissolves again through the pipe. As the method of passing the solvent through the pipe, there are a method in which the rear surface, the side surface, and the like of the substrate are cleaned with a solvent in which the resist dissolves and then the solvent is allowed to flow after cleaning with the rinsing liquid, and a method of flowing a solvent in which a resist dissolves without being in contact with the resist so as to pass through a pipe.

The solvent to be passed through the pipe is not particularly limited as long as it can dissolve the resist, and may be, for example, the above-mentioned organic solvent. Use may be made of propylene glycol monomethyl ether acetate (PGMEA), propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, ethylene glycol monoethyl ether acetate, propylene glycol monomethyl ether (PGME), propylene glycol monoethyl ether, propylene glycol monopropyl ether, propylene glycol monobutyl ether, ethylene glycol monomethyl ether, ethylene glycol monoethyl ether, 2-heptanone, ethyl lactate, 1-propanol, acetone, or the like. Among them, PGMEA, PGME, or cyclohexanone may be preferably used.

The present invention is also suitable for a resist pattern formed by the above-mentioned pattern forming method of the present invention, a method for producing an electronic device including the above-mentioned pattern forming method of the present invention, and an electronic device produced by such a production method.

The electronic device is suitably mounted in electrical and electronic equipment (home appliances, OA/media-related equipment, optical equipment, communication equipment, and the like).

<Actinic Ray-Sensitive or Radiation-Sensitive Composition (Resist Composition)>

Next, the resist composition of the present invention will be described in detail.

The resist composition of the present invention preferably does not contain impurities such as a metal, a metal salt containing halogen, an acid, an alkali, and the like. A specific preferred range of the content of impurities is the same as the range described for the content of impurities contained in the above-mentioned organic processing liquid, and the method of removing impurities is as described above. Individual components contained in the resist composition may be used after removal of impurities by the same method as the method of removing impurities described above.

(A) Resin

<Resin (A)>

The resist composition of the present invention preferably contains a resin (A). The resin (A) has at least (i) a repeating unit having a group capable of decomposing by the action of an acid to generate a carboxyl group (which may further have a repeating unit having a phenolic hydroxyl group), or at least (ii) a repeating unit having a phenolic hydroxyl group.

When the resin (A) has a repeating unit capable of decomposing by the action of an acid to have a carboxyl group, the solubility in an alkali developer increases due to the action of an acid, and the solubility in an organic solvent decreases.

Examples of the repeating unit having a phenolic hydroxyl group contained in the resin (A) include a repeating unit represented by the following General Formula (I) and a repeating unit represented by the following General Formula (I-1).

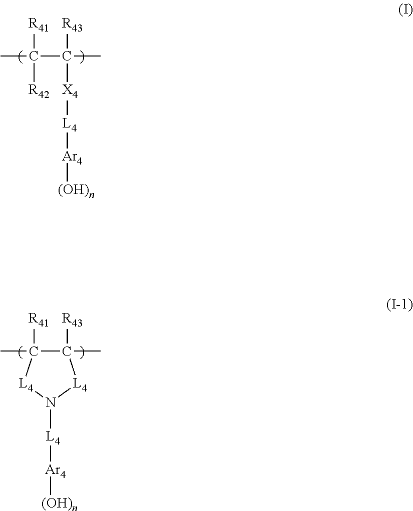

In General Formula (I),

R₄₁, R₄₂, and R₄₃ each independently represent a hydrogen atom, an alkyl group, a halogen atom, a cyano group, or an alkoxycarbonyl group. Meanwhile, R₄₂ and Ar₄ may be bonded to each other to form a ring, and R₄₂ in this case represents a single bond or an alkylene group.

X₄ represents a single bond, —COO—, or —CONR₆₄— in which R₆₄ represents a hydrogen atom or an alkyl group.

L₄ represents a single bond or an alkylene group.

Ar₄ represents a (n+1)-valent aromatic ring group, and in the case of being bonded to R₄₂ to form a ring, Ar₄ represents an (n+2)-valent aromatic ring group.

n represents an integer of 1 to 5.

In General Formula (I-1), R₄₁, R₄₃, L₄, Ar₄, and n are respectively the same as R₄₁, R₄₃, L₄, Ar₄, and n in General Formula (I) and preferred embodiments thereof are also the same. In General Formula (I-1), a plurality of L₄'s may be the same or different from one another.

Examples of the alkyl group of R₄₁, R₄₂, and R₄₃ in General Formula (I) preferably include alkyl groups having 20 or less carbon atoms which may have a substituent, such as a methyl group, an ethyl group, a propyl group, an isopropyl group, an n-butyl group, a sec-butyl group, a hexyl group, a 2-ethylhexyl group, an octyl group, and a dodecyl group, more preferably alkyl groups having 8 or less carbon atoms, and particularly preferably alkyl groups having 3 or less carbon atoms.

The cycloalkyl group of R₄₁, R₄₂, and R₄₃ in General Formula (I) may be monocyclic or polycyclic. Examples of the cycloalkyl group preferably include monocyclic cycloalkyl groups having 3 to 8 carbon atoms which may have a substituent, such as a cyclopropyl group, a cyclopentyl group, and a cyclohexyl group.

Examples of the halogen atom of R₄₁, R₄₂, and R₄₃ in General Formula (I) include a fluorine atom, a chlorine atom, a bromine atom, and an iodine atom, among which particularly preferred is a fluorine atom.

The alkyl group contained in the alkoxycarbonyl group of R₄₁, R₄₂, and R₄₃ in General Formula (I) is preferably the same as the alkyl group represented by R₄₁, R₄₂, and R₄₃.

Examples of preferred substituents in each of the above-mentioned groups include an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group. The number of carbon atoms in substituents is preferably 8 or less.

Ar₄ represents a (n+1)-valent aromatic ring group. The divalent aromatic ring group in the case where n is 1 may have a substituent, and preferred examples thereof include arylene groups having 6 to 18 carbon atoms, such as a phenylene group, a tolylene group, a naphthylene group, and an anthracenylene group, and aromatic ring groups containing a hetero ring, such as thiophene, furan, pyrrole, benzothiophene, benzofuran, benzopyrrole, triazine, imidazole, benzimidazole, triazole, thiadiazole, and thiazole.

Specific examples of the (n+1)-valent aromatic ring group in the case where n is an integer of 2 or more preferably include groups formed by removing a (n−1) number of any hydrogen atoms from the above-mentioned specific examples of the divalent aromatic ring group.

The (n+1)-valent aromatic ring group may further have a substituent.

Examples of the substituent that the above-mentioned alkyl group, cycloalkyl group, alkoxycarbonyl group, alkylene group, and (n+1)-valent aromatic ring group may have include alkyl groups exemplified for R₄₁, R₄₂, and R₄₃ in General Formula (I), alkoxy groups such as a methoxy group, an ethoxy group, a hydroxyethoxy group, a propoxy group, a hydroxypropoxy group, and a butoxy group; and aryl groups such as a phenyl group.

Examples of the alkyl group for R₆₄ in —CONR₆₄— (R₆₄ represents a hydrogen atom or an alkyl group) represented by X₄ preferably include alkyl groups having 20 or less carbon atoms which may have a substituent, such as a methyl group, an ethyl group, a propyl group, an isopropyl group, an n-butyl group, a sec-butyl group, a hexyl group, a 2-ethylhexyl group, an octyl group, and a dodecyl group, and more preferably include alkyl groups having 8 or less carbon atoms.

X₄ is preferably a single bond, —COO—, or —CONH— and more preferably a single bond or —COO—.

Examples of the alkylene group for L₄ preferably include alkylene groups having 1 to 8 carbon atoms which may have a substituent, such as a methylene group, an ethylene group, a propylene group, a butylene group, a hexylene group, and an octylene group.

Ar₄ is more preferably an aromatic ring group having 6 to 18 carbon atoms which may have a substituent, and particularly preferably a benzene ring group, a naphthalene ring group, or a biphenylene ring group.

The repeating unit represented by General Formula (I) is preferably a repeating unit having a hydroxystyrene structure. That is, Ar₄ is preferably a benzene ring group.

The repeating unit having a phenolic hydroxyl group contained in the resin (A) may be preferably, for example, a repeating unit represented by the following General Formula (p1).

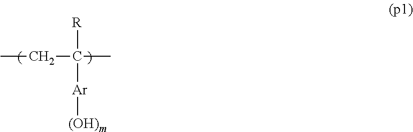

R in General Formula (p1) represents a hydrogen atom, a halogen atom, or a linear or branched alkyl group having 1 to 4 carbon atoms. A plurality of R's may be the same or different from one another. R in General Formula (p1) is particularly preferably a hydrogen atom.

The Ar in General Formula (p1) represents an aromatic ring, examples of which include aromatic hydrocarbon rings having 6 to 18 carbon atoms which may have a substituent, such as a benzene ring, a naphthalene ring, an anthracene ring, a fluorene ring, and a phenanthrene ring, and aromatic hetero rings containing a hetero ring, such as a thiophene ring, a furan ring, a pyrrole ring, a benzothiophene ring, a benzofuran ring, a benzopyrrole ring, a triazine ring, an imidazole ring, a benzimidazole ring, a triazole ring, a thiadiazole ring, and a thiazole ring. Among them, most preferred is a benzene ring.

m in General Formula (p1) represents an integer of 1 to 5 and is preferably 1.

Specific examples of the repeating unit having a phenolic hydroxyl group contained in the resin (A) are shown below, but the present invention is not limited thereto. In the formulae, a represents 1 or 2.

As the repeating unit having a phenolic hydroxyl group contained in the resin (A), the repeating units described in paragraphs [0177] and [0178] of JP2014-232309A may also be used.

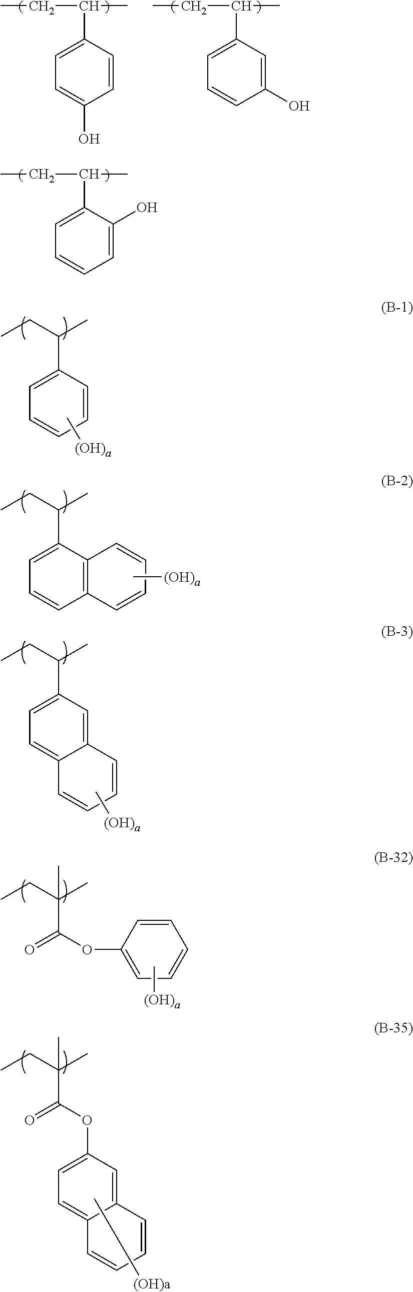

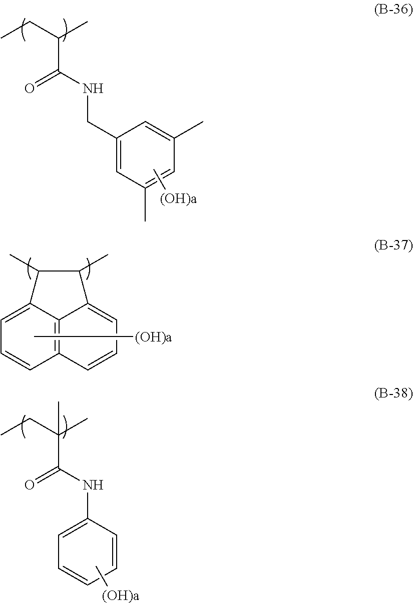

The content of the repeating unit having a phenolic hydroxyl group is preferably 0 to 50 mol %, more preferably 0 to 45 mol %, and still more preferably 0 to 40 mol %, with respect to all repeating units in the resin (A).

The repeating unit having a group capable of decomposing by the action of an acid to generate a carboxyl group, which is contained in the resin (A), is a repeating unit having a group in which a hydrogen atom of the carboxyl group has been substituted with a group capable of decomposing and leaving by the action of an acid.

Examples of the group capable of leaving by the action of an acid include —C(R₃₆)(R₃₇)(R₃₈), —C(R₃₆)(R₃₇)(OR₃₉), and —C(R₀₁)(R₀₂)(OR₃₉).

In the formulae, R₃₆ to R₃₉ each independently represent an alkyl group, a cycloalkyl group, an aryl group, an aralkyl group, or an alkenyl group. R₃₆ and R₃₇ may be bonded to each other to form a ring.

R₀₁ and R₀₂ each independently represent a hydrogen atom, an alkyl group, a cycloalkyl group, an aryl group, an aralkyl group, or an alkenyl group.

The repeating unit having a group capable of decomposing by the action of an acid to generate a carboxyl group, which is contained in the resin (A), is preferably a repeating unit represented by the following General Formula (AI).

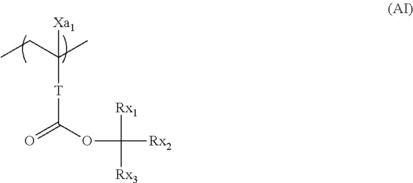

In General Formula (AI),

Xa₁ represents a hydrogen atom or an alkyl group which may have a substituent.

T represents a single bond or a divalent linking group.

Rx₁ to Rx₃ each independently represent an alkyl group (linear or branched) or a cycloalkyl group (monocyclic or polycyclic). Meanwhile, in the case where all of Rx₁ to Rx₃ are an alkyl group (linear or branched), at least two of Rx₁ to Rx₃ are preferably a methyl group.

Two of Rx₁ to Rx₃ may be bonded to form a cycloalkyl group (monocyclic or polycyclic).

The alkyl group which may have a substituent, which is represented by Xa₁, may be, for example, a methyl group or a group represented by —CH₂—R₁₁. R₁₁ represents a halogen atom (a fluorine atom or the like), a hydroxyl group, or a monovalent organic group which is, for example, an alkyl group having 5 or less carbon atoms or an acyl group having 5 or less carbon atoms, preferably an alkyl group having 3 or less carbon atoms, and more preferably a methyl group. In one embodiment, Xa₁ is preferably a hydrogen atom, a methyl group, a trifluoromethyl group, or a hydroxymethyl group.

Examples of the divalent linking group of T include an alkylene group, a —COO-Rt- group, and an —O-Rt- group. In the formulae, Rt represents an alkylene group or a cycloalkylene group.

T is preferably a single bond or a —COO-Rt- group. Rt is preferably an alkylene group having 1 to 5 carbon atoms and more preferably a —CH₂— group, a —(CH₂)₂— group, or a —(CH₂)₃— group.

The alkyl group of Rx₁ to Rx₃ is preferably an alkyl group having 1 to 4 carbon atoms, such as a methyl group, an ethyl group, an n-propyl group, an isopropyl group, an n-butyl group, an isobutyl group, or a t-butyl group.

The cycloalkyl group of Rx₁ to Rx₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group.

The cycloalkyl group formed by bonding of two of Rx₁ to Rx₃ is preferably a monocyclic cycloalkyl group such as a cyclopentyl group or a cyclohexyl group, or a polycyclic cycloalkyl group such as a norbornyl group, a tetracyclodecanyl group, a tetracyclododecanyl group, or an adamantyl group. The monocyclic cycloalkyl group having 5 or 6 carbon atoms is particularly preferable.

In the cycloalkyl group formed by bonding of two of Rx₁ to Rx₃, for example, one of methylene groups constituting the ring may be substituted with a heteroatom such as an oxygen atom, or a group having a heteroatom such as a carbonyl group.

With respect to the repeating unit represented by General Formula (AI), preferred is, for example, an embodiment in which Rx₁ is a methyl group or an ethyl group, and Rx₂ and Rx₃ are bonded to each other to form the above-mentioned cycloalkyl group.

The above respective groups may have a substituent, and examples of the substituent include an alkyl group (having 1 to 4 carbon atoms), a halogen atom, a hydroxyl group, an alkoxy group (having 1 to 4 carbon atoms), a carboxyl group, and an alkoxycarbonyl group (having 2 to 6 carbon atoms), with the number of carbon atoms being preferably 8 or less.

The repeating unit represented by General Formula (AI) is preferably an acid-decomposable (meth)acrylic acid tertiary alkyl ester-based repeating unit (a repeating unit in which Xa₁ represents a hydrogen atom or a methyl group, and T represents a single bond). More preferred is a repeating unit in which Rx₁ to Rx₃ each independently represent a linear or branched alkyl group, and still more preferred is a repeating unit in which Rx₁ to Rx₃ each independently represent a linear alkyl group.

Specific examples of the repeating unit having a group capable of decomposing by the action of an acid to generate a carboxyl group, which is contained in the resin (A), are shown below, but the present invention is not limited thereto.

As the repeating unit having a group capable of decomposing by the action of an acid to generate a carboxyl group, the repeating units described in paragraphs [0227] to [0232] of JP2014-232309A may also be used.

In the specific examples, Rx and Xa₁ represent a hydrogen atom, CH₃, CF₃, or CH₂OH. Rxa and Rxb each represent an alkyl group having 1 to 4 carbon atoms. Z represents a substituent containing a polar group, and in the case where a plurality of Z's are present, they are each independent from one another. p represents 0 or a positive integer. Examples of the substituent containing a polar group, which is represented by Z, include a linear or branched alkyl group and a cycloalkyl group, each having a hydroxyl group, a cyano group, an amino group, an alkyl amide group or a sulfonamide group, among which preferred is an alkyl group having a hydroxyl group. The branched alkyl group is particularly preferably an isopropyl group.

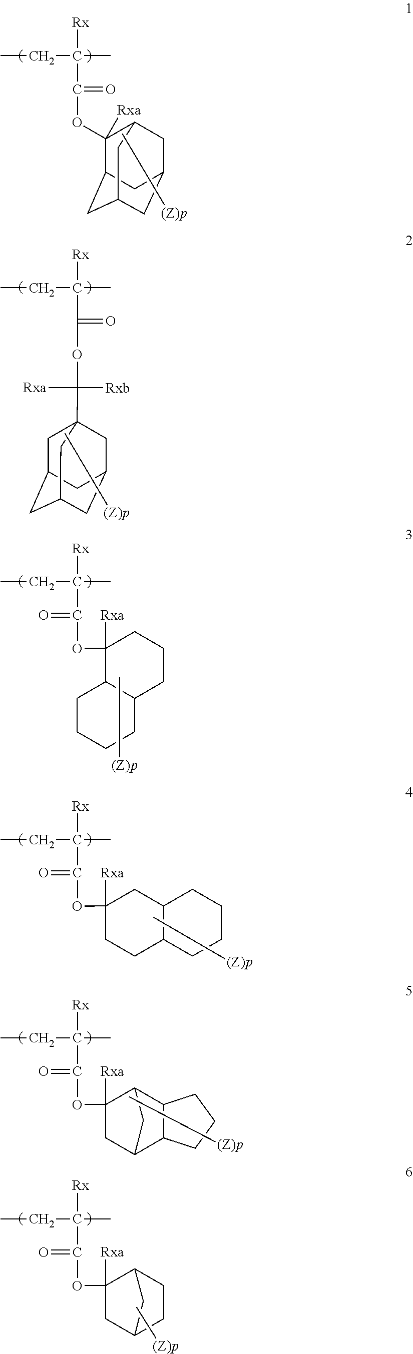

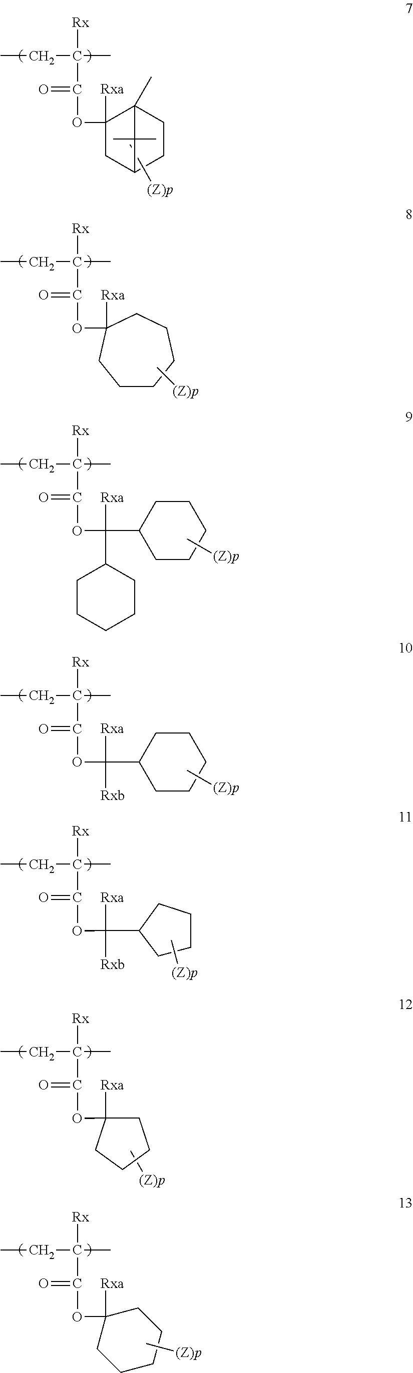

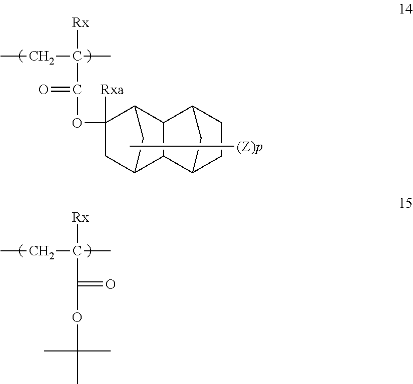

The content of the repeating unit having a group capable of decomposing by the action of an acid to generate a carboxyl group is preferably 20 to 90 mol %, more preferably 25 to 80 mol %, and still more preferably 30 to 70 mol %, with respect to all repeating units in the resin (A).

The resin (A) preferably contains a repeating unit which further has a lactone group.

As for the lactone group, any group may be used as long as it has a lactone structure, but a group having a 5- to 7-membered ring lactone structure is preferable. The 5- to 7-membered ring lactone structure is preferably condensed with another ring structure in a fashion to form a bicyclo structure or a spiro structure. It is more preferred that the resin (A) contains a repeating unit containing a group having a lactone structure represented by any one of the following General Formulae (LC1-1) to (LC1-10). The group having a lactone structure may be directly bonded to the main chain. Preferred lactone structures are groups represented by General Formulae (LC1-1), (LC1-4), (LC1-5), and (LC1-6).

Further, the resin (A) may have structures and repeating units described in paragraphs [0306] to [0313] of JP2014-232309A.

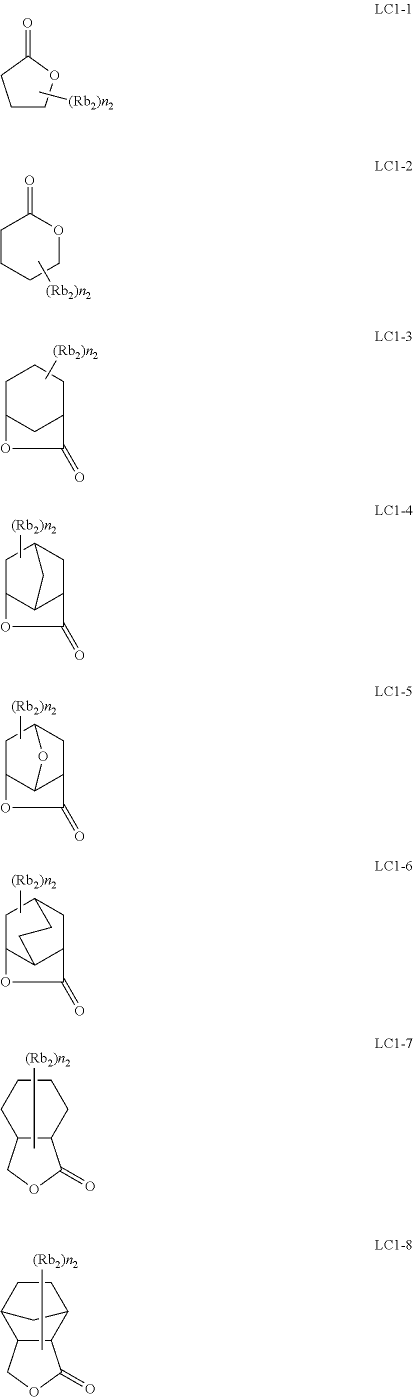

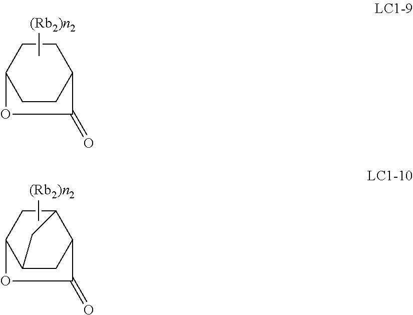

The lactone structure moiety may or may not have a substituent (Rb₂). Preferred examples of the substituent (Rb₂) include an alkyl group having 1 to 8 carbon atoms, a cycloalkyl group having 4 to 7 carbon atoms, an alkoxy group having 1 to 8 carbon atoms, an alkoxycarbonyl group having 1 to 8 carbon atoms, a carboxyl group, a halogen atom, a hydroxyl group, a cyano group, and an acid-decomposable group. n2 represents an integer of 0 to 4. When n2 is 2 or more, a plurality of Rb₂'s may be the same or different from one another or may be bonded to each other to form a ring.

The repeating unit containing a group having a lactone structure represented by any one of General Formulae (LC1-1) to (LC1-10) may be, for example, a repeating unit represented by the following General Formula (AI).

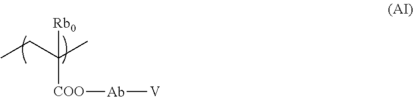

In General Formula (AI), Rb₀ represents a hydrogen atom, a halogen atom, or an alkyl group having 1 to 4 carbon atoms.

Preferred examples of the substituent which may be possessed by the alkyl group of Rb₀ include a hydroxyl group and a halogen atom.

Examples of the halogen atom of Rb₀ include a fluorine atom, a chlorine atom, a bromine atom, and an iodine atom. Rb₀ is preferably a hydrogen atom or a methyl group.

Ab represents a single bond, an alkylene group, a divalent linking group having a monocyclic or polycyclic alicyclic hydrocarbon structure, an ether group, an ester group, a carbonyl group, a carboxyl group, or a divalent group formed by combining these groups. Preferred is a single bond or a linking group represented by -Ab₁-CO₂—. Ab₁ is a linear or branched alkylene group or a monocyclic or polycyclic cycloalkylene group, preferably a methylene group, an ethylene group, a cyclohexylene group, an adamantylene group, or a norbornylene group.

V represents a group represented by any one of General Formulae (LC1-1) to (LC1-10).

The repeating unit having a lactone structure usually has an optical isomer, but any optical isomer may be used. One optical isomer may be used alone or a mixture of a plurality of optical isomers may be used. In the case of mainly using one optical isomer, the optical purity (ee) thereof is preferably 90 or more and more preferably 95 or more.

Specific examples of the repeating unit having a group having a lactone structure are shown below, but the present invention is not limited thereto.

(In the formulae, Rx is H, CH₃, CH₂OH, or CF₃)

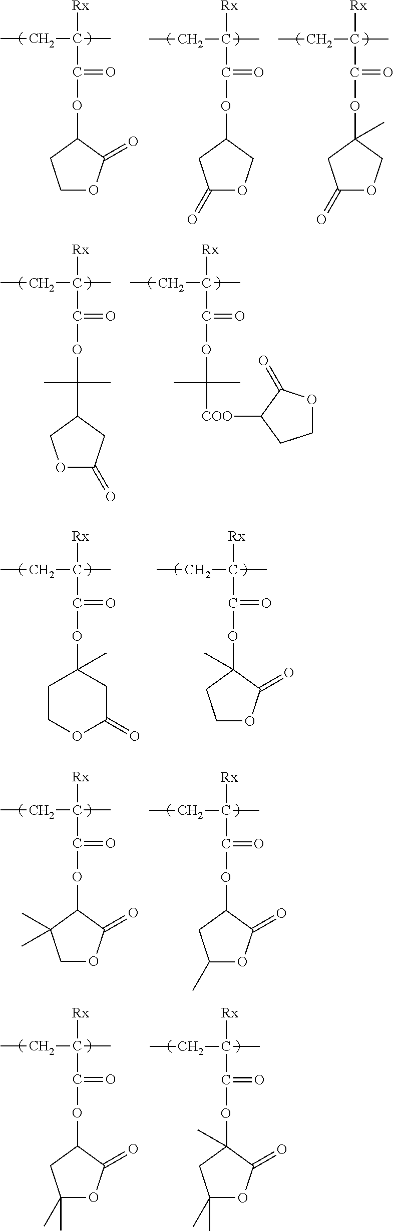

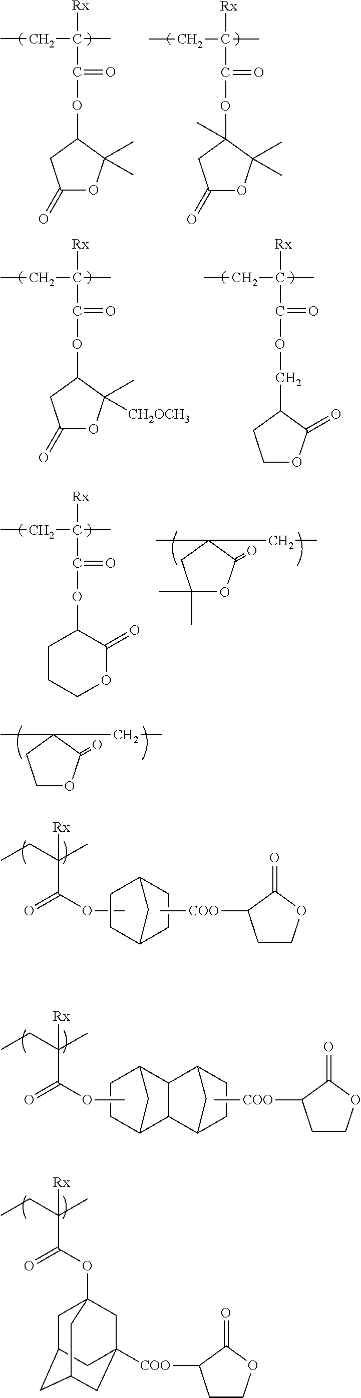

(In the formulae, Rx is H, CH₃, CH₂OH, or CF₃)

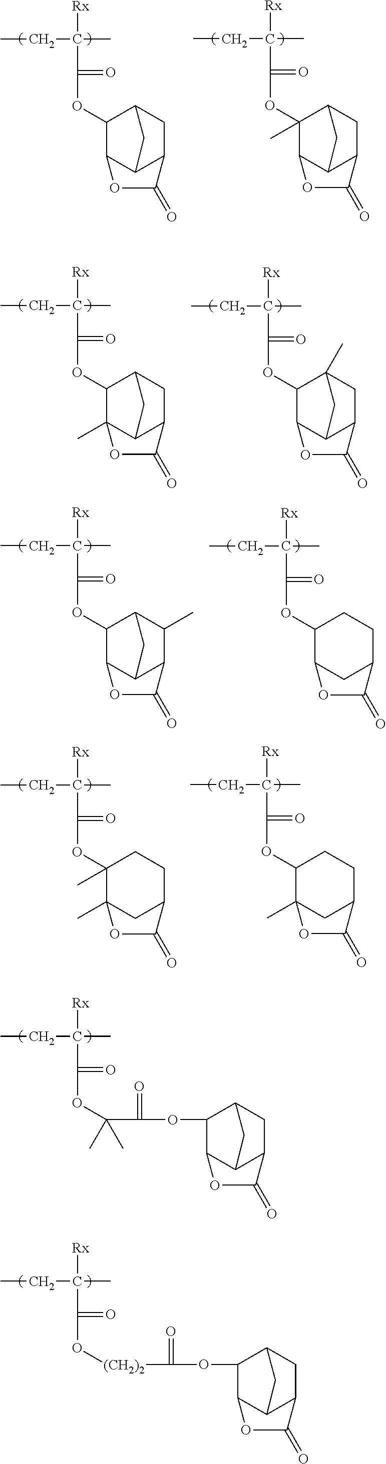

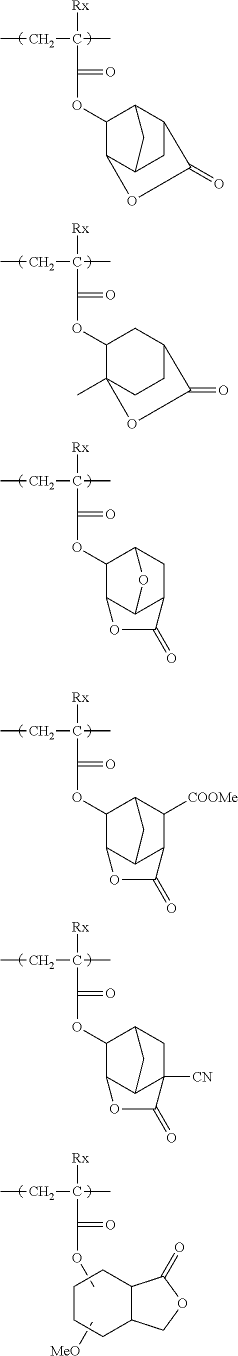

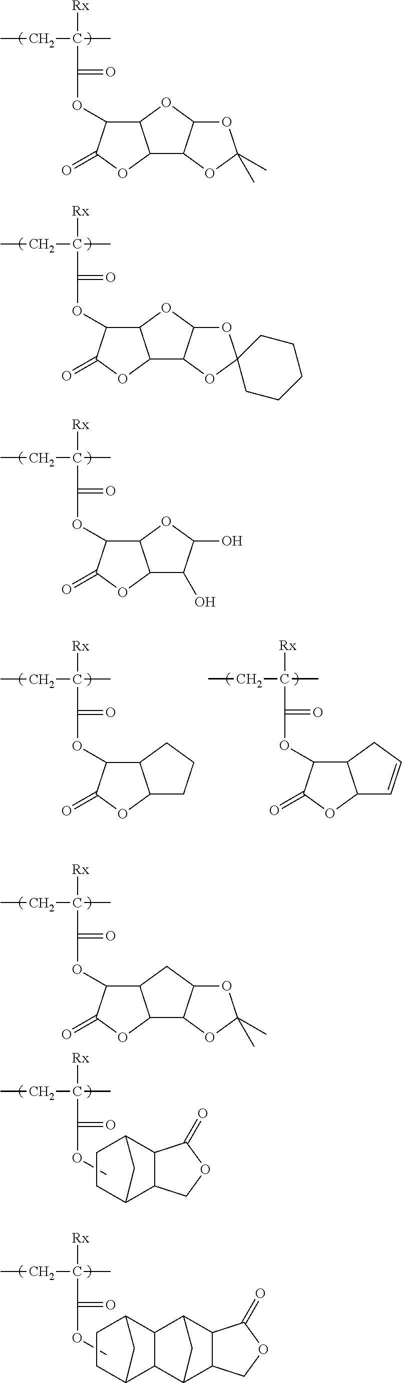

The content of the repeating unit having a lactone group is preferably 1 to 30 mol %, more preferably 5 to 25 mol %, and still more preferably 5 to 20 mol %, with respect to all repeating units in the resin (A).

The resin (A) may further have a repeating unit containing an organic group having a polar group, in particular, a repeating unit having an alicyclic hydrocarbon structure substituted by a polar group.

Thus, adhesiveness to a substrate and affinity to a developer are improved. The alicyclic hydrocarbon structure of the alicyclic hydrocarbon structure substituted by a polar group is preferably an adamantyl group, a diamantyl group, or a norbornane group. The polar group is preferably a hydroxyl group or a cyano group.

Specific examples of the repeating unit having a polar group are shown below, but the present invention is not limited thereto.

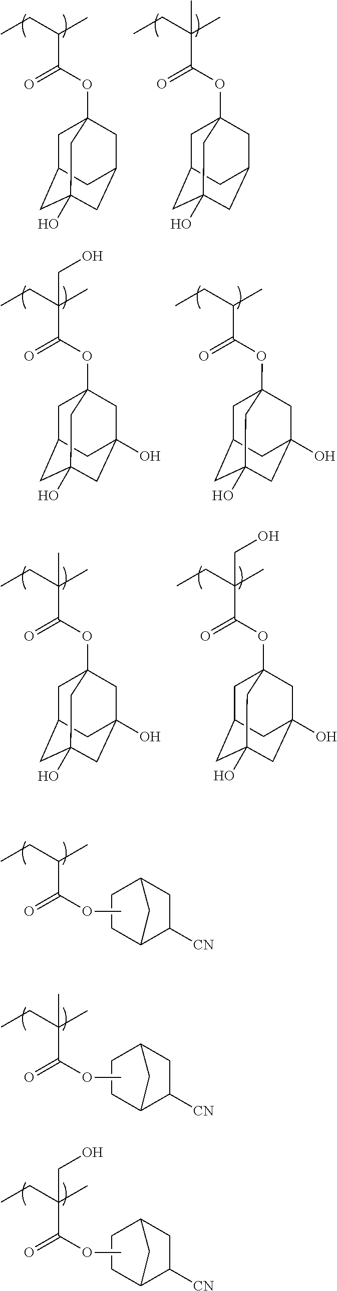

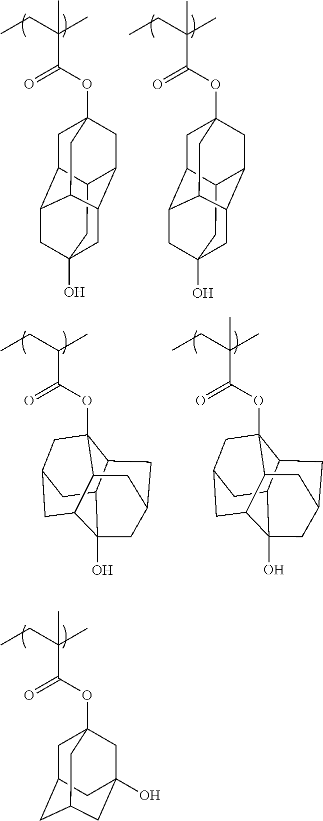

In the case where the resin (A) has a repeating unit containing an organic group having a polar group, the content thereof is preferably 1 to 30 mol %, more preferably 5 to 25 mol %, and still more preferably 5 to 20 mol %, with respect to all repeating units in the resin (A).

A repeating unit having a group capable of generating an acid upon irradiation with actinic rays or radiation (photoacid generating group) may be further included as a repeating unit other than the above-mentioned repeating units. In this case, it can be considered that this repeating unit having a photoacid generating group corresponds to a compound (B) capable of generating an acid upon irradiation with actinic rays or radiation which will be described hereinafter.

Such a repeating unit may be, for example, a repeating unit represented by the following General Formula (4).

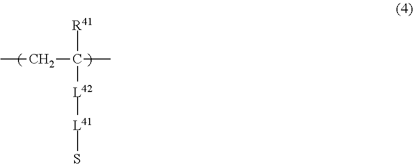

R⁴¹ represents a hydrogen atom or a methyl group. L⁴¹ represents a single bond or a divalent linking group. L⁴² represents a divalent linking group. S represents a structural moiety capable of decomposing upon irradiation with actinic rays or radiation to generate an acid on the side chain.

Specific examples of the repeating unit represented by General Formula (4) are shown below, but the present invention is not limited thereto.

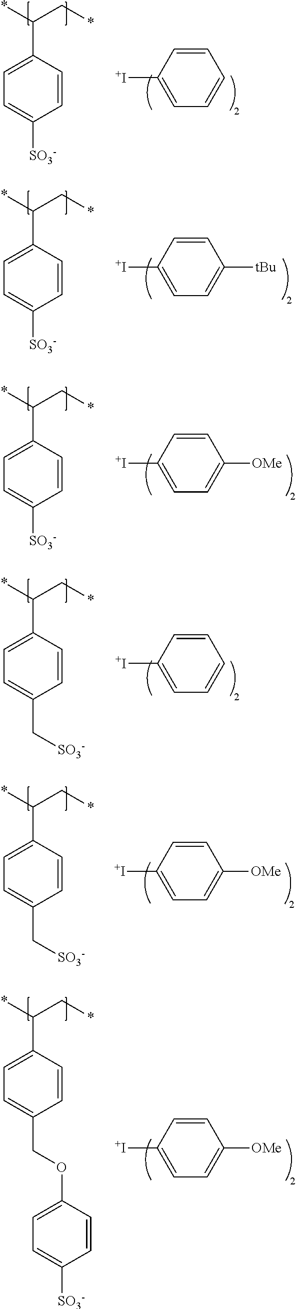

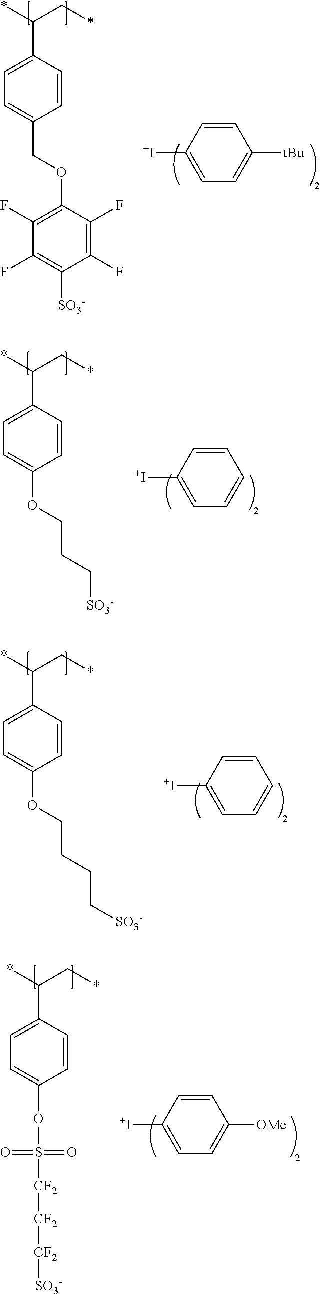

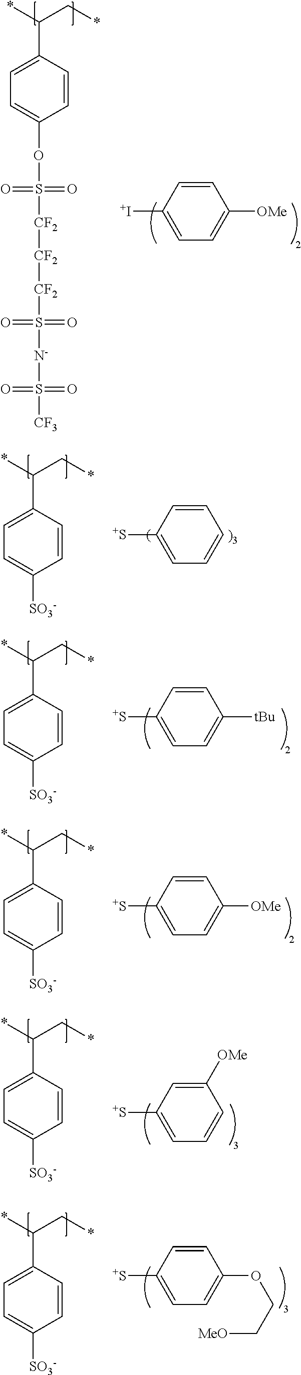

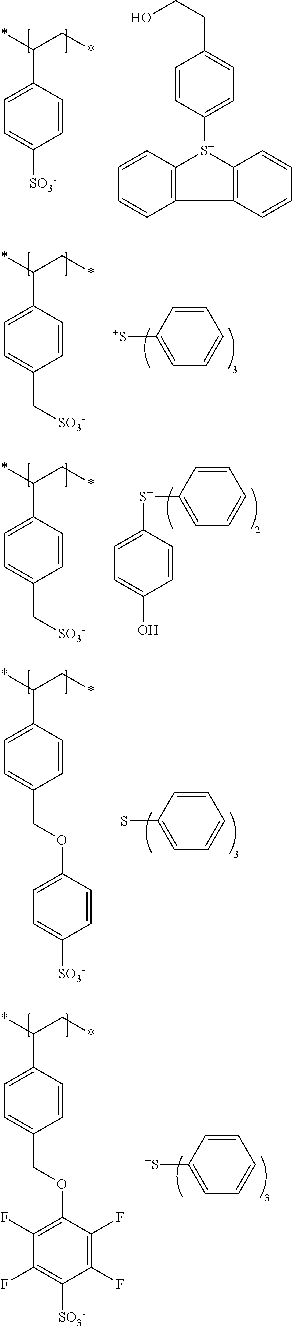

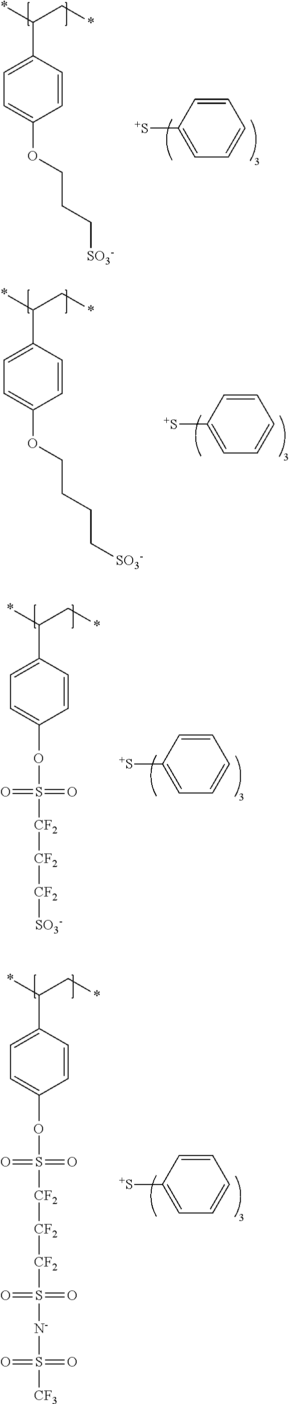

Additional examples of the repeating unit represented by General Formula (4) include those repeating units described in paragraphs [0094] to [0105] of JP2014-041327A.

In the case where the resin (A) contains a repeating unit having a photoacid generating group, the content of the repeating unit having a photoacid generating group is preferably 1 to 40 mol %, more preferably 5 to 35 mol %, and still more preferably 5 to 30 mol %, with respect to all repeating units in the resin (A).

The resin (A) can be synthesized in accordance with a conventional method (for example, radical polymerization). Examples of the general synthesis method include a bulk polymerization method in which polymerization is carried out by dissolving monomer species and an initiator in a solvent and heating the solution, and a dropwise addition polymerization method in which a solution of monomer species and an initiator is added dropwise to a heating solvent over 1 hour to 10 hours, with the dropwise addition polymerization method being preferable.

Examples of the reaction solvent include ethers such as tetrahydrofuran, 1,4-dioxane, and diisopropyl ether; ketones such as methyl ethyl ketone and methyl isobutyl ketone; ester-based solvents such as ethyl acetate; amide solvents such as dimethylformamide and dimethylacetamide; and solvents which dissolve the resist composition of the present invention, such as propylene glycol monomethyl ether acetate, propylene glycol monomethyl ether, and cyclohexanone, which will be described hereinafter. It is more preferred to carry out polymerization using the same solvent as the solvent used in the resist composition of the present invention. Thus, generation of particles during storage can be suppressed.

The polymerization reaction is preferably carried out under an inert gas atmosphere such as nitrogen or argon. As the polymerization initiator, a commercially available radical initiator (an azo-based initiator, peroxide, or the like) is used to initiate the polymerization. As the radical initiator, an azo-based initiator is preferable, and the azo-based initiator having an ester group, a cyano group, or a carboxyl group is preferable. Preferred examples of the initiator include azobisisobutyronitrile, azobisdimethylvaleronitrile, and dimethyl 2,2′-azobis(2-methyl propionate). The initiator is added or added in portionwise, as desired. After the reaction has been completed, the reaction mixture is poured into a solvent, and then a desired polymer is recovered by a method such as powder or solid recovery. The concentration of the reactant is 5 to 50 mass % and preferably 10 to 30 mass %. The reaction temperature is usually 10° C. to 150° C., preferably 30° C. to 120° C., and more preferably 60° C. to 100° C.

For the purification, use can be made of a conventional method such as a liquid-liquid extraction method by washing with water or combining suitable solvents to remove the residual monomer and oligomer components, a purification method in the solution state which includes conducting ultrafiltration to thereby extract and remove only components having a specific molecular weight or less, a reprecipitation method which includes dropwise adding a resin solution to a poor solvent, thus solidifying the resin in the poor solvent and removing the residual monomers and the like, or a purification method in the solid state which includes filtering a resin slurry and washing with a poor solvent.

The weight-average molecular weight of the resin (A), as calculated in terms of polystyrene by the GPC method, is preferably 1,000 to 200,000, more preferably 3,000 to 20,000, and most preferably 5,000 to 15,000. By setting the weight-average molecular weight to 1,000 to 200,000, it is possible to prevent deterioration of heat resistance and dry etching resistance and it is also possible to prevent deterioration of developability and deterioration of film formability due to an increase in viscosity.

In particularly preferred another embodiment, the weight-average molecular weight of the resin (A), as calculated in terms of polystyrene by the GPC method, is preferably 3,000 to 9,500. By setting the weight-average molecular weight to 3,000 to 9,500, the formation of particularly a resist residue (hereinafter, also referred to as “scum”) can be prevented and thus a better pattern can be formed.

Use is made of a resin having a dispersity (molecular weight distribution) of usually 1 to 5, preferably 1 to 3, more preferably 1.2 to 3.0, and particularly preferably 1.2 to 2.0. A resin having a smaller dispersity can bring about superior resolution, resist shape, smoothness in the side wall of a resist pattern, and roughness.

In the resist composition of the present invention, the content of the resin (A) is preferably 50 to 99.9 mass % and more preferably 60 to 99.0 mass %, based on the total solid content.

In the resist composition of the present invention, the resins (A) may be used alone or in combination of two or more thereof.

The polymer compound described in paragraphs [0019] to [0077] of JP2014-170167A may also be used as the resin (A). Such a polymer compound preferably has a group (acid-labile protecting group) represented by the following General Formulae (L1) to (L8).

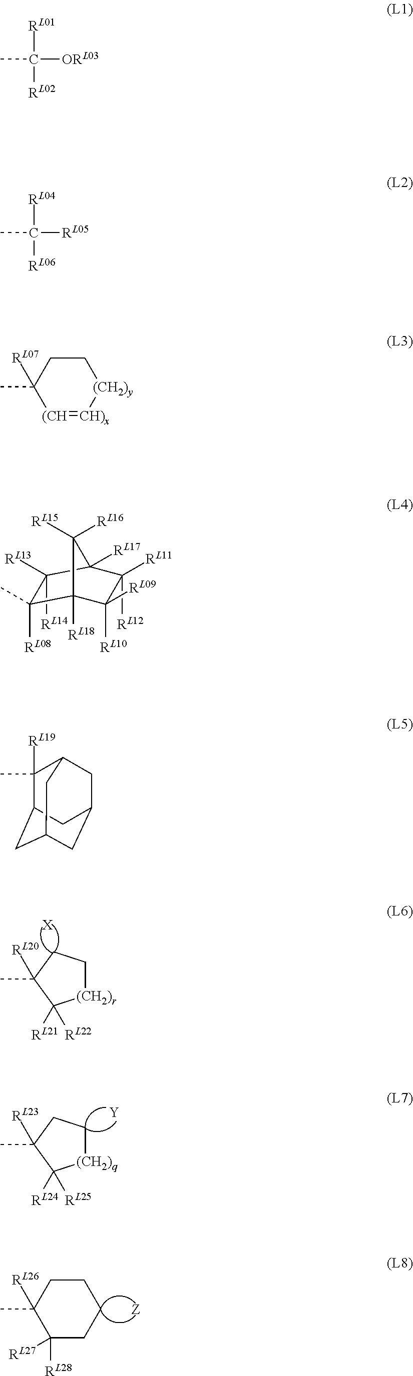

In the above formulae, the dashed line represents a bond. R^{L01} and R^{L02} represent a hydrogen atom or a linear, branched or cyclic alkyl group having 1 to 18 carbon atoms, preferably 1 to 10, examples of which include a methyl group, an ethyl group, a propyl group, an isopropyl group, an n-butyl group, a sec-butyl group, a tert-butyl group, a cyclopentyl group, a cyclohexyl group, a 2-ethylhexyl group, an n-octyl group, and an adamantyl group. R^{L03} represents a monovalent hydrocarbon group having 1 to 18 carbon atoms, preferably having 1 to 10 carbon atoms which may contain a heteroatom such as an oxygen atom, examples of which include a linear, branched or cyclic alkyl group whose hydrogen atoms may be partially substituted by a hydroxyl group, an alkoxy group, an oxo group, an amino group, an alkylamino group, or the like. Specifically, the linear, branched or cyclic alkyl group may be the same one as for R^{L01} and R^{L02}.

For the purpose of improving adhesiveness, the resin (A) may have repeating units c1 to c9 represented by the following General Formula (9).

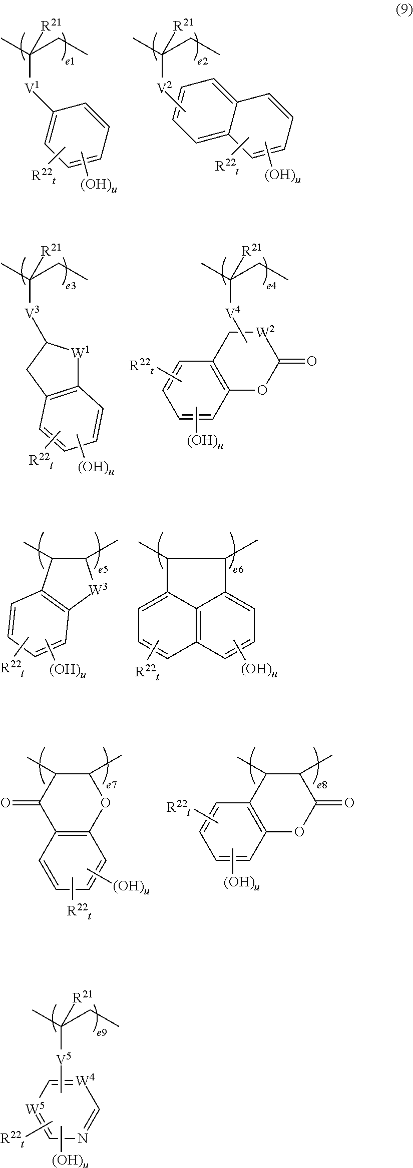

In the formulae, V¹, V², and V⁵ are a single bond or —C(═O)—O—R²³—, and V³ and V⁴ are —C(═O)—O—R²⁴—, in which R²³ and R²⁴ are a single bond or a linear, branched or cyclic alkylene group having 1 to 10 carbon atoms, which may have an ether group or an ester group. R²² is a hydrogen atom, or a linear or branched alkyl group having 1 to 4 carbon atoms, an alkoxy group, a cyano group, an alkoxycarbonyl group, an acyloxy group, or an acyl group, R²¹'s are the same or different and are a hydrogen atom or a methyl group. W¹ and W² are a methylene group or an ethylene group, W³ is a methylene group, an oxygen atom, or a sulfur atom, and W⁴ and W⁵ are CH or a nitrogen atom. u and t are 1 or 2.

The resin (A) may contain a polymer compound including a repeating unit p and one or more repeating units selected from repeating units q1 to q4 and represented by the following General Formula (2).

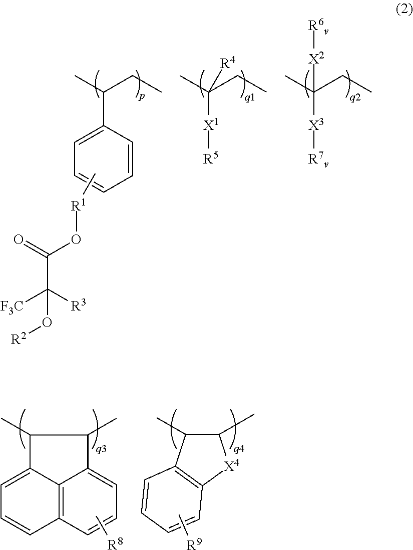

In the formulae, R¹ is a linear or branched alkylene group having 1 to 4 carbon atoms, R² is a hydrogen atom, an acyl group having 1 to 15 carbon atoms, or an acid-labile group, R³ is a hydrogen atom, a methyl group, or a trifluoromethyl group, and 0<p≦1.0. R⁴ is a hydrogen atom or a methyl group, X¹ is a single bond, —C(═O)—O—, or —O—, X² and X³ are a phenylene group or a naphthylene group, and X⁴ is a methylene group, an oxygen atom, or a sulfur atom. R⁵ is an aryl group or aralkyl group having 6 to 20 carbon atoms, which may have a hydroxyl group, a linear, branched or cyclic alkyl group or alkoxy group, an ester group (—OCOR or —COOR: R is a C₁₋₆ alkyl group), a ketone group (—COR: R is a C₁₋₆ alkyl group), a fluorine atom, a trifluoromethyl group, a nitro group, an amino group, or a cyano group. R⁶, R⁷, R⁸, and R⁹ are the same or different and are a hydrogen atom, a hydroxy group, a linear, branched or cyclic alkyl group, alkoxy group or acyloxy group having 1 to 10 carbon atoms, a cyano group, a nitro group, an amino group, a halogen atom, an ester group (—OCOR or —COOR: R is a C₁₋₆ alkyl group or a fluorinated alkyl group), or a carboxyl group. v is 1 or 2. 0<p<1.0, 0≦q1<1.0, 0≦q2<1.0, 0≦q3<1.0, 0≦q4<1.0, and 0<q1+q2+q3+q4<1.0.

The resin (A) may have a repeating unit described in paragraphs [0058] to [0110] of JP2014-126623A (for example, a repeating unit having an acid-labile group), a repeating unit described in paragraphs [0111] to [0130] of JP2014-126623A (for example, an adhesive group), and a repeating unit derived from the polymerizable monomer described in paragraphs [0034] to [0042] of JP2014-126623A.

The resin (A) may have a repeating unit having a non-acid-decomposable group described in paragraphs [0173] to [0211] of JP2014-134686A. A specific example of the repeating unit having a non-acid-decomposable group may be a repeating unit represented by the following General Formula (4). If the resin (A) has the repeating unit represented by General Formula (4), the Tg of the polymer compound (D) becomes higher and a very hard resist film can be formed, so that the acid diffusibility and the dry etching resistance can be further controlled.

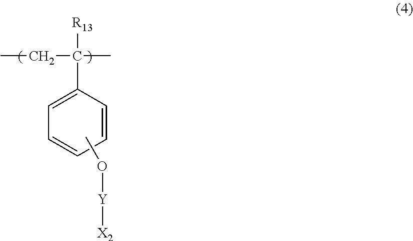

In General Formula (4), R₁₃ represents a hydrogen atom or a methyl group. Y represents a single bond or a divalent linking group. X₂ represents a non-acid-decomposable polycyclic alicyclic hydrocarbon group.

The resin (A) preferably contains, for example, a repeating unit (a) having an acid-decomposable group on the main chain, the side chain, or both thereof of the resin.

The repeating unit (a) is more preferably a repeating unit represented by the following General Formula (V).

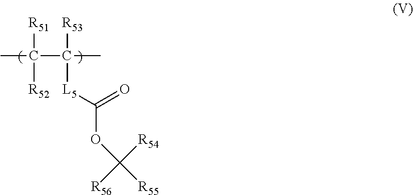

In General Formula (V),

R₅₁, R₅₂, and R₅₃ each independently represent a hydrogen atom, an alkyl group, a cycloalkyl group, a halogen atom, a cyano group, or an alkoxycarbonyl group. R₅₂ and L₅ may be bonded to each other to form a ring, and R₅₂ in this case represents an alkylene group.

L₅ represents a single bond or a divalent linking group, and L₅ represents a trivalent linking group in the case of forming a ring together with R₅₂.

R₅₄ represents an alkyl group, and R₅₅ and R₅₆ each independently represent a hydrogen atom, an alkyl group, a cycloalkyl group, an aryl group, or an aralkyl group. R₅₅ and R₅₆ may be bonded to each other to form a ring. Meanwhile, R₅₅ and R₅₆ are not simultaneously a hydrogen atom.

General Formula (V) will be described in further detail.

Examples of the alkyl group of R₅₁ to R₅₃ in General Formula (V) preferably include alkyl groups having 20 or less carbon atoms which may have a substituent, such as a methyl group, an ethyl group, a propyl group, an isopropyl group, an n-butyl group, a sec-butyl group, a hexyl group, a 2-ethylhexyl group, an octyl group, and a dodecyl group, more preferably alkyl groups having 8 or less carbon atoms, and particularly preferably alkyl groups having 3 or less carbon atoms.

The alkyl group contained in the alkoxycarbonyl group is preferably the same as the alkyl group in R₅₁ to R₅₃.

The cycloalkyl group may be monocyclic or polycyclic. Examples of the cycloalkyl group preferably include monocyclic cycloalkyl groups having 3 to 10 carbon atoms which may have a substituent, such as a cyclopropyl group, a cyclopentyl group, and a cyclohexyl group.

Examples of the halogen atom include a fluorine atom, a chlorine atom, a bromine atom, and an iodine atom, among which particularly preferred is a fluorine atom.

Preferable examples of the substituent in each of the above-mentioned groups include an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group. The number of carbon atoms in the substituent is preferably 8 or less.

In the case where R₅₂ is an alkylene group and forms a ring together with L₅, examples of the alkylene group preferably include alkylene groups having 1 to 8 carbon atoms such as a methylene group, an ethylene group, a propylene group, a butylene group, a hexylene group, and an octylene group. More preferred are alkylene groups having 1 to 4 carbon atoms, and particularly preferred are alkylene groups having 1 or 2 carbon atoms. The ring formed by bonding of R₅₂ and L₅ is particularly preferably a 5- or 6-membered ring.

R₅₁ and R₅₃ in Formula (V) are more preferably a hydrogen atom, an alkyl group, or a halogen atom, and particularly preferably a hydrogen atom, a methyl group, an ethyl group, a trifluoromethyl group (—CF₃), a hydroxymethyl group (—CH₂—OH), a chloromethyl group (—CH₂—Cl), or a fluorine atom (—F). R₅₂ is more preferably a hydrogen atom, an alkyl group, a halogen atom, or an alkylene group (which forms a ring together with L₅), and particularly preferably a hydrogen atom, a methyl group, an ethyl group, a trifluoromethyl group (—CF₃), a hydroxymethyl group (—CH₂—OH), a chloromethyl group (—CH₂—Cl), a fluorine atom (—F), methylene group (which forms a ring together with L₅), or an ethylene group (which forms a ring together with L₅).

Examples of the divalent linking group represented by L₅ include an alkylene group, a divalent aromatic ring group, —COO-L₁-, —O-L₁-, and a group formed by combining two or more of these groups. Here, L₁ represents an alkylene group, a cycloalkylene group, a divalent aromatic ring group, or a group formed by combining an alkylene group and a divalent aromatic ring group.

L₅ is preferably a single bond, a group represented by —COO-L₁-, or a divalent aromatic ring group. L₁ is preferably an alkylene group having 1 to 5 carbon atoms and more preferably a methylene or propylene group. The divalent aromatic ring group is preferably a 1,4-phenylene group, a 1,3-phenylene group, a 1,2-phenylene group, or a 1,4-naphthylene group and more preferably a 1,4-phenylene group.

Examples of the trivalent linking group represented by L₅ in the case of forming a ring by bonding of L₅ and R₅₂ preferably include groups formed by removing one hydrogen atom from the above-mentioned specific examples of the divalent linking group represented by L₅.

The alkyl group of R₅₄ to R₅₆ is preferably an alkyl group having 1 to 20 carbon atoms, more preferably an alkyl group having 1 to 10 carbon atoms, and particularly preferably an alkyl group having 1 to 4 carbon atoms, such as a methyl group, an ethyl group, an n-propyl group, an isopropyl group, an n-butyl group, an isobutyl group, or a t-butyl group.

The cycloalkyl group represented by R₅₅ and R₅₆ is preferably a cycloalkyl group having 3 to 20 carbon atoms and may be a monocyclic cycloalkyl group such as a cyclopentyl group or a cyclohexyl group or a polycyclic cycloalkyl group such as a norbornyl group, an adamantyl group, a tetracyclodecanyl group, or a tetracyclododecanyl group.

The ring formed by bonding of R₅₅ and R₅₆ to each other is preferably a ring having 3 to 20 carbon atoms and may be a monocyclic ring such as a cyclopentyl group or a cyclohexyl group or a polycyclic ring such as a norbornyl group, an adamantyl group, a tetracyclodecanyl group, or a tetracyclododecanyl group. In the case where R₅₅ and R₅₆ are bonded to each other to form a ring, R₅₄ is preferably an alkyl group having 1 to 3 carbon atoms and more preferably a methyl group or an ethyl group.

The aryl group represented by R₅₅ and R₅₆ is preferably an aryl group having 6 to 20 carbon atoms and may be monocyclic or polycyclic and may have a substituent. For example, mention may be made of a phenyl group, a 1-naphthyl group, a 2-naphthyl group, a 4-methylphenyl group, and a 4-methoxyphenyl group. In the case where one of R₅₅ and R₅₆ is a hydrogen atom, it is preferred that the other is an aryl group.

The aralkyl group represented by R₅₅ and R₅₆ may be monocyclic or polycyclic and may have a substituent. Preferred is an aralkyl group having 7 to 21 carbon atoms, examples of which include a benzyl group and a 1-naphthylmethyl group.

With respect to the synthetic method of a monomer corresponding to the repeating unit represented by General Formula (V), it is possible to apply a general method for synthesizing a polymerizable group-containing ester, for which there is no case of being particularly limited.

Specific examples of the repeating unit (a) represented by General Formula (V) are shown below, but the present invention is not limited thereto.

In the specific examples, Rx and Xa₁ represent a hydrogen atom, CH₃, CF₃, or CH₂OH. Rxa and Rxb each independently represent an alkyl group having 1 to 4 carbon atoms, an aryl group having 6 to 18 carbon atoms, or an aralkyl group having 7 to 19 carbon atoms. Z represents a substituent. p represents 0 or a positive integer and is preferably 0 to 2, more preferably 0 or 1. In the case where there are a plurality of Z's, they may be the same or different from one another. From the viewpoint of increasing the dissolution contrast in a developer containing an organic solvent before and after acid decomposition, Z may be suitably a group consisting of only hydrogen atoms and carbon atoms, which is preferably, for example, a linear or branched alkyl group or cycloalkyl group.

As the repeating unit (a) represented by General Formula (V), the repeating unit described in paragraphs [0227] to [0232] of JP2014-232309A may also be used.

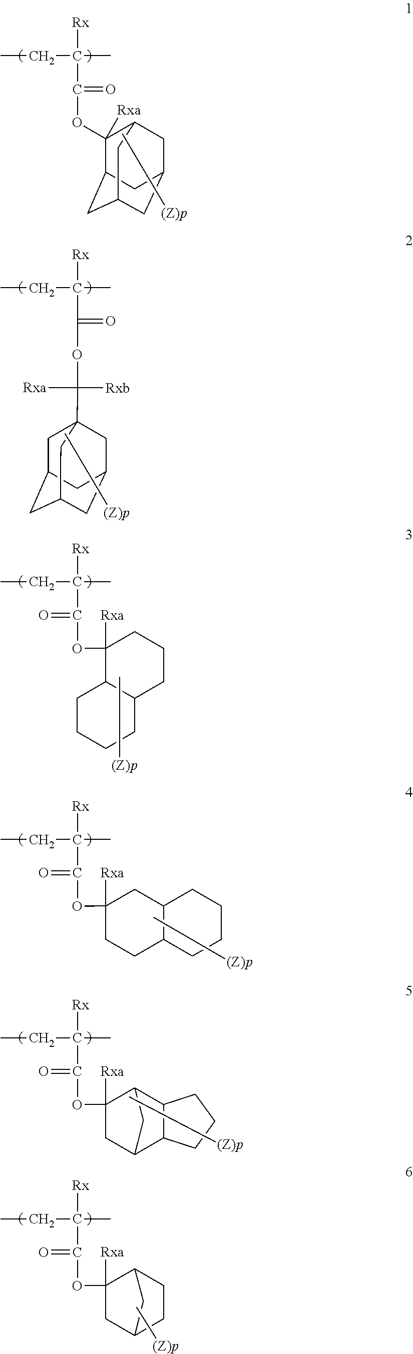

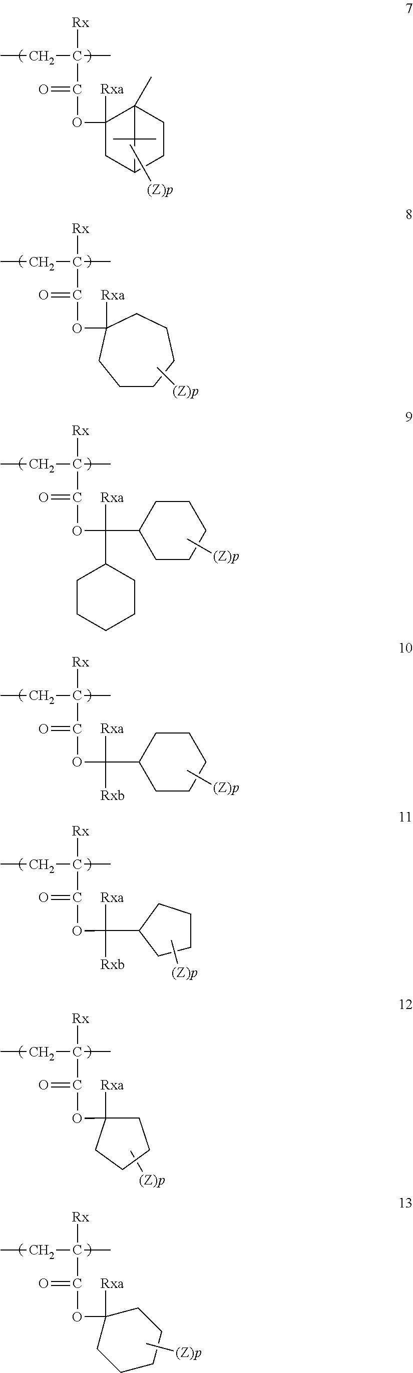

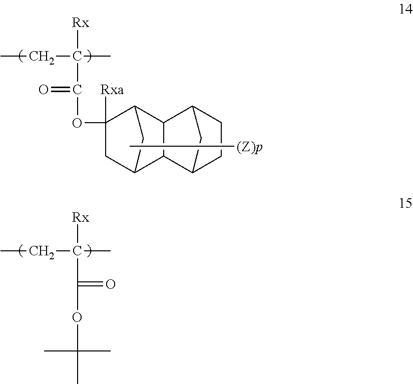

Further, the resin (A) may contain a repeating unit represented by the following General Formula (VI) as the repeating unit (a).

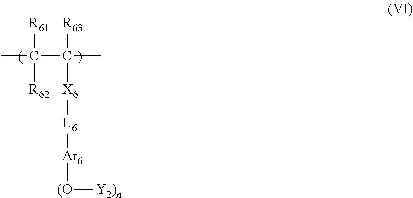

In General Formula (VI),

R₆₁, R₆₂, and R₆₃ each independently represent a hydrogen atom, an alkyl group, a cycloalkyl group, a halogen atom, a cyano group, or an alkoxycarbonyl group. Meanwhile, R₆₂ and Ar₆ may be bonded to each other to form a ring, and R₆₂ in this case represents a single bond or an alkylene group.

X₆ represents a single bond, —COO—, or —CONR₆₄—. R₆₄ represents a hydrogen atom or an alkyl group.

L₆ represents a single bond or an alkylene group.

Ar₆ represents a (n+1)-valent aromatic ring group, and Ar₆ represents a (n+2)-valent aromatic ring group in the case of being bonded to R₆₂ to form a ring.

In the case of n≧2, Y₂'s each independently represent a hydrogen atom or a group capable of leaving by the action of an acid, provided that at least one of Y₂'s represents a group capable of leaving by the action of an acid.

n represents an integer of 1 to 4.

The group Y₂ capable of leaving by the action of an acid is more preferably a structure represented by the following General Formula (VI-A).

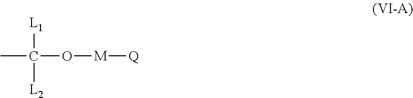

Here, L₁ and L₂ each independently represent a hydrogen atom, an alkyl group, a cycloalkyl group, an aryl group, or a group formed by combining an alkylene group and an aryl group.

M represents a single bond or a divalent linking group.

Q represents an alkyl group, a cycloalkyl group which may contain a heteroatom, an aryl group which may contain a heteroatom, an amino group, an ammonium group, a mercapto group, a cyano group, or an aldehyde group.

At least two of Q, M, and L₁ may be bonded to form a ring (preferably, a 5-membered or 6-membered ring).

The repeating unit represented by General Formula (VI) is preferably a repeating unit represented by the following General Formula (3).

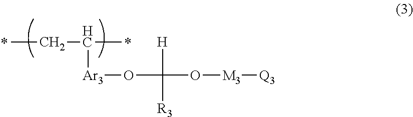

In General Formula (3),

Ar₃ represents an aromatic ring group.

R₃ represents a hydrogen atom, an alkyl group, a cycloalkyl group, an aryl group, an aralkyl group, an alkoxy group, an acyl group, or a hetero ring group.

M₃ represents a single bond or a divalent linking group.

Q₃ represents an alkyl group, a cycloalkyl group, an aryl group, or a hetero ring group.

At least two of Q₃, M₃, and R₃ may be bonded to form a ring.

The aromatic ring group represented by Ar₃ is the same as Ar₆ in General Formula (VI) in the case where n in General Formula (VI) is 1, more preferably a phenylene group or a naphthylene group, and still more preferably a phenylene group.

Specific examples of the repeating unit represented by General Formula (VI) as preferred specific examples of the repeating unit (a) are shown below, but the present invention is not limited thereto.

As the repeating unit represented by General Formula (VI), the repeating units described in paragraphs [0210] to [0216] of JP2014-232309A may also be used.

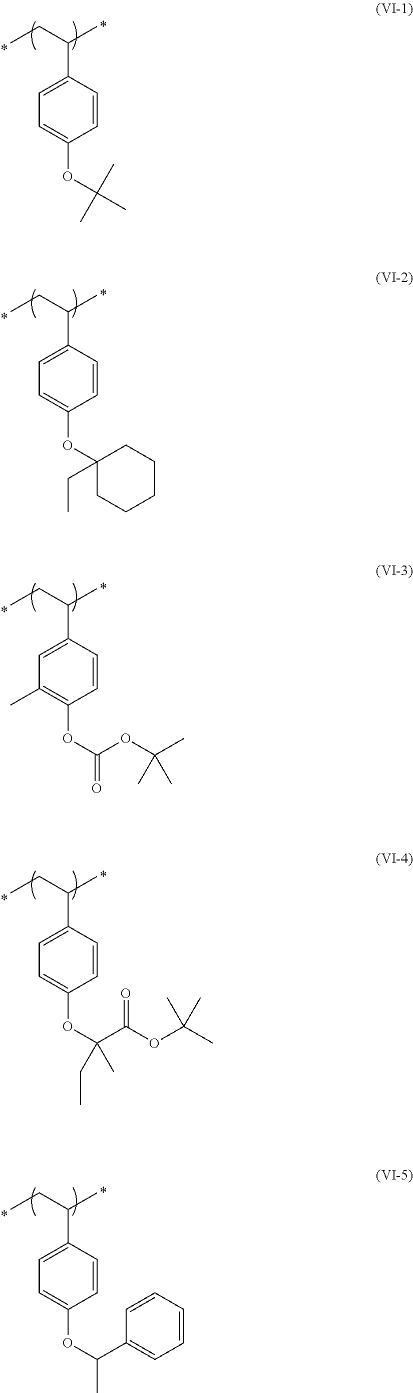

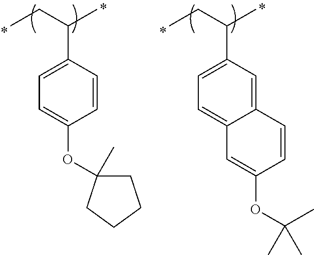

The resin (A) also preferably contains a repeating unit represented by the following General Formula (4).

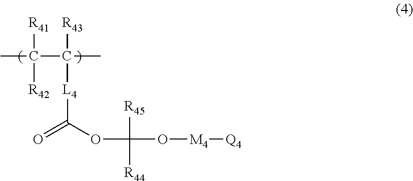

In General Formula (4),

R₄₁, R₄₂, and R₄₃ each independently represent a hydrogen atom, an alkyl group, a cycloalkyl group, a halogen atom, a cyano group, or an alkoxycarbonyl group. R₄₂ and L₄ may be bonded to form a ring, and R₄₂ in this case represents an alkylene group.

L₄ represents a single bond or a divalent linking group, and L₄ represents a trivalent linking group in the case of forming a ring together with R₄₂.

R₄₄ and R₄₅ represent a hydrogen atom, an alkyl group, a cycloalkyl group, an aryl group, an aralkyl group, an alkoxy group, an acyl group, or a hetero ring group.

M₄ represents a single bond or a divalent linking group.

Q₄ represents an alkyl group, a cycloalkyl group, an aryl group, or a hetero ring group.

At least two of Q₄, M₄, and R₄₄ may be bonded to form a ring.

R₄₁, R₄₂, and R₄₃ have the same definition as R₅₁, R₅₂, and R₅₃ in the above-mentioned General Formula (V), and preferred ranges thereof are also the same.

L₄ has the same definition as L₅ in the above-mentioned General Formula (V), and a preferred range thereof is also the same.

R₄₄ and R₄₅ have the same definition as R₃ in the above-mentioned General Formula (3), and preferred ranges thereof are also the same.

M₄ has the same definition as M₃ in the above-mentioned General Formula (3), and a preferred range thereof is also the same.

Q₄ has the same definition as Q₃ in the above-mentioned General Formula (3), and a preferred range thereof is also the same. Examples of the ring formed by bonding of at least two of Q₄, M₄, and R₄₄ include rings formed by bonding of at least two of Q₃, M₃, and R₃, and preferred ranges thereof are also the same.

Specific examples of the repeating unit represented by General Formula (4) include the repeating units described in paragraphs [0270] to [0272] of JP2014-232309A, but the present invention is not limited thereto.

Further, the resin (A) may contain repeating units described in paragraphs [0101] to [0131] of JP2012-208447A as the repeating unit (a).

The repeating units having an acid-decomposable group may be used alone or in combination of two or more thereof.

The content of the repeating unit having an acid-decomposable group in the resin (A) (total content of repeating units in the case of containing a plurality of types of repeating units) is preferably 5 mol % or more and 80 mol % or less, more preferably 5 mol % or more and 75 mol % or less, and still more preferably 10 mol % or more and 65 mol % or less, with respect to all repeating units in the resin (A).

The resin (A) may further have a repeating unit having a silicon atom in the side chain. Examples of the repeating unit having a silicon atom in the side chain include a (meth)acrylate-based repeating unit having a silicon atom and a vinyl-based repeating unit having a silicon atom. The repeating unit having a silicon atom in the side chain is typically a repeating unit having a group having a silicon atom in the side chain. Examples of the group having a silicon atom include a trimethylsilyl group, a triethylsilyl group, a triphenylsilyl group, a tricyclohexylsilyl group, a tristrimethylsiloxysilyl group, a tristrimethylsilylsilyl group, a methylbistrimethylsilylsilyl group, a methylbistrimethylsiloxysilyl group, a dimethyltrimethylsilylsilyl group, a dimethyltrimethylsiloxysilyl group, a cyclic or linear polysiloxane, and a cage-type or ladder-type or random-type silsesquioxane structure as described below. In the formulae, R and R¹ each independently represent a monovalent substituent. * represents a bond.

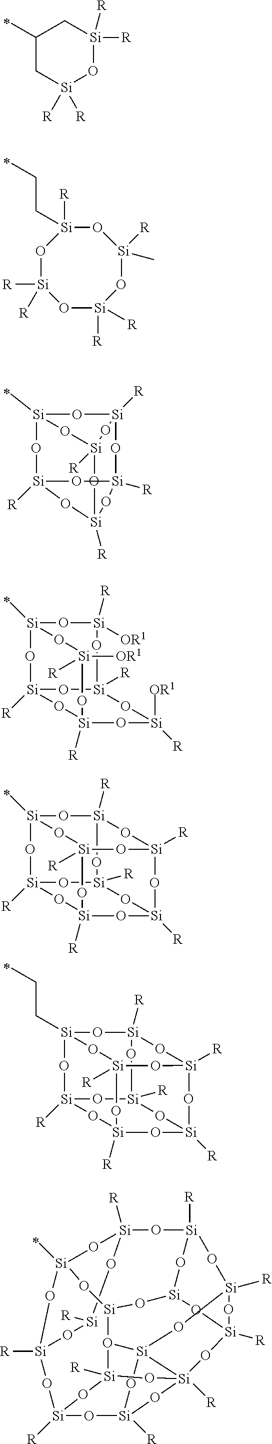

Examples of the repeating units having the above-mentioned group preferably include a repeating unit derived from an acrylate or methacrylate compound having the above-mentioned group, and a repeating unit derived from compound having the above-mentioned group and a vinyl group.

The repeating unit having a silicon atom is preferably a repeating unit having a silsesquioxane structure, whereby it is possible to express a very excellent collapse performance in the formation of an ultra fine (for example, a line width of 50 nm or less) pattern having a cross-sectional shape of a high aspect ratio (for example, film thickness/line width of 3 or more).

Examples of the silsesquioxane structure include a cage-type silsesquioxane structure, a ladder-type silsesquioxane structure, and a random-type silsesquioxane structure. Among them, preferred is a cage-type silsesquioxane structure.

Here, the cage-type silsesquioxane structure is a silsesquioxane structure having a cage-like skeleton. The cage-type silsesquioxane structure may be a complete cage-type silsesquioxane structure or an incomplete cage-type silsesquioxane structure, among which preferred is a complete cage-type silsesquioxane structure.

The ladder-type silsesquioxane structure is a silsesquioxane structure having a ladder-like skeleton.

The random-type silsesquioxane structure is a silsesquioxane structure whose skeleton is of random.

The cage-type silsesquioxane structure is preferably a siloxane structure represented by the following Formula (S).

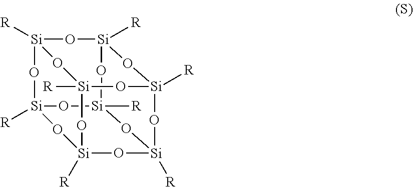

In Formula (S), R represents a monovalent organic group. A plurality of R's may be the same or different.

The organic group is not particularly limited, and specific examples thereof include a hydrocarbon group which may have a hydroxy group, a nitro group, a carboxy group, an alkoxy group, an amino group, a mercapto group, a blocked mercapto group (for example, an acyl group-blocked (protected) mercapto group), an acyl group, an imido group, a phosphino group, a phosphinyl group, a silyl group, a vinyl group, or a heteroatom, a (meth)acrylic group-containing group, and an epoxy group-containing group.

Examples of the heteroatom in the hydrocarbon group which may have a heteroatom include an oxygen atom, a nitrogen atom, a sulfur atom, and a phosphorus atom.

Examples of the hydrocarbon group in the hydrocarbon group which may have a heteroatom include an aliphatic hydrocarbon group, an aromatic hydrocarbon group, and a group formed by combining these groups.

The aliphatic hydrocarbon group may be linear, branched or cyclic. Specific examples of the aliphatic hydrocarbon group include a linear or branched alkyl group (particularly, having 1 to 30 carbon atoms), a linear or branched alkenyl group (particularly, having 2 to 30 carbon atoms), and a linear or branched alkynyl group (particularly, having 2 to 30 carbon atoms).

Examples of the aromatic hydrocarbon group include aromatic hydrocarbon groups having 6 to 18 carbon atoms, such as a phenyl group, a tolyl group, a xylyl group, and a naphthyl group.

In the case where the resin (A) has a repeating unit having a silicon atom in the side chain, the content thereof is preferably 1 to 30 mol %, more preferably 5 to 25 mol %, and still more preferably 5 to 20 mol %, with respect to all repeating units in the resin (A).

<Resin (A′)>

The resist composition of the present invention may contain a resin (A′) in place of the resin (A). The resin (A′) can be referred to as a main chain scission type resin because the main chain of the polymer is cleaved by the direct or indirect action of radiation (or actinic energy rays) to result in lowering of the molecular weight. Cleavage of the main chain by the direct action of radiation (or actinic energy rays) takes place by excited molecules generated upon irradiation of the polymer with radiation (or actinic energy rays) and cleavage of polymer radicals generated in the stabilization process of the excited molecules.

The resin (A′) is a resin containing a copolymer of a styrene-based monomer and an acrylic monomer and is suitable for the formation of a pattern by irradiation of electron beams. The ratio (on a molar basis) of structural units in this copolymer is 80/20 to 20/80, preferably 75/25 to 25/75, and more preferably 70/30 to 30/70 in terms of styrene-based monomer-derived structural unit/acrylic monomer-derived structural unit.

The styrene-based monomer is a monomer having a styrene structure and specific examples thereof include styrene such as styrene, 4-methylstyrene, 4-propylstyrene, 4-isopropylstyrene, 4-butylstyrene, 4-isobutylstyrene, 3,4-dimethylstyrene, 4-ethyl-3-methylstyrene, 4-hydroxystyrene, 4-hydroxy-3-methylstyrene, or 4-methoxystyrene, a 4-position substitution product thereof, or a 3,4-position substitution product thereof; α-methylstyrene such as α-methylstyrene, 4-methyl-α-methylstyrene, 4-propyl-α-methylstyrene, 4-isopropyl-α-methylstyrene, 4-butyl-α-methylstyrene, 4-isobutyl-α-methylstyrene, 3,4-dimethyl-α-methyl styrene, 4-ethyl-3-methyl-α-methylstyrene, 4-hydroxy-α-methylstyrene, 4-hydroxy-3-methyl-α-methylstyrene, or 4-methoxy-α-methylstyrene, a 4-position substitution product thereof, or a 3,4-position substitution product thereof; and

α-chlorostyrene such as α-chlorostyrene, 4-methyl-α-chlorostyrene, 4-propyl-α-chlorostyrene, 4-isopropyl-α-chlorostyrene, 4-butyl-α-chlorostyrene, 4-isobutyl-α-chlorostyrene, 3,4-dimethyl-α-chlorostyrene, 4-ethyl-3-methyl-α-chlorostyrene, 4-hydroxy-α-chlorostyrene, 4-hydroxy-3-methyl-α-chlorostyrene, or 4-methoxy-α-chlorostyrene, a 4-position substitution product thereof, or a 3,4-position substitution product thereof.

Among these, an α-methylstyrene-based compound (α-methylstyrene, a 4-position substitution product thereof, or a 3,4-position substitution product thereof) is particularly preferable in terms of giving a good pattern shape.

The acrylic monomer is an acrylic acid derivative and specific examples thereof include alkyl (meth)acrylate such as methyl (meth)acrylate, ethyl (meth)acrylate, propyl (meth)acrylate, isopropyl (meth)acrylate, or butyl (meth)acrylate; aryl (meth)acrylate such as phenyl (meth)acrylate or 4-chlorophenyl (meth)acrylate; aralkyl (meth)acrylate such as benzyl (meth)acrylate or 3,4-dimethylbenzyl (meth)acrylate; alkyl α-haloacrylate such as methyl α-chloroacrylate, ethyl α-chloroacrylate, propyl α-bromoacrylate, isopropyl α-chloroacrylate, or butyl α-bromoacrylate; aryl α-haloacrylate such as phenyl α-chloroacrylate; aralkyl α-haloacrylate such as benzyl α-bromoacrylate or 3,4-dimethylbenzyl α-chloroacrylate;

alkyl α-cyanoacrylate such as methyl α-cyanoacrylate, ethyl α-cyanoacrylate, propyl α-cyanoacrylate, isopropyl α-cyanoacrylate, or butyl α-cyanoacrylate; aryl α-cyanoacrylate such as phenyl α-cyanoacrylate; aralkyl α-cyanoacrylate such as benzyl α-cyanoacrylate or 3,4-dimethylbenzyl α-cyanoacrylate; substitutable acrylonitrile such as acrylonitrile, methacrylonitrile, α-chloroacrylonitrile, or α-bromoacrylonitrile; N-substitutable acrylamide such as acrylamide, N-methylacrylamide, N,N-dimethylacrylamide, or N-phenylacrylamide; N-substitutable methacrylamide such as methacrylamide, N-methylmethacrylamide, N,N-dimethylmethacrylamide, or N-phenylmethacrylamide; and N-substitutable α-haloacrylamide such as α-chloroacrylamide, α-bromoacrylamide, N-methyl-α-chloroacrylamide, N,N-dimethyl-α-chloroacrylamide, or N-phenyl-α-chloroacrylamide.

Further examples of the acrylic monomer include resist materials containing a copolymer of an α-chloroacrylic acid ester-based compound and an α-methylstyrene-based compound as a main component, described in paragraphs [0025] to [0029] and [0056] of JP2013-210411A and paragraphs [0032] to [0036] and [0063] of US2015/0008211A.

The resist composition of the present invention may contain a molecular resist (A″) in place of the resin (A).

The molecular resist is a low molecular weight material consisting of a single molecule and generally refers to a non-polymer having a molecular weight of 300 to 3000. Specifically, it is possible to use, for example, cyclic polyphenolic compounds having a low molecular weight described in JP2009-173623A and JP2009-173625A, calixarenes described in JP2004-18421A, Noria derivatives described in JP2009-222920A, and the like.

The resist composition of the present invention may contain a metal resist (A′″) in place of the resin (A).

The metal resist (A′″) includes a metal complex (which is a complex of magnesium, chromium, manganese, iron, cobalt, nickel, copper, zinc, silver, cadmium, indium, tin, antimony, cesium, zirconium, hafnium, or the like, among which titanium, zirconium, or hafnium is preferable from the viewpoint of pattern formability), examples of which include resists involving a ligand exchange process in combination with ligand elimination or an acid generator (resist materials described in paragraphs [0017] to [0033] and [0037] to [0047] of JP2015-075500A, paragraphs [0017] to [0032] and [0043] to [0044] of JP2012-185485A, paragraphs [0042] to [0051] and [0066] of US2012/0208125A, or the like).

As the metal resist (A′″), it is possible to use those described in literature, for example, Ekinci et al., Proc. SPIE, 2013, 8679, Trikeriotis, et al., Proc. SPIE, 2012, 8322, Souvik Chakrabarty et al., Proc. SPIE 9048, 90481C (2014), Marie E. Krysak et al., Proc. SPIE 9048, 904805 (2014), James Singh et al., Proc. SPIE 9051, 90512A (2014), Vikram Singh et al., Proc. SPIE 9051, 90511 W (2014), Mankyu Kang et al., Proc. SPIE 9051, 90511U (2014), and R. P. Oleksak et al., Proc. SPIE 9048, 90483H (2014).

As the resist composition, it is also possible to use the resist compositions described in paragraphs [0010] to [0062] and [0129] to [0165] of JP2008-83384A.

(B) Compound capable of generating acid upon irradiation with actinic rays or radiation

The resist composition of the present invention contains a compound capable of generating an acid upon irradiation with actinic rays or radiation (also referred to as “photoacid generator” or “(B) component”).

As such a photoacid generator, there are known compounds capable of generating an acid upon irradiation with actinic rays or radiation, and mixtures thereof, which have been used in a photocationic polymerization photoinitiator, a photoradical polymerization photoinitiator, a dye photodecolorizer, a photodiscolorizer, or a microresist. These acid generators may be properly selected for use.

For example, mention may be made of a diazonium salt, a phosphonium salt, a sulfonium salt, an iodonium salt, an imide sulfonate, an oxime sulfonate, a diazodisulfone, a disulfone, and an o-nitrobenzyl sulfonate.

Compounds in which such a group or compound capable of generating an acid upon irradiation with actinic rays or radiation is introduced into the main chain or side chain of the polymer, for example, the compounds described in U.S. Pat. No. 3,849,137A, German Patent No. 3914407, JP1988-26653A (JP-S63-26653A), JP1980-164824A (JP-S55-164824A), JP1987-69263A (JP-S62-69263A), JP1988-146038A (JP-S63-146038A), JP1988-163452A (JP-S63-163452A), JP1987-153853A (JP-S62-153853A), JP1988-146029A (JP-S63-146029A), and the like may be used.

Further compounds capable of generating an acid by the action of light, which are described in U.S. Pat. No. 3,779,778A, EP126712B, or the like, may also be used.

Examples of the preferred compound among the compounds capable of decomposing upon irradiation of actinic rays or radiation to generate an acid include compounds represented by the following General Formulae (ZI), (ZII), and (ZIII).

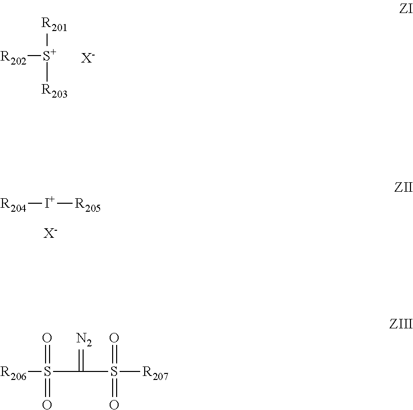

In General Formula (ZI), R₂₀₁, R₂₀₂, and R₂₀₃ each independently represent an organic group.

X⁻ represents a non-nucleophilic anion, examples of which preferably include a sulfonic acid anion, a carboxylic acid anion, a bis(alkylsulfonyl)amide anion, a tris(alkylsulfonyl)methide anion, BF₄⁻, PF₆⁻, and SbF₆⁻. Preferred is an organic anion containing a carbon atom.

Preferred examples of the organic anion include organic anions represented by the following formulae.

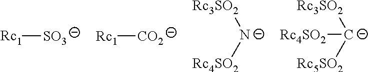

In the formulae, Rc₁ represents an organic group.

Examples of the organic group in Rc₁ include organic groups having 1 to 30 carbon atoms, preferably alkyl groups or aryl groups which may be substituted, and a group formed by linking a plurality of these groups through a linking group such as a single bond, —O—, —CO₂—, —S—, —SO₃—, or —SO₂N(Rd₁)-. Rd₁ represents a hydrogen atom or an alkyl group.

Rc₃, Rc₄, and Rc₅ each independently represent an organic group. The organic group of Rc₃, Rc₄, and Rc₅ may be preferably the same as the preferred organic group in Rc₁ and is most preferably a perfluoroalkyl group having 1 to 4 carbon atoms.

Rc₃ and Rc₄ may be bonded to each other to form a ring. Examples of the group formed by bonding of Rc₃ and Rc₄ include an alkylene group and an arylene group. Preferred is a perfluoroalkylene group having 2 to 4 carbon atoms.

The organic group of Rc₁, and Rc₃ to Rc₅ is particularly preferably an alkyl group in which the 1-position is substituted with a fluorine atom or a fluoroalkyl group, or a phenyl group substituted with a fluorine atom or a fluoroalkyl group. By the incorporation of a fluorine atom or a fluoroalkyl group, the acidity of the acid generated upon irradiation with light is increased and the sensitivity is improved. By bonding of Rc₃ and Rc₄ to form a ring, the acidity of the acid generated upon irradiation with light is increased and the sensitivity is improved.

Preferred examples of the organic anion X⁻ include sulfonic acid anions represented by the following General Formula (SA1) or (SA2).

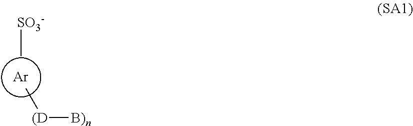

In Formula (SA1),

Ar represents an aryl group which may further have a substituent other than the -(D-B) group.

n represents an integer of 1 or more. n is preferably 1 to 4, more preferably 2 to 3, and most preferably 3.

D represents a single bond or a divalent linking group. The divalent linking group is, for example, an ether group, a thioether group, a carbonyl group, a sulfoxide group, a sulfone group, a sulfonic acid ester group, or an ester group.

B represents a hydrocarbon group.

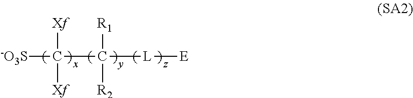

In Formula (SA2),

Xf's each independently represent a fluorine atom, or an alkyl group in which at least one hydrogen atom is substituted with a fluorine atom.

R₁ and R₂ each independently represent a group selected from the group consisting of a hydrogen atom, a fluorine atom, an alkyl group, and an alkyl group in which at least one hydrogen atom is substituted with a fluorine atom. In the case where there is a plurality of R₁'s and R₂'s, they may be respectively the same or different from one another.

L represents a single bond or a divalent linking group, and in the case where there is a plurality of L's, they may be the same or different from one another.

E represents a group having a cyclic structure.

x represents an integer of 1 to 20, y represents an integer of 0 to 10, and z represents an integer of 0 to 10.

First, the sulfonic acid anion represented by Formula (SA1) will be described in detail.

In Formula (SA1), Ar is preferably an aromatic ring having 6 to 30 carbon atoms. Specifically, Ar is, for example, a benzene ring, a naphthalene ring, a pentalene ring, an indene ring, an azulene ring, a heptalene ring, an indecene ring, a perylene ring, a pentacene ring, an acenaphthalene ring, a phenanthrene ring, an anthracene ring, a naphthacene ring, a chrysene ring, a triphenylene ring, a fluorene ring, a biphenyl ring, a pyrrole ring, a furan ring, a thiophene ring, an imidazole ring, an oxazole ring, a thiazole ring, a pyridine ring, a pyrazine ring, a pyrimidine ring, a pyridazine ring, an indolizine ring, an indole ring, a benzofuran ring, a benzothiophene ring, an isobenzofuran ring, a quinolizine ring, a quinoline ring, a phthalazine ring, a naphthyridine ring, a quinoxaline ring, a quinoxazoline ring, an isoquinoline ring, a carbazole ring, a phenanthridine ring, an acridine ring, a phenanthroline ring, a thianthrene ring, a chromene ring, a xanthene ring, a phenoxathiin ring, a phenothiazine ring, or a phenazine ring. Among these, from the viewpoint of compatibility between roughness improvement and high sensitivity, a benzene ring, a naphthalene ring, or an anthracene ring is preferable, and a benzene ring is more preferable.

In the case where Ar further has a substituent other than the -(D-B) group, examples of the substituent include the same ones as those described above for R, among which a linear alkyl group and a branched alkyl group are preferable from the viewpoint of improving roughness.

In Formula (SA1), D is preferably a single bond, an ether group, or an ester group and more preferably a single bond.

In Formula (SA1), B is, for example, an alkyl group, an alkenyl group, an alkynyl group, an aryl group, or a cycloalkyl group. B is preferably an alkyl group or a cycloalkyl group. The alkyl group, the alkenyl group, the alkynyl group, the aryl group, or the cycloalkyl group represented by B may have a substituent.

The alkyl group represented by B is preferably a branched alkyl group. Examples of the branched alkyl group include an isopropyl group, a tert-butyl group, a tert-pentyl group, a neopentyl group, a sec-butyl group, an isobutyl group, an isohexyl group, a 3,3-dimethylpentyl group, and a 2-ethylhexyl group.

The cycloalkyl group represented by B may be a monocyclic or polycyclic cycloalkyl group. Examples of the monocyclic cycloalkyl group include a cyclopropyl group, a cyclobutyl group, a cyclopentyl group, a cyclohexyl group, a cycloheptyl group, and a cyclooctyl group. Examples of the polycyclic cycloalkyl group include an adamantyl group, a norbornyl group, a bornyl group, a camphenyl group, a decahydronaphthyl group, a tricyclodecanyl group, a tetracyclodecanyl group, a camphoroyl group, a dicyclohexyl group, and a pinenyl group.

In the case where the alkyl group, the alkenyl group, the alkynyl group, the aryl group, or the cycloalkyl group represented by B has a substituent, examples of the substituent include the same ones as those described above for R, among which a linear alkyl group and a branched alkyl group are preferable from the viewpoint of compatibility between roughness improvement and high sensitivity.

Next, the sulfonic acid anion represented by Formula (SA2) will be described in detail.

In Formula (SA2), Xf is a fluorine atom or an alkyl group in which at least one hydrogen atom is substituted with a fluorine atom. This alkyl group preferably has 1 to 10 carbon atoms and more preferably 1 to 4 carbon atoms. The alkyl group substituted with a fluorine atom is preferably a perfluoroalkyl group.

Xf is preferably a fluorine atom or a perfluoroalkyl group having 1 to 4 carbon atoms. Specifically, Xf is preferably a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, or CH₂CH₂C₄F₉. Among these, a fluorine atom or CF₃ is preferable, and a fluorine atom is most preferable.

In Formula (SA2), each of R₁ and R₂ is a group selected from a hydrogen atom, a fluorine atom, an alkyl group, and an alkyl group in which at least one hydrogen atom is substituted with a fluorine atom. The alkyl group which may be substituted with a fluorine atom is preferably an alkyl group having 1 to 4 carbon atoms. The alkyl group substituted with a fluorine atom is particularly preferably a perfluoroalkyl group having 1 to 4 carbon atoms. Specifically, examples of the alkyl group substituted with a fluorine atom include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉, and CH₂CH₂C₄F₉. Among these, CF₃ is preferable.

In Formula (SA2), x is preferably 1 to 8 and more preferably 1 to 4. y is preferably 0 to 4 and more preferably 0. z is preferably 0 to 8 and more preferably 0 to 4.

In Formula (SA2), L represents a single bond or a divalent linking group. Examples of the divalent linking group include —COO—, —OCO—, —CO—, —O—, —S—, —SO—, —SO₂—, an alkylene group, a cycloalkylene group, and an alkenylene group. Among these, —COO—, —OCO—, —CO—, —O—, —S—, —SO—, or —SO₂— is preferable, and COO—, —OCO—, or —SO₂— is more preferable.

In General Formula (SA2), SO³⁻—CF₂—CH₂—OCO—, SO³⁻—CF₂—CHF—CH₂—OCO—, SO³⁻—CF₂—COO—, SO³⁻—CF₂—CF₂—CH₂—, or SO³⁻—CF₂—CH(CF₃)—OCO— is preferable as a combination of partial structures other than A.

In Formula (SA2), E represents a group having a cyclic structure. Examples of the group having a cyclic structure include a cyclic aliphatic group, an aryl group, and a group having a heterocyclic structure.

The cyclic aliphatic group represented by E may have a monocyclic structure or a polycyclic structure. As the cyclic aliphatic group having a monocyclic structure, monocyclic cycloalkyl groups such as a cyclopentyl group, a cyclohexyl group, and a cyclooctyl group are preferable. As the cyclic aliphatic group having a polycyclic structure, polycyclic cycloalkyl groups such as a norbornyl group, a tricyclodecanyl group, a tetracyclodecanyl group, a tetracyclododecanyl group, and an adamantyl group are preferable. Particularly, in the case where a cyclic aliphatic group having a bulky structure constituted by a 6- or more membered ring is employed as E, this group is inhibited from being diffused into the film in a post exposure bake (PEB) step, and the resolution and exposure latitude (EL) can be further improved.

The aryl group represented by E is, for example, a phenyl group, a naphthyl group, a phenanthryl group, or an anthryl group.

The group having a heterocyclic structure represented by E may or may not be aromatic. As the heteroatom contained in this group, a nitrogen atom or an oxygen atom is preferable. Specific examples of the heterocyclic structure include a lactone ring, a furan ring, a thiophene ring, a benzofuran ring, a benzothiophene ring, a dibenzofuran ring, a dibenzothiophene ring, a pyridine ring, a piperidine ring, and a morpholine ring. Among these, a furan ring, a thiophene ring, a pyridine ring, a piperidine ring, and a morpholine ring are preferable.

E may have a substituent, and examples of the substituent include an alkyl group (which may be a linear, branched or cyclic alkyl group preferably having 1 to 12 carbon atoms), an aryl group (preferably having 6 to 14 carbon atoms), a hydroxyl group, an alkoxy group, an ester group, an amide group, a urethane group, a ureido group, a thioether group, a sulfonamide group, and a sulfonic acid ester group.

The component (B) decomposes upon irradiation with actinic rays or radiation to generate an acid represented by General Formula HX.

The present inventors have found that when an acid having a volume of 240 Å³ or more represented by General Formula HX is used as the organic anion X⁻, the resolution and the good line edge roughness line can be more highly compatible.

The volume of the acid represented by General Formula HX is preferably 240 Å³ or more, more preferably 300 Å³ or more, still more preferably 350 Å³ or more, and most preferably 400 Å³ or more. The volume is preferably 2000 Å³ or less and more preferably 1500 Å³ or less from the viewpoint of sensitivity or coating solvent solubility.

In the case where an acid generated by decomposition upon irradiation with actinic rays or radiation is bonded to the side chain of the resin, the volume of the acid represented by General Formula HX is 240 Å³ or more, which is likewise preferable.

The volume of the acids was calculated in the following manner using software “WinMOPAC” (manufactured by Fujitsu Limited). Namely, first, the chemical structure of each of the acids was input. Subsequently, taking this structure as an initial structure, the most stable conformation of the acid was determined by a molecular force field calculation using an MM3 method. Thereafter, a molecular orbital calculation using a PM3 method was carried out with respect to the most stable conformation. Thus, the “accessible volume” of each of the acids was determined.

Specific examples of the anions represented by General Formula HX are shown below. The numerical value described also includes the calculated value of the volume of HX.

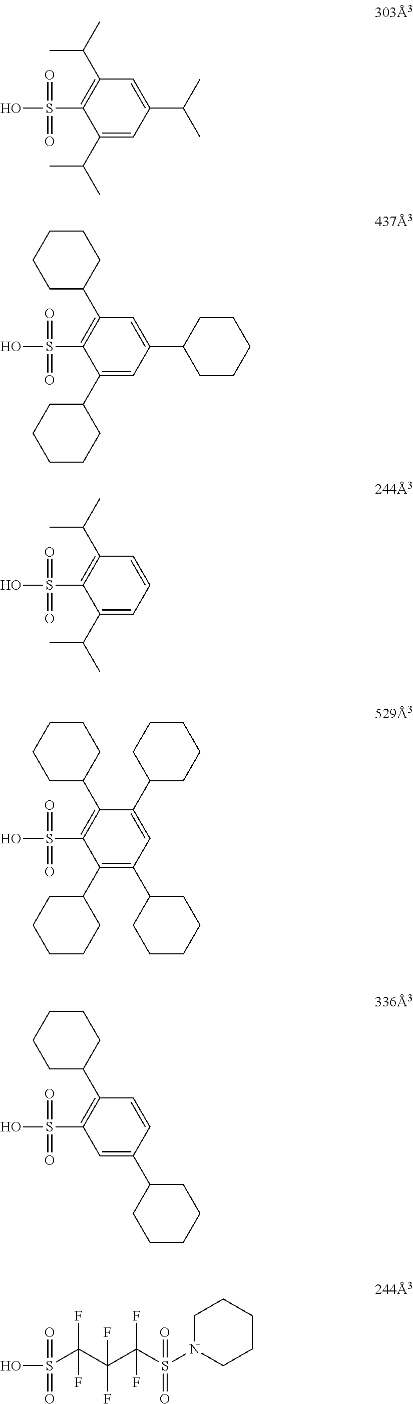

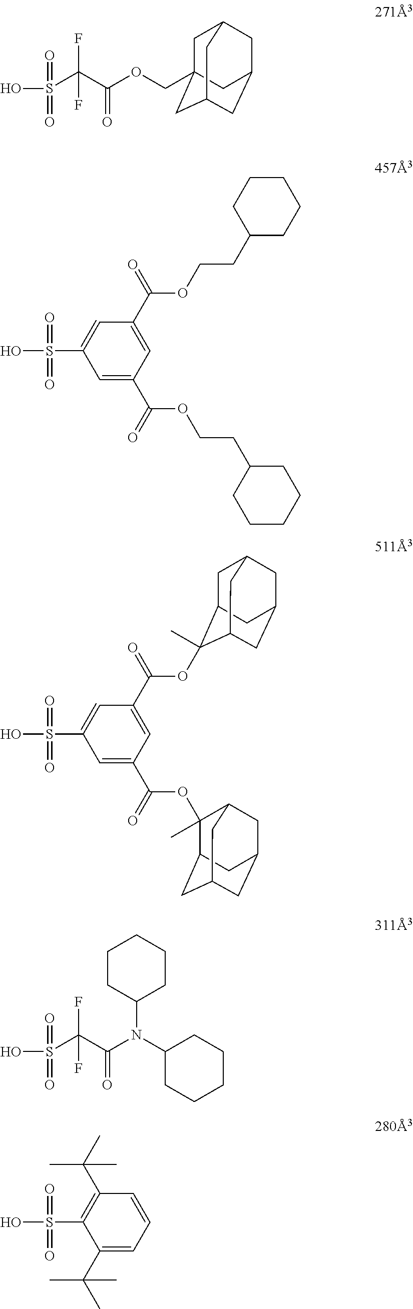

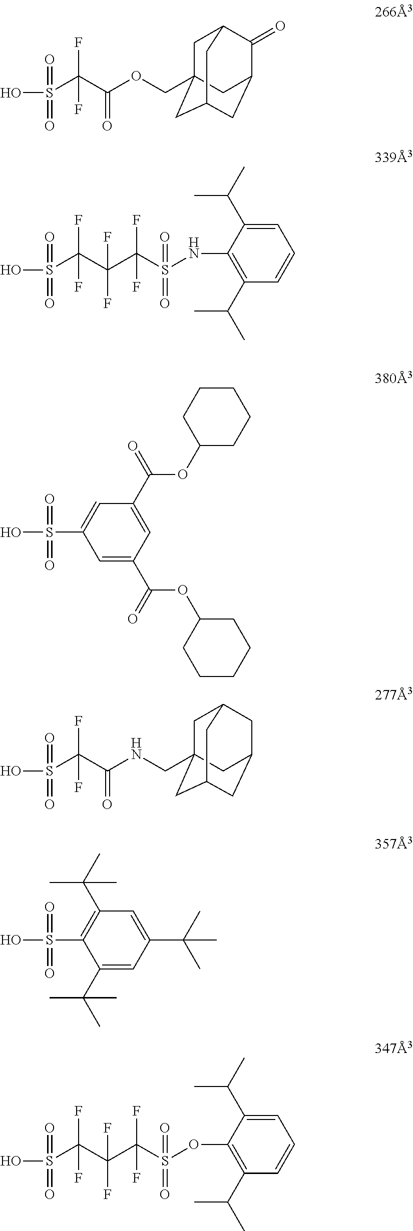

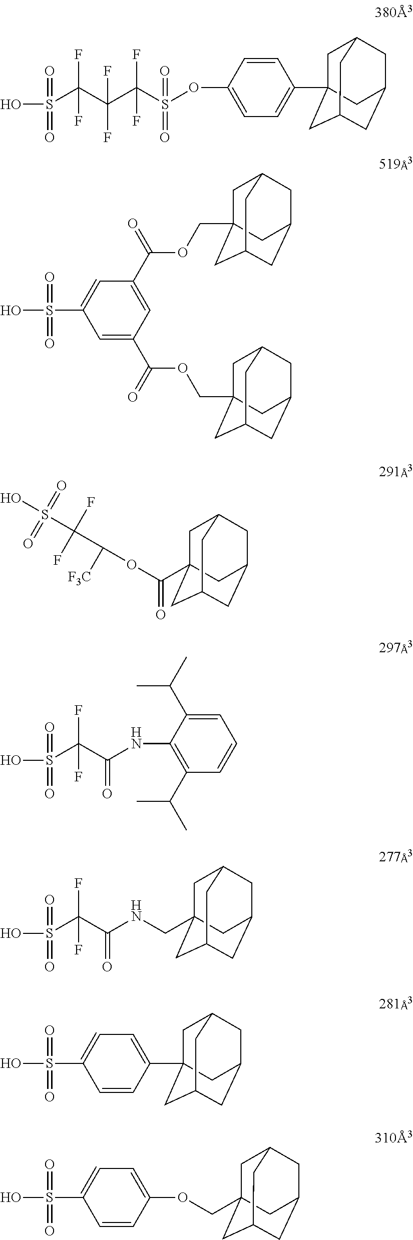

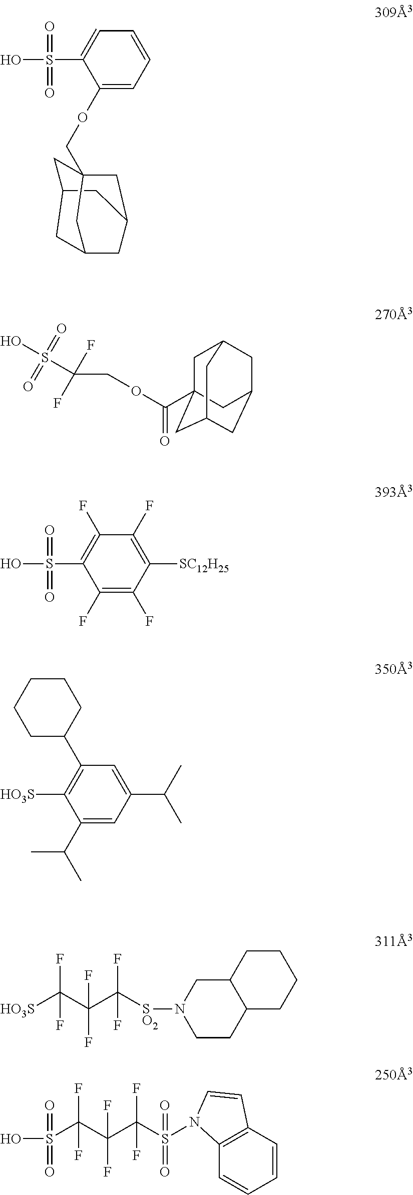

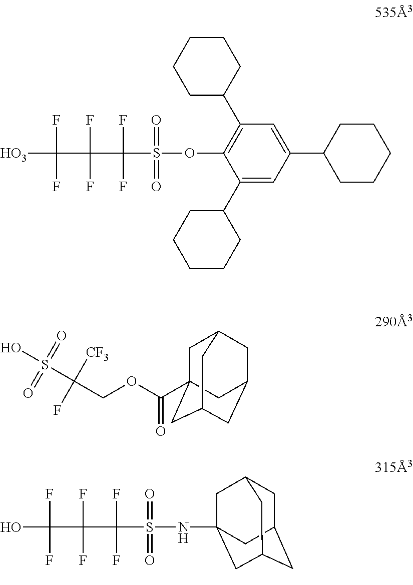

The number of carbon atoms in the organic group represented by R₂₀₁, R₂₀₂, and R₂₀₃ is generally 1 to 30 and preferably 1 to 20.

Two of R₂₀₁ to R₂₀₃ may be bonded to form a ring structure, and the ring may contain an oxygen atom, a sulfur atom, an ester bond, an amide bond, or a carbonyl group. Examples of the group formed by bonding of two of R₂₀₁ to R₂₀₃ include alkylene groups (for example, a butylene group and a pentylene group).

Specific examples of the organic group represented by R₂₀₁, R₂₀₂, and R₂₀₃ include corresponding groups in the compounds (ZI-1), (ZI-2), and (ZI-3) to be described hereinafter.

A compound having a plurality of structures represented by General Formula (ZI) may also be used. For example, it may be a compound having a structure in which at least one of R₂₀₁, R₂₀₂, or R₂₀₃ of the compound represented by General Formula (ZI) binds to at least one of R₂₀₁, R₂₀₂, or R₂₀₃ of another compound represented by General Formula (ZI).

Examples of more preferable (ZI) components include compounds (ZI-1), (ZI-2), and (ZI-3) described below.

The compound (ZI-1) is an arylsulfonium compound in which at least one of R₂₀₁, R₂₀₂, or R₂₀₃ of General Formula (ZI) is an aryl group, that is, a compound having an arylsulfonium as a cation.

In the arylsulfonium compound, all of R₂₀₁ to R₂₀₃ may be an aryl group; alternatively, a part of R₂₀₁ to R₂₀₃ may be an aryl group and the remainder thereof may be an alkyl group or a cycloalkyl group.

Examples of the arylsulfonium compound include a triarylsulfonium compound, a diarylalkylsulfonium compound, an aryldialkylsulfonium compound, a diarylcycloalkylsulfonium compound, and an aryldicycloalkylsulfonium compound.

As the aryl group in the arylsulfonium compound, an aryl group such as a phenyl group or a naphthyl group, or a heteroaryl group such as an indole residue or a pyrrole residue is preferable, and a phenyl group or an indole residue is more preferable. In the case where the arylsulfonium compound has two or more aryl groups, the two or more aryl groups may be the same or different from one another.

As the alkyl group that the arylsulfonium compound optionally contains, a linear or branched alkyl group having 1 to 15 carbon atoms is preferable, and examples thereof include a methyl group, an ethyl group, a propyl group, an n-butyl group, a sec-butyl group, and a t-butyl group.

As the cycloalkyl group that the arylsulfonium compound optionally contains, a cycloalkyl group having 3 to 15 carbon atoms is preferable, and examples thereof include a cyclopropyl group, a cyclobutyl group, and a cyclohexyl group.

The aryl group, the alkyl group, and the cycloalkyl group of R₂₀₁ to R₂₀₃ may have an alkyl group (for example, having 1 to 15 carbon atoms), a cycloalkyl group (for example, having 3 to 15 carbon atoms), an aryl group (for example, having 6 to 14 carbon atoms), an alkoxy group (for example, having 1 to 15 carbon atoms), a halogen atom, a hydroxyl group, or a phenylthio group as a substituent. The preferred substituent is a linear or branched alkyl group having 1 to 12 carbon atoms, a cycloalkyl group having 3 to 12 carbon atoms, or a linear, branched or cyclic alkoxy group having 1 to 12 carbon atoms, and particularly preferably an alkyl group having 1 to 4 carbon atoms or an alkoxy group having 1 to 4 carbon atoms. The substituent may be substituted with any one of R₂₀₁ to R₂₀₃ or may be substituted with all of R₂₀₁ to R₂₀₃. In the case where R₂₀₁ to R₂₀₃ are an aryl group, the substituent is preferably substituted at the p-position of the aryl group.

Next, the compound (ZI-2) will be described. The compound (ZI-2) is a compound in the case where R₂₀₁ to R₂₀₃ in Formula (ZI) each independently represent an organic group not containing an aromatic ring. The aromatic ring herein also includes an aromatic ring containing a heteroatom.

The organic group represented by R₂₀₁ to R₂₀₃ and not containing an aromatic ring generally has 1 to 30 carbon atoms and preferably 1 to 20 carbon atoms.

R₂₀₁ to R₂₀₃ are each independently preferably an alkyl group, a cycloalkyl group, an allyl group, or a vinyl group, more preferably a linear, branched or cyclic 2-oxoalkyl group or an alkoxycarbonylmethyl group, and particularly preferably a linear or branched 2-oxoalkyl group.

The alkyl group represented by R₂₀₁ to R₂₀₃ may be linear or branched and may be preferably, for example, a linear or a branched alkyl group having 1 to 10 carbon atoms (for example, a methyl group, an ethyl group, a propyl group, a butyl group, or a pentyl group). The alkyl group represented by R₂₀₁ to R₂₀₃ is preferably a linear or branched 2-oxoalkyl group or an alkoxycarbonylmethyl group.

The cycloalkyl group represented by R₂₀₁ to R₂₀₃ may be preferably, for example, a cycloalkyl group having 3 to 10 carbon atoms (a cyclopentyl group, a cyclohexyl group, or a norbornyl group). The cycloalkyl group represented by R₂₀₁ to R₂₀₃ is preferably a cyclic 2-oxoalkyl group.

The linear, branched or cyclic 2-oxoalkyl group represented by R₂₀₁ to R₂₀₃ may be preferably, for example, a group having >C═O at the 2-position of the above-mentioned alkyl group or cycloalkyl group.

The alkoxy group in the alkoxycarbonylmethyl group represented by R₂₀₁ to R₂₀₃ may be preferably, for example, an alkoxy group (a methoxy group, an ethoxy group, a propoxy group, a butoxy group, or a pentoxy group) having 1 to 5 carbon atoms.

R₂₀₁ to R₂₀₃ may be further substituted with a halogen atom, an alkoxy group (for example, having 1 to 5 carbon atoms), a hydroxyl group, a cyano group or a nitro group.

The compound (ZI-3) is a compound which is represented by the following General Formula (ZI-3) and has a phenacyl sulfonium salt structure.

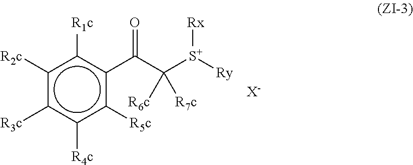

In General Formula (ZI-3), R_{1c} to R_{5c} each independently represent a hydrogen atom, an alkyl group, a cycloalkyl group, an alkoxy group, or a halogen atom.

R_{6c} and R_{7c} each independently represent a hydrogen atom, an alkyl group, or a cycloalkyl group.

Rx and Ry each independently represent an alkyl group, a cycloalkyl group, an allyl group, or a vinyl group.

Two or more of R_{1c} to R_{7c} may be bonded to each other to form a ring, and Rₓ and R_{y} may be bonded to each other to form a ring. These ring structures may contain an oxygen atom, a sulfur atom, an ester bond, or an amide bond. Examples of the group formed by bonding of two or more of R_{1c} to R_{7c} and by bonding of Rₓ and R_{y} include a butylene group and a pentylene group.

X⁻ represents a non-nucleophilic anion and examples thereof include the same non-nucleophilic anions of X⁻ in General Formula (ZI).

The alkyl group represented by R_{1c} to R_{7c} may be linear or branched and may be, for example, a linear or branched alkyl group having 1 to 20 carbon atoms and preferably a linear or branched alkyl group having 1 to 12 carbon atoms (for example, a methyl group, an ethyl group, a linear or branched propyl group, a linear or branched butyl group, or a linear or branched pentyl group).

The cycloalkyl group represented by R_{1c} to R_{7c} may be preferably, for example, a cycloalkyl group having 3 to 8 carbon atoms (for example, a cyclopentyl group or a cyclohexyl group).

The alkoxy group represented by R_{1c} to R_{5c} may be linear, branched or cyclic and may be, for example, an alkoxy group having 1 to 10 carbon atoms, preferably a linear and branched alkoxy group having 1 to 5 carbon atoms (for example, a methoxy group, an ethoxy group, a linear or branched propoxy group, a linear or branched butoxy group, or a linear or branched pentoxy group), or a cyclic alkoxy group having 3 to 8 carbon atoms (for example, a cyclopentyloxy group or a cyclohexyloxy group).

Preferably, any one of R_{1c} to R_{5c} is a linear or branched alkyl group, a cycloalkyl group, or a linear, branched or cyclic alkoxy group. More preferably, the total number of carbon atoms in R_{1c} to R_{5c} is 2 to 15. Thus, the solubility in a solvent is further improved and generation of particles during storage is suppressed.

The alkyl group represented by Rₓ and R_{y} may be the same as the alkyl group represented by R_{1c} to R_{7c}. The alkyl group represented by Rₓ and R_{y} is preferably a linear or branched 2-oxoalkyl group or an alkoxycarbonylmethyl group.

The cycloalkyl group represented by Rₓ and R_{y} may be the same as the cycloalkyl group represented by R_{1c} to R_{7c}. The cycloalkyl group represented by Rₓ and R_{y} is preferably a cyclic 2-oxoalkyl group.

The linear, branched or cyclic 2-oxoalkyl group may be, for example, a group having >C═O at the 2-position of the alkyl group or cycloalkyl group represented by R_{1c} to R_{7c}.

The alkoxy group in the alkoxycarbonylmethyl group may be the same as the alkoxy group represented by R_{1c} to R_{5c}.

Rₓ and R_{y} are preferably an alkyl group having 4 or more carbon atoms, more preferably an alkyl group having 6 or more carbon atoms, and still more preferably an alkyl group having 8 or more carbon atoms.

In General Formulae (ZII) and (ZIII), R₂₀₄ to R₂₀₇ each independently represent an aryl group, an alkyl group, or a cycloalkyl group.

The aryl group represented by R₂₀₄ to R₂₀₇ is preferably a phenyl group or a naphthyl group and more preferably a phenyl group.

The alkyl group represented by R₂₀₄ to R₂₀₇ may be linear or branched and may be preferably, for example, a linear or branched alkyl group having 1 to 10 carbon atoms (for example, a methyl group, an ethyl group, a propyl group, a butyl group, or a pentyl group).

The cycloalkyl group represented by R₂₀₄ to R₂₀₇ may be preferably, for example, a cycloalkyl group having 3 to 10 carbon atoms (a cyclopentyl group, a cyclohexyl group, or a norbornyl group).

R₂₀₄ to R₂₀₇ may have a substituent. Examples of the substituent which may be contained in R₂₀₄ to R₂₀₇ include an alkyl group (for example, having 1 to 15 carbon atoms), a cycloalkyl group (for example, having 3 to 15 carbon atoms), an aryl group (for example, having 6 to 15 carbon atoms), an alkoxy group (for example, having 1 to 15 carbon atoms), a halogen atom, a hydroxyl group, and a phenylthio group.

X⁻ represents a non-nucleophilic anion and may be the same as the non-nucleophilic anion of X⁻ in General Formula (ZI).

Examples of the preferred compound among the compounds capable of generating an acid upon irradiation with actinic rays or radiation include compounds represented by the following General Formulae (ZIV), (ZV), and (ZVI).

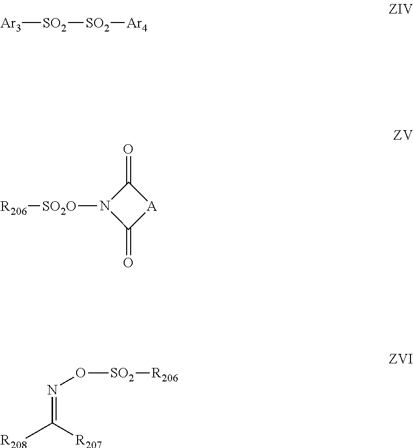

In General Formulae (ZIV) to (ZVI), Ar₃ and Ar₄ each independently represent an aryl group. R₂₀₆ represents an alkyl group or an aryl group. R₂₀₇ and R₂₀₈ each independently represent an alkyl group, an aryl group, or an electron-withdrawing group. R₂₀₇ is preferably an aryl group.

R₂₀₈ is preferably an electron-withdrawing group and more preferably a cyano group or a fluoroalkyl group.

A represents an alkylene group, an alkenylene group, or an arylene group.

As the compound capable of generating an acid upon irradiation with actinic rays or radiation, compounds represented by General Formulae (ZI) to (ZIII) are preferable.

The compound (B) is preferably a compound capable of generating an aliphatic sulfonic acid having a fluorine atom or a benzenesulfonic acid having a fluorine atom upon irradiation with actinic rays or radiation.

The compound (B) preferably has a triphenylsulfonium structure.

The compound (B) is preferably a triphenylsulfonium salt compound having an alkyl group or cycloalkyl group which is not fluorine-substituted in the cationic moiety.

Among the compounds capable of generating an acid upon irradiation with actinic rays or radiation, particularly preferred examples thereof are shown below.

Specific examples of the acid generator include those described in paragraphs [0368] to [0377] of JP2014-41328A, paragraphs [0240] to [0262] of JP2013-228681A, and paragraph [0339] of US2015/004533A, in addition to those shown below.

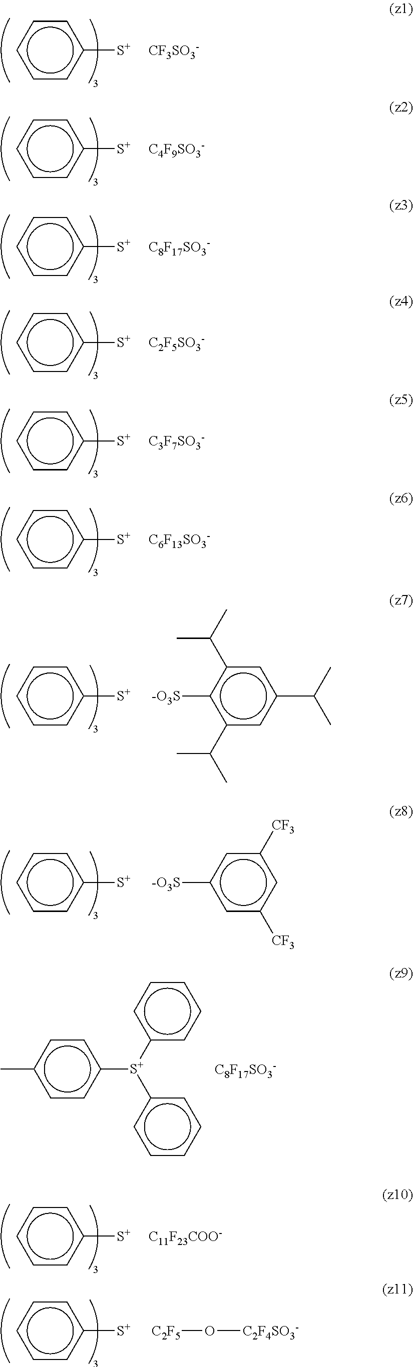

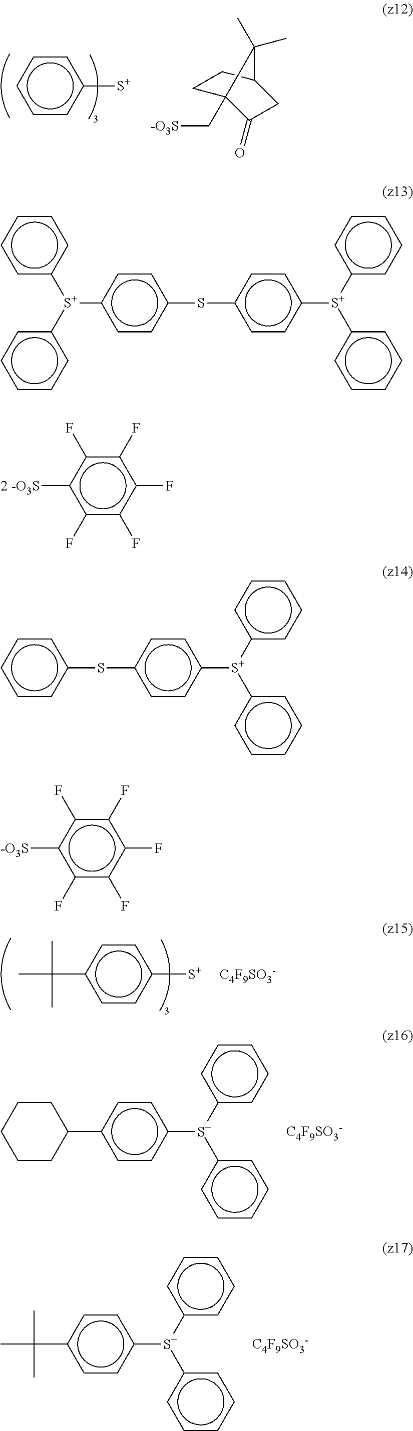

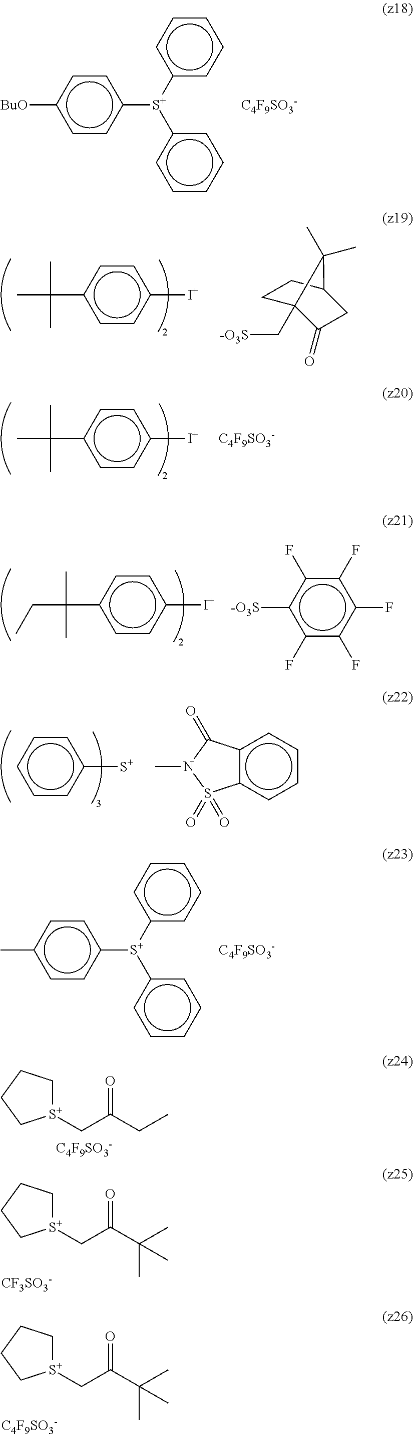

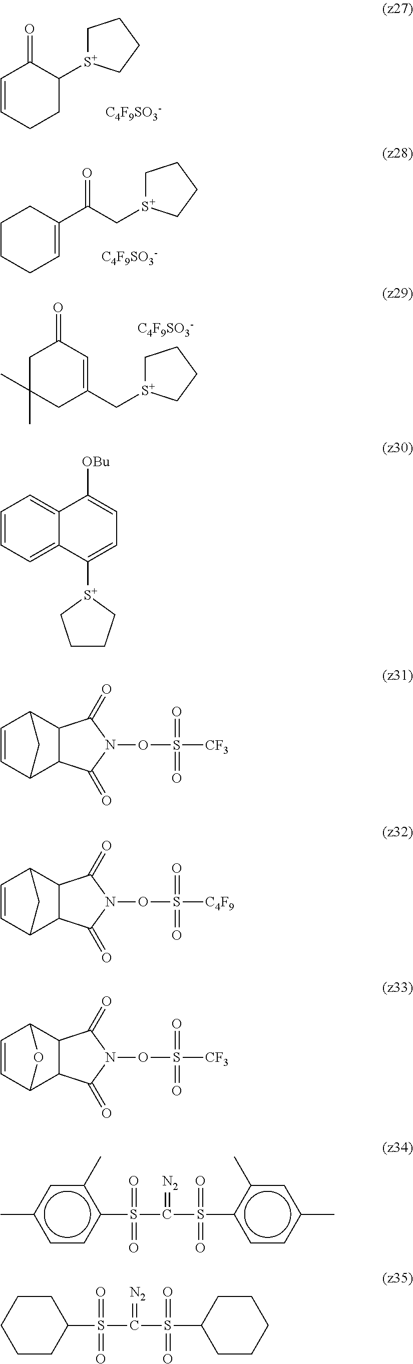

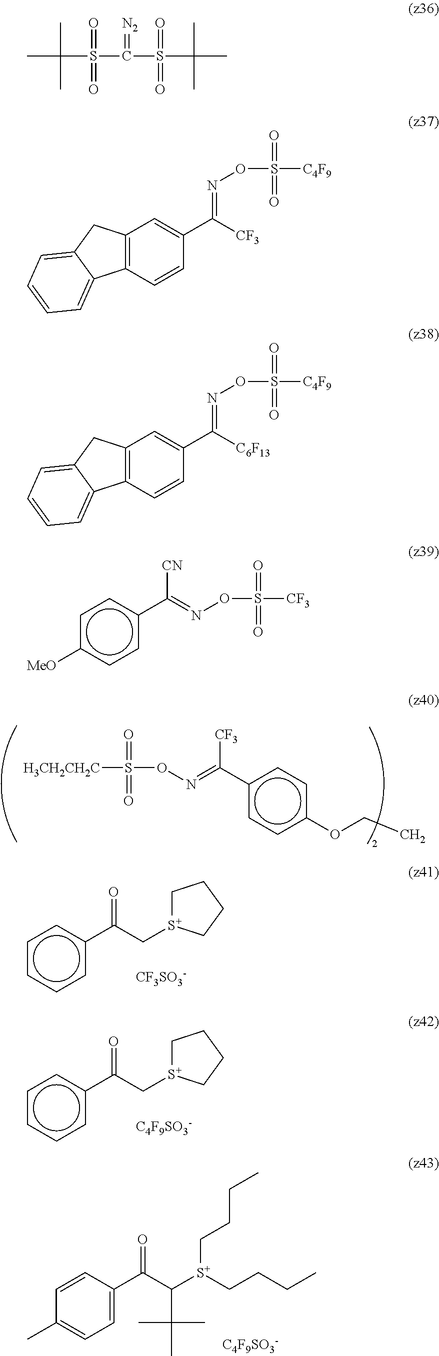

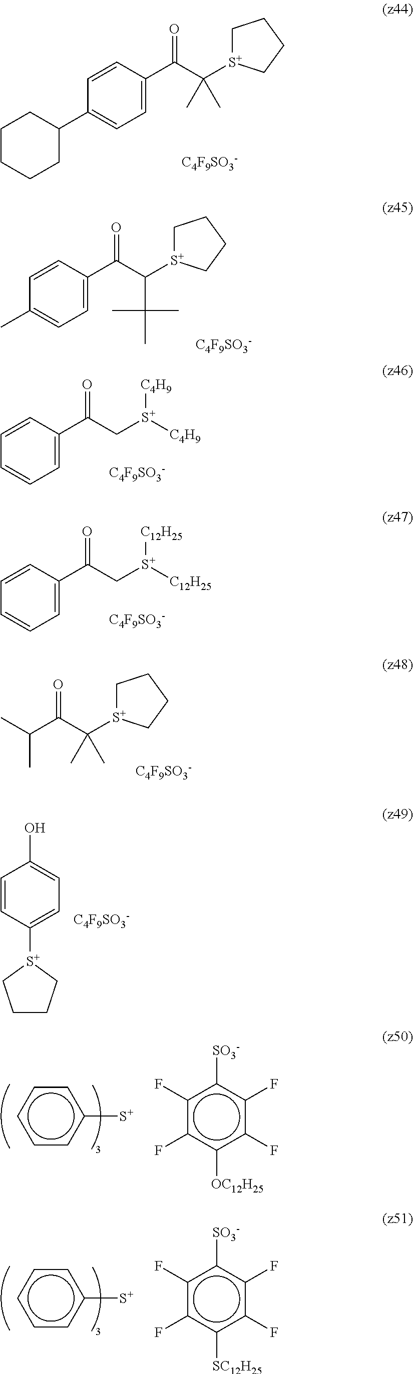

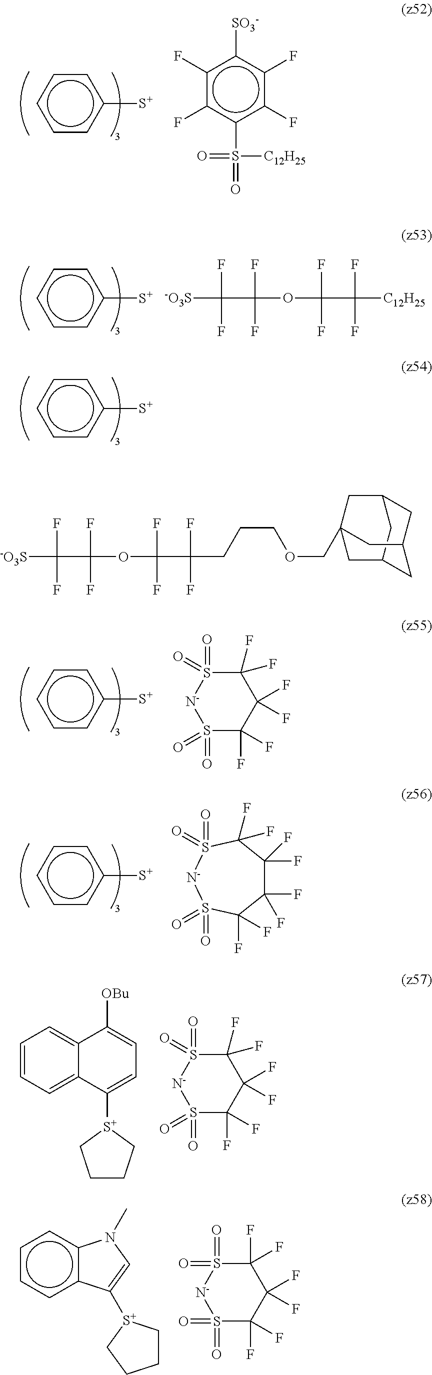

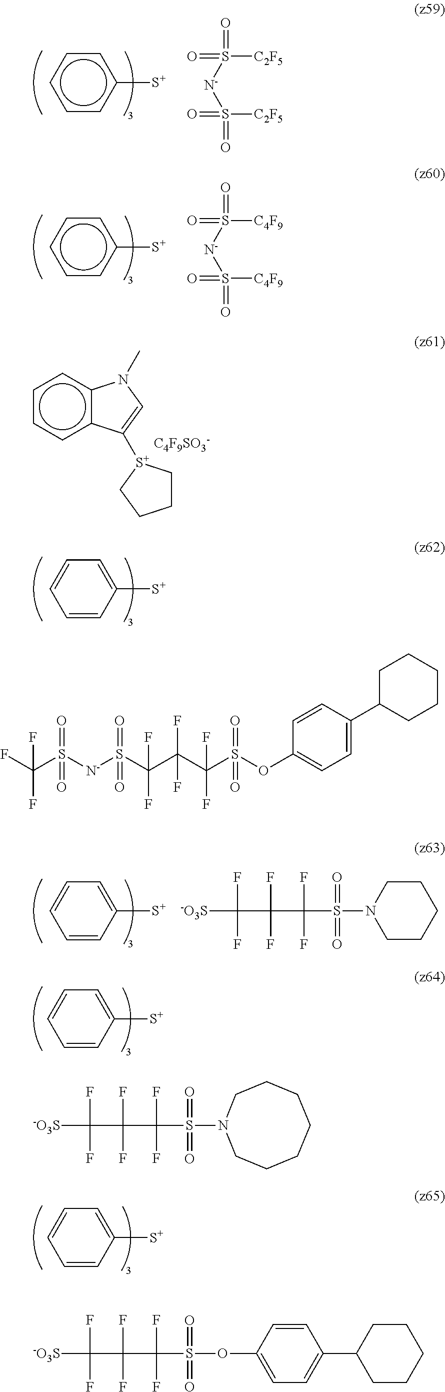

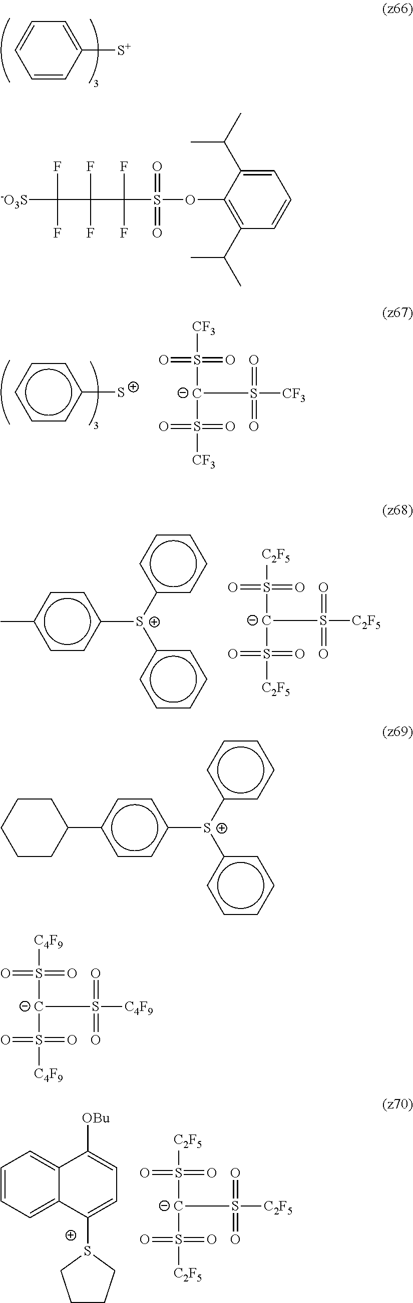

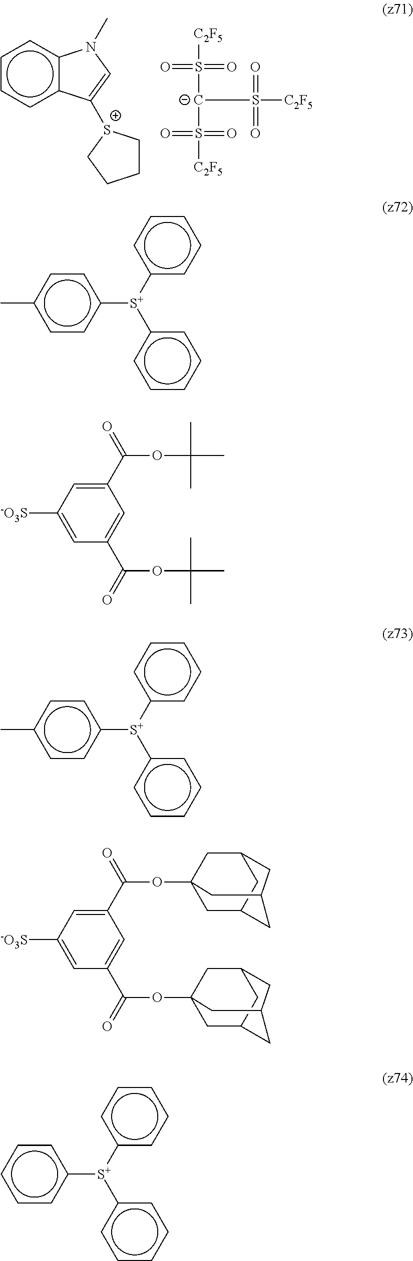

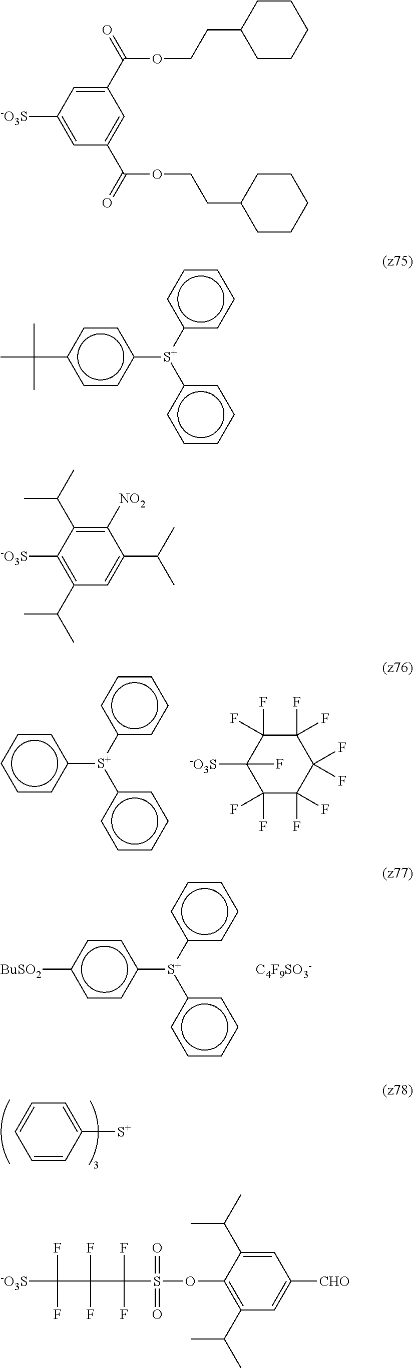

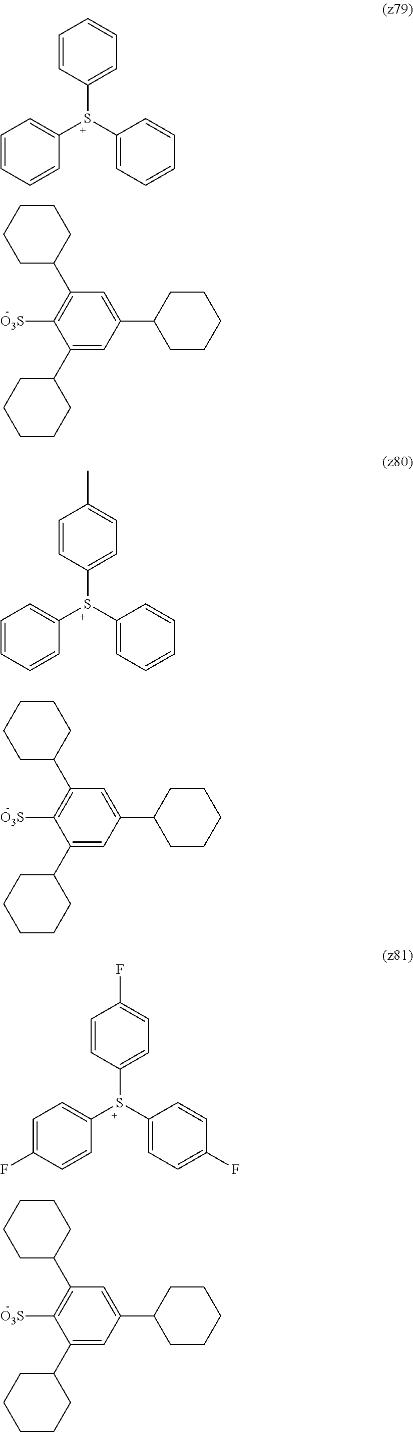

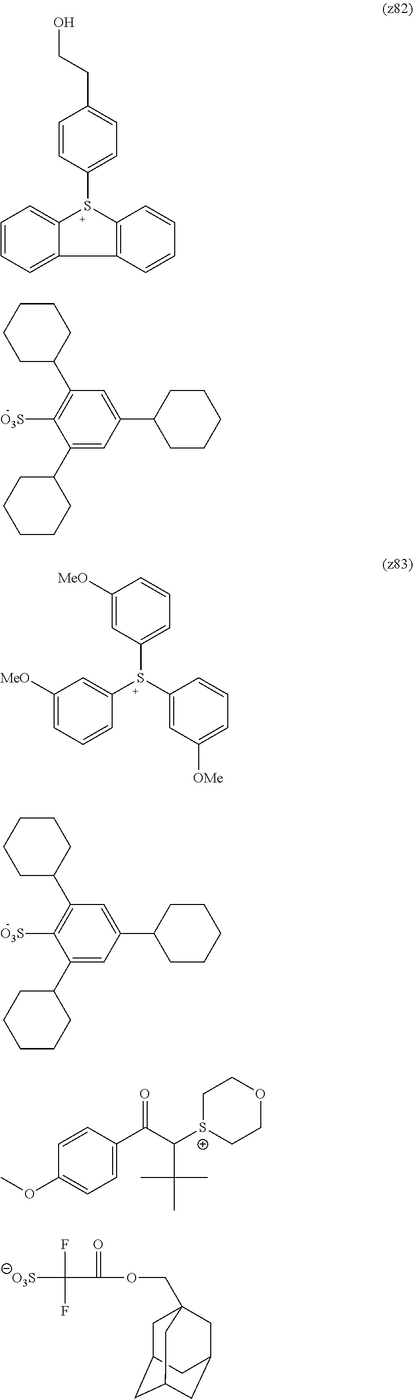

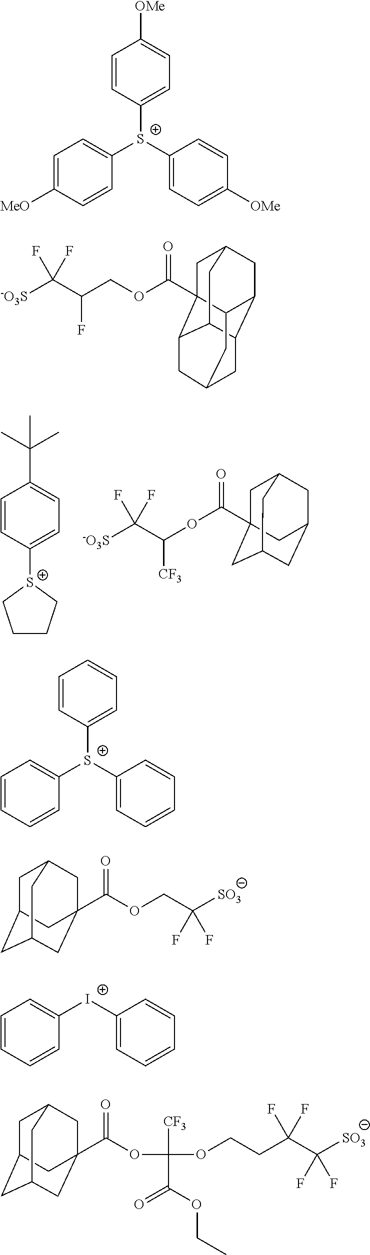

The photoacid generators may be used alone or in combination of two or more thereof. When two or more photoacid generators are used in combination, it is preferred to combine compounds from which two types of organic acids being different from each other by 2 or greater in the total number of atoms excluding hydrogen atoms are generated.

The content of the photoacid generator is preferably 0.1 to 20 mass %, more preferably 0.5 to 10 mass %, and still more preferably 1 to 7 mass %, based on the total solid content of the actinic ray-sensitive or radiation-sensitive composition. When the content of the photoacid generator is within this range, the exposure margin when forming the resist pattern is improved and the crosslinking reactivity with the crosslinked layer forming material is improved.

Solvent (C)

When preparing the resist composition of the present invention by dissolving each of the above-mentioned components, a solvent can be used. Examples of the solvent which can be used include organic solvents such as alkylene glycol monoalkyl ether carboxylate, alkylene glycol monoalkyl ether, alkyl lactate, alkyl alkoxypropionate, cyclic lactone having 4 to 10 carbon atoms, a monoketone compound having 4 to 10 carbon atoms which may have a ring, alkylene carbonate, alkyl alkoxyacetate, and alkyl pyruvate.

Examples of the alkylene glycol monoalkyl ether carboxylate preferably include propylene glycol monomethyl ether acetate, propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, and ethylene glycol monoethyl ether acetate.

Examples of the alkylene glycol monoalkyl ether preferably include propylene glycol monomethyl ether, propylene glycol monoethyl ether, propylene glycol monopropyl ether, propylene glycol monobutyl ether, ethylene glycol monomethyl ether, and ethylene glycol monoethyl ether.

Examples of the alkyl lactate preferably include methyl lactate, ethyl lactate, propyl lactate, and butyl lactate.

Examples of the alkyl alkoxypropionate preferably include ethyl 3-ethoxypropionate, methyl 3-methoxypropionate, methyl 3-ethoxypropionate, and ethyl 3-methoxypropionate.

Examples of the cyclic lactone having 4 to 10 carbon atoms preferably include β-propiolactone, β-butyrolactone, γ-butyrolactone, α-methyl-γ-butyrolactone, β-methyl-γ-butyrolactone, γ-valerolactone, γ-caprolactone, γ-octanoiclactone, and α-hydroxy-γ-butyrolactone.

Examples of the monoketone compound having 4 to 10 carbon atoms that may have a ring preferably include 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanone, 2,2-dimethylcyclohexanone, 2,6-dimethylcyclohexanone, 2,2,6-trimethylcyclohexanone, cycloheptanone, 2-methylcycloheptanone, and 3-methylcycloheptanone.

Examples of the alkylene carbonate preferably include propylene carbonate, vinylene carbonate, ethylene carbonate, and butylene carbonate.

Examples of the alkyl alkoxyacetate preferably include 2-mefhoxyethyl acetate, 2-ethoxyethyl acetate, 2-(2-ethoxyethoxy)ethyl acetate, 3-methoxy-3-methylbutyl acetate, and 1-methoxy-2-propyl acetate.

Examples of the alkyl pyruvate preferably include methyl pyruvate, ethyl pyruvate, and propyl pyruvate.

The solvent which can be preferably used may be, for example, a solvent having a boiling point of 130° C. or higher at ordinary temperatures and pressures. Specific examples thereof include cyclopentanone, γ-butyrolactone, cyclohexanone, ethyl lactate, ethylene glycol monoethyl ether acetate, propylene glycol monomethyl ether acetate, 3-ethoxyethyl propionate, ethyl pyruvate, 2-ethoxyethyl acetate, 2-(2-ethoxyethoxy)ethyl acetate, and propylene carbonate.

In the present invention, the above-mentioned solvents may be used alone or in combination of two or more thereof.

In the present invention, a mixed solvent in which a solvent containing a hydroxyl group in the structure and a solvent not containing a hydroxyl group are mixed may be used as an organic solvent.

Examples of the solvent containing a hydroxyl group include ethylene glycol, ethylene glycol monomethyl ether, ethylene glycol monoethyl ether, propylene glycol, propylene glycol monomethyl ether, propylene glycol monoethyl ether, and ethyl lactate, among which particularly preferred is propylene glycol monomethyl ether or ethyl lactate.

Examples of the solvent not containing a hydroxyl group include propylene glycol monomethyl ether acetate, ethyl ethoxy propionate, 2-heptanone, γ-butyrolactone, cyclohexanone, butyl acetate, N-methylpyrrolidone, N,N-dimethylacetamide, and dimethylsulfoxide, among which particularly preferred is propylene glycol monomethyl ether acetate, ethyl ethoxy propionate, 2-heptanone, γ-butyrolactone, cyclohexanone, or butyl acetate, and most preferred is propylene glycol monomethyl ether acetate, ethylethoxypropionate, or 2-heptanone.

The mixing ratio (mass) of a solvent containing a hydroxyl group to a solvent not containing a hydroxyl group is preferably 1/99 to 99/1, more preferably 10/90 to 90/10, and still more preferably 20/80 to 60/40. A mixed solvent containing 50 mass % or more of a solvent not containing a hydroxyl group is particularly preferable from the viewpoint of coating uniformity.

The solvent is preferably a mixed solvent of two or more solvents containing propylene glycol monomethyl ether acetate.

As the solvent, it is possible to use the solvents described in, for example, paragraphs [0013] to [0029] of JP2014-219664A.

(E) Basic Compound

The resist composition of the present invention preferably contains a basic compound (E) in order to reduce changes in performance over time from exposure to heating.

The basic compound may be preferably, for example, a compound having a structure represented by the following Formulae (A) to (E).

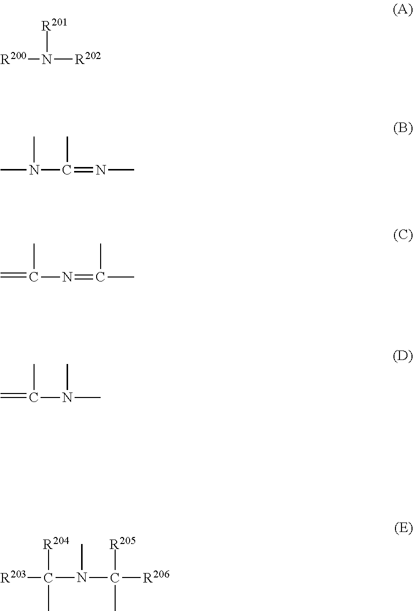

In General Formulae (A) and (E), R²⁰⁰, R²⁰¹, and R²⁰² may be the same or different from one another and represent a hydrogen atom, an alkyl group (preferably having 1 to 20 carbon atoms), a cycloalkyl group (preferably having 3 to 20 carbon atoms), or an aryl group (preferably having 6 to 20 carbon atoms), in which R²⁰¹ and R²⁰² may be bonded to each other to form a ring.

As for the alkyl group, the alkyl group having a substituent is preferably an aminoalkyl group having 1 to 20 carbon atoms, a hydroxyalkyl group having 1 to 20 carbon atoms, or a cyanoalkyl group having 1 to 20 carbon atoms.

R²⁰³, R²⁰⁴, R²⁰⁵, and R²⁰⁶ may be the same or different from one another and represent an alkyl group having 1 to 20 carbon atoms.

The alkyl group in General Formulae (A) and (E) is more preferably unsubstituted.

Preferred examples of the compound include guanidine, aminopyrrolidine, pyrazole, pyrazoline, piperazine, aminomorpholine, aminoalkylmorpholine, and piperidine, and more preferred examples of the compound include a compound having an imidazole structure, a diazabicyclo structure, an onium hydroxide structure, an onium carboxylate structure, a trialkylamine structure, an aniline structure, or a pyridine structure; an alkylamine derivative having a hydroxyl group and/or an ether bond; and an aniline derivative having a hydroxyl group and/or an ether bond.

Examples of the compound having an imidazole structure include imidazole, 2,4,5-triphenylimidazole, and benzimidazole. Examples of the compound having a diazabicyclo structure include 1,4-diazabicyclo[2,2,2]octane, 1,5-diazabicyclo[4,3,0]nona-5-ene, and 1,8-diazabicyclo[5,4,0]undeca-7-ene. Examples of the compound having an onium hydroxide structure include triarylsulfonium hydroxide, phenacylsulfonium hydroxide, and sulfonium hydroxide having a 2-oxoalkyl group, with the specific examples thereof including triphenylsulfonium hydroxide, tris(t-butylphenyl)sulfonium hydroxide, bis(t-butylphenyl)iodonium hydroxide, a phenacylthiophenium hydroxide, and 2-oxopropylthiophenium hydroxide. The compound having an onium carboxylate structure is a compound in which the anionic moiety of the compound having an onium hydroxide structure is carboxlated, and examples thereof include acetate, adamantane-1-carboxylate, and perfluoroalkyl carboxylate. Examples of the compound having a trialkylamine structure include tri(n-butyl)amine and tri(n-octyl)amine. Examples of the compound having an aniline structure include 2,6-diisopropylaniline, N,N-dimethylaniline, N,N-dibutylaniline, and N,N-dihexylaniline. Examples of the alkylamine derivative having a hydroxyl group and/or an ether bond include ethanolamine, diethanolamine, triethanolamine, and tris(methoxyethoxyethyl)amine. Examples of the aniline derivative having a hydroxyl group and/or an ether bond include N,N-bis(hydroxyethyl)aniline.

Preferred examples of the basic compound further include an amine compound having a phenoxy group and an ammonium salt compound having a phenoxy group.

The amine compound may be a primary, secondary, or tertiary amine compound, and is preferably an amine compound in which at least one alkyl group is bonded to a nitrogen atom. Further, the amine compound is more preferably a tertiary amine compound. In the amine compound, when at least one alkyl group (preferably having 1 to 20 carbon atoms) is bonded to a nitrogen atom, a cycloalkyl group (preferably having 3 to 20 carbon atoms) or an aryl group (preferably having 6 to 12 carbon atoms) other than the alkyl group may be bonded to a nitrogen atom.

Further, the amine compound preferably contains an oxygen atom and an oxyalkylene group formed in the alkyl chain. The number of the oxyalkylene groups is 1 or more in the molecule, preferably 3 to 9, and more preferably 4 to 6. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

The ammonium salt compound may be a primary, secondary, tertiary, or quaternary ammonium salt compound and is preferably an ammonium salt compound in which at least one alkyl group is bonded to a nitrogen atom. In the ammonium salt compound, when at least one alkyl group (preferably having 1 to 20 carbon atoms) is bonded to a nitrogen atom, a cycloalkyl group (preferably having 3 to 20 carbon atoms) or an aryl group (preferably having 6 to 12 carbon atoms) other than the alkyl group may be bonded to a nitrogen atom.

The ammonium salt compound preferably contains an oxygen atom and an oxyalkylene group formed in the alkyl chain. The number of the oxyalkylene groups is 1 or more in the molecule, preferably 3 to 9, and more preferably 4 to 6. Among the oxyalkylene groups, an oxyethylene group (—CH₂CH₂O—) or an oxypropylene group (—CH(CH₃)CH₂O— or —CH₂CH₂CH₂O—) is preferable, and an oxyethylene group is more preferable.

Examples of the anion of the ammonium salt compound include a halogen atom, a sulfonate, a borate, and a phosphate, among which preferred is a halogen atom or a sulfonate. The halogen atom is particularly preferably a chloride, a bromide, or an iodide, and the sulfonate is particularly preferably an organic sulfonate having 1 to 20 carbon atoms. Examples of the organic sulfonate include an alkylsulfonate and an arylsulfonate each having 1 to 20 carbon atoms. The alkyl group in the alkylsulfonate may have a substituent, and examples of the substituent include fluorine, chlorine, bromine, an alkoxy group, an acyl group, and an aryl group. Specific examples of the alkylsulfonate include methansulfonate, ethansulfonate, butanesulfonate, hexanesulfonate, octanesulfonate, benzylsulfonate, trifluoromethansulfonate, pentafluoroethansulfonate, and nonafluorobutanesulfonate. Examples of the aryl group in the arylsulfonate include a benzene ring, a naphthalene ring, and an anthracene ring. A benzene ring, a naphthalene ring, and an anthracene ring may have a substituent, and the substituent is preferably a linear or branched alkyl group having 1 to 6 carbon atoms or a cycloalkyl group having 3 to 6 carbon atoms. Specific examples of the linear or branched alkyl group and the cycloalkyl group include methyl, ethyl, n-propyl, isopropyl, n-butyl, i-butyl, t-butyl, n-hexyl, and cyclohexyl. Examples of other substituents include an alkoxy group having 1 to 6 carbon atoms, a halogen atom, cyano, nitro, an acyl group, and an acyloxy group.

The amine compound having a phenoxy group or the ammonium salt compound having a phenoxy group is a compound having a phenoxy group at the terminal opposite to the nitrogen atom of the alkyl group of the amine compound or ammonium salt compound. The phenoxy group may have a substituent. Examples of the substituent of the phenoxy group include an alkyl group, an alkoxy group, a halogen atom, a cyano group, a nitro group, a carboxyl group, a carboxylic acid ester group, a sulfonic acid ester group, an aryl group, an aralkyl group, an acyloxy group, and an aryloxy group. The substitution position of the substituent may be any one of 2 to 6 positions. The number of the substituents may be in the range of 1 to 5.

At least one oxyalkylene group is preferably included between the phenoxy group and the nitrogen atom. The number of the oxyalkylene groups is 1 or more in the molecule, preferably 3 to 9, and more preferably 4 to 6. Among the oxyalkylene groups, an oxyethylene group (—CH₂CH₂O—) or an oxypropylene group (—CH(CH₃)CH₂O or —CH₂CH₂CH₂O—) is preferable, and an oxyethylene group is more preferable.

The amine compound having a phenoxy group can be obtained by heating and reacting a primary or secondary amine having a phenoxy group and a haloalkyl ether, and adding an aqueous solution of a strong base such as sodium hydroxide, potassium hydroxide, or tetraalkylammonium, followed by extraction with an organic solvent such as ethyl acetate or chloroform. Alternatively, the amine compound having a phenoxy group can be obtained by heating and reacting a primary or secondary amine and a haloalkyl ether having a phenoxy group at the terminal thereof, and adding an aqueous solution of a strong base such as sodium hydroxide, potassium hydroxide, or tetraalkylammonium, followed by extraction with an organic solvent such as ethyl acetate or chloroform.

(Compound Having Proton Acceptor Functional Group and Undergoing Decomposition Upon Irradiation with Actinic Rays or Radiation to Generate Compound Reduced in or Deprived of Proton Acceptor Property or Changed to be Acidic from being Proton Acceptor-Functioning (PA))

The composition according to the present invention may further contain a compound having a proton acceptor functional group and undergoing decomposition upon irradiation with actinic rays or radiation to generate a compound reduced in or deprived of the proton acceptor property or changed to be acidic from being proton acceptor-functioning (hereinafter, also referred to as a “compound (PA)”) as a basic compound.

The proton acceptor functional group is a functional group having a group or electron capable of electrostatically interacting with a proton and includes, for example, a functional group having a macrocyclic structure such as cyclic polyether, and a functional group containing a nitrogen atom having an unshared electron pair not contributing to π-conjugation. The nitrogen atom having an unshared electron pair not contributing to π-conjugation is a nitrogen atom having a partial structure represented by the following general formulae.

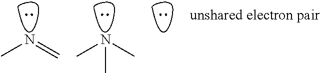

Preferred examples of the partial structure of the proton acceptor functional group include a crown ether structure, an aza-crown ether structure, a primary amine structure, a secondary amine structure, a tertiary amine structure, a pyridine structure, an imidazole structure, and a pyrazine structure.

The compound (PA) undergoes decomposition upon irradiation with actinic rays or radiation to generate a compound reduced in or deprived of the proton acceptor property or changed to be acidic from being proton acceptor-functioning. As used herein, the expression “reduced in or deprived of the proton acceptor property or changed to be acidic from being proton acceptor-functioning” refers to a change in the proton acceptor property due to the addition of a proton to a proton acceptor functional group and specifically means that when a proton adduct is produced from a proton acceptor functional group-containing compound (PA) and a proton, the equilibrium constant at the chemical equilibrium decreases.

Specific examples of the compound (PA) include the following compounds. Further specific examples of the compound (PA) may incorporate, for example, those described in paragraphs [0421] to [0428] of JP2014-41328A and paragraphs [0108] to [0116] of JP2014-134686A, the contents of which are incorporated herein.

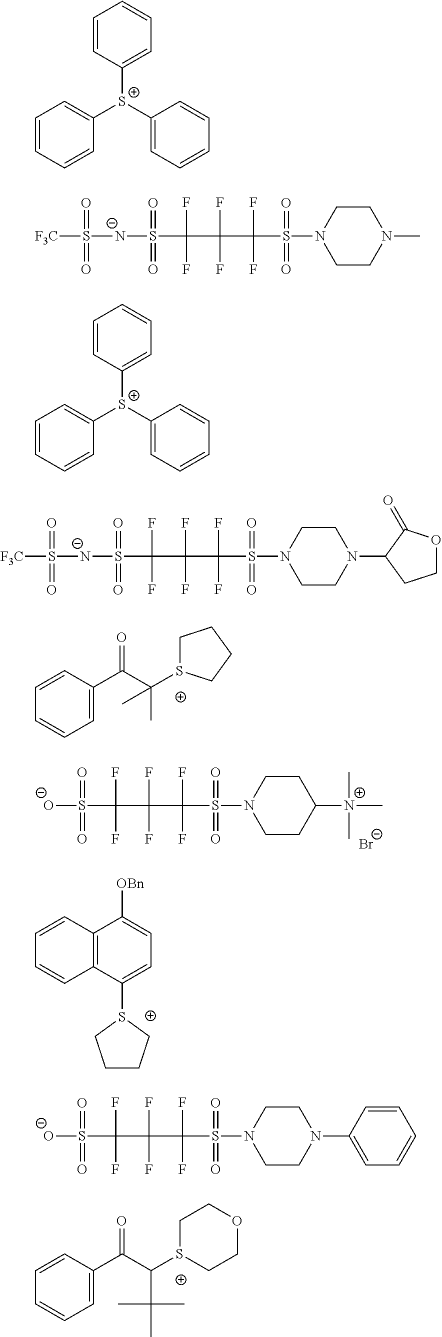

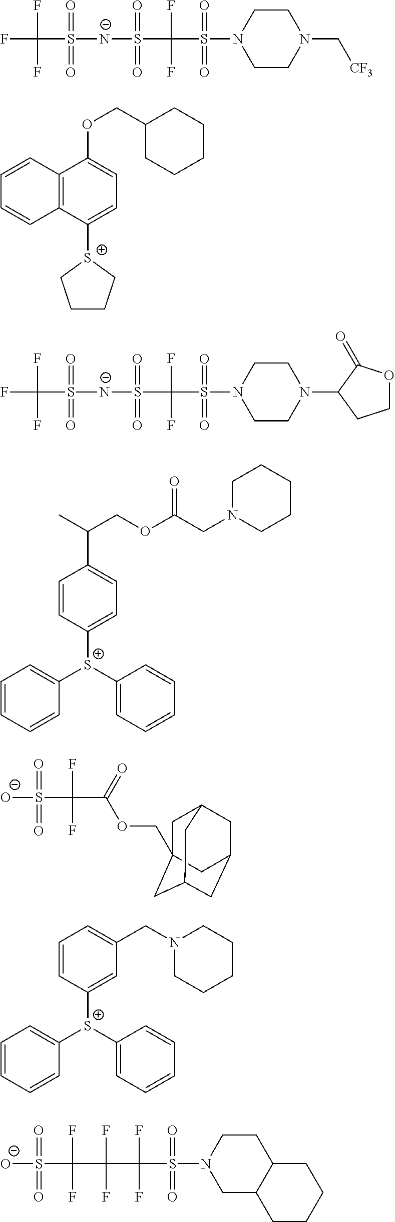

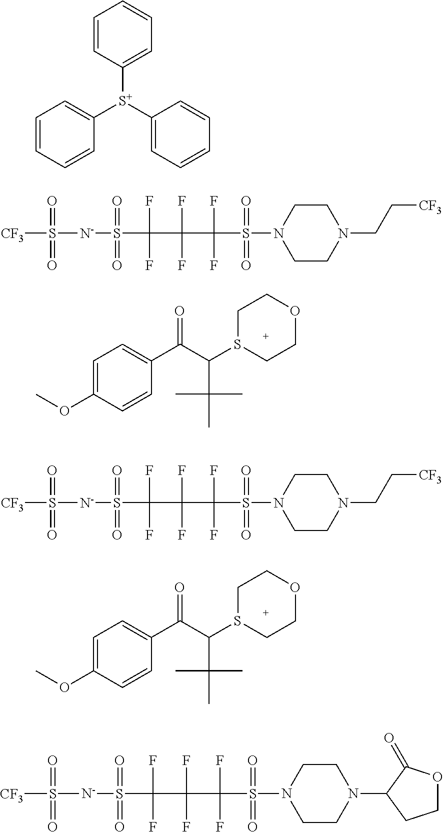

These basic compounds are used alone or in combination of two or more thereof.

The amount of the basic compound used is usually 0.001 to 10 mass % and preferably 0.01 to 5 mass %, based on the solid content of the resist composition.

The ratio of the acid generator to the basic compound used in the composition is preferably acid generator/basic compound (molar ratio) of 2.5 to 300. That is, the molar ratio of 2.5 or more is preferable from the viewpoint of sensitivity and resolution, and a molar ratio of 300 or less is preferable from the viewpoint of suppressing the reduction of resolution due to the thickening of the resist pattern over time until post exposure bake. The acid generator/basic compound (molar ratio) is more preferably 5.0 to 200 and still more preferably 7.0 to 150.

For example, compounds described in paragraphs [0140] to [0144] of JP2013-11833A (an amine compound, an amide group-containing compound, a urea compound, a nitrogen-containing heterocyclic compound, and the like) may be used as the basic compound.

(F) Surfactant

The resist composition of the present invention may further contain a surfactant (F), and may contain any one of or two or more of fluorine-based and/or silicon-based surfactants (a fluorine-based surfactant, a silicon-based surfactant, and a surfactant containing both a fluorine atom and a silicon atom).

Examples of the fluorine-based and/or silicon-based surfactants include surfactants described in JP1987-36663A (JP-S62-36663A), JP1986-226746A (JP-H61-226746A), JP1986-226745A (JP-S61-226745A), JP1987-170950A (JP-S62-170950A), JP1988-34540A (JP-S63-34540A), JP1995-230165A (JP-H07-230165A), JP1996-62834A (JP-H08-62834A), JP1997-54432A (JP-H09-54432A), JP1997-5988A (JP-H09-5988A), JP2002-277862A, U.S. Pat. No. 5,405,720A, U.S. Pat. No. 5,360,692A, U.S. Pat. No. 5,529,881A, U.S. Pat. No. 5,296,330A, U.S. Pat. No. 5,436,098A, U.S. Pat. No. 5,576,143A, U.S. Pat. No. 5,294,511A, and U.S. Pat. No. 5,824,451A. The following commercially available surfactants may be used as they are.

Examples of usable commercially available surfactants include fluorine-based surfactants or silicon-based surfactants such as EFTOP EF301 and EF303 (manufactured by Shin-Akita Kasei Co., Ltd.), FLUORAD FC430, 431, and 4430 (manufactured by Sumitomo 3M Limited), MEGAFAC F171, F173, F176, F189, F113, F110, F177, F120, and R08 (manufactured by Dainippon Ink and Chemicals Inc.), SURFLON S-382, SC101, 102, 103, 104, 105, and 106 (manufactured by Asahi Glass Co., Ltd.), TROYSOL S-366 (manufactured by Troy Chemical Co., Ltd.), GF-300 and GF-150 (manufactured by Toagosei Co., Ltd.), SURFLON S-393 (manufactured by Seimi Chemical Co., Ltd.), EFTOP EF121, EF122A, EF122B, RF122C, EF125M, EF135M, EF351, EF352, EF801, EF802, and EF601 (manufactured by Jemco Inc.), PF636, PF656, PF6320, and PF6520 (manufactured by OMNOVA Solutions Inc.), FTX-204G, 208G, 218G, 230G, 204D, 208D, 212D, 218D, and 222D (manufactured by Neos Company Limited). In addition, a polysiloxane polymer KP-341 (manufactured by Shin-Etsu Chemical Co., Ltd.) may also be used as the silicon-based surfactant.

Surfactants using a polymer having a fluoroaliphatic group derived from a fluoroaliphatic compound manufactured by a telomerization method (also referred to as a telomer method) or an oligomerization method (also referred to as an oligomer method) can be used as the surfactant, in addition to the above-mentioned known surfactants. The fluoroaliphatic compound can be synthesized according to the method disclosed in JP2002-90991A.

The polymer having a fluoroaliphatic group is preferably a copolymer of a monomer having a fluoroaliphatic group and a (poly(oxyalkylene))acrylate and/or a (poly(oxyalkylene))methacrylate, which may have irregular distribution or may be of block copolymerizion. Examples of the poly(oxyalkylene) group include a poly(oxyethylene) group, a poly(oxypropylene) group, and a poly(oxybutylene) group. Further, the polymer may be a unit having alkylene of a different chain length in the same chain length, such as a block combination of poly(oxyethylene, oxypropylene and oxybutylene), and a block combination of poly(oxyethylene and oxypropylene). In addition, the copolymer of a monomer having a fluoroaliphatic group and a (poly(oxyalkylene))acrylate (or methacrylate) may be not only a binary copolymer, but also a ternary or more copolymer obtained by simultaneous copolymerization of two or more different monomers having a fluoroaliphatic group and two or more different poly(oxyalkylene)acrylates (or methacrylates).

Examples of commercially available surfactants include MEGAFAC F-178, F-470, F-473, F-475, F-476, and F-472 (manufactured by Dainippon Ink and Chemicals Inc.). Further, a copolymer of acrylate (or methacrylate) having a C₆F₁₃ group and (poly(oxyalkylene))acrylate (or methacrylate), and a copolymer of acrylate (or methacrylate) having a C₃F₇ group, (poly(oxyethylene))acrylate (or methacrylate), and (poly(oxypropylene))acrylate (or methacrylate) are exemplified.

Surfactants other than the fluorine-based and/or silicon-based surfactants may also be used in the present invention. Specific examples thereof include nonionic surfactants, such as polyoxyethylene alkyl ethers, for example, polyoxyethylene lauryl ether, polyoxyethylene stearyl ether, polyoxyethylene cetyl ether, and polyoxyethylene oleyl ether; polyoxyethylene alkylallyl ethers, for example, polyoxyethylene octylphenol ether and polyoxyethylene nonylphenol ether; polyoxyethylene-polyoxypropylene block copolymers; sorbitan fatty acid esters, for example, sorbitan monolaurate, sorbitan monopalmitate, sorbitan monostearate, sorbitan monooleate, sorbitan trioleate, and sorbitan tristearate; and polyoxyethylene sorbitan fatty acid esters, for example, polyoxyethylene sorbitan monolaurate, polyoxyethylene sorbitan monopalmitate, polyoxyethylene sorbitan monostearate, polyoxyethylene sorbitan trioleate, and polyoxyethylene sorbitan tristearate.

These surfactants may be used alone or in some combination.

The content of the surfactant in the resist composition is preferably 0.01 to 10 mass % and more preferably 0.1 to 5 mass %, with respect to the total amount of the resist composition (excluding a solvent).

(G) Carboxylic Acid Onium Salt

The resist composition of the present invention may contain a carboxylic acid onium salt (G). Examples of the carboxylic acid onium salt include a carboxylic acid sulfonium salt, a carboxylic acid iodonium salt, and a carboxylic acid ammonium salt. In particular, the carboxylic acid onium salt (G) is preferably an iodonium salt or a sulfonium salt. It is preferred that the carboxylate residue of the carboxylic acid onium salt (G) of the present invention does not contain an aromatic group and a carbon-carbon double bond. A particularly preferred anionic moiety is a linear or branched, monocyclic or polycyclic alkylcarboxylic acid anion having 1 to 30 carbon atoms, and a carboxylic acid anion in which a part or all of the alkyl groups are substituted with fluorine atoms is more preferable. An oxygen atom may be contained in the alkyl chain. Thus, the transparency to the light of 220 nm or less is ensured, sensitivity and resolution are increased, and condensation and rarefaction dependency and exposure margin are improved.

Examples of anions of the fluorine-substituted carboxylic acid include anions of fluoroacetic acid, difluoroacetic acid, trifluoroacetic acid, pentafluoropropionic acid, heptafluorobutyric acid, nonafluoropentanoic acid, perfluorododecanoic acid, perfluorotridecanoic acid, perfluorocyclohexanecarboxylic acid, and 2,2-bistrifluoromethylpropionic acid.

These carboxylic acid onium salts (G) can be synthesized by reacting sulfonium hydroxide, iodonium hydroxide or ammonium hydroxide and carboxylic acid with silver oxide in a suitable solvent.

The content of carboxylic acid onium salt in the resist composition is generally 0.1 to 20 mass %, preferably 0.5 to 10 mass %, and more preferably 1 to 7 mass %, with respect to the total solid content of the composition.

(H) Hydrophobic Resin

The resist composition of the present invention may contain a hydrophobic resin (hereinafter, also referred to as a “hydrophobic resin (H)” or simply a “resin (H)”). Incidentally, it is preferred that the hydrophobic resin (H) is different from the resin (A).

It is preferred that the hydrophobic resin (H) is designed to be unevenly distributed to the interface, but in contrast to a surfactant, the hydrophobic resin (H) is not necessarily required to have a hydrophilic group in the molecule, and may not contribute to uniform mixing of polar/nonpolar materials.

The effect of adding a hydrophobic resin includes control of the static/dynamic contact angle of the resist film surface with respect to water, improved followability of the immersion liquid, suppression of outgassing, and the like.

From the viewpoint of uneven distribution to the film surface layer, it is preferred that the hydrophobic resin (H) contains one or more of a “fluorine atom”, a “silicon atom” and a “CH₃ partial structure contained in the side chain portion of the resin”, and it is more preferred that the hydrophobic resin (H) contains two or more thereof.

In the case where the hydrophobic resin (H) contains a fluorine atom and/or a silicon atom, the fluorine atom and/or silicon atom in the hydrophobic resin (H) may be contained in the main chain of the resin or may be contained in side chain of the resin.

In the case where the hydrophobic resin (H) contains a fluorine atom, the resin preferably contains a fluorine atom-containing alkyl group, a fluorine atom-containing cycloalkyl group or a fluorine atom-containing aryl group, as a fluorine atom-containing partial structure.

The fluorine atom-containing alkyl group (preferably having 1 to 10 carbon atoms and more preferably having 1 to 4 carbon atoms) is a linear or branched alkyl group in which at least one hydrogen atom is substituted with a fluorine atom and which may further have a substituent other than a fluorine atom.

The fluorine atom-containing cycloalkyl group and the fluorine atom-containing aryl group are respectively a cycloalkyl group in which one hydrogen atom is substituted with a fluorine atom and an aryl group which contains a fluorine atom, each of which may further have a substituent other than a fluorine atom.

As the fluorine atom-containing alkyl group, fluorine atom-containing cycloalkyl group, and fluorine atom-containing aryl group, the groups represented by the following General Formulae (F2) to (F4) are preferable, but the present invention is not limited thereto.

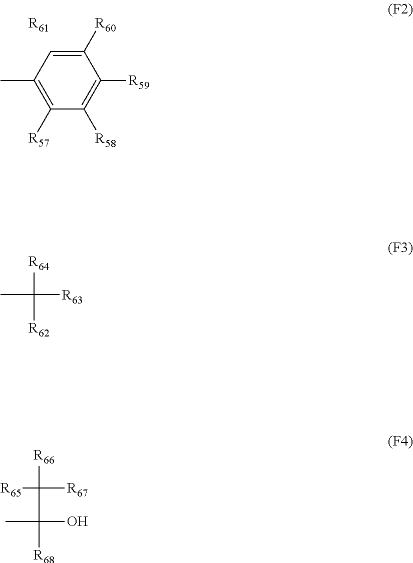

In General Formulae (F2) to (F4),

R₅₇ to R₆₈ each independently represent a hydrogen atom, a fluorine atom, or an alkyl group (linear or branched), provided that at least one of R₅₇, R₅₈, R₅₉, R₆₀, or R₆₁, at least one of R₆₂, R₆₃, or R₆₄, and at least one of R₆₅, R₆₆, R₆₇, or R₆₈ each independently represent a fluorine atom or an alkyl group (preferably having 1 to 4 carbon atoms) in which at least one hydrogen atom is substituted with a fluorine atom.

It is preferred that all of R₅₇ to R₆₁ and R₆₅ to R₆₇ are a fluorine atom. R₆₂, R₆₃, and R₆₈ are preferably an alkyl group (preferably having 1 to 4 carbon atoms) in which at least one hydrogen atom is substituted with a fluorine atom, and more preferably a perfluoroalkyl group having 1 to 4 carbon atoms. R₆₂ and R₆₃ may be bonded to each other to form a ring.

The hydrophobic resin (H) may contain a silicon atom. The resin preferably has an alkylsilyl structure (preferably a trialkylsilyl group) or a cyclic siloxane structure, as a silicon atom-containing partial structure.

Examples of the repeating unit having a fluorine atom or a silicon atom include those exemplified in paragraph [0519] of US2012/0251948A1.

As mentioned above, it is also preferred that the hydrophobic resin (H) contains a CH₃ partial structure in the side chain portion thereof.

As used herein, the CH₃ partial structure that the hydrophobic resin (H) has in the side chain portion thereof (hereinafter simply referred to as “side chain CH₃ partial structure”) is intended to include a CH₃ partial structure that an ethyl group, a propyl group, or the like has.

On the other hand, a methyl group directly bonded to the main chain of the hydrophobic resin (H) (for example, α-methyl group in the repeating unit having a methacrylic acid structure) makes only a small contribution to surface localization of the hydrophobic resin (H) owing to influence of the main chain, and therefore it is not included in the CH₃ partial structure in the present invention.

More specifically, in the case where the hydrophobic resin (H) contains a repeating unit derived from a monomer having a polymerizable moiety with a carbon-carbon double bond, such as a repeating unit represented by, for example, the following General Formula (M), if each of R₁₁ to R₁₄ is CH₃ itself, such CH₃ is not included in the CH₃ partial structure contained in the side chain in the present invention.

On the other hand, it is assumed that the CH₃ partial structure existing from the C—C main chain through some atom corresponds to the CH₃ partial structure in the present invention. For example, in the case where R₁₁ is an ethyl group (CH₂CH₃), it is assumed to have “one” CH₃ partial structure in the present invention.

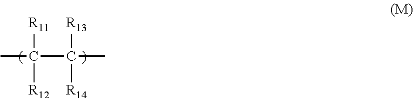

In General Formula (M),

R₁₁ to R₁₄ each independently represent a side chain portion.

Examples of R₁₁ to R₁₄ of the side chain portion include a hydrogen atom and a monovalent organic group.

Examples of the monovalent organic group for R₁₁ to R₁₄ include an alkyl group, a cycloalkyl group, an aryl group, an alkyloxycarbonyl group, a cycloalkyloxycarbonyl group, an aryloxycarbonyl group, an alkylaminocarbonyl group, a cycloalkylaminocarbonyl group, and an arylaminocarbonyl group, each of which may further have a substituent.

It is preferred that the hydrophobic resin (H) is a resin containing a repeating unit having a CH₃ partial structure in the side chain portion thereof, and it is more preferred that such a repeating unit includes at least one repeating unit (x) of a repeating unit represented by the following General Formula (II) and a repeating unit represented by the following General Formula (III).

Hereinafter, the repeating unit represented by General Formula (II) will be described in detail.

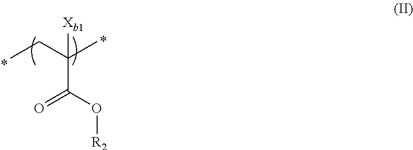

In General Formula (II), X_{b1} represents a hydrogen atom, an alkyl group, a cyano group, or a halogen atom, and R₂ represents an organic group which has one or more CH₃ partial structures and is stable to an acid. Here, more specifically, the organic group stable to an acid is preferably an organic group having no acid-decomposable group.

The alkyl group of X_{b1} is preferably an alkyl group having 1 to 4 carbon atoms, and examples thereof include a methyl group, an ethyl group, a propyl group, a hydroxymethyl group, and trifluoromethyl group, among which preferred is a methyl group.

X_{b1} is preferably a hydrogen atom or a methyl group.

Examples of R₂ include an alkyl group, a cycloalkyl group, alkenyl group, cycloalkenyl group, an aryl group, and an aralkyl group, each of which has one or more CH₃ partial structures. Each of the cycloalkyl group, the alkenyl group, the cycloalkenyl group, the aryl group and the aralkyl group may further have an alkyl group as a substituent.

R₂ is preferably an alkyl group or an alkyl-substituted cycloalkyl group, each of which has one or more CH₃ partial structures.

The number of CH₃ partial structures contained in the organic group having one or more CH₃ partial structures and stable to an acid, which is represented by R₂, is preferably 2 or more and 10 or less and more preferably 2 or more and 8 or less.

Specific preferred examples of the repeating unit represented by General Formula (II) are shown below, but the present invention is not limited thereto.

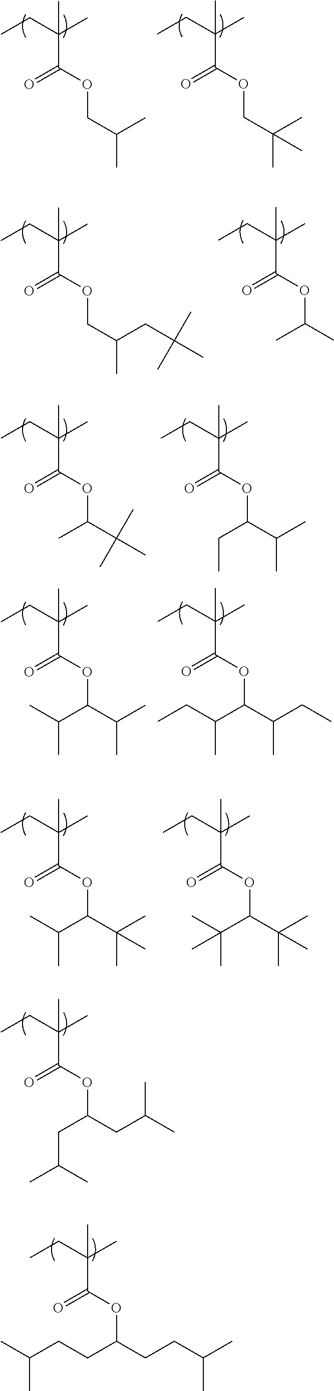

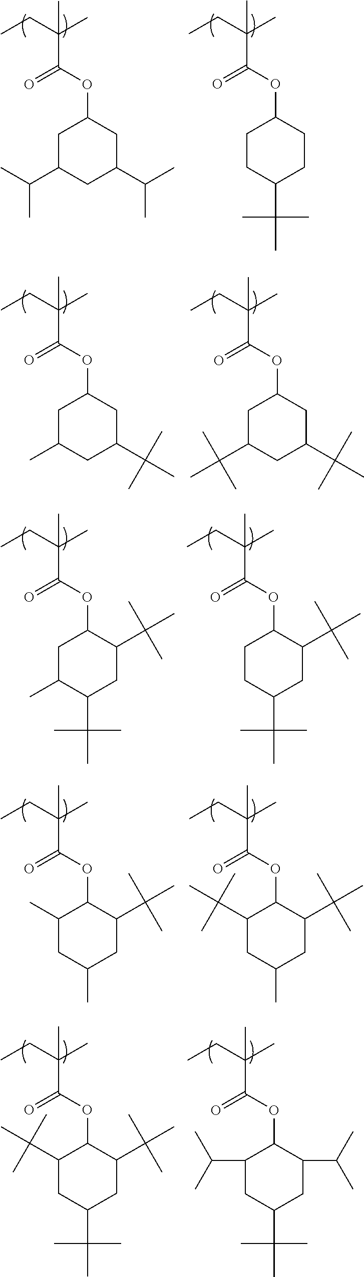

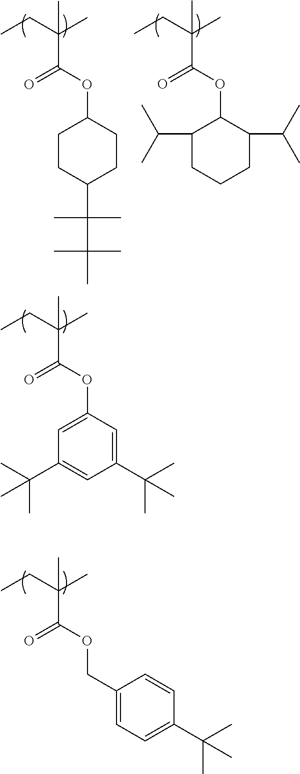

The repeating unit represented by General Formula (II) is preferably a repeating unit which is stable to an acid (non-acid-decomposable), and more specifically, it is a repeating unit which is free of a group capable of decomposing by the action of an acid to generate a polar group.

Hereinafter, the repeating unit represented by General Formula (III) will be described in detail.

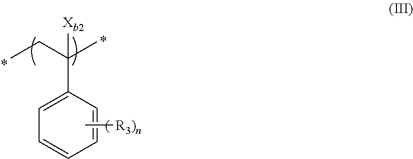

In General Formula (III), Xb₂ represents a hydrogen atom, an alkyl group, a cyano group, or a halogen atom, R₃ represents an organic group which has one or more CH₃ partial structures and is stable to an acid, and n represents an integer of 1 to 5.

The alkyl group of Xb₂ is preferably an alkyl group having 1 to 4 carbon atoms, and examples thereof include a methyl group, an ethyl group, a propyl group, a hydroxymethyl group, and a trifluoromethyl group.

X_{b2} is preferably a hydrogen atom.

R₃ is an organic group stable to an acid. More specifically, R₃ is preferably an organic group having no acid-decomposable group.

An example of R₃ may be an alkyl group having one or more CH₃ partial structures.

The number of the CH₃ partial structures contained in the organic group having one or more CH₃ partial structures and stable to an acid, which is represented by R₃, is preferably 1 or more and 10 or less, more preferably 1 or more and 8 or less, and still more preferably 1 or more and 4 or less.

n represents an integer of 1 to 5, preferably an integer of 1 to 3, and more preferably 1 or 2.

Preferred specific examples of the repeating unit represented by General Formula (III) are shown below, but the present invention is not limited thereto.

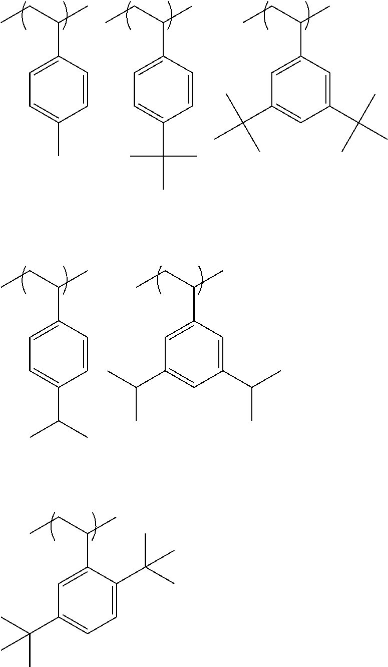

The repeating unit represented by General Formula (III) is preferably a repeating unit which is stable to an acid (non-acid-decomposable) and more specifically, it is preferably a repeating unit which is free of a group capable of decomposing by the action of an acid to generate a polar group.

In the case where the hydrophobic resin (H) contains a CH₃ partial structure in the side chain portion thereof and moreover in particular in the case where the hydrophobic resin (H) has no fluorine atom and no silicon atom, the content of at least one repeating unit (x) of the repeating unit represented by General Formula (II) and the repeating unit represented by General Formula (III) is preferably 90 mol % or more and more preferably 95 mol % or more, with respect to all repeating units of the hydrophobic resin (H). Such a content is usually 100 mol % or less with respect to all repeating units of the hydrophobic resin (H).

When the hydrophobic resin (H) contains at least one repeating unit (x) of the repeating unit represented by General Formula (II) and the repeating unit represented by General Formula (III) in an amount of 90 mol % or more with respect to all repeating units of the hydrophobic resin (H), surface free energy of the hydrophobic resin (H) increases. As a result, it becomes difficult for the hydrophobic resin (H) to be unevenly distributed on the surface of the resist film and the static/dynamic contact angle of the resist film with respect to water is improved with certainty, thus resulting in improved followability of the immersion liquid.

In addition, the hydrophobic resin (H) may have at least one group selected from the group consisting of the following (x) to (z) in the case of containing (i) a fluorine atom and/or a silicon atom as well as in the case of containing (ii) a CH₃ partial structure in the side chain portion:

(x) an acid group,

(y) a lactone structure-containing group, an acid anhydride group, or an acid imide group,

(z) a group capable of decomposing by the action of an acid.

Examples of the acid group (x) include a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group.

Preferred examples of the acid group include a fluorinated alcohol group (preferably hexafluoroisopropanol), a sulfonimide group, and a bis(alkylcarbonyl)methylene group.

The repeating unit having (x) an acid group may be, for example, a repeating unit in which the acid group is directly bonded to the main chain of the resin, such as a repeating unit by an acrylic acid or a methacrylic acid, and a repeating unit in which the acid group is bonded to the main chain of the resin through a linking group, and the acid group may also be introduced into the terminal of the polymer chain by using an acid group-containing polymerization initiator or chain transfer agent at the polymerization. All of these cases are preferable. The repeating unit having (x) an acid group may have at least any one of a fluorine atom or a silicon atom.

The content of the repeating unit having (x) an acid group is preferably 1 to 50 mol %, more preferably 3 to 35 mol %, and still more preferably 5 to 20 mol %, with respect to all repeating units in the hydrophobic resin (H).

Specific examples of the repeating unit having (x) an acid group are shown below, but the present invention is not limited thereto. In the formulae, Rx represents a hydrogen atom, CH₃, CF₃, or CH₂OH.

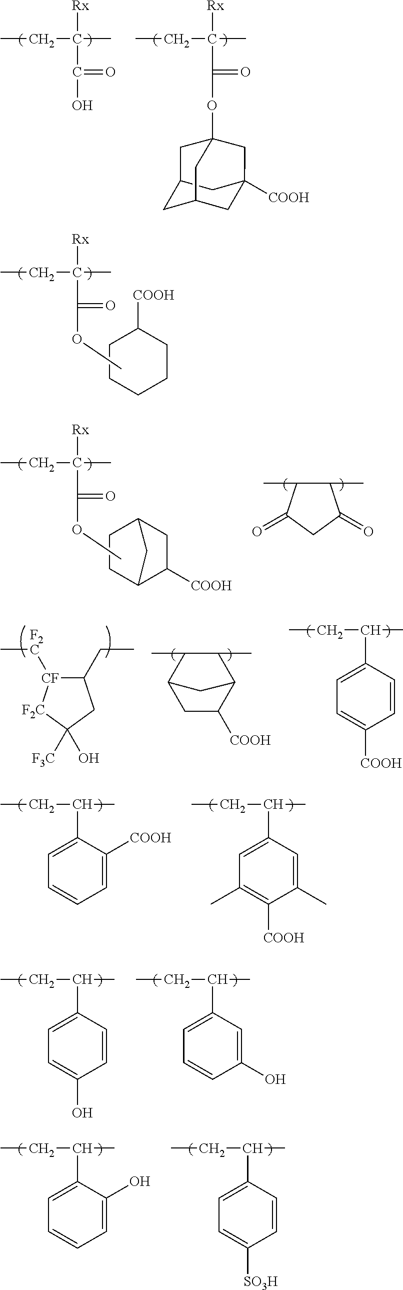

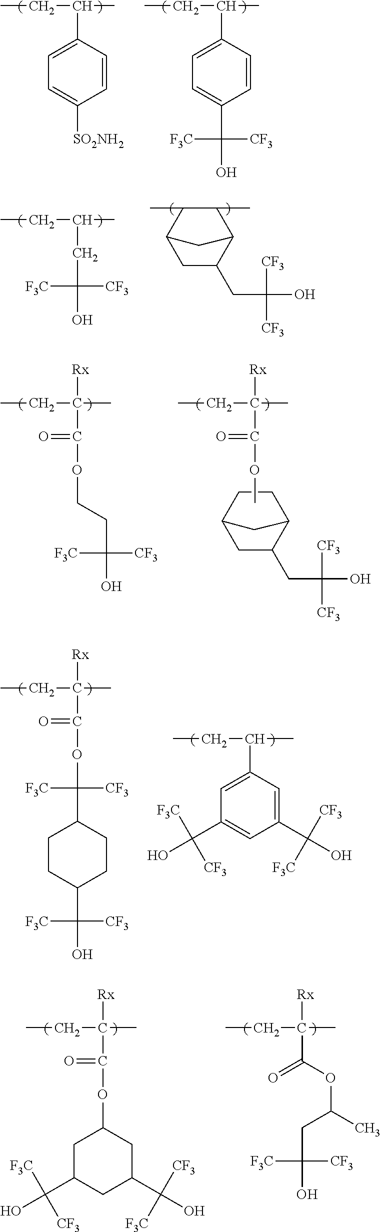

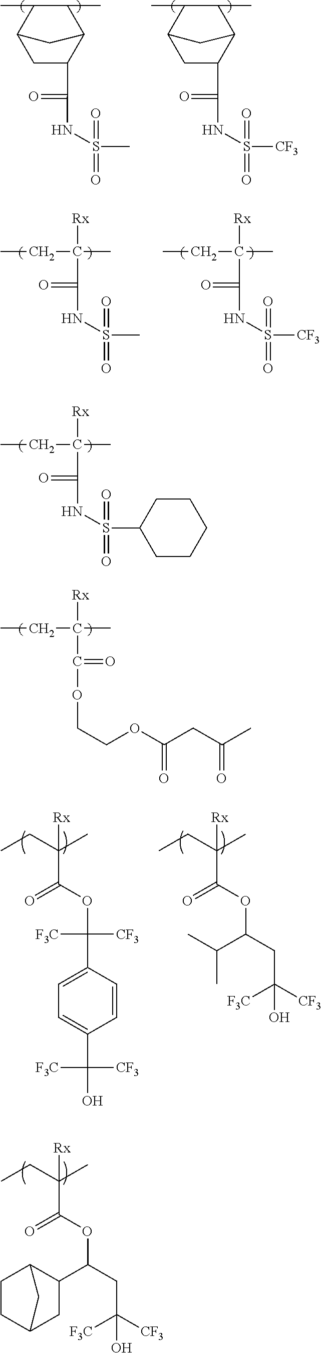

The lactone structure-containing group, acid anhydride group, or acid imide group (y) is particularly preferably a lactone structure-containing group.

The repeating unit containing such a group is, for example, a repeating unit in which the group is directly bonded to the main chain of the resin, such as a repeating unit by an acrylic acid ester or a methacrylic acid ester. This repeating unit may be a repeating unit in which the group is bonded to the main chain of the resin through a linking group. Alternatively, in this repeating unit, the group may be introduced into the terminal of the resin by using a polymerization initiator or chain transfer agent containing the group at the polymerization.

Examples of the repeating unit having a lactone structure-containing group are the same as those of the repeating unit having a lactone structure described in the section of (A) Resin.

The content of the repeating unit having a lactone structure-containing group, acid anhydride group or acid imide group is preferably 1 to 100 mol %, more preferably 3 to 98 mol %, and still more preferably 5 to 95 mol %, based on all repeating units in the hydrophobic resin (H).

Examples of the repeating unit having (z) a group capable of decomposing by the action of an acid, contained in the hydrophobic resin (H), include, but are not limited to, those of the repeating unit having a group capable of decomposing by the action of an acid to generate a carboxyl group described in the section of (A) Resin. The repeating unit having (z) a group capable of decomposing by the action of an acid may contain at least one of a fluorine atom or a silicon atom. In the hydrophobic resin (H), the content of the repeating unit having (z) a group capable of decomposing by the action of an acid is preferably 1 to 80 mol %, more preferably 10 to 80 mol %, and still more preferably 20 to 60 mol %, with respect to all repeating units in the resin (H).

The hydrophobic resin (H) may further have other repeating units than the repeating units described above.

The fluorine atom-containing repeating unit preferably accounts for 10 to 100 mol % and more preferably 30 to 100 mol %, based on all repeating units contained in the hydrophobic resin (H). The silicon atom-containing repeating unit preferably accounts for 10 to 100 mol % and more preferably 20 to 100 mol %, based on all repeating units contained in the hydrophobic resin (H).

On the other hand, in particular, in the case where the hydrophobic resin (H) contains a CH₃ partial structure in the side chain portion thereof, it is also preferred that the hydrophobic resin (H) has a form substantially free of both a fluorine atom and a silicon atom. In addition, it is preferred that the hydrophobic resin (H) is composed substantially of a repeating unit whose constituent atom is only an atom selected from the group consisting of a carbon atom, an oxygen atom, a hydrogen atom, a nitrogen atom, and a sulfur atom.

The weight-average molecular weight of the hydrophobic resin (H) in terms of standard polystyrene is preferably 1,000 to 100,000 and more preferably 1,000 to 50,000.

As for the hydrophobic resin (H), one resin may be used or a plurality of resins may be used in combination.

The content of the hydrophobic resin (H) in the composition is preferably 0.01 to 10 mass % and more preferably 0.05 to 8 mass %, with respect to the total solid content in the composition of the present invention.

In the hydrophobic resin (H), the content of residual monomer or oligomer components is 0.01 to 5 mass % and more preferably 0.01 to 3 mass %.

The molecular weight distribution (Mw/Mn, also referred to as “dispersity”) is preferably in the range of 1 to 5 and more preferably in the range of 1 to 3.

As the hydrophobic resin (H), various commercial products may be used, or the resin may be synthesized by a conventional method (for example, radical polymerization).

(I) Crosslinking Agent

The resist composition of the present invention may contain a crosslinking agent (I). As the crosslinking agent, it is preferred to have a bifunctional crosslinking agent.

Such a bifunctional crosslinking agent (hereinafter, also referred to as a crosslinking agent (C1)), in one embodiment thereof, is preferably a compound represented by the following General Formula (I).

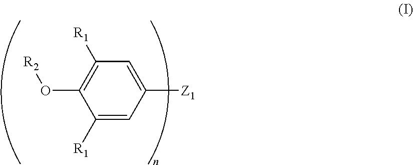

In General Formula (I),

R₁'s each independently represent a hydrogen atom, an alkyl group, an aryl group, a hydroxymethyl group, an alkoxymethyl group, or a group represented by —CH₂—O—R₁₁ in which R₁₁ represents an aryl group or an acyl group, provided that two or more and four or less R₁'s in the whole molecule are a hydroxymethyl group or an alkoxymethyl group.

In the case where n is 2 or more, R₂'s each independently represent a hydrogen atom, an alkyl group, an aryl group, or a group represented by —CO-A in which A represents an alkyl group, an alkoxy group, or N(R₂₂)₂ in which R₂₂ represents an alkyl group having 4 or less carbon atoms.

Z₁ represents a hydrogen atom in the case where n is 1 and Z₁ represents a linking group or a single bond in the case where n is 2 or more.

n represents an integer of 1 to 4.

In the compound represented by General Formula (I), as described above, two or more and four or less R₁'s among R₁'s contained in the whole molecule are a hydroxymethyl group or an alkoxymethyl group. In one embodiment of the present invention, it is preferred that two or three R₁'s among R₁'s contained in the whole molecule are hydroxymethyl group or an alkoxymethyl group, and it is more preferred that two R₁'s are a hydroxymethyl group or an alkoxymethyl group. Further, it is still more preferred that two hydroxymethyl groups or alkoxymethyl groups represented by R₁'s are substituted on different benzene rings.

The alkyl moiety in the alkoxymethyl group is preferably an alkyl group having 6 or less carbon atoms, specific examples of which include a methyl group, an ethyl group, a propyl group, an isopropyl group, an n-butyl group, an isobutyl group, a sec-butyl group, a pentyl group, a neopentyl group, and a hexyl group.

The alkyl group represented by R₁ is preferably, for example, an alkyl group having 1 to 5 carbon atoms, and the aryl group is preferably, for example, an aryl group having 6 to 18 carbon atoms.

The aryl group represented by R₁₁ in —CH₂—O—R₁₁ as R₁ is preferably, for example, an aryl group having 6 to 18 carbon atoms, and the acyl group is preferably, for example, an acyl group in which the alkyl moiety is an alkyl group having 1 to 6 carbon atoms.

In one embodiment of the present invention, R₁ other than a hydroxymethyl group and an alkoxymethyl group is preferably an alkyl group or an aryl group.

The alkyl group represented by R₂ is preferably, for example, an alkyl group having 1 to 6 carbon atoms, and the aryl group is preferably, for example, an aryl group having 6 to 18 carbon atoms.

The alkyl group represented by A in —CO-A as R₂ is preferably, for example, an alkyl group having 1 to 6 carbon atoms, and the alkoxy group is preferably, for example, an alkoxy group having 1 to 6 carbon atoms. In one embodiment of the present invention, A preferably has 6 or less carbon atoms.

In one embodiment of the present invention, R₂ is preferably a hydrogen atom, an alkyl group, or an aryl group, and more preferably a hydrogen atom or an alkyl group.

In one embodiment of the present invention, n is preferably an integer of 2 to 4 and is more preferably 2.

As described above, Z₁ represents a hydrogen atom in the case where n is 1 and Z₁ represents a linking group in the case where n is 2 or more. Z₁ is preferably a divalent to tetravalent linking group, and more preferably a divalent linking group.

The linking group represented by Z₁ is not particularly limited. Specific examples of the linking group in the case where Z₁ is, for example, a divalent linking group include an alkylene group, an arylene group, and a group formed by combining two or more thereof, each of which may further have a substituent.

In the case where Z₁ is a divalent linking group, it is preferably, for example, a structure represented by the following formula. In the following formula, R₃ and R₄ have the same definition as R₃ and R₄ in General Formula (I-B) to be described hereinafter. Further, * represents a site of boding to the benzene ring which is a remainder of General Formula (I).

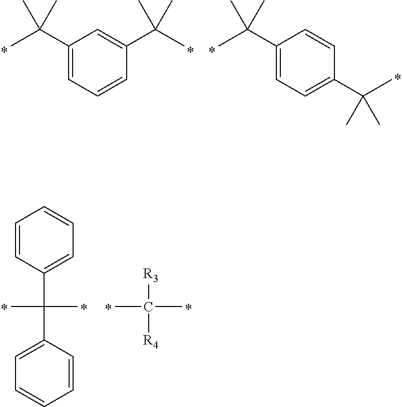

In one embodiment, the crosslinking agent (C1) is preferably a compound represented by the following General Formula (I-B).

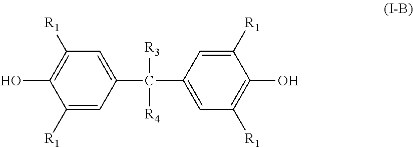

In General Formula (I-B),

R₁ has the same definition as R₁ in General Formula (I).

R₃ and R₄ each independently represent a hydrogen atom or organic group. R₃ and R₄ may be bonded to each other to form a ring.

In one embodiment of the present invention, it is preferred that at least one of the organic groups represented by R₃ and R₄ is an organic group having two or more carbon atoms, and it is more preferred that both of the organic groups represented by R₃ and R₄ are an organic group having two or more carbon atoms.

Examples of the organic group represented by R₃ and R₄ include an alkyl group, a cycloalkyl group, and an aryl group. In addition, it is preferred that R₃ and R₄ are bonded to each other to form a ring which will be described in detail below.

Examples of the ring formed by bonding of R₃ and R₄ to each other include an aromatic or non-aromatic hydrocarbon ring, an aromatic or non-aromatic heterocyclic ring, and a polycyclic condensed ring formed by combining two or more thereof.

These rings may have a substituent, and examples of such a substituent include an alkyl group, a cycloalkyl group, an alkoxy group, a carboxyl group, an aryl group, an alkoxymethyl group, an acyl group, an alkoxycarbonyl group, a nitro group, a halogen, and a hydroxy group.

Hereinafter, specific examples of the ring formed by bonding of R₃ and R₄ to each other are shown below. In the formula, * represents a linking site to the phenol nucleus.

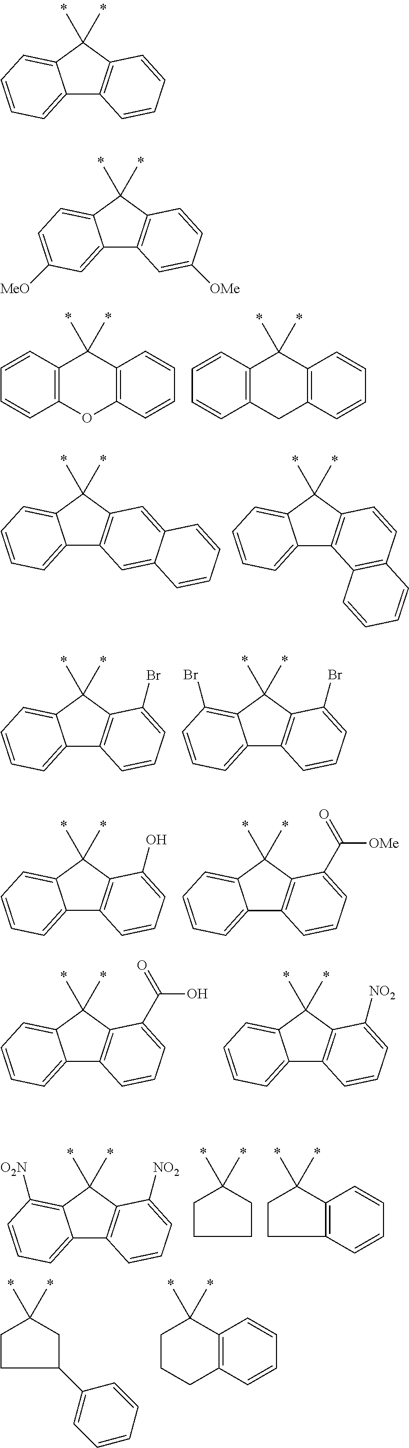

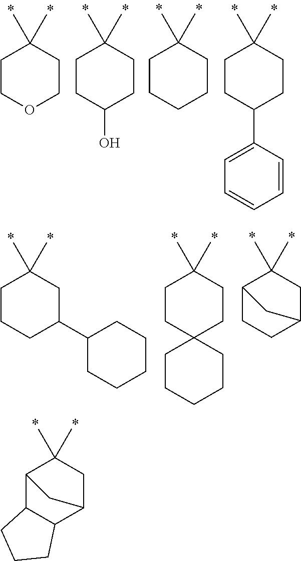

In one embodiment of the present invention, it is preferred that R₃ and R₄ in General Formula (I-B) are bonded to form a polycyclic condensed ring containing a benzene ring and it is more preferred that R₃ and R₄ are bonded to form a fluorene structure.

For example, the crosslinking agent (C1) preferably has a fluorene structure represented by the following General Formula (I-d), which is formed by bonding of R₃ and R₄ in General Formula (I-B).

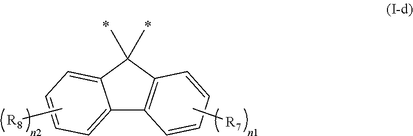

In the formula, R₇ and R₈ each independently represent a substituent. Examples of the substituent include an alkyl group, a cycloalkyl group, an alkoxy group, an aryl group, an alkoxymethyl group, an acyl group, an alkoxycarbonyl group, a nitro group, a halogen atom, and a hydroxy group.

n1 and n2 each independently represent an integer of 0 to 4 and preferably 0 or 1.

* represents a linking site to the phenol nucleus.

Further, in one embodiment of the present invention, the crosslinking agent (I) is preferably represented by the following General Formula (I-b).

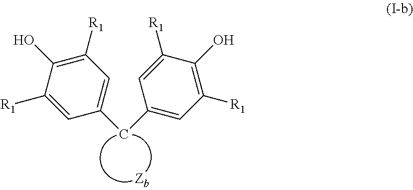

In the formula,

R₁ has the same definition as R₁ in General Formula (I).

Z_{b} represents an atomic group necessary to form a ring together with the carbon atom in the formula, and such a ring may have a substituent.

The ring formed by Z_{b} together with the carbon atom in the formula is the same as that described for the ring formed by bonding of R₃ and R₄ to each other in the explanation of the above-mentioned General Formula (I-B.

Further, in one embodiment of the present invention, the crosslinking agent (I) is preferably represented by the following General Formula (I-c).

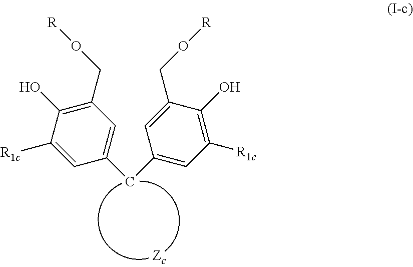

In the formula,

R's each independently represent an alkyl group or a cycloalkyl group.

R_{1c}'s each independently represent an alkyl group.

Z_{c} represents an atomic group necessary to form a ring together with the carbon atom in the formula, and such a ring may have a substituent.

In General Formula (I-c), the alkyl group represented by R is preferably, for example, an alkyl group having 1 to 6 carbon atoms, and the cycloalkyl group is preferably, for example, a cycloalkyl group having 3 to 12 carbon atoms.

The alkyl group represented by R_{1c} is preferably, for example, an alkyl group having 1 to 5 carbon atoms.

The ring formed by Z_{c} together with the carbon atom in the formula is the same as that described for the ring formed by bonding of R₃ and R₄ to each other in the explanation of the above-mentioned General Formula (I-B).

Further, in another embodiment of the present invention, the crosslinking agent (C1) is preferably represented by the following General Formula (I-e), (I-f), or (I-g). In the formula, R₁ has the same definition as R₁ in General Formula (I).

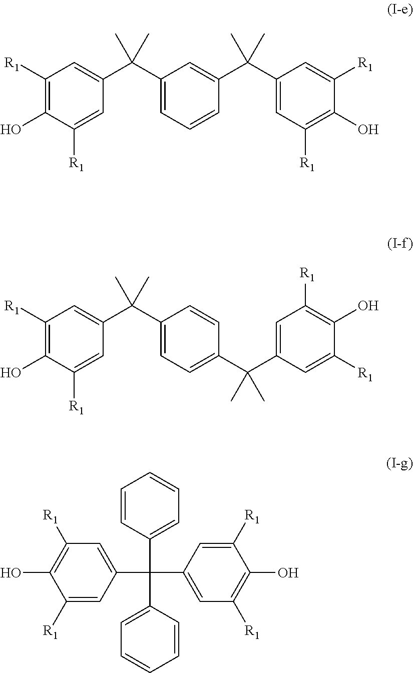

In another embodiment, the crosslinking agent (C1) is preferably a compound represented by the following General Formula (II).

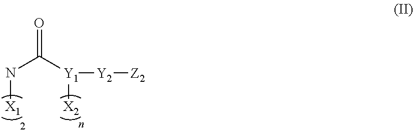

In General Formula (II),

X₁ and X₂ each independently represent a hydrogen atom, an alkyl group, a cycloalkyl group, a hydroxymethyl group, or an alkoxymethyl group, provided that at least one of two X₁'s is a hydroxymethyl group or an alkoxymethyl group.

In the case where both of two X₁'s are a hydroxymethyl group or an alkoxymethyl group, Y₁ represents a carbon atom, a nitrogen atom, or an oxygen atom. In the case where one X₁ is neither a hydroxymethyl group nor an alkoxymethyl group, Y₁ is a nitrogen atom, and X₂ is a hydroxymethyl group or an alkoxymethyl group.

Y₂ represents a single bond, an alkylene group, or a cycloalkylene group.

Z₂ represents an organic group.

When Y₁ is a carbon atom, n is 2. When Y₁ is a nitrogen atom, n is 1. When Y₁ is an oxygen atom, n is 0.

Any two of X₁, X₂, and Y₂ may be bonded to form a ring.

The alkyl group represented by X₁ and X₂ are preferably an alkyl group having 1 to 30 carbon atoms. Specific examples of the alkyl group include a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, and an eicosyl group.

The alkyl group represented by X₁ and X₂ may have a substituent.

The cycloalkyl group represented by X₁ and X₂ may be monocyclic or polycyclic and is preferably a cycloalkyl group having 3 to 30 carbon atoms. Specific examples thereof include a cyclopropyl group, a cyclopentyl group, a cyclohexyl group, an adamantyl group, a norbornyl group, and a bornyl group.

The cycloalkyl group represented by X₁ and X₂ may have a substituent.

The alkyl moiety of the alkoxy group in the alkoxymethyl group represented by X₁ and X₂ may be chain-like or cyclic, and examples thereof are the same as specific examples of the above-mentioned alkyl group and cycloalkyl group represented by X₁ and X₂. The alkoxy group in the alkoxymethyl group is more preferably a methoxy group or an ethoxy group, and particularly preferably a methoxy group.

The alkylene group represented by Y₂ preferably has 1 to 10 carbon atoms, more preferably 1 to 5 carbon atoms, and examples thereof include a methylene group, an ethylene group, and a propylene group.

The cycloalkylene group represented by Y₂ is preferably a cycloalkylene group having 3 to 20 carbon atoms, and examples thereof include a cyclohexylene group, a cyclopentylene group, a norbornylene group, and an adamantylene group.

The organic group represented by Z₂ is an organic group having a molecular weight of preferably 100 or more and 2,000 or less and particularly preferably 200 or more and 1,500 or less.

Hereinafter, specific examples of the crosslinking agent (I) are shown together with the molecular weight.

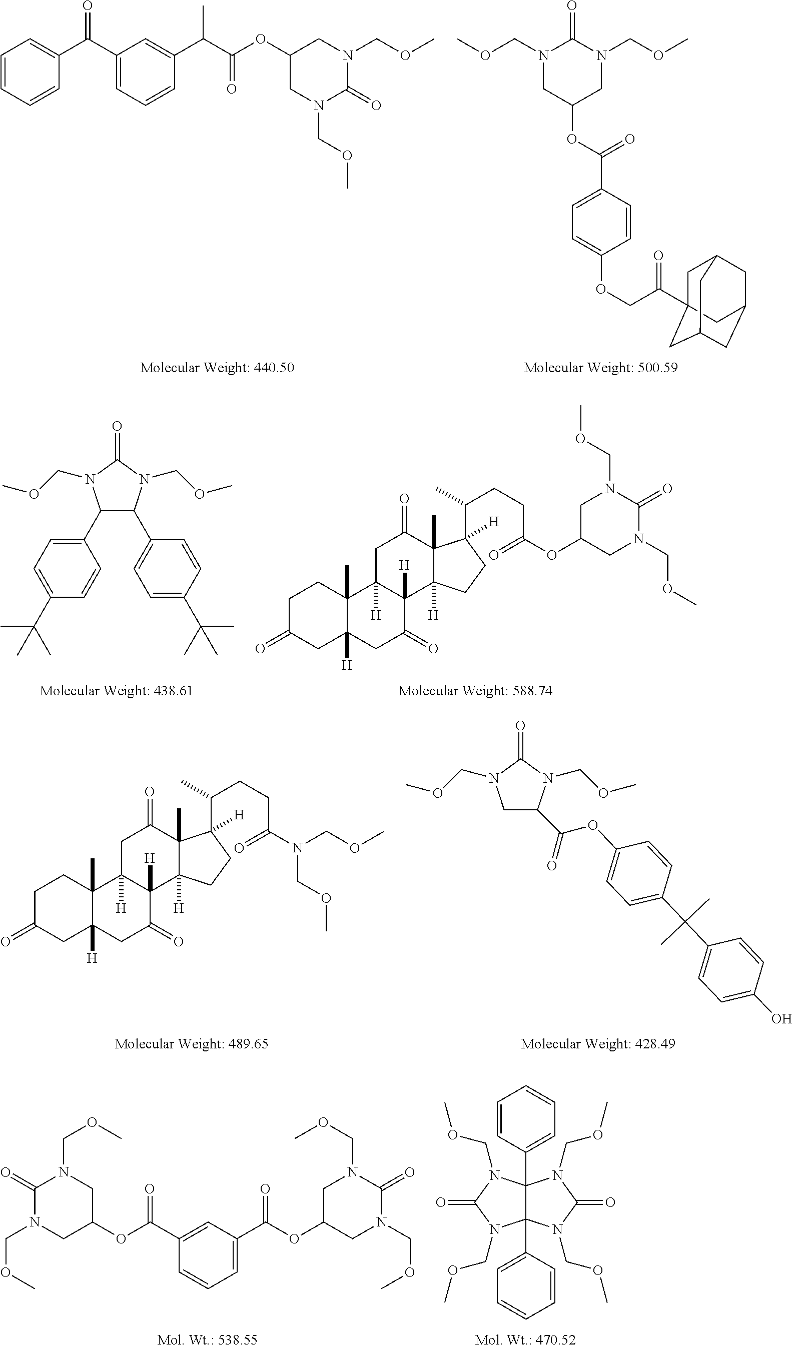

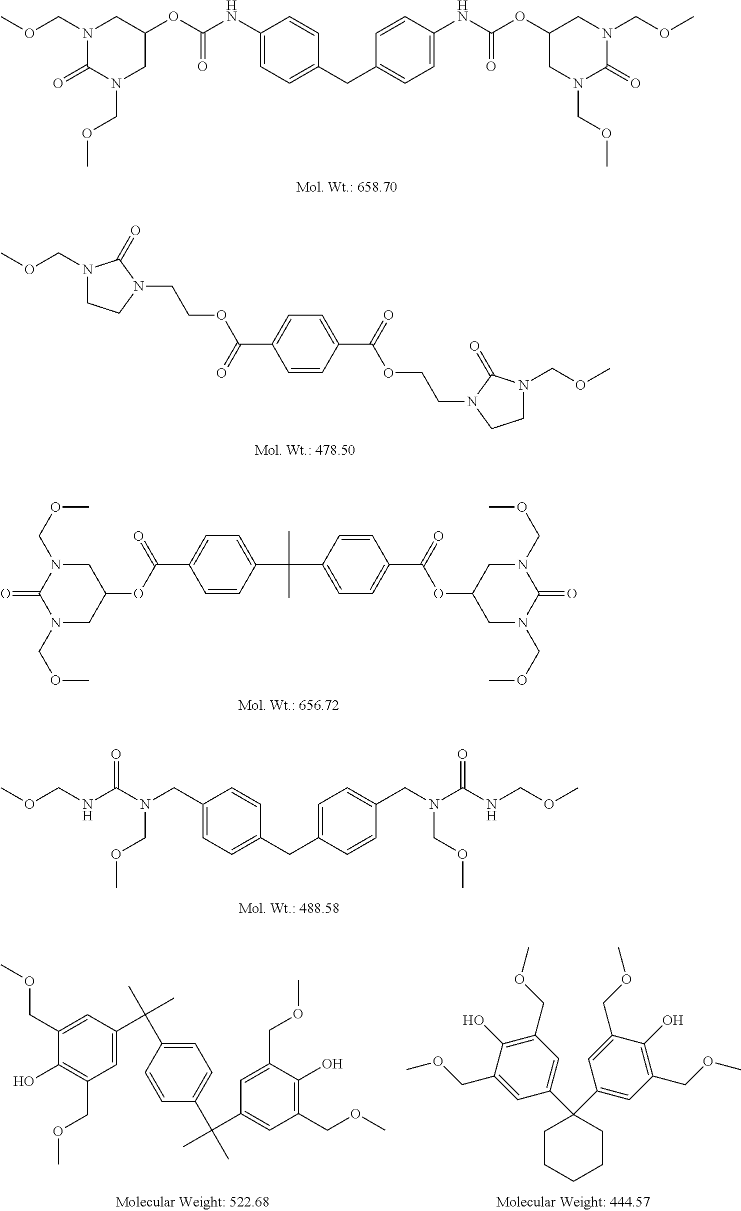

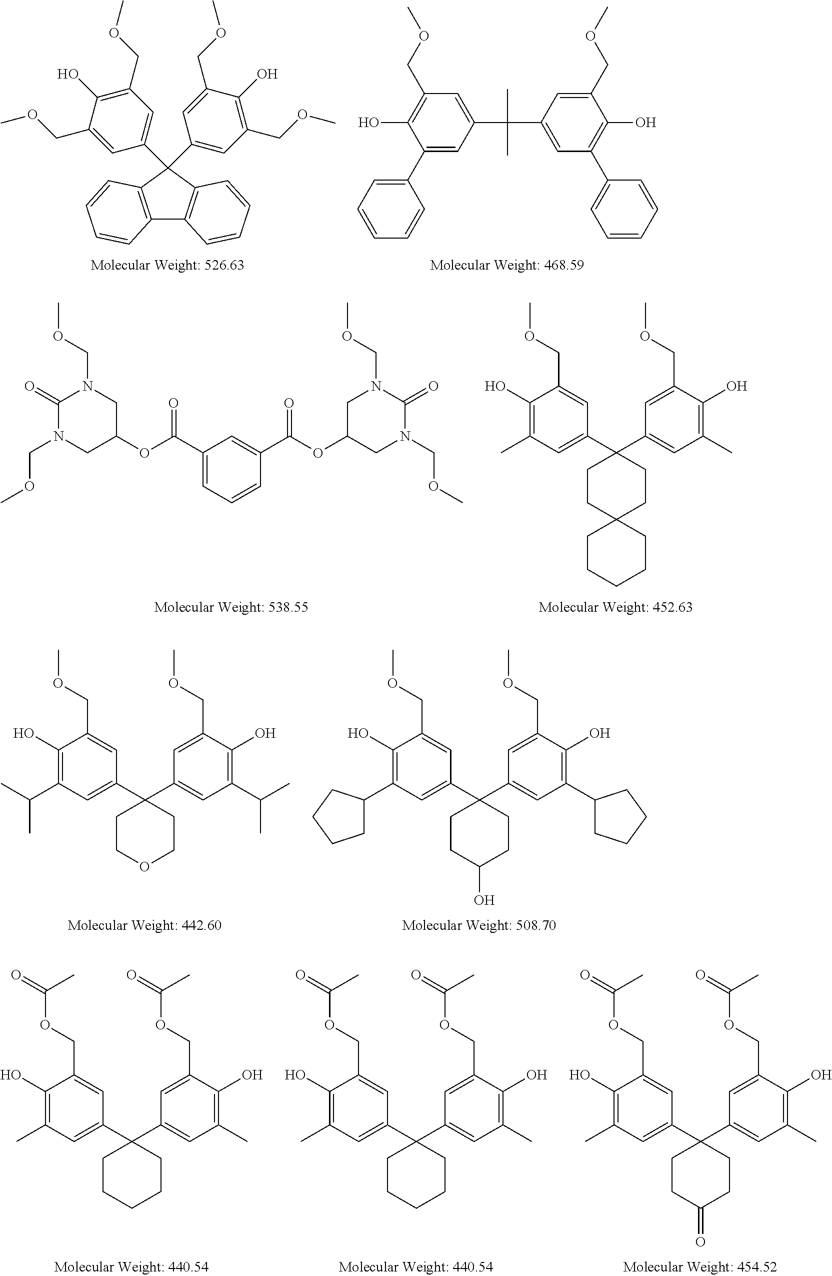

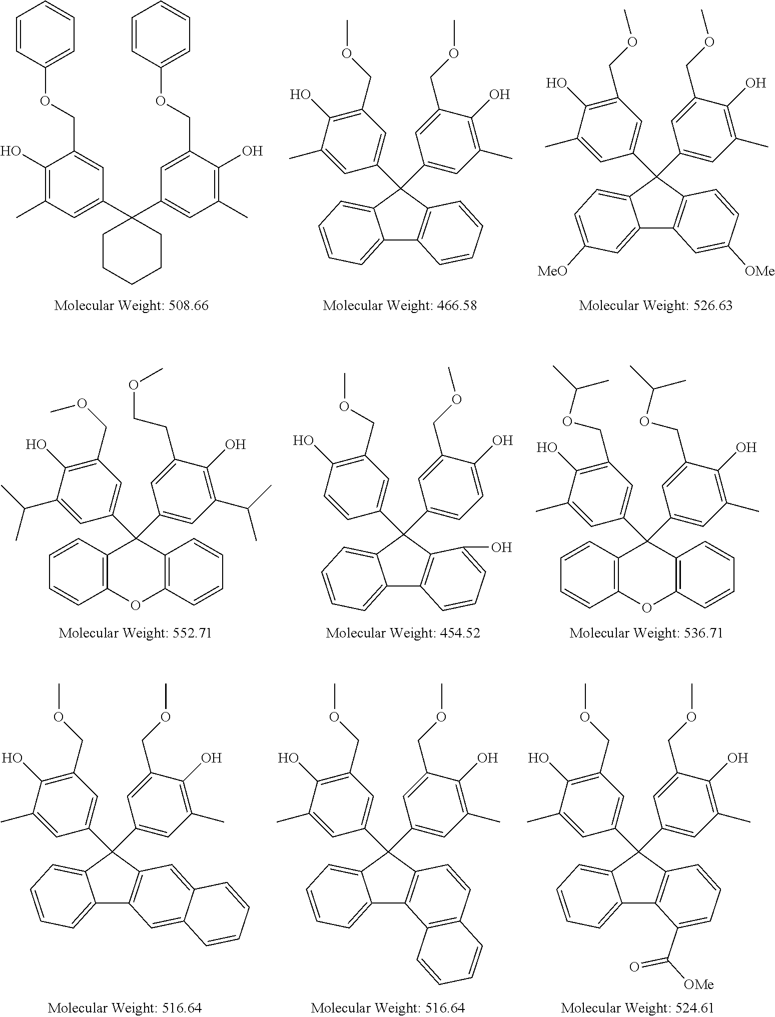

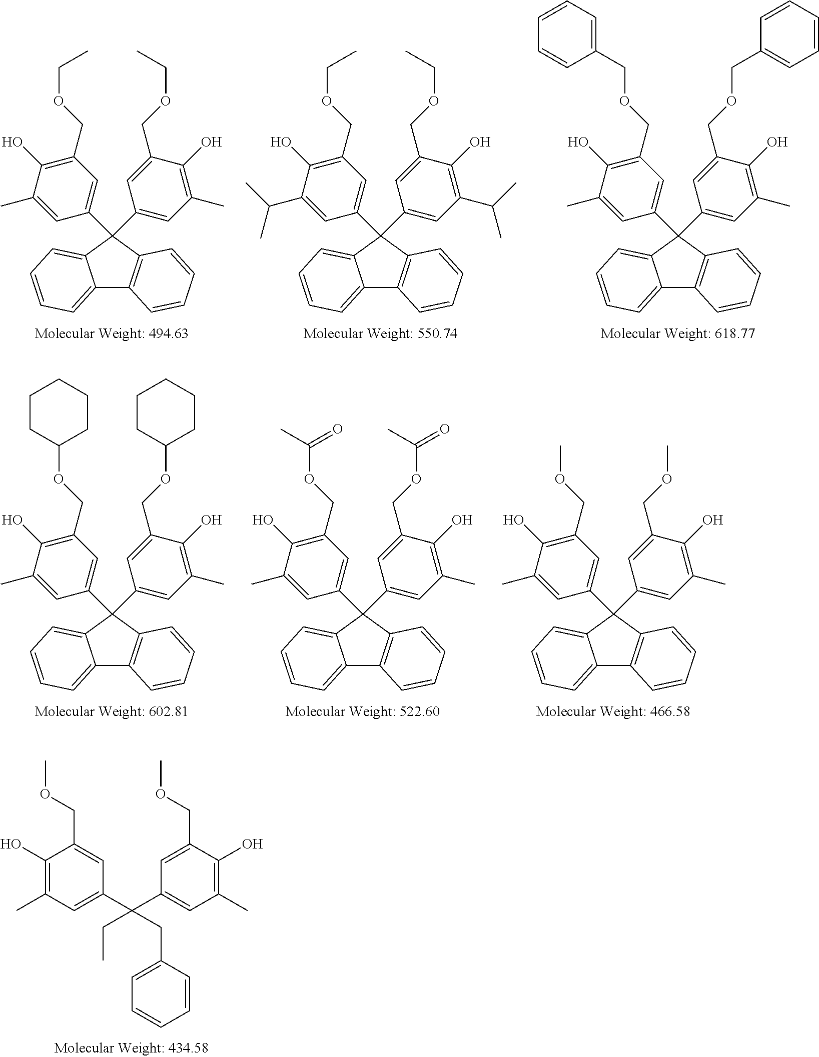

The content of the crosslinking agent (C1) in the present invention is preferably 1 to 50 mass % and more preferably 2 to 40 mass %, based on the solid content of the actinic ray-sensitive or radiation-sensitive resin composition of the present invention.

The crosslinking agents (C1) may be used alone or in combination of two or more thereof.

As described above, the composition of the present invention contains the crosslinking agent (C1) in a ratio such that the total concentration of hydroxymethyl groups or alkoxymethyl groups contained in the crosslinking agent (C1) relative to 1 g of the solid content in the composition of the present invention is 0.30 mmol/g or more. In one embodiment of the present invention, the total concentration of hydroxymethyl groups or alkoxymethyl groups contained in the crosslinking agent (I) relative to 1 g of the solid content in the composition of the present invention is preferably 0.30 to 1.00 mmol/g and more preferably 0.40 to 0.90 mmol/g.

The composition of the present invention contains the crosslinking agent (C1) in a ratio of 60 mol % to 100 mol % with respect to the total amount of the crosslinking agent (I) contained in the composition of the present invention. In one embodiment of the present invention, the ratio of the crosslinking agent (C1) relative to the crosslinking agent (I) is preferably 70 to 100 mol % and more preferably 80 to 100 mol %.

As described above, the crosslinking agent (I) as used herein refers to a crosslinking agent having two or more hydroxymethyl groups or alkoxymethyl groups in total in the molecule and also includes the crosslinking agent (C1) of the present invention.

As the crosslinking agent (I) other than the crosslinking agent (C1) of the present invention, it is possible to appropriately use a compound not corresponding to the crosslinking agent (C1) of the present invention from crosslinking agents selected from a hydroxymethylated or alkoxymethylated phenol compound, an alkoxymethylated melamine-based compound, an alkoxymethylglycoluril-based compound, and an alkoxymethylated urea-based compound. Specific examples of the crosslinking agent (I) include those which do not correspond to the crosslinking agent (C1) of the present invention among the crosslinking agents described in paragraphs [0070] to [0074] of JP2013-44808A.

The composition of the present invention may further contain a crosslinking agent other than the crosslinking agent (I), within the range not impairing the effect of the present invention.

The composition of the present invention contains, for example, a compound having an acid-crosslinkable group (C2) (hereinafter, also referred to as a “compound (C2)” or “crosslinking agent”) as the crosslinking agent other than the crosslinking agent (I). The compound (C2) is preferably a compound containing two or more hydroxymethyl groups or alkoxymethyl groups in the molecule. From the viewpoint of improving LER, it is preferred that the compound (C2) contains a methylol group.

First, the case where the compound (C2) is a low molecular weight compound will be described (hereinafter, referred to as a compound (C2′)). Examples of the compound (C2′) preferably include a hydroxymethylated or alkoxymethylated phenol compound, an alkoxymethylated melamine-based compound, an alkoxymethylglycoluril-based compound, and an alkoxymethylated urea-based compound. The particularly preferred compound (C2′) may be, for example, a phenol derivative or alkoxymethylglycoluril derivative containing 3 to 5 benzene rings in the molecule, having two or more hydroxymethyl groups or alkoxymethyl groups in total, and having a molecular weight of 1200 or less.

The alkoxymethyl group is preferably a methoxymethyl group or an ethoxymethyl group.

Among examples of the compound (C2′), the phenol derivative having a hydroxymethyl group can be obtained by reacting the corresponding phenol compound having no hydroxymethyl group with formaldehyde in the presence of a base catalyst. Further, the phenol derivative having an alkoxymethyl group can be obtained by reacting the corresponding phenol derivative having a hydroxymethyl group with an alcohol in the presence of an acid catalyst.

Other preferred examples of the compound (C2′) further include compounds having an N-hydroxymethyl group or N-alkoxymethyl group, such as an alkoxymethylated melamine-based compound, an alkoxymethylglycoluril-based compound, and an alkoxymethylated urea-based compound.

Examples of such compounds include hexamethoxymethylmelamine, hexaethoxymethylmelamine, tetramethoxymethylglycoluril, 1,3-bismethoxymethyl-4,5-bismethoxyethyleneurea, and bismethoxymethylurea which have been disclosed in EP0133216A, DE3634671, DE3711264, and EP0212482A.

Particularly preferred compounds among specific examples of the compound (C2′) are shown below.

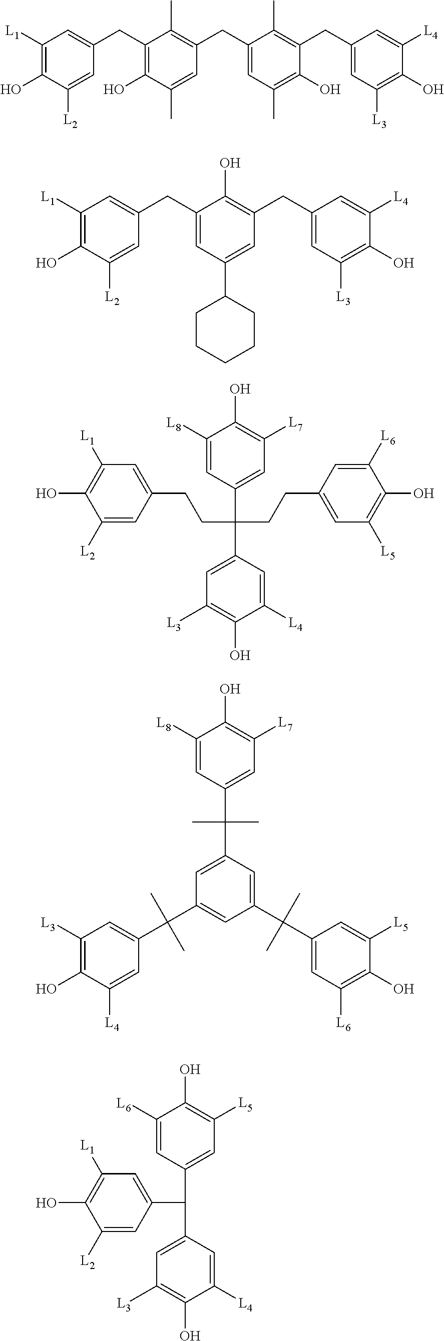

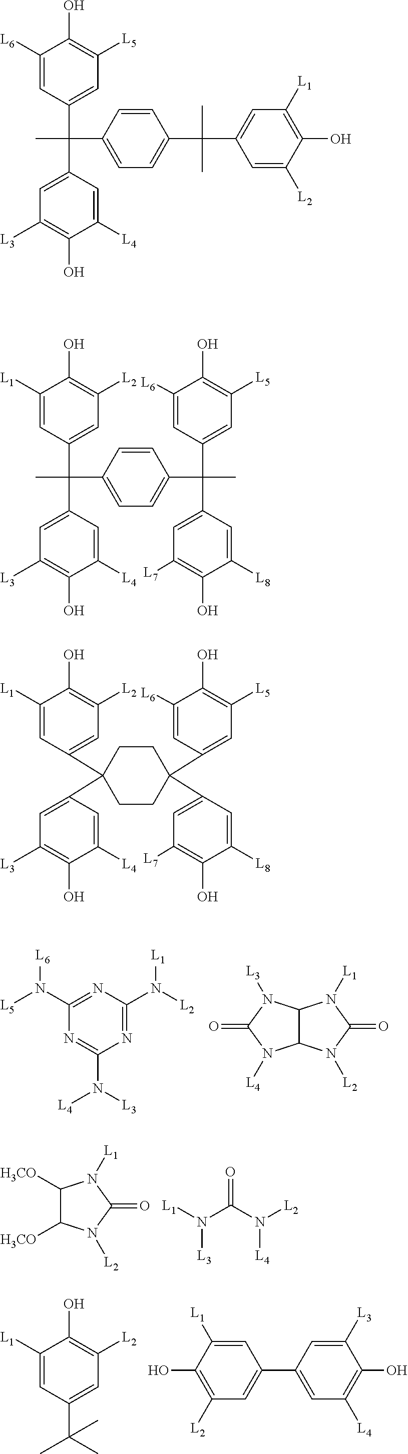

In the formulae, L₁ to L₈ each independently represent a hydrogen atom, a hydroxymethyl group, a methoxymethyl group, an ethoxymethyl group, or an alkyl group having 1 to 6 carbon atoms.

In the present invention, the content of the compound (C2′) is preferably 3 to 65 mass % and more preferably 5 to 50 mass %, based on the total solid content of the resist composition. By setting the content of the compound (C2′) in the range of 3 to 65 mass %, it is possible to prevent lowering of the residual film ratio and resolution and to maintain a good stability of the composition of the present invention during storage.

The compound (C2) having an acid-crosslinkable group may be an aspect of a resin containing a repeating unit having an acid-crosslinkable group described in, for example, paragraphs [0138] to [0157] of JP2014-134686A (hereinafter, also referred to as a compound (C2″)).

The compound (C2″) may be specifically, for example, a resin containing a repeating unit represented by the following General Formula (1). The repeating unit represented by General Formula (1) is a structure containing at least one methylol group which may have a substituent. The “methylol group” as used herein refers to a group represented by the following General Formula (M), and is preferably a hydroxymethyl group or an alkoxymethyl group in one embodiment of the present invention.

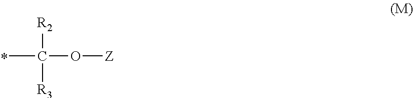

In the formula, R₂, R₃, and Z are as defined in General Formula (1) to be described hereinafter.

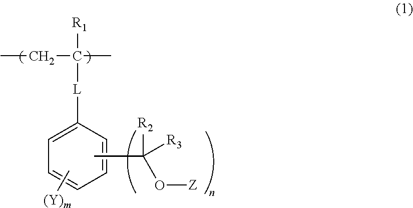

In General Formula (1), R₁ represents a hydrogen atom, a methyl group, or a halogen atom. R₂ and R₃ represent a hydrogen atom, an alkyl group, or a cycloalkyl group. L represents a divalent linking group or a single bond. Y represents a substituent other than a methylol group. Z represents a hydrogen atom or a substituent. m represents an integer of 0 to 4. n represents an integer of 1 to 5. m+n is 5 or less. In the case where m is 2 or more, a plurality of Y's may be the same or different from one another. In the case where n is 2 or more, a plurality of R₂'s, R₃'s, and Z's may be respectively the same or different from one another. Further, two or more of Y, R₂, R₃, and Z may be bonded to one another to form a ring structure. R₁, R₂, R₃, L, and Y each may have a substituent. Further, when m is 2 or more, a plurality of Y's may be bonded to one another through a single bond or a linking group to form a ring structure.

(K) Other Additives

If necessary, the resist composition of the present invention may further contain a dye, a plasticizer, a photosensitizer, a light absorber, an alkali-soluble resin, a dissolution inhibitor, and a compound promoting solubility in a developer (for example, a phenol compound having a molecular weight of 1,000 or less, or an alicyclic or aliphatic compound having a carboxyl group), and the like.

Such a phenol compound having a molecular weight of 1,000 or less can be easily synthesized by those skilled in the art, with reference to the methods described in, for example, JP1992-122938A (JP-H04-122938A), JP1990-28531A (JP-H02-28531A), U.S. Pat. No. 4,916,210A, and EP219294B.

Specific examples of the alicyclic or aliphatic compound having a carboxyl group include, but are not limited to, a carboxylic acid derivative having a steroid structure, such as cholic acid, deoxycholic acid, or lithocholic acid, an adamantane carboxylic acid derivative, adamantine dicarboxylic acid, cyclohexane carboxylic acid, and cyclohexane dicarboxylic acid.

There is no particular limitation on the method of obtaining the organic processing liquid of the present invention as long as it satisfies the above-mentioned conditions. The organic processing liquid of the present invention can be suitably obtained by preparing an accommodating container for accommodating an organic processing liquid for patterning a chemically amplified resist film, including an accommodating portion, in which the inner wall of the accommodating portion being in contact with the organic processing liquid is formed of a resin different from one or more resins selected from the group consisting of a polyethylene resin, a polypropylene resin, and a polyethylene-polypropylene resin, or of a metal subjected to a rust prevention/metal elution prevention treatment, introducing an organic solvent to be used as an organic processing liquid for patterning a chemically amplified resist film into the accommodating portion of the accommodating container, and discharging the organic solvent from the accommodating portion at the time of patterning the chemically amplified resist film.

Accordingly, the present invention also relates to an accommodating container for accommodating an organic processing liquid for patterning a chemically amplified resist film, including an accommodating portion for accommodating the above-mentioned organic processing liquid of the present invention for patterning a chemically amplified resist film and a sealing part for sealing the accommodating portion, in which the inner wall of the accommodating portion being in contact with the organic processing liquid is formed of a resin different from one or more resins selected from the group consisting of a polyethylene resin, a polypropylene resin, and a polyethylene-polypropylene resin, or of a metal subjected to a rust prevention/metal elution prevention treatment.

When the organic processing liquid is accommodated in the accommodating portion of the accommodating container, it is possible to suitably satisfy the requirement that “the content of the alkylolefin having 22 or less carbon atoms is 1 ppm or less, and the metal element concentrations of Na, K, Ca, Fe, Cu, Mg, Mn, Li, Al, Cr, Ni, and Zn are all 5 ppm or less in the organic processing liquid”. The reason is not completely clear, but it is presumed as follows.

That is, in the case where the inner wall of the accommodating portion in the accommodating container being in contact with the organic processing liquid is formed of one or more resins selected from the group consisting of a polyethylene resin, a polypropylene resin, and a polyethylene-polypropylene resin, or of a metal not subjected to a rust prevention/metal elution prevention treatment, due to contact between the organic processing liquid and the above-mentioned one or more resins or the metal not subjected to a rust prevention/metal dissolution prevention treatment, the low molecular weight olefin contained in the resin (it is thought that it remains in the resin synthesis process) is eluted into the organic processing liquid, in a general period (for example, one week to one year) from the time of enclosing the organic processing liquid in the accommodating portion to the time of ejecting the organic processing liquid from the accommodating portion at the time of patterning the chemically amplified resist film, and therefore it is difficult to satisfy the requirement that “the content of the alkylolefin having 22 or less carbon atoms is 1 ppm or less, and the metal element concentrations of Na, K, Ca, Fe, Cu, Mg, Mn, Li, Al, Cr, Ni, and Zn are all 5 ppm or less in the organic processing liquid”. In contrast, according to the accommodating container of the present invention, as described above, it is presumed that the organic processing liquid of the present invention satisfying the above requirement is obtained due to use of a resin different from one or more resins selected from the group consisting of a polyethylene resin, a polypropylene resin, and a polyethylene-polypropylene resin, or of a metal subjected to a rust prevention/metal elution prevention treatment.

In the case where the above-mentioned accommodating container also has a seal portion for sealing the above-mentioned accommodating portion, this seal portion is also preferably formed of a resin different from one or more resins selected from the group consisting of a polyethylene resin, a polypropylene resin, and a polyethylene-polypropylene resin, or of a metal subjected to a rust prevention/metal elution prevention treatment.

Here, the seal portion refers to a member capable of shielding the accommodating portion from the outside air, examples of which preferably include packing, an O ring, and the like.

The resin different from one or more resins selected from the group consisting of a polyethylene resin, a polypropylene resin, and a polyethylene-polypropylene resin is preferably a perfluoro resin.

Examples of the perfluoro resin include a tetrafluoroethylene resin (PTFE), a tetrafluoroethylene-perfluoroalkyl vinyl ether copolymer (PFA), a tetrafluoroethylene-hexafluoropropylene copolymer resin (FEP), a tetrafluoroethylene-ethylene copolymer resin (ETFE), a trifluoroethylene chloride-ethylene copolymer resin (ECTFE), a polyvinylidene fluoride resin (PVDF), a trifluoroethylene chloride resin (PCTFE), and a polyvinyl fluoride resin (PVF).

Examples of the particularly preferred perfluoro resin include a tetrafluoroethylene resin, a tetrafluoroethylene-perfluoroalkyl vinyl ether copolymer, and a tetrafluoroethylene-hexafluoropropylene copolymer resin.

Examples of the metal in the metal subjected to a rust prevention/metal elution prevention treatment include carbon steel, alloy steel, nickel chromium steel, nickel chromium molybdenum steel, chromium steel, chromium molybdenum steel, and manganese steel.

As for the rust prevention/metal elution prevention treatment, it is preferred to apply a coating technique.

The coating technique is roughly divided into three types of metal coating (various plating), inorganic coating (various chemical conversion treatments, glass, concrete, ceramics, and the like), and organic coating (rust preventive oil, paint, rubber, and plastics).

Examples of the preferred coating technique include a rust preventive oil, a rust inhibitor, a corrosion inhibitor, a chelate compound, a strippable plastic, and a surface treatment with a lining agent.

Among them, corrosion inhibitors, such as various chromates, nitrites, silicates, phosphates, oleic acid, dimer acid, carboxylic acids such as naphthenic acid, carboxylic acid metal soaps, sulfonates, amine salts, and esters (glycerol esters of higher fatty acids and phosphoric acid esters); chelate compounds such as ethylenediaminetetraacetic acid, gluconic acid, nitrilotriacetic acid, hydroxyethyl ethylene diamine triacetic acid, and diethylenetriamine pentaacetic acid; and fluorine resin lining are preferable. Particularly preferred are a phosphate treatment and fluorine resin lining.

Although it does not directly prevent rust when compared with a direct coating treatment, it is also preferable to adopt “pretreatment” which is a step prior to a rust prevention treatment, as a treatment method leading to prolongation of the rust prevention period by a coating treatment.

As a specific example of such a pretreatment, a treatment for removing a variety of corrosive factors such as chlorides and sulfates present on the metal surface by cleaning or polishing can be suitably exemplified.

Specific examples of the accommodating container include the following.
FluoroPurePFA composite drum manufactured by Entegris Inc. (wetted inner surface; PFA resin lining)
Steel drum manufactured by JFE Corporation (wetted inner surface; zinc phosphate coating)

### EXAMPLES

Hereinafter, the present invention will be described in more detail with reference to the following Examples, but the present invention is not limited thereto unless they go beyond its gist.

Unless otherwise specified, “part(s)” and “%” are based on mass.

Quantitative analysis of a metal salt containing an acid, an alkali, and a halogen was carried out on an organic processing liquid (processing liquid described in the 6^{th} table and 15^{th} table) used in the development or rinsing of the subsequent stage. It was confirmed that the organic processing liquid is substantially free of a metal salt containing an acid, an alkali, and a halogen.

1. EUV and EB Exposure

<Resin (A), and the Like>

### (Synthesis Example 1) Synthesis of Resin (A-1)

600 g of cyclohexanone was placed in a 2 L flask which was then purged with nitrogen at a flow rate of 100 mL/min for one hour. Thereafter, 4.60 g (0.02 mol) of a polymerization initiator V-601 (manufactured by Wako Pure Chemical Industries, Ltd.) was added thereto, and the temperature was raised until the internal temperature reached 80° C. Then, the following monomers and 4.60 g (0.02 mol) of a polymerization initiator V-601 (manufactured by Wako Pure Chemical Industries, Ltd.) were dissolved in 200 g of cyclohexanone to prepare a monomer solution. The monomer solution was added dropwise over 6 hours to the above flask heated to 80° C. After the dropwise addition was completed, the mixture was allowed to react for another 2 hours at 80° C.

4-Acetoxystyrene 48.66 g (0.3 mol)

1-Ethyl cyclopentyl methacrylate 109.4 g (0.6 mol)

Monomer 122.2 g (0.1 mol)

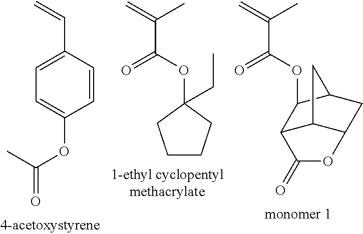

The reaction solution was cooled to room temperature and was added dropwise to 3 L of hexane to precipitate a polymer. The filtered solid was dissolved in 500 mL of acetone which was then added dropwise again to 3 L of hexane, followed by filtration. The filtered solid was dried under reduced pressure to give 160 g of a 4-acetoxystyrene/1-ethylcyclopentyl methacrylate/monomer 1 copolymer (A-1a).

10 g of the above-obtained polymer, 40 mL of methanol, 200 mL of 1-methoxy-2-propanol, and 1.5 mL of concentrated hydrochloric acid were added to a reaction vessel which was then heated to 80° C., followed by stirring for 5 hours. The reaction solution was allowed to cool to room temperature and was added dropwise to 3 L of distilled water. The filtered solid was dissolved in 200 mL of acetone which was then added dropwise again to 3 L of distilled water, followed by filtration. The filtered solid was dried under reduced pressure to give a resin (A-1) (8.5 g). The weight-average molecular weight by GPC was 10,800, and the molecular weight dispersity (Mw/Mn) was 1.55.

Resins (A-2) to (A-4) having the structure shown in Table 1 were synthesized in the same manner as in Synthesis Example 1, except that the monomer used was changed. The composition ratio (molar ratio) of the resin was calculated by ¹H-Nuclear Magnetic Resonance (NMR) measurement. The weight-average molecular weight (Mw: polystyrene conversion) and dispersity (Mw/Mn) of the resin were calculated by GPC (solvent: tetrahydrofuran (THF)) measurement.

TABLE 3

| | | Composition ratio | | |
|---|---|---|---|---|
| | | (molar ratio) | | |
| 1^{st} table | Structure | from the left | Mw | Mw/Mn |
| Resin A-1 | 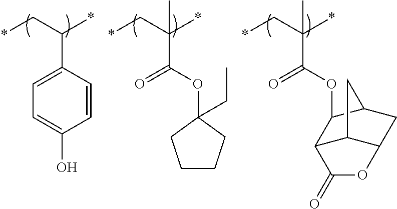 | 30/60/10 | 10,800 | 1.55 |
| Resin A-2 | 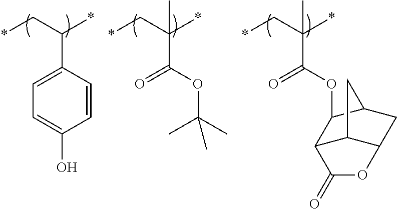 | 30/60/10 | 10,100 | 1.55 |
| Resin A-3 | 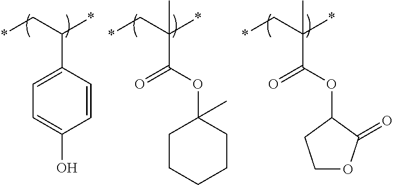 | 30/50/20 | 9,800 | 1.58 |
| Resin A-4 | 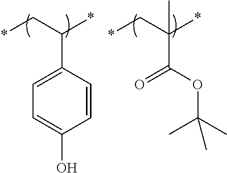 | 30/70 | 11,000 | 1.52 |

Resins (A-5) to (A-7) having the structure shown in Table 2 were synthesized in the same manner as in Synthesis Example 1, except that the monomer used was changed. The composition ratio (molar ratio) of the resin was calculated by ¹H-NMR measurement. The weight-average molecular weight (Mw: polystyrene conversion) and dispersity (Mw/Mn) of the resin were calculated by GPC (solvent: THF) measurement.

TABLE 4

| | | Composition ratio | | |
|---|---|---|---|---|
| | | (molar ratio) | | |
| 2^{nd} table | Structure | from the left | Mw | Mw/Mn |
| Resin A-5 | 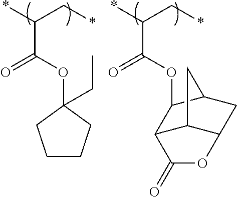 | 50/50 | 10,800 | 1.55 |
| Resin A-6 | 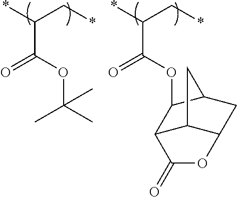 | 60/40 | 10,200 | 1.45 |
| Resin A-7 | 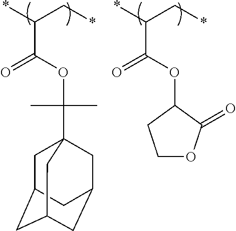 | 50/50 | 9,500 | 1.5 |

Resins (A-8) to (A-11) having the structure shown in Table 3 were synthesized in the same manner as in Synthesis Example 1, except that the monomer used was changed. The composition ratio (molar ratio) of the resin was calculated by ¹H-NMR measurement. The weight-average molecular weight (Mw: polystyrene conversion) and dispersity (Mw/Mn) of the resin were calculated by GPC (solvent: THF) measurement.

TABLE 5

| | | Composition ratio | | |
|---|---|---|---|---|
| | | (molar ratio) | | |
| 3^{rd} table | Structure | from the left | Mw | Mw/Mn |
| Resin A-8 | 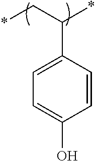 | 100 | 3,200 | 1.2 |
| Resin A-9 | 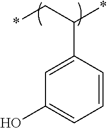 | 100 | 4,500 | 1.2 |
| Resin A-10 | 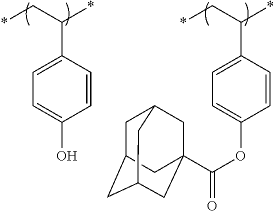 | 90/10 | 5,500 | 1.25 |
| Resin A-11 | 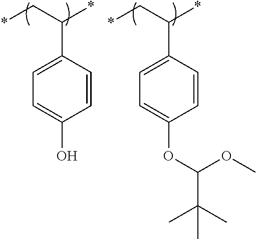 | 40/60 | 4,100 | 1.1 |

Further, as Resin (A-12) to Resin (A-14), resins shown in the 4^{th} table were prepared.

TABLE 6

| | | Composition ratio | | | |
|---|---|---|---|---|---|
| | | (molar ratio) | | | |
| 4^{th} table | Structure | from the left | Mw | Mw/Mn | Trade name |
| Resin A-12 | 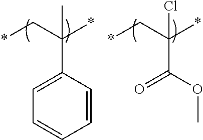 | 50/50 | 57,000 | 1.8 | ZEP520A (manufactured by Zeon Corporation, Positive type) |
| Resin A-13 | 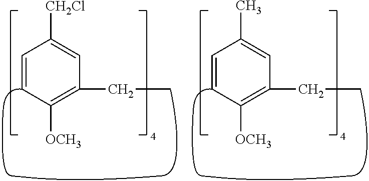 | 60/40 | — | — | TEBN-1 (manufactured by Tokuyama Corporation, Negative type) |
| Resin A-14 | HfO₂ + MAA (methacrylic acid) | — | — | — | Hf nanoparticles |
| | | | | | (according to |
| | | | | | Tang et al., |
| | | | | | “Solid-Solution |
| | | | | | Nanoparticles: |
| | | | | | Use of |
| | | | | | Nonhydrolytic |
| | | | | | Sol-Gel |
| | | | | | Prepare HfO₂ |
| | | | | | and HfxZr1-xO₂ |
| | | | | | Nanocrystals”, |
| | | | | | Chem. |
| | | | | | Master., 16, |
| | | | | | 1336 (2004), a |
| | | | | | synthetic metal |
| | | | | | resist) |

<Acid Generator (B)>

As the acid generator, the following compounds were used.

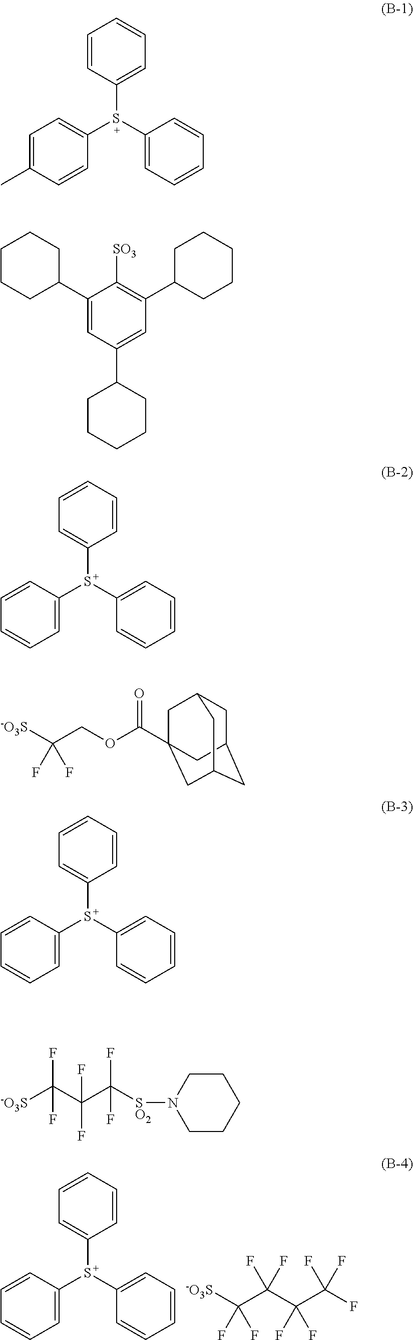

<Basic Compound (E)>

As the basic compound, the following compounds were used.

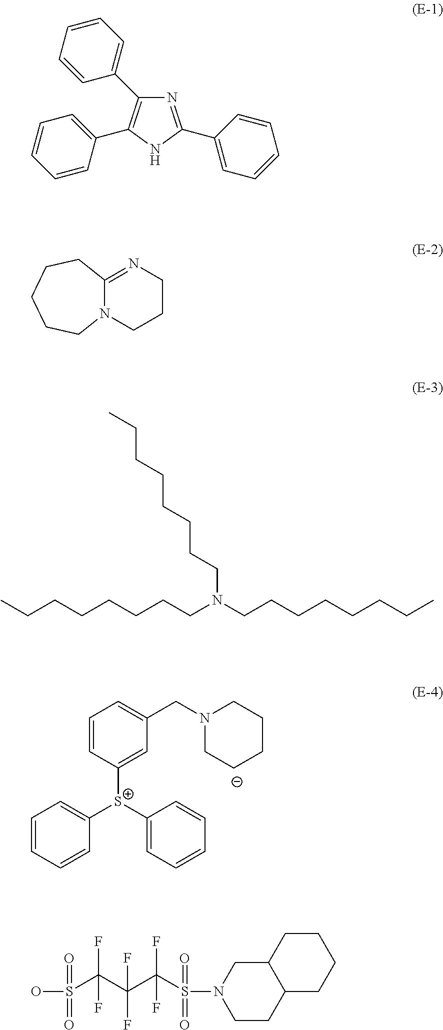

<Solvent (C)>

As the resist solvent, the following compounds were used.

C-1: propylene glycol monomethyl ether acetate

C-2: propylene glycol

C-3: ethyl lactate

C-4: cyclohexanone

C-5: anisole

<Other Additives>

Other additives used were as follows.

Additive 1: 2-hydroxy-3-naphthoic acid

Additive 2: surfactant PF6320 (manufactured by OMNOVA Solutions Inc.)

Crosslinking agent MM-1: Formula (MM-1) shown below

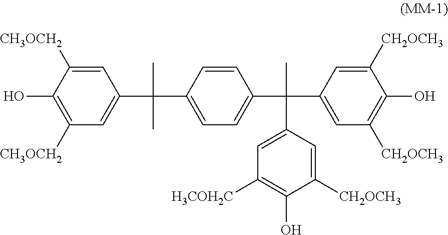

<Resist Composition>

The individual components shown in the following 5^{th} table were dissolved in the solvent shown in the same table. This was filtered using a polyethylene filter having a pore size of 0.03 μm to obtain a resist composition.

TABLE 7

| | 5^{th} table Part 1 | | | | | |
|---|---|---|---|---|---|---|
| | | Acid | Basic | | | |
| 5^{th} table | Resin | generator | compound | Solvent | | Other |
| Part 1 | (A) | (B) | (E) | (C) | | additives |
| Resist | A-1 | B-1 | E-3 | C-1 | C-3 | Additive 1 |
| composition 1 | 0.77 g | 0.2 g | 0.03 g | 67.5 g | 7.5 g | 0.01 g |
| Resist | A-2 | B-2 | E-1 | C-1 | C-2 | — |
| composition 2 | 0.79 g | 0.18 g | 0.03 g | 45 g | 30 g | |
| Resist | A-3 | B-3 | E-2 | C-1 | C-4 | Additive 2 |
| composition 3 | 0.8 g | 0.19 g | 0.01 g | 67.5 g | 7.5 g | 0.01 g |
| Resist | A-4 | B-2 | E-1 | C-1 | C-3 | — |
| composition 4 | 0.79 g | 0.18 g | 0.03 g | 60 g | 15 g | |
| | 5^{th} table Part 2 | | | | | |
| | | Acid | Basic | | | |
| | Resin | generator | compound | Solvent | | Other |
| | (A) | (B) | (E) | (C) | | additives |
| Resist | A-5 | B-3 | E-3 | C-1 | C-3 | — |
| composition 5 | 0.78 g | 0.19 g | 0.03 g | 67.5 g | 7.5 g | |
| Resist | A-6 | B-2 | E-1 | C-1 | C-3 | — |
| composition 6 | 0.79 g | 0.18 g | 0.03 g | 67.5 g | 7.5 g | |
| Resist | A-7 | B-2 | E-2 | C-1 | C-4 | Additive 2 |
| composition 7 | 0.79 g | 0.2 g | 0.01 g | 45 g | 30 g | 0.01 g |

| | 5^{th} table Part 3 | | | | | |
|---|---|---|---|---|---|---|
| | | Acid | Basic | | | |
| | Resin | generator | compound | Solvent | Other | |
| | (A) | (B) | (E) | (C) | additives | |
| Resist | A-8 | B-2 | E-1 | C-1 | — | MM-1 |
| composition 8 | 0.553 g | 0.18 g | 0.03 g | 75 g | | 0.237 g |
| Resist | A-9 | B-2 | E-1 | C-1 | Additive 2 | MM-1 |
| composition 9 | 0.553 g | 0.18 g | 0.03 g | 75 g | 0.01 g | 0.237 g |
| Resist | A-10 | B-2 | E-1 | C-1 | — | MM-1 |
| composition 10 | 0.553 g | 0.18 g | 0.03 g | 75 g | | 0.237 g |
| Resist | A-11 | B-1 | E-1 | C-1 | — | — |
| composition 11 | 0.553 g | 0.18 g | 0.03 g | 75 g | | |

| | 5^{th} table Part 4 | | | | | |
|---|---|---|---|---|---|---|
| | | Acid | Basic | | | |
| | Resin | generator | compound | Solvent | | Other |
| | (A) | (B) | (E) | (C) | | additives |
| Resist | A-2 | B-2 | E-4 | C-1 | C-3 | — |
| composition 10-2 | 0.8 g | 0.14 g | 0.06 g | 75 g | 15 g | — |

| | 5^{th} table Part 5 | | | | |
|---|---|---|---|---|---|
| | | Acid | Basic | | |
| | Resin | generator | compound | Solvent | Other |
| | (A) | (B) | (E) | (C) | additives |
| Resist | A-12 | — | — | C-5 | — |
| composition 12 | 1 g | | | 75 g | |
| Resist | A-13 | — | — | C-1 | — |
| composition 13 | 1 g | | | 75 g | |
| Resist | A-14 | B-4 | — | C-1 | — |
| composition 14 | 0.95 g | 0.05 g | — | 75 g | |

<EUV Exposure Evaluation>

Using the resist composition described in the 5^{th} table, a resist pattern was formed by the following procedure.

### [Application and Post Application Bake (PB) of Resist Composition]

The above-obtained resist composition was applied onto a 4-inch silicon wafer subjected to a hexamethyldisilazane (HMDS) treatment, and baked for 60 seconds under the conditions of 120° C. to form a resist film having a film thickness of 40 nm.

[Exposure]

EUV exposure was carried out on the wafer prepared above with Numerical Aperture (NA) of 0.3, dipole illumination. Specifically, EUV exposure was carried out by changing the exposure amount through a mask including a pattern for forming a line and space pattern of 15 to 45 nm.

[Post Exposure Bake (PEB)]

Once removed from the EUV exposure apparatus following the irradiation, the wafer was immediately baked for 60 seconds under the conditions of 110° C.

[Development]

Thereafter, using a shower-type developing apparatus (ADE3000S, manufactured by ACTES), development was carried out by spraying and ejecting the developer (23° C.) described in the 6^{th} table (1) and the 6^{th} table (2) at a flow rate of 200 mL/min for a predetermined time while rotating the wafer at 50 revolutions (rpm).

In the following table, the content of the additives represents the percentage with respect to the total amount (100 mass %) of the developer. The content of the component is the remaining amount excluding the content of the additives.

The “KAYAESTER O” (trade name, manufactured by Kayaku Akzo Corporation) among the additives in the table is t-butylperoxy-2-ethylhexanoate.

It should be noted that “A/B” in the column “Component” of the following table is intended to refer to a mixing ratio on a mass basis.

TABLE 8
6^{th} table (1)

| Developer | | | | |
|---|---|---|---|---|
| (rinsing | | | Content of | |
| liquid) | Component | Additives | additives | Content of oxidant |
| S-1 | butyl acetate | — | | 0.2 mmol/L |
| S-2 | isoamyl acetate | — | | 0.2 mmol/L |
| | (3-methylbutyl acetate) | | | |
| S-3 | butyl butanoate | — | | 0.2 mmol/L |
| S-4 | decane | — | | 0.2 mmol/L |
| S-5 | undecane | — | | 0.2 mmol/L |
| S-6 | isopropylalcohol (IPA) | — | | 0.2 mmol/L |
| S-7 | butyl acetate | 4-methoxyphenol (MEHQ) | 0.05% | 0.05 mmol/L |
| S-8 | butyl acetate | trioctylamine | 1% | 0.2 mmol/L |
| S-9 | isoamyl acetate | monooctylamine | 0.5% | 0.05 mmol/L |
| | (3-methylbutyl acetate) | 4-methoxyphenol (MEHQ) | 0.05% | |
| S-10 | butyl acetate/decane = | — | | 0.2 mmol/L |
| | 70/30 | | | |
| S-11 | butyl acetate/decane = | 4-methoxyphenol (MEHQ) | 0.05% | 0.05 mmol/L |
| | 80/20 | | | |
| S-12 | isoamyl acetate/undecane = | — | | 0.05 mmol/L |
| | 70/30 | | | |
| S-13 | butyl acetate/undecane | — | | 0.05 mmol/L |
| | 60/40 | | | |
| S-14 | xylene | — | | 0.1 mmol/L |
| S-15 | 2-heptanone/methyl isobutyl ketone = | — | | 0.1 mmol/L |
| | 40/60 | | | |
| S-16 | 4-methyl-2-hexanol | — | | 0.1 mmol/L |
| S-17 | isoamyl acetate | 1-aminodecane | 2% | 0.05 mmol/L |
| | (3-methylbutyl acetate) | | | |
| S-18 | isoamyl acetate | di-n-octylamine | 2% | 0.05 mmol/L |
| | (3-methylbutyl acetate) | | | |
| S-19 | isoamyl acetate | tri-n-octylamine | 2% | 0.05 mmol/L |
| | (3-methylbutyl acetate) | | | |
| S-20 | isoamyl acetate | tetramethylethylenediamine | 2% | 0.05 mmol/L |
| | (3-methylbutyl acetate) | | | |
| S-21 | isoamyl acetate | N,N-dibutylaniline | 2% | 0.05 mmol/L |
| | (3-methylbutyl acetate) | | | |
| S-22 | dodecane | — | | 0.05 mmol/L |
| SA-1 | butyl acetate | KAYAESTER O | 0.38% | 15 mmol/L |
| SA-2 | butyl acetate | trioctylamine | 1% | 15 mmol/L |
| | | KAYAESTER O | 0.38% | |
| SA-3 | butyl acetate/anisole = 70/30 | KAYAESTER O | 0.5% | 20 mmol/L |
| SA-4 | anisole | KAYAESTER O | 0.5% | 20 mmol/L |

TABLE 9
6^{th} table (2)

| Developer | | | | |
|---|---|---|---|---|
| (rinsing | | | Content of | |
| liquid) | Component | Additives | additives | Content of oxidant |
| SB-1 | hexyl acetate | — | — | 0.05 mmol/L |
| SB-2 | butyl propionate | — | — | 0.05 mmol/L |
| SB-3 | pentyl propionate | — | — | 0.05 mmol/L |
| SB-4 | isobutyl acetate | — | — | 0.05 mmol/L |
| SB-5 | isohexyl acetate | — | — | 0.05 mmol/L |
| SB-6 | 2-ethylhexyl acetate | — | — | 0.05 mmol/L |
| SB-7 | isoamyl acetate/isobutyl isobutanoate = 90/10 | — | — | 0.05 mmol/L |
| SB-8 | isoamyl acetate/amyl acetate = 30/70 | — | — | 0.05 mmol/L |
| SB-9 | isoamyl acetate/butyl butanoate = 80/20 | — | — | 0.05 mmol/L |
| SB-10 | isoamyl acetate/hexyl acetate = 70/30 | — | — | 0.05 mmol/L |
| SB-11 | isoamyl acetate/PGMEA = 90/10 | — | — | 0.05 mmol/L |
| SB-12 | isoamyl acetate/propyl propionate = 40/60 | — | — | 0.05 mmol/L |
| SB-13 | isoamyl acetate/butyl propionate = 70/30 | — | — | 0.05 mmol/L |
| SB-14 | isoamyl acetate/pentyl propionate = 80/20 | — | — | 0.05 mmol/L |
| SB-15 | isoamyl acetate/butyl acetate = 20/80 | — | — | 0.05 mmol/L |
| SB-16 | isoamyl acetate/butyl acetate = 90/10 | — | — | 0.05 mmol/L |
| SB-17 | isoamyl acetate/butyl acetate/amyl | — | — | 0.05 mmol/L |
| | acetate = 80/10/10 | | | |
| SB-18 | isoamyl acetate/isobutyl acetate = 60/40 | — | — | 0.05 mmol/L |
| SB-19 | isoamyl acetate/isohexyl acetate = 70/30 | — | — | 0.05 mmol/L |
| SB-20 | isoamyl acetate/2-ethylhexyl acetate = 70/30 | — | — | 0.05 mmol/L |
| SB-21 | isoamyl acetate/propyl propionate = 40/60 | — | — | 0.05 mmol/L |
| SB-22 | isoamyl acetate/2-heptanone = 50/50 | — | — | 0.05 mmol/L |
| SB-23 | butyl acetate/2-octanone = 30/70 | — | — | 0.05 mmol/L |
| SB-24 | isoamyl acetate/diisobutyl ketone = 80/20 | — | — | 0.05 mmol/L |
| SB-25 | isoamyl acetate/anisole = 95/5 | — | — | 0.05 mmol/L |
| SB-26 | butyl acetate/isopropyl ether = 95/5 | — | — | 0.05 mmol/L |
| SB-27 | isoamyl acetate/PGME = 95/5 | — | — | 0.05 mmol/L |
| SB-28 | isoamyl acetate/PGME = 80/20 | — | — | 0.05 mmol/L |
| SB-29 | butyl acetate/4-methyl-2-pentanol = 95/5 | — | — | 0.05 mmol/L |
| SB-30 | isoamyl acetate/undecane = 10/90 | — | — | 0.05 mmol/L |
| SB-31 | isoamyl acetate/undecane = 50/50 | — | — | 0.05 mmol/L |
| SB-32 | isoamyl acetate/undecane = 80/20 | — | — | 0.05 mmol/L |
| SB-33 | isoamyl acetate/undecane/butyl | — | — | 0.05 mmol/L |
| | acetate = 10/70/20 | | | |
| SB-34 | isoamyl | | — | 0.05 mmol/L |
| | acetate/undecane/PGMEA = 10/80/10 | | | |
| SB-35 | undecane/2-heptanone = 70/30 | — | — | 0.05 mmol/L |
| SB-36 | undecane/anisole = 50/50 | — | — | 0.05 mmol/L |
| SB-37 | undecane/4-methyl-2-pentanol = 90/10 | — | — | 0.05 mmol/L |
| SB-38 | undecane/4-methyl-2-pentanol = 50/50 | — | — | 0.05 mmol/L |
| SB-39 | undecane/4-methyl-2-pentanol = 20/80 | — | — | 0.05 mmol/L |
| SB-40 | undecane/PGME = 80/20 | — | — | 0.05 mmol/L |
| SB-41 | undecane/butyl acetate = 80/20 | — | — | 0.05 mmol/L |
| SB-42 | decane/butyl acetate = 80/20 | — | — | 0.05 mmol/L |
| SB-43 | undecane/PGMEA/PGME = 80/14/6 | — | — | 0.05 mmol/L |

[Rinsing]

Thereafter, a rinsing treatment was carried out by spraying and ejecting a rinsing liquid (23° C.) at a flow rate of 200 mL/min for a predetermined time while rotating the wafer at 50 revolutions (rpm).

Finally, the wafer was dried by high-speed spinning at 2,500 revolutions (rpm) for 60 seconds.

Any one of the above-mentioned developers was used as the rinsing liquid.

[Evaluation Test]

The resist pattern was evaluated for the following items. The details of the results are shown in the 7^{th} table.

(Sensitivity)

The obtained resist pattern was observed by using a scanning electron microscope (S-9380II, manufactured by Hitachi, Ltd.). The irradiation energy when separately resolving line and space at a ratio of 1:1 for a line width of 30 nm was taken as the sensitivity (mJ/cm²).

The irradiation energy when separately resolving line and space at a ratio of 1:1 for a line width of 32 nm in Comparative Example 3 and a line width of 45 nm in Comparative Example 4 was taken as the sensitivity (mJ/cm²).

(Limiting Resolution)

The resolution condition of 45 nm to 15 nm was observed using a scanning electron microscope (S-9380II, manufactured by Hitachi, Ltd.), and the resolution value when resolving the 1:1 line and space without any problem was taken as the limit resolution value.

(Defect Residue)

The resolution condition and pattern shape of the line width of 30 nm obtained by the above method were observed with a scanning electron microscope (S-9380II, manufactured by Hitachi, Ltd.) to determine the number of residue defects. 1000 images were photographed while shifting the observation point by 1 micron, and the number of residual defects confirmed on the pattern was counted. The smaller the number of residue defects, the better the performance.

(Relationship between evaluation results and number of residue defects in the table)

A: 0

B: 1 to 4

C: 5 to 9

D: 10 to 19

E: 20 or more

TABLE 10

| | | 7^{th} table 1 | | | | | | |
|---|---|---|---|---|---|---|---|---|
| | | | | | | 30 nm | Limiting | |
| | | PB (60 | PEB (60 | Develop- | | sensitivity | resolution | Defect |
| | | seconds) | seconds) | ment | Rinsing | [mJ/cm²] | (nm) | residue |
| Example 1 | Resist composition 1 | 120° C. | 120° C. | S-1 | — | 150 | 28 | A |
| Example 2 | Resist composition 2 | 120° C. | 110° C. | S-2 | S-5 | 120 | 16 | A |
| Example 3 | Resist composition 3 | 120° C. | 110° C. | S-7 | S-4 | 150 | 22 | A |
| Example 4 | Resist composition 4 | 120° C. | 110° C. | S-3 | S-5 | 100 | 18 | A |
| Example 5 | Resist composition 2 | 120° C. | 110° C. | S-17 | S-5 | 110 | 16 | A |
| Example 6 | Resist composition 2 | 120° C. | 110° C. | S-18 | S-5 | 90 | 16 | A |
| Example 7 | Resist composition 2 | 120° C. | 110° C. | S-19 | S-5 | 100 | 16 | A |
| Example 8 | Resist composition 2 | 120° C. | 110° C. | S-20 | S-5 | 110 | 16 | A |
| Example 9 | Resist composition 2 | 120° C. | 110° C. | S-21 | S-5 | 80 | 16 | A |
| Example 10 | Resist composition 11 | 100° C. | 90° C. | S-12 | S-5 | 80 | 16 | A |
| Example 11 | Resist composition 2 | 120° C. | 110° C. | S-2 | S-22 | 120 | 17 | A |
| Example 12 | Resist composition 2 | 120° C. | 110° C. | S-2 | S-16 | 120 | 20 | A |
| Example 13 | Resist composition 2 | 120° C. | 110° C. | S-2 | — | 120 | 24 | A |
| Example 14 | Resist composition 10 | 120° C. | 110° C. | S-11 | S-15 | 110 | 24 | A |
| Example 15 | Resist composition 1 | 100° C. | 110° C. | S-13 | S-5 | 100 | 17 | A |
| Example 16 | Resist composition 2 | 120° C. | 110° C. | S-1 | S-5 | 160 | 20 | A |
| Example 17 | Resist composition 2 | 120° C. | 110° C. | S-1 | S-5 | 160 | 20 | A |
| Comparative | Resist composition 1 | 120° C. | 110° C. | SA-1 | — | 150 | 30 | E |
| Example 1 | | | | | | | | |
| Comparative | Resist composition 3 | 120° C. | 140° C. | SA-3 | — | 120 | 30 | E |
| Example 2 | | | | | | | | |
| Comparative | Resist composition 10 | 120° C. | 140° C. | SA-4 | — | 75 | 32 | Not |
| Example 3 | | | | | | | | determinable |
| | | 7^{th} table 2 | | | | | | |
| | | | | | | 30 nm | Limiting | |
| | | PB (60 | PEB (60 | Develop- | | sensitivity | resolution | Defect |
| | | seconds) | seconds) | ment | Rinsing | [mJ/cm²] | (nm) | residue |
| Example 18 | Resist composition 13 | 110° C. | — | S-2 | S-5 | 2500 | 15 | A |
| Example 19 | Resist composition 14 | — | — | S-2 | — | 40 | 25 | A |
| Comparative | Resist composition 14 | — | — | SA-2 | — | <20 | 45 | Not |
| Example 4 | | | | | | | | determinable |

TABLE 11
7^{th} table 3

| | | | | | | 30 nm | Limiting | |
|---|---|---|---|---|---|---|---|---|
| | | PB (60 | PEB (60 | Develop- | | sensitivity | resolution | Defect |
| | | seconds) | seconds) | ment | Rinsing | [mJ/cm²] | (nm) | residue |
| Example c1 | Resist composition 4 | 120° C. | 110° C. | S-1 | SB-30 | 140 | 28 | A |
| Example c2 | Resist composition 2 | 120° C. | 110° C. | S-2 | SB-31 | 80 | 16 | A |
| Example c3 | Resist composition 5 | 120° C. | 110° C. | S-3 | SB-32 | 70 | 15 | A |
| Example c4 | Resist composition 2 | 120° C. | 110° C. | S-1 | SB-33 | 126 | 26 | A |
| Example c5 | Resist composition 4 | 120° C. | 110° C. | S-2 | SB-34 | 123 | 17 | A |
| Example c6 | Resist composition 5 | 120° C. | 120° C. | S-3 | SB-35 | 83 | 16 | A |
| Example c7 | Resist composition 2 | 120° C. | 110° C. | S-1 | SB-36 | 115 | 28 | A |
| Example c8 | Resist composition 4 | 120° C. | 130° C. | S-2 | SB-37 | 99 | 16 | A |
| Example c9 | Resist composition 5 | 120° C. | 110° C. | S-3 | SB-38 | 81 | 18 | A |
| Example c10 | Resist composition 2 | 100° C. | 90° C. | S-1 | SB-39 | 126 | 26 | A |
| Example c11 | Resist composition 4 | 120° C. | 110° C. | S-2 | SB-40 | 92 | 18 | A |
| Example c12 | Resist composition 2 | 120° C. | 110° C. | S-2 | SB-30 | 132 | 17 | A |
| Example c13 | Resist composition 2 | 120° C. | 110° C. | S-2 | SB-32 | 107 | 16 | A |
| Example c14 | Resist composition 4 | 130° C. | 110° C. | SB-1 | SB-40 | 116 | 18 | A |
| Example c15 | Resist composition 5 | 90° C. | 110° C. | SB-2 | SB-30 | 111 | 17 | A |
| Example c16 | Resist composition 2 | 120° C. | 110° C. | SB-3 | S-4 | 117 | 16 | A |
| Example c17 | Resist composition 2 | 120° C. | 110° C. | SB-4 | S-5 | 94 | 16 | A |
| Example c18 | Resist composition 4 | 120° C. | 110° C. | SB-5 | S-4 | 85 | 18 | A |
| Example c19 | Resist composition 2 | 120° C. | 110° C. | SB-6 | S-5 | 118 | 16 | A |
| Example c20 | Resist composition 5 | 120° C. | 110° C. | SB-7 | SB-30 | 82 | 18 | A |
| Example c21 | Resist composition 4 | 120° C. | 110° C. | SB-8 | SB-31 | 112 | 17 | A |
| Example c22 | Resist composition 2 | 120° C. | 130° C. | SB-9 | S-5 | 109 | 20 | A |
| Example c23 | Resist composition 5 | 120° C. | 110° C. | SB-10 | SB-32 | 103 | 16 | A |
| Example c24 | Resist composition 4 | 100° C. | 90° C. | SB-11 | SB-33 | 120 | 20 | A |
| Example c25 | Resist composition 2 | 120° C. | 110° C. | SB-12 | S-5 | 109 | 16 | A |
| Example c26 | Resist composition 5 | 120° C. | 110° C. | SB-13 | SB-34 | 103 | 18 | A |
| Example c27 | Resist composition 4 | 120° C. | 110° C. | SB-14 | SB-35 | 120 | 17 | A |
| Example c28 | Resist composition 2 | 130° C. | 110° C. | SB-15 | S-5 | 122 | 25 | A |
| Example c29 | Resist composition 2 | 120° C. | 110° C. | SB-16 | S-5 | 85 | 16 | A |
| Example c30 | Resist composition 2 | 120° C. | 110° C. | SB-17 | S-5 | 146 | 18 | A |
| Example c31 | Resist composition 5 | 120° C. | 110° C. | SB-18 | S-36 | 92 | 17 | A |
| Example c32 | Resist composition 4 | 120° C. | 110° C. | SB-19 | S-37 | 125 | 16 | A |
| Example c33 | Resist composition 2 | 120° C. | 110° C. | SB-20 | S-5 | 84 | 16 | A |
| Example c34 | Resist composition 5 | 120° C. | 130° C. | SB-21 | SB-38 | 84 | 18 | A |
| Example c35 | Resist composition 4 | 120° C. | 110° C. | SB-22 | SB-39 | 145 | 28 | A |
| Example c36 | Resist composition 2 | 100° C. | 90° C. | SB-23 | S-4 | 150 | 24 | A |
| Example c37 | Resist composition 5 | 120° C. | 110° C. | SB-24 | S-5 | 140 | 22 | A |
| Example c38 | Resist composition 4 | 120° C. | 110° C. | SB-25 | SB-40 | 122 | 20 | A |
| Example c39 | Resist composition 2 | 120° C. | 110° C. | SB-26 | S-4 | 134 | 28 | A |
| Example c40 | Resist composition 2 | 120° C. | 110° C. | SB-27 | S-5 | 134 | 22 | A |
| Example c41 | Resist composition 2 | 90° C. | 110° C. | SB-28 | S-4 | 126 | 24 | A |
| Example c42 | Resist composition 5 | 120° C. | 110° C. | SB-29 | S-5 | 116 | 27 | A |
| Example c43 | Resist composition 2 | 120° C. | 110° C. | S-2 | S-13 | 136 | 22 | A |
| Example c44 | Resist composition 2 | 120° C. | 110° C. | S-2 | SB-41 | 100 | 19 | A |
| Example c45 | Resist composition 5 | 120° C. | 110° C. | S-2 | S-10 | 146 | 24 | A |
| Example c46 | Resist composition 5 | 120° C. | 110° C. | S-2 | SB-42 | 113 | 21 | A |
| Example c47 | Resist composition 2 | 120° C. | 110° C. | S-2 | SB-43 | 148 | 25 | A |

<EB Exposure Evaluation>

Using the resist composition described in the 5^{th} table above, a resist pattern was formed by the following procedure.

[Application and Post Application Bake of Resist Composition]

The organic film DUV44 (manufactured by Brewer Science Co., Ltd.) was applied onto a 6-inch silicon wafer, and baked for 60 seconds at 200° C. to form an organic film having a film thickness of 60 nm. The resist composition described in the 5^{th} table was applied thereon and baked for 60 seconds at 120° C. to form a resist film having a film thickness of 40 nm.

[Exposure]

The above-prepared wafer was exposed to a line and space pattern of 20 nm to 17.5 nm (length direction: 0.12 mm, number of lines drawn: 20) in steps of 1.25 nm by using an electron beam irradiation apparatus (JBX6000FS/E, manufactured by JEOL, accelerating voltage: 50 keV) while varying the exposure amount.

[Post Exposure Bake]

Once removed from the electron beam irradiation following the irradiation, the wafer was immediately was heated on a hot plate under the conditions of 60 seconds at 110° C.

[Development]

Using a shower-type developing apparatus (ADE3000S, manufactured by ACTES), development was carried out by spraying and ejecting the developer (23° C.) described in the 6^{th} table above at a flow rate of 200 mL/min for a predetermined time while rotating the wafer at 50 revolutions (rpm).

[Rinsing]

Thereafter, a rinsing treatment was carried out by spraying and ejecting a rinsing liquid (23° C.) at a flow rate of 200 mL/min for a predetermined time while rotating the wafer at 50 revolutions (rpm).

Finally, the wafer was dried by high-speed spinning at 2,500 revolutions (rpm) for 60 seconds.

Any one of the above-mentioned developers was used as the rinsing liquid.

The evaluation of the resist pattern was carried out in the same manner as in the section <EUV exposure evaluation> for the same items as those mentioned therein, except for using a scanning electron microscope “S-9220” (manufactured by Hitachi, Ltd.) in the evaluation of sensitivity and resolution limit. The details of the result are shown in the 8^{th} table.

TABLE 12

| | | 8^{th} table 1 | | | | | | |
|---|---|---|---|---|---|---|---|---|
| | | | | | | 30 nm | Limiting | |
| | | PB (60 | PEB (60 | Develop- | | sensitivity | resolution | Defect |
| | | seconds) | seconds) | ment | Rinsing | [mJ/cm²] | (nm) | residue |
| Example a1 | Resist composition 8 | 120° C. | 110° C. | S-2 | S-5 | 100 | 18.75 | A |
| Example a2 | Resist composition 9 | 120° C. | 110° C. | S-10 | S-4 | 100 | 18.75 | A |
| Example a3 | Resist composition 10 | 120° C. | 110° C. | S-11 | S-5 | 100 | 18.75 | A |
| Example a4 | Resist composition 8 | 120° C. | 110° C. | SA-1 | S-5 | 100 | 30 | C |

8^{th} table 2

| | | | | | | 30 nm | Limiting | |
|---|---|---|---|---|---|---|---|---|
| | | PB (60 | PEB (60 | Develop- | | sensitivity | resolution | Defect |
| | | seconds) | seconds) | ment | Rinsing | [mJ/cm²] | (nm) | residue |
| Example a5 | Resist composition 10-2 | 120° C. | 110° C. | S-1 | — | 150 | 25 | A |
| Example a6 | Resist composition 10-2 | 120° C. | 110° C. | S-2 | S-6 | 120 | 25 | A |
| Example a7 | Resist composition 10-2 | 120° C. | 110° C. | S-2 | S-5 | 120 | 20 | A |

| | | 8^{th} table 3 | | | | | | |
|---|---|---|---|---|---|---|---|---|
| | | | | | | 30 nm | Limiting | |
| | | PB (60 | PEB (60 | Develop- | | sensitivity | resolution | Defect |
| | | seconds) | seconds) | ment | Rinsing | [mJ/cm²] | (nm) | residue |
| Example a8 | Resist composition 12 | 180° C. | — | S-1 | S-5 | 200 | 17.5 | A |
| Example a9 | Resist composition 12 | 180° C. | — | S-14 | S-5 | 180 | 20 | A |
| Example a10 | Resist composition 12 | 180° C. | — | S-15 | S-5 | 150 | 22.5 | A |
| Example a11 | Resist composition 12 | 180° C. | — | SA-1 | S-4 | 250 | 30 | C |
| | | 8^{th} table 4 | | | | | | |
| | | | | | | 30 nm | Limiting | |
| | | PB (60 | PEB (60 | Develop- | | sensitivity | resolution | Defect |
| | | seconds) | seconds) | ment | Rinsing | [mJ/cm²] | (nm) | residue |
| Example a12 | Resist composition 5 | 120° C. | 110° C. | S-8 | S-5 | 150 | 20 | A |
| Example a13 | Resist composition 6 | 120° C. | 110° C. | S-9 | S-5 | 150 | 20 | A |
| Example a14 | Resist composition 7 | 120° C. | 110° C. | S-8 | S-5 | 150 | 20 | A |
| Comparative | Resist composition 5 | 120° C. | 110° C. | SA-2 | — | 125 | 30 | D |
| Example b1 | | | | | | | | |

<Evaluation Results>

As shown in the 7^{th} and 8^{th} tables above, it was found that when any of the exposure light sources is used, if the content of the oxidant (peroxide) in at least one of a developer or a rinsing liquid is small, the number of defect residues is small (Examples).

On the other hand, it was found that unless a material having a low oxidant (peroxide) content is used for at least one of a developer or a rinsing liquid, the number of defect residues increases (Comparative Examples). Thus, it has been shown that unless a material having a low oxidant (peroxide) content is used for at least one of a developer or a rinsing liquid, the number of defect residues increases, which in turn adversely affects pattern performance such as sensitivity and limiting resolution.

1.2. ArF Exposure

1.2.1. ArF Exposure (Part 1)

### Synthesis Example 1: Synthesis of Resin (1)

102.3 parts by mass of cyclohexanone were heated to 80° C. under a nitrogen flow. While stirring this solution, a mixed solution of 22.2 parts by mass of a monomer represented by the following structural formula M-1, 22.8 parts by mass of a monomer represented by the following structural formula M-2, 6.6 parts by mass of a monomer represented by the following structural formula M-3, 189.9 parts by mass of cyclohexanone, and 2.40 parts by mass of dimethyl 2,2′-azobisisobutyrate [V-601, manufactured by Wako Pure Chemical Industries, Ltd.] was added dropwise over 5 hours. After the dropwise addition was completed, the mixture was stirred at 80° C. for another 2 hours. The reaction was allowed to cool, which was followed by re-precipitation with a large amount of hexane/ethyl acetate (mass ratio 9:1), and filtration. The resulting solid was dried in vacuo to give 41.1 parts by mass of a resin (1).

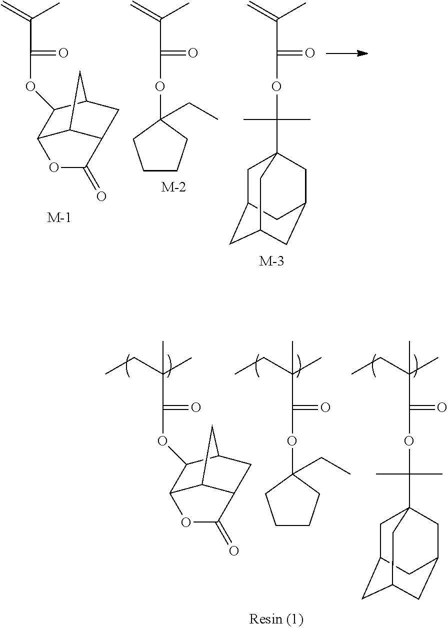

The weight-average molecular weight (Mw: polystyrene conversion) of the resulting resin (1) determined by GPC (carrier: tetrahydrofuran (THF)) was Mw=9500 and the dispersity was Mw/Mn=1.62. The composition ratio measured by ¹³C-NMR was 40/50/10 in molar ratio.

### Synthesis Example 2: Synthesis of Resins (2) to (13)

The following resins (2) to (13) as the acid-decomposable resin were synthesized in the same manner as in Synthesis Example 1. The structures of resins (1) to (13) are shown below.

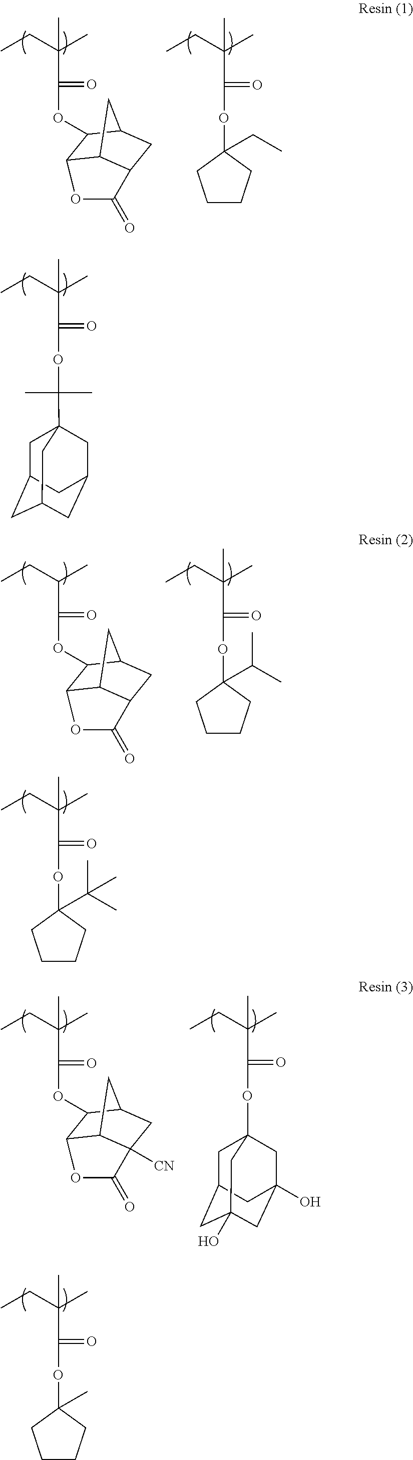

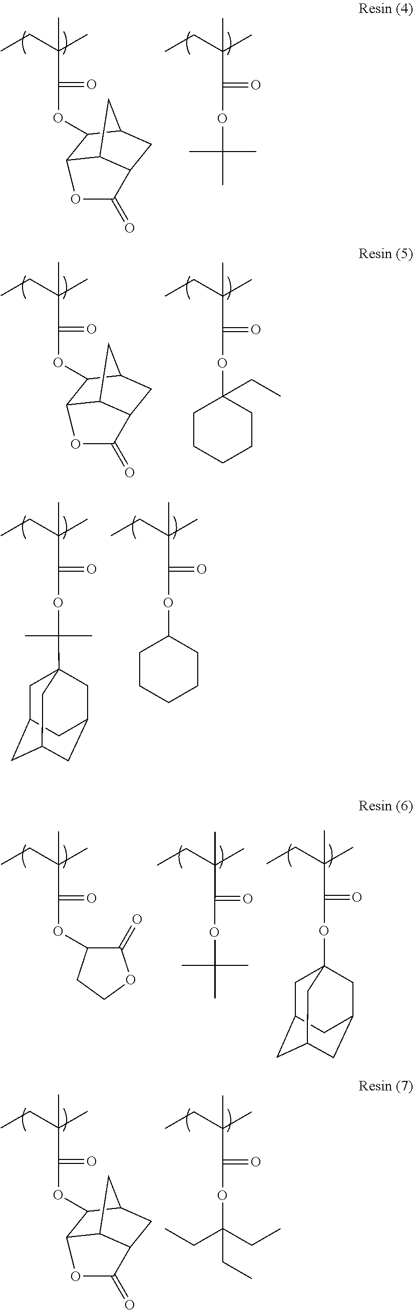

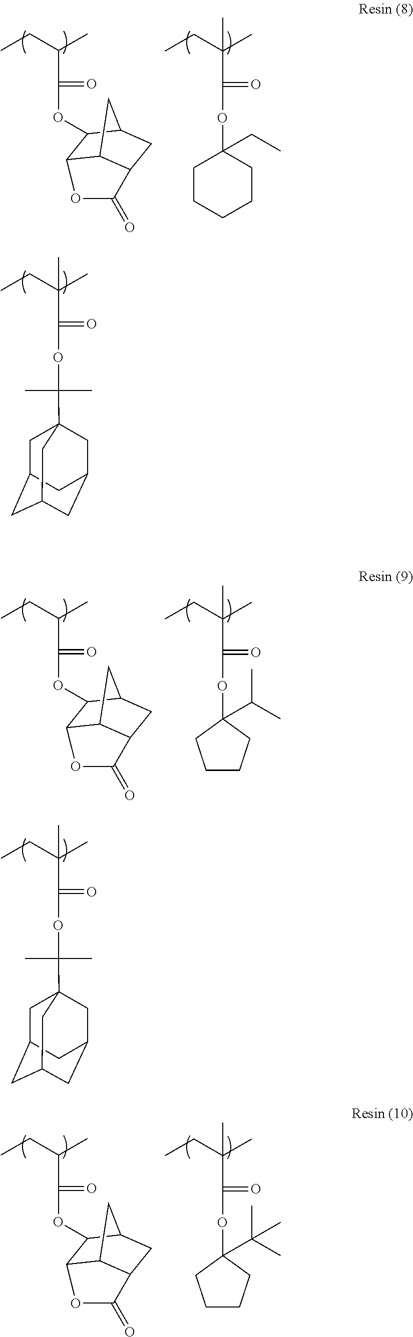

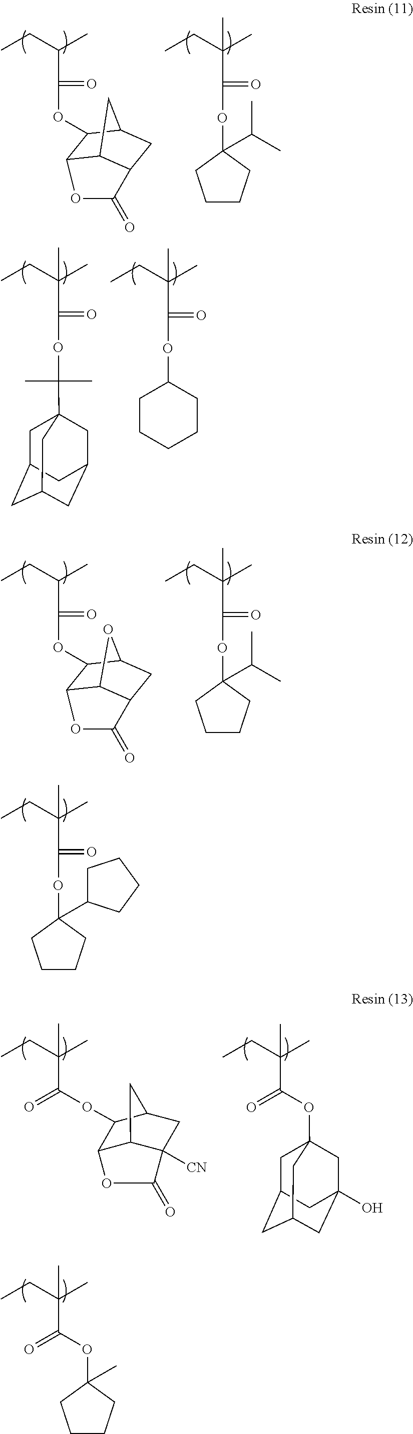

The composition ratio (molar ratio; corresponding from the left), weight-average molecular weight (Mw) and dispersity (Mw/Mn) of each repeating unit in resins (1) to (13) are summarized in the following table. These were determined in the same manner as the resin (1) described above.

TABLE 13
9^{th} table

| | | |
|---|---|---|
| Composition ratio | | |
| (molar ratio) | Mw | Mw/Mn |

| | | | | | | |
|---|---|---|---|---|---|---|
| Resin (1) | 40 | 50 | 10 | — | 9500 | 1.62 |
| Resin (2) | 40 | 40 | 20 | — | 17000 | 1.70 |
| Resin (3) | 45 | 5 | 50 | — | 11000 | 1.63 |
| Resin (4) | 40 | 60 | — | — | 15000 | 1.66 |
| Resin (5) | 40 | 40 | 10 | 10 | 10500 | 1.62 |
| Resin (6) | 40 | 50 | 10 | — | 15500 | 1.68 |
| Resin (7) | 40 | 60 | — | — | 11000 | 1.65 |
| Resin (8) | 40 | 40 | 20 | — | 10000 | 1.64 |
| Resin (9) | 40 | 50 | 10 | — | 9000 | 1.60 |
| Resin (10) | 40 | 60 | — | — | 10000 | 1.61 |
| Resin (11) | 40 | 40 | 10 | 10 | 8500 | 1.60 |
| Resin (12) | 40 | 40 | 20 | — | 9500 | 1.61 |
| Resin (13) | 40 | 40 | 20 | — | 11000 | 1.63 |

<Preparation of Resist Composition>

The components shown in the following table were dissolved in the solvent shown in the following table to prepare a solution having a solid content concentration of 3.5 mass %, which was then filtered through a polyethylene filter having a pore size of 0.03 μm to prepare resist compositions Re-1 to Re-14.

TABLE 14
10^{th} table

| | | Photoacid | Basic | Hydrophobic | | |
|---|---|---|---|---|---|---|
| | Resin | generator | compound | resin | Solvent | Surfactant |
| | (10 g) | (g) | (g) | (0.05 g) | (mass ratio) | (10 mg) |
| Re-1 | Resin (1) | A1(1.5) | D-2(0.61) | 1b | A1 | W-1 |
| Re-2 | Resin (2) | A2(1.6) | D-5(0.31) | 2b | A1/A2(70/30) | — |
| Re-3 | Resin (3) | A3(1.6) | D-3(0.30) | 3b | A1/B1(80/20) | — |
| Re-4 | Resin (4) | A4(1.6) | D-4(0.30) | 4b | A1 | W-3 |
| Re-5 | Resin (5) | A5(1.8) | D-1(0.70) | 4b | A1 | — |
| Re-6 | Resin (6) | A6(1.7) | D-6(0.30) | 1b | A1/B1(80/20) | — |
| Re-7 | Resin (7) | A7(2.1) | D-4(0.30) | 1b | A1/B1(90/10) | W-2 |
| Re-8 | Resin (8) | A8(2.0) | D-8(0.30) | 3b | A1 | — |
| Re-9 | Resin (9) | A9(2.2) | D-7(0.30) | 3b | A1/A2(80/20) | — |
| Re-10 | Resin (10) | A10(1.9) | D-5(0.31) | 1b | A1/B1(90/10) | — |
| Re-11 | Resin (11) | A11(2.0) | D-5(0.31) | 4b | A1 | — |
| Re-12 | Resin (12) | A12(1.8) | D-8(0.30) | 1b/5b | A1/A3(95/5) | W-1 |
| | | | | (0.02 g/ | | |
| | | | | 0.03 g) | | |
| Re-13 | Resin (2) | A1/A13 | D-2(0.61) | 4b | A1/A2(70/30) | W-1 |
| | | (1.1/1.3) | | | | |
| Re-14 | Resin (13) | A3(1.6) | D-3(0.30) | 3b | A1/B1(80/20) | — |

Abbreviations in the 10^{th} table are as follows.

<Photoacid Generator>

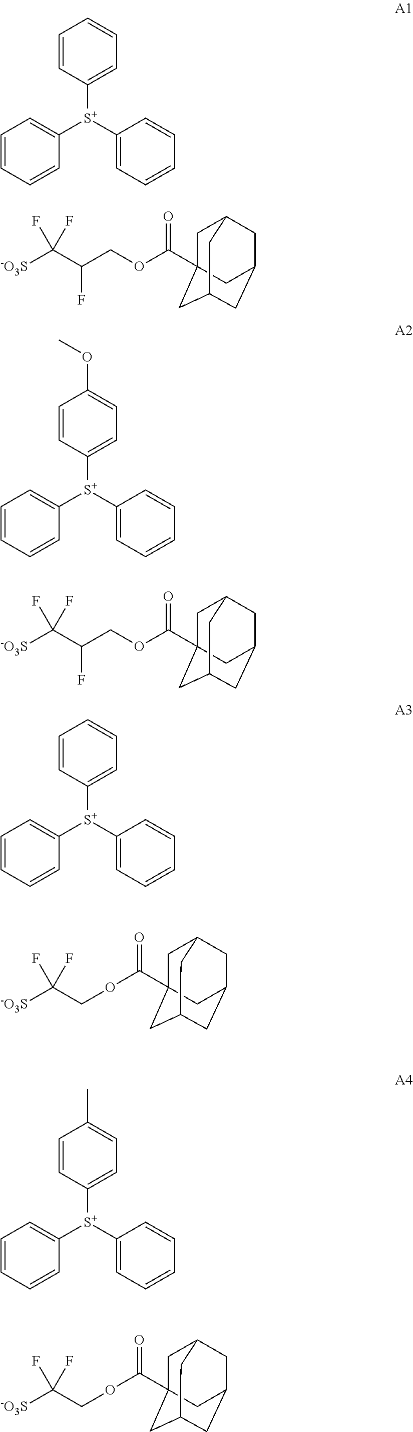

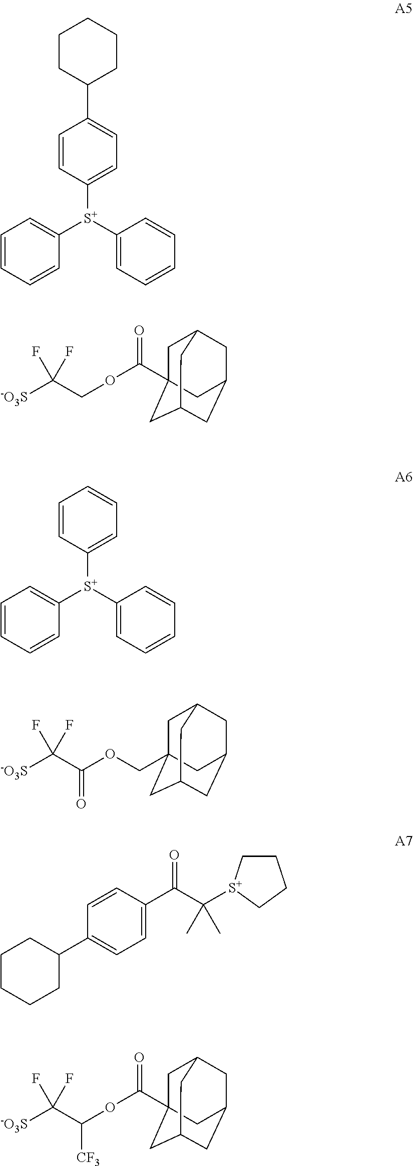

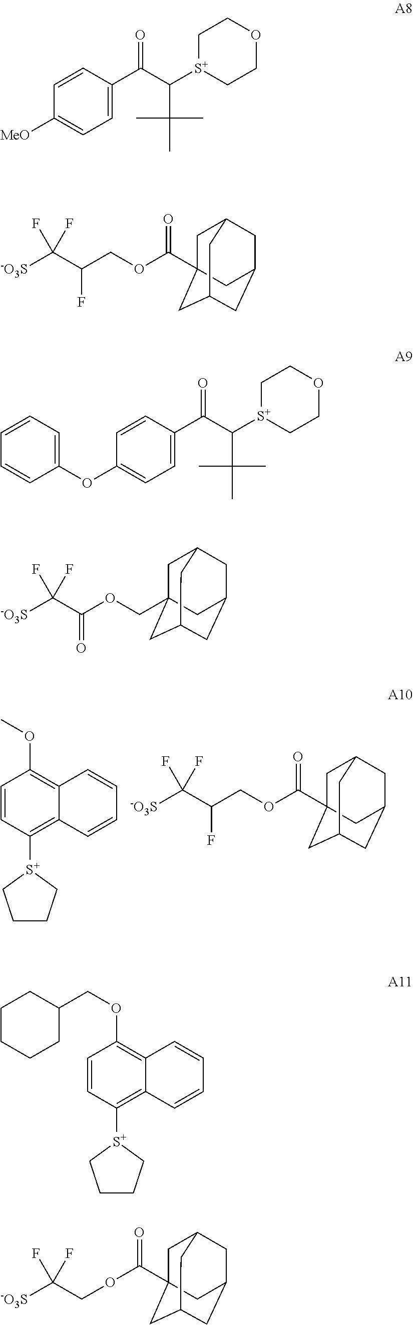

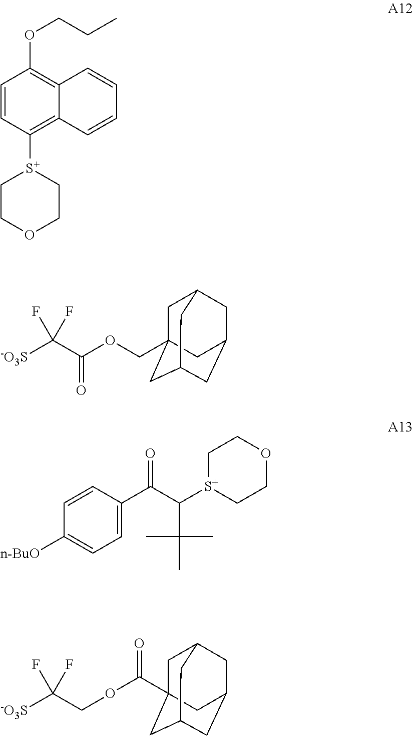

<Basic Compound>

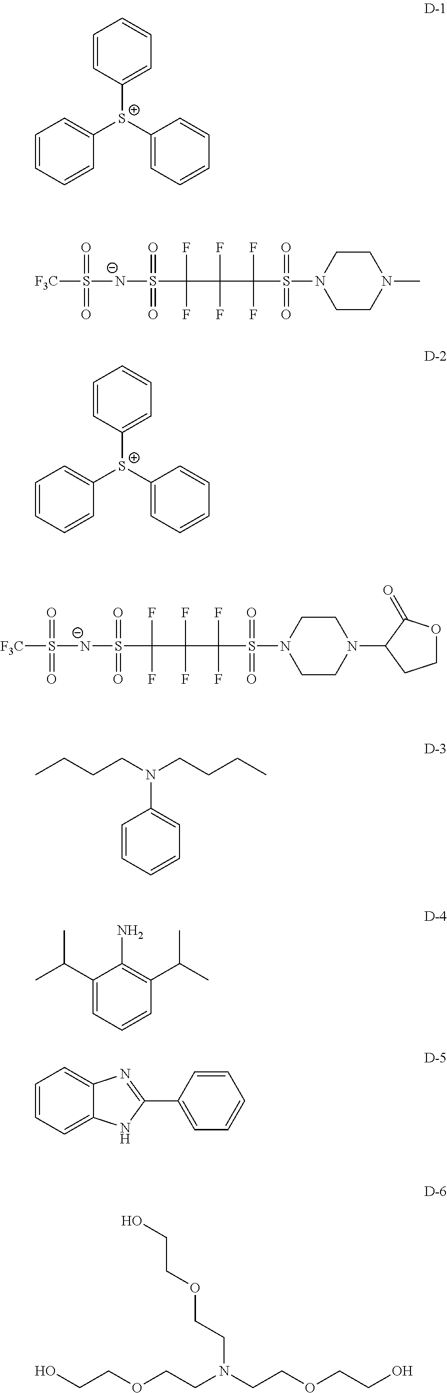

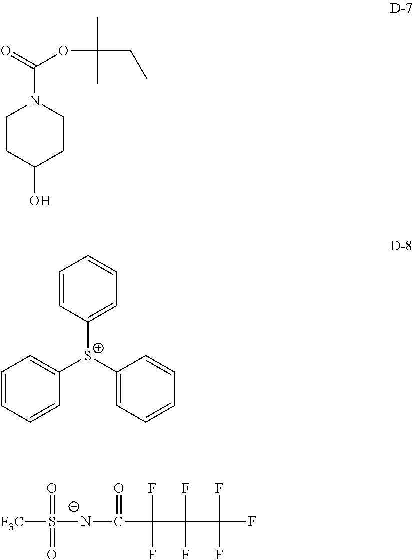 [SMILES: CCC(C)(C)OC(=O)N1CCC(O)CC1 ; c1ccc([S+](c2ccccc2)c2ccccc2)cc1 ; O=C([N-]S(=O)(=O)C(F)(F)F)C(F)(F)C(F)(F)C(F)(F)F]

<Hydrophobic Resin>

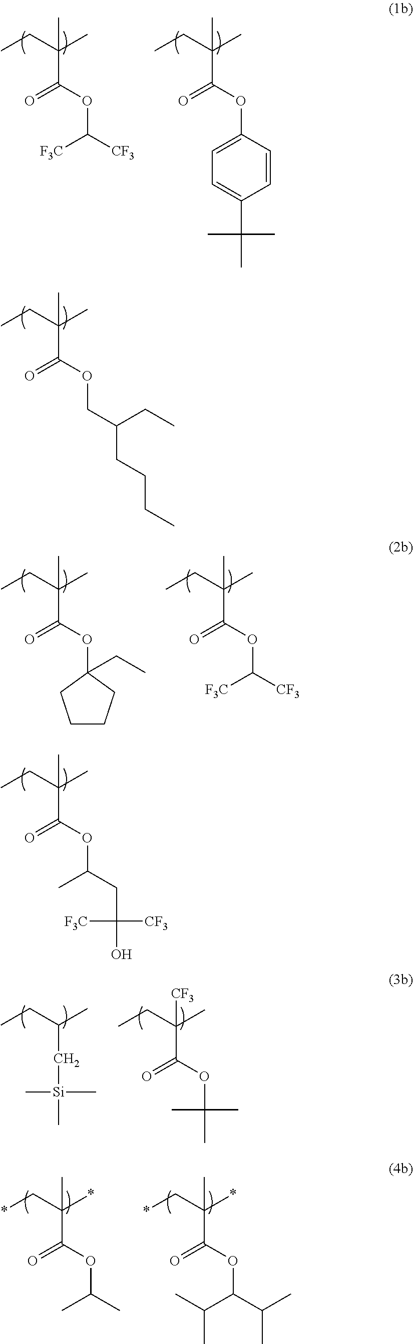

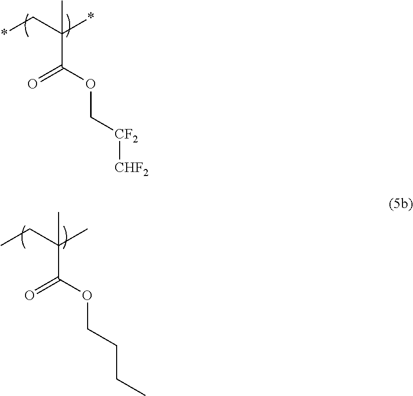

The composition ratio (molar ratio; corresponding from the left), weight-average molecular weight (Mw) and dispersity (Mw/Mn) of each repeating unit in hydrophobic resins (1b) to (5b) are summarized in the 11^{th} table. These were determined in the same manner as the resin (1) described above.

TABLE 15
11^{th} table

| | | |
|---|---|---|
| Composition ratio | | |
| (molar ratio) | Mw | Mw/Mn |

| | | | | | | |
|---|---|---|---|---|---|---|
| Resin (1b) | 50 | 45 | 5 | — | 7000 | 1.30 |
| Resin (2b) | 40 | 40 | 20 | — | 18600 | 1.57 |
| Resin (3b) | 50 | 50 | — | — | 25400 | 1.63 |
| Resin (4b) | 30 | 65 | 5 | — | 28000 | 1.70 |
| Resin (5b) | 100 | — | — | — | 12500 | 1.65 |

<Solvent>

A1: propylene glycol monomethyl ether acetate (PGMEA)

A2: cyclohexanone

A3: γ-butyrolactone

B1: propylene glycol monomethyl ether (PGME)

<Surfactant>

W-1: MEGAFAC F176 (manufactured by DIC Corporation) (fluorine-based)

W-2: MEGAFAC R08 (manufactured by DIC Corporation) (fluorine- and silicon-based)

W-3: PF6320 (manufactured by OMNOVA Solutions Inc.) (fluorine-based)

<ArF Exposure Evaluation>

A resist pattern was formed using the resist composition prepared above and then was evaluated by the following method.

[Formation of Hole Pattern]

An organic antireflection film ARC29SR (manufactured by Brewer) was coated on a 150 mm diameter (8 inch diameter) silicon wafer and baked at 205° C. for 60 seconds to form an antireflection film with a film thickness of 86 nm. The resist composition shown in the following 12^{th} table was applied thereon and baked at 100° C. for 60 seconds to form a resist film having a film thickness of 90 nm.

In Examples 1A to 16A, Examples 21A to 24A, and Comparative Example 1B, using a topcoat composition containing 2.5 mass % of a resin shown below, 0.5 mass % of a polyethylene glycol compound shown below, and 97 mass % of 4-methyl-2-pentanol solvent, a topcoat layer having a thickness of 100 nm was provided on the resist film.

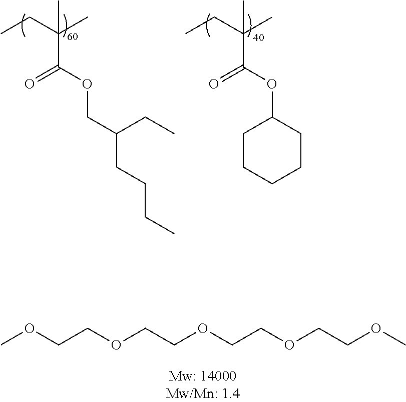

In Examples 17A to 20A, using a topcoat composition containing 2.5 mass % of a resin shown below, 0.5 mass % of a basic compound shown below, and 97 mass % of 4-methyl-2-pentanol solvent, a topcoat layer having a thickness of 100 nm was provided on the resist film.

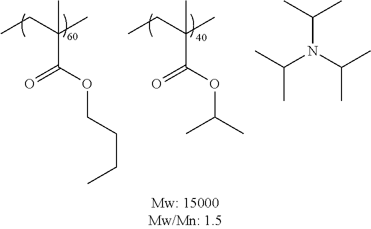

Subsequently, using an ArF excimer laser immersion scanner (XT1700i, NA1.20, C-Quad, outer sigma 0.730, inner sigma 0.630, XY deflection, manufactured by ASML Co., Ltd.), patternwise exposure of the resist film was carried out through a square arrangement halftone mask (the hole portion is shielded) having a hole portion of 65 nm and a pitch between holes of 100 nm. Ultra-pure water was used as the immersion solution. This was followed by heating (PEB: Post Exposure Bake) for 60 seconds at 105° C. Then, the resist film was subjected to puddle development for 30 seconds with the developer described in the following table, and puddle rinsing for 30 seconds with a rinsing liquid (in the case where no rinsing was carried out, “−” was stated in the following table). Subsequently, the wafer was rotated at a rotation speed of 2000 rpm for 30 seconds to obtain a hole pattern having a pore size of 50 nm.

The details of the developer in the following table are as follows.
DEV-1A: butyl acetate (peroxide amount 0.05 mmol/L)
DEV-2A: 2-heptanone (peroxide amount 0.05 mmol/L)
DEV-1B: butyl acetate (peroxide amount 15.0 mmol/L)

The details of the rinsing liquid in the following table are as follows.
RIN-1A: 4-methyl-2-heptanol (peroxide amount 0.05 mmol/L)
RIN-2A: butyl acetate (peroxide amount 0.05 mmol/L)
RIN-3A: PGMEA (peroxide amount 0.05 mmol/L)
RIN-4A: PGME (peroxide amount 0.05 mmol/L)
RIN-5A: 2-heptanone (peroxide amount 0.05 mmol/L)
RIN-1B: 4-methyl-2-heptanol (peroxide amount 15.0 mmol/L)

[Evaluation Test]

Regarding the following items, the resist pattern was evaluated. The details of the results are shown in the 12^{th} table.

(Defect Residue)

The silicon wafer after hole pattern formation obtained by the above method was observed with a scanning electron microscope (S-9380II, manufactured by Hitachi, Ltd.) to determine the number of residue defects. 1000 images were photographed while shifting the observation point by 1 micron, and the number of residual defects confirmed on the wafer was counted. The smaller the number of residue defects, the better the performance.

(Relationship between evaluation results and number of residue defects in the table)

A: 0

B: 1 to 4

C: 5 to 9

D: 10 to 19

E: 20 or more

TABLE 16
12^{th} table

| | Resist | | | Defect |
|---|---|---|---|---|
| | composition | Developer | Rinsing liquid (mass ratio) | residue |
| Example 1A | Re-1 | DEV-1A | RIN-1A | C |
| Example 2A | Re-1 | DEV-1A | RIN-2A | C |
| Example 3A | Re-1 | DEV-1A | RIN-2A/RIN-3A(80/20) | C |
| Example 4A | Re-1 | DEV-1A | RIN-2A/RIN-4A(80/20) | C |
| Example 5A | Re-2 | DEV-1A | RIN-2A/RIN-3A(85/15) | C |
| Example 6A | Re-3 | DEV-1A | RIN-2A/RIN-4A(85/15) | C |
| Example 7A | Re-4 | DEV-1A | RIN-2A/RIN-3A(90/10) | B |
| Example 8A | Re-5 | DEV-1A | RIN-2A/RIN-4A(90/10) | B |
| Example 9A | Re-6 | DEV-1A | RIN-2A/RIN-3A(95/5) | A |
| Example 10A | Re-7 | DEV-1A | RIN-2A/RIN-4A(95/5) | A |
| Example 11A | Re-8 | DEV-1A | RIN-2A/RIN-3A/RIN-4A | A |
| | | | (95/3/2) | |
| Example 12A | Re-9 | DEV-1A | RIN-2A/RIN-3A/RIN-4A | A |
| | | | (95/2/3) | |
| Example 13A | Re-10 | DEV-1A | RIN-2A/RIN-3A/RIN-4A | A |
| | | | (95/4/1) | |
| Example 14A | Re-11 | DEV-1A | RIN-2A/RIN-3A/RIN-4A | A |
| | | | (95/1/4) | |
| Example 15A | Re-12 | DEV-1A | RIN-5A/RIN-3A/RIN-4A | A |
| | | | (95/4/1) | |
| Example 16A | Re-13 | DEV-1A | RIN-5A/RIN-3A/RIN-4A | A |
| | | | (95/1/4) | |
| Example 17A | Re-1 | DEV-1A | RIN-5A/RIN-3A/RIN-4A | B |
| | | | (90/6/4) | |
| Example 18A | Re-1 | DEV-2A | RIN-5A | C |
| Example 19A | Re-1 | DEV-2A | RIN-5A/RIN-4A(90/10) | B |
| Example 20A | Re-1 | DEV-2A | RIN-5A/RIN-3A(95/5) | A |
| Example 21A | Re-1 | DEV-2A | RIN-5A/RIN-3A/RIN-4A | A |
| | | | (95/3/2) | |
| Example 22A | Re-1 | DEV-1B | RIN-1A | C |
| Example 23A | Re-1 | DEV-1A | RIN-1B | C |
| Example 24A | Re-14 | DEV-1A | RIN-2A/RIN-4A(85/15) | C |
| Comparative | Re-1 | DEV-1B | RIN-1B | E |
| Example 1B | | | | |

<Evaluation Results>

As shown in the 12^{th} table above, it was found that if the content of the oxidant (peroxide) in at least one of a developer or a rinsing liquid is small, the number of defect residues is small (Examples).

On the other hand, it was found that unless a material having a low oxidant (peroxide) content is used for at least one of a developer or a rinsing liquid, the number of defect residues increases (Comparative Examples).

After storage of the organic processing liquid according to the present invention in a FluoroPurePFA composite drum manufactured by Entegris Inc. (wetted inner surface; PFA resin lining) and a steel drum manufactured by JFE Corporation (wetted inner surface; zinc phosphate coating) for 14 days at room temperature in a manner described in JP2014-112176A, wet particles, organic impurity concentration analysis, and metal impurity concentration analysis showed that it was able to obtain better results in the FluoroPurePFA composite drum manufactured by Entegris Inc. (wetted inner surface; PFA resin lining) than the steel drum manufactured by JFE Corporation (wetted inner surface; zinc phosphate coating).

1.2.2. ArF Exposure (Part 2)

A resin (AC-1) having the structure shown in the C1 table was synthesized in the same manner as in Synthesis Example 1, except that the monomer used was changed. The composition ratio (molar ratio) of the resin was calculated by ¹H-NMR measurement. The weight-average molecular weight (Mw: polystyrene conversion) and dispersity (Mw/Mn) of the resin were calculated by GPC (solvent: THF) measurement.

TABLE 17

| | | Composition ratio | | |
|---|---|---|---|---|
| | | (molar ratio) | | |
| C1 table | Structure | from the left | Mw | Mw/Mn |
| Resin AC-1 | 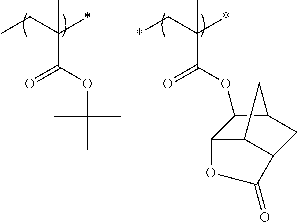 | 70/30 | 12,500 | 1.43 |

<Preparation of Resist Composition>

The individual components shown in the following C2 table were dissolved in the solvent shown in the following C2 table, which was then filtered through a polyethylene filter having a pore size of 0.03 μm to obtain a resist composition AC1.

In the C2 table, the acid generator (B-2), the basic compound (E-1), the solvent (C-1), and the solvent (C-2) are as described in the section “1. EUV and EB exposure”.

TABLE 18
C2 table

| | | Acid | Basic | | | |
|---|---|---|---|---|---|---|
| | Resin | generator | compound | Solvent | | Other |
| | (A) | (B) | (E) | (C) | | additives |
| Resist | AC-1 | B-2 | E-1 | C-1 | C-2 | — |
| composition | 0.79 g | 0.18 g | 0.03 g | 45 g | 30 g | |
| AC1 | | | | | | |

<ArF Exposure Evaluation>

In the same manner as in Example 1A of the section “1.2.1. ArF exposure (Part 1)”, except that the resist composition AC1 prepared above was used and the components shown in the following C3 table were used as a developer and a rinsing liquid in the combination of the following C4 table, a hole pattern was formed on the resist film provided with a topcoat layer.

TABLE 19
C3 table

| Developer | | | | |
|---|---|---|---|---|
| (rinsing | | | Content of | Content of |
| liquid) | Main component | Additives | additives | oxidant |
| SE-1 | diisobutyl ether | — | | 0.05 mmol/L |
| SE-2 | diisopentyl ether | — | | 0.05 mmol/L |
| SE-3 | diisohexyl ether | — | | 0.05 mmol/L |
| SE-4 | anisole | — | | 0.05 mmol/L |
| SE-5 | di-n-butyl ether | — | | 0.05 mmol/L |
| SE-6 | di-n-pentyl ether | — | | 0.05 mmol/L |
| SE-7 | di-n-hexyl ether | — | | 0.05 mmol/L |
| SE-8 | diisopropyl ether | — | | 0.05 mmol/L |
| SE-18 | diisobutyl ketone | — | | 0.05 mmol/L |

[Evaluation Test]

The defect residue of the resist pattern was evaluated by the same evaluation method and evaluation standards as those of the section “1.2.1. ArF exposure (Part 1)” described above. The details of the results are shown in the C4 table.

TABLE 20

| | | | Rinsing | Defect |
|---|---|---|---|---|
| C4 table | | Developer | liquid | residue |
| Example | Resist composition AC1 | SE-18 | SE-1 | A |
| 100A | | | | |
| Example | Resist composition AC1 | SE-18 | SE-2 | A |
| 101A | | | | |
| Example | Resist composition AC1 | SE-18 | SE-3 | A |
| 102A | | | | |
| Example | Resist composition AC1 | SE-18 | SE-4 | A |
| 103A | | | | |
| Example | Resist composition AC1 | SE-18 | SE-5 | A |
| 104A | | | | |
| Example | Resist composition AC1 | SE-18 | SE-6 | A |
| 105A | | | | |
| Example | Resist composition AC1 | SE-18 | SE-7 | A |
| 106A | | | | |
| Example | Resist composition AC1 | SE-18 | SE-8 | A |
| 107A | | | | |

[Evaluation Results]

As shown in the C4 table, it was found that if the content of the oxidant (peroxide) in at least one of a developer or a rinsing liquid is small, the number of defect residues is small (Examples).

1.3. EUV Exposure

1.3.1. EUV Exposure (Part 1)

### Synthesis Example

Resins (AA-1) to (AA-11) having the structure shown in the 13^{th} table were synthesized in the same manner as in Synthesis Example 1, except that the type and the addition amount of the monomer used were changed. The composition ratio (molar ratio) of the resin was calculated by ¹H-NMR measurement. The weight-average molecular weight (Mw: polystyrene conversion) and dispersity (Mw/Mn) of the resin were calculated by GPC (solvent: THF) measurement.

TABLE 21

| 13^{th} | | Composition ratio | | |
|---|---|---|---|---|
| table | | (molar ratio) | | |
| (Part 1) | Structure | from the left | Mw | Mw/Mn |
| Resin AA-1 | 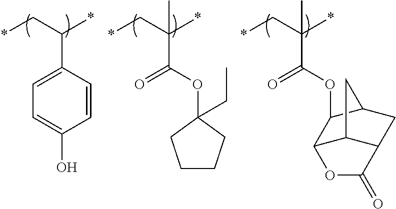 | 20/70/10 | 12,500 | 1.48 |
| Resin AA-2 | 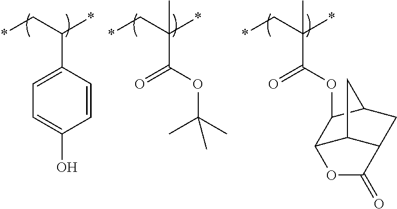 | 10/80/10 | 14,500 | 1.62 |
| Resin AA-3 | 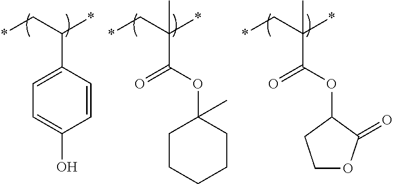 | 5/80/15 | 9,200 | 1.68 |
| Resin AA-4 | 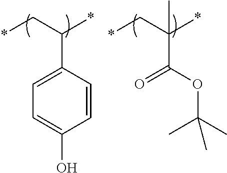 | 10/90 | 18,500 | 1.52 |
| Resin AA-5 | 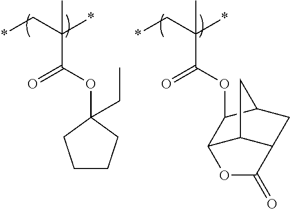 | 75/25 | 13,000 | 1.56 |
| Resin AA-6 | 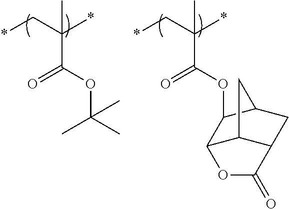 | 50/50 | 12,500 | 1.43 |
| Resin AA-7 | 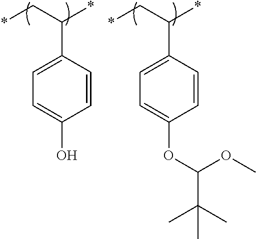 | 20/80 | 13,400 | 1.12 |

TABLE 22

| | | Composition | | |
|---|---|---|---|---|
| 13^{th} | | ratio | | |
| table | | (molar ratio) | | Mw/ |
| (Part 2) | Structure | from the left | Mw | Mn |
| Resin AA-8 | 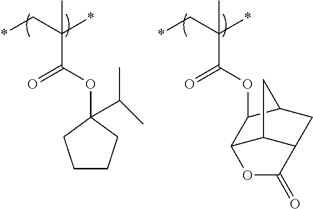 | 50/50 | 10,800 | 1.48 |
| Resin AA-9 | 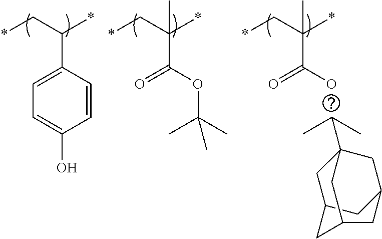 | 20/60/20 | 10,200 | 1.62 |
| Resin AA-10 | 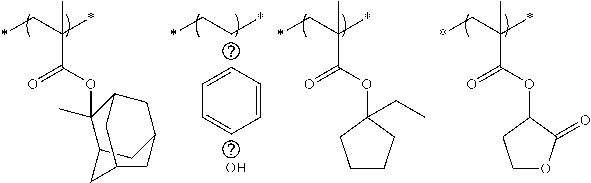 | 10/20/50/20 | 9,500 | 1.68 |
| Resin AA-11 | 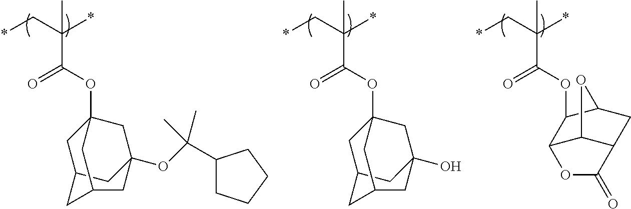 | 40/10/50 | 12,500 | 1.52 |
| Resin AA-12 | 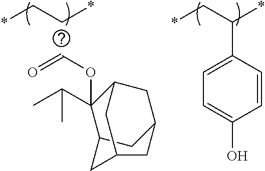 | 50/50 | 11,000 | 1.48 |
| Resin AA-13 | 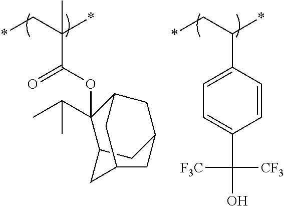 | 90/10 | 14,500 | 1.62 |
| Resin AA-14 | 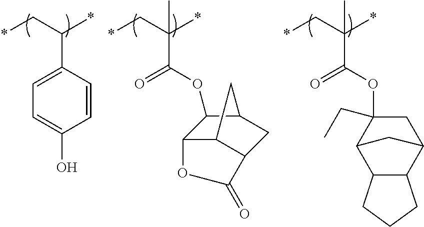 | 30/10/60 | 12,000 | 1.68 |
| Resin AA-15 | 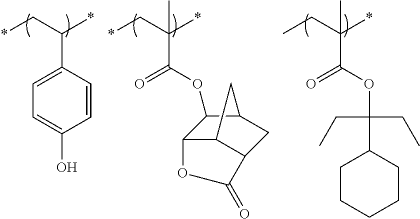 | 30/20/50 | 12,500 | 1.52 |
| Resin AA-16 | 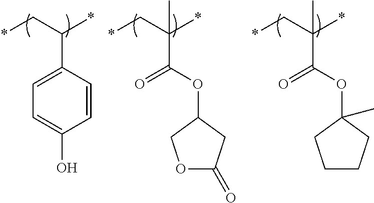 | 30/10/60 | 9,500 | 1.43 |
| Resin AA-17 | 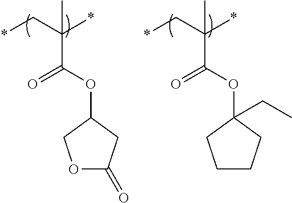 | 40/60 | 8,200 | 1.35 |
| Resin AA-18 | 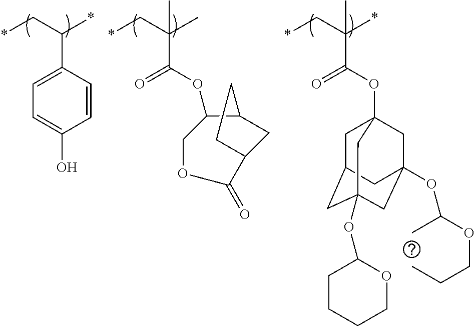 | 20/20/60 | 14,500 | 1.55 |

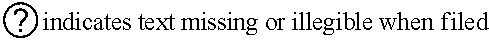

<Acid Generator (B)>

As the acid generator, the following compounds were used together with a part of the acid generators (B) used in the above section “1. EUV and EB exposure”.

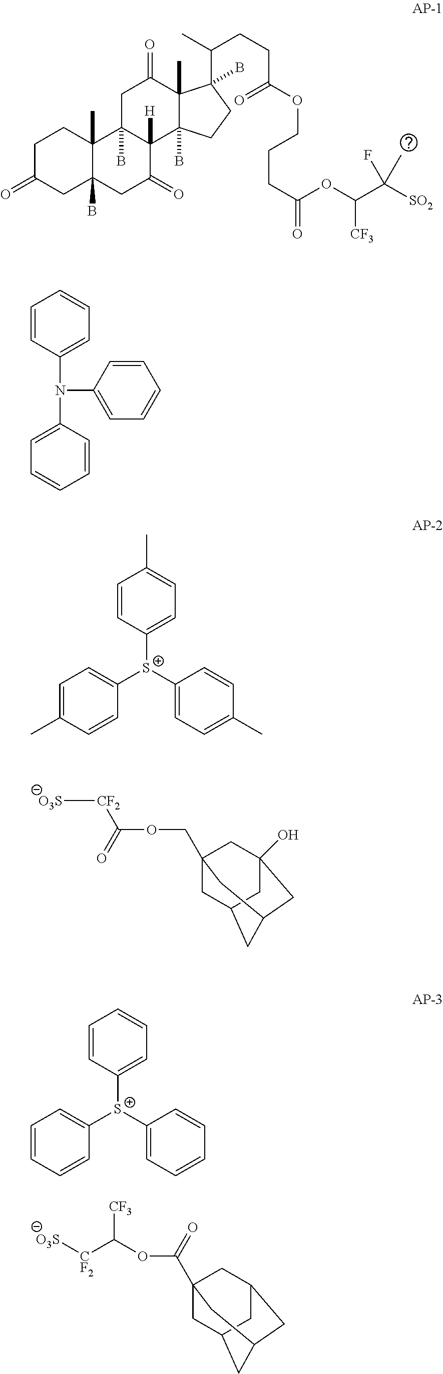

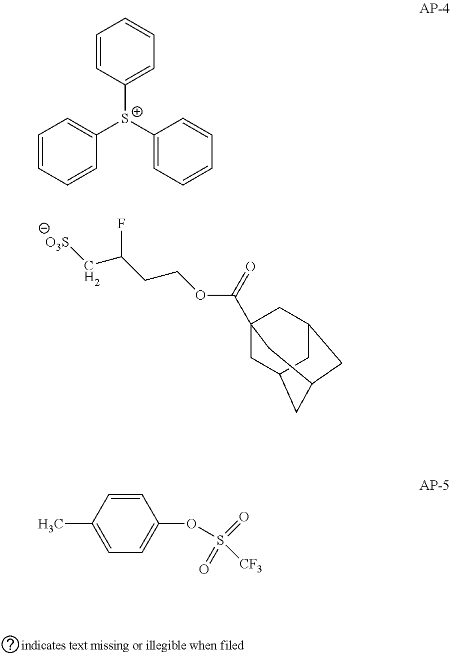

<Basic Compound (E)>

As the basic compound, the following compounds were used together with a part of the basic compounds (E) used in the above section “1. EUV and EB exposure”.

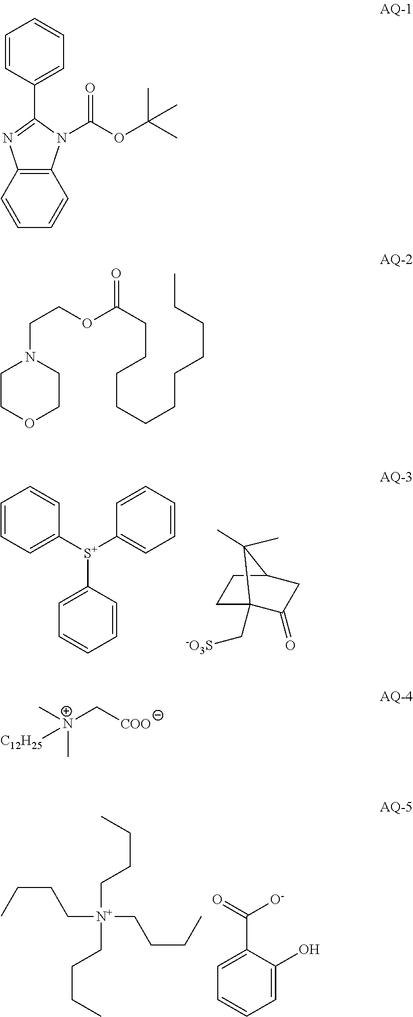

<Solvent (C)>

As the resist solvent, the following compounds were used.

C-1: propylene glycol monomethyl ether acetate

C-2: propylene glycol

<Resist Composition>

The individual components shown in the following 14^{th} table were dissolved in the solvent shown in the following 14^{th} table, which was then filtered using a polyethylene filter having a pore size of 0.03 μm to obtain a resist composition.

TABLE 23
14^{th} table (Part 1)

| | | Acid | Basic | | | |
|---|---|---|---|---|---|---|
| | Resin | generator | compound | Solvent | | Other |
| | (A) | (B) | (E) | (C) | | additives |
| Resist | AA-1 | B-2 | E-1 | C-1 | C-2 | — |
| composition | 0.79 g | 0.18 g | 0.03 g | 45 g | 30 g | |
| AA1 | | | | | | |
| Resist | AA-2 | B-2 | E-1 | C-1 | C-2 | — |
| composition | 0.79 g | 0.18 g | 0.03 g | 45 g | 30 g | |
| AA2 | | | | | | |
| Resist | AA-3 | B-2 | E-1 | C-1 | C-2 | — |
| composition | 0.79 g | 0.18 g | 0.03 g | 45 g | 30 g | |
| AA3 | | | | | | |
| Resist | AA-4 | B-2 | E-1 | C-1 | C-2 | — |
| composition | 0.79 g | 0.18 g | 0.03 g | 45 g | 30 g | |
| AA4 | | | | | | |
| Resist | AA-5 | B-2 | E-1 | C-1 | C-2 | — |
| composition | 0.79 g | 0.18 g | 0.03 g | 45 g | 30 g | |
| AA5 | | | | | | |
| Resist | AA-6 | B-2 | E-1 | C-1 | C-2 | — |
| composition | 0.79 g | 0.18 g | 0.03 g | 45 g | 30 g | |
| AA6 | | | | | | |
| Resist | AA-7 | B-2 | E-1 | C-1 | C-2 | — |
| composition | 0.79 g | 0.18 g | 0.03 g | 45 g | 30 g | |
| AA7 | | | | | | |
| Resist | AA-8 | B-2 | E-1 | C-1 | C-2 | — |
| composition | 0.79 g | 0.18 g | 0.03 g | 45 g | 30 g | |
| AA8 | | | | | | |
| Resist | AA-9 | B-2 | E-1 | C-1 | C-2 | — |
| composition | 0.79 g | 0.18 g | 0.03 g | 45 g | 30 g | |
| AA9 | | | | | | |
| Resist | AA-10 | B-2 | E-1 | C-1 | C-2 | — |
| composition | 0.79 g | 0.18 g | 0.03 g | 45 g | 30 g | |
| AA10 | | | | | | |
| Resist | AA-11 | B-2 | E-1 | C-1 | C-2 | — |
| composition | 0.79 g | 0.18 g | 0.03 g | 45 g | 30 g | |
| AA11 | | | | | | |
| Resist | AA-12 | B-2 | E-1 | C-1 | C-2 | — |
| composition | 0.79 g | 0.18 g | 0.03 g | 45 g | 30 g | |
| AA12 | | | | | | |
| Resist | AA-13 | B-2 | E-1 | C-1 | C-2 | — |
| composition | 0.79 g | 0.18 g | 0.03 g | 45 g | 30 g | |
| AA13 | | | | | | |
| Resist | AA-14 | B-2 | E-1 | C-1 | C-2 | — |
| composition | 0.79 g | 0.18 g | 0.03 g | 45 g | 30 g | |
| AA14 | | | | | | |
| Resist | AA-15 | B-2 | E-1 | C-1 | C-2 | — |
| composition | 0.79 g | 0.18 g | 0.03 g | 45 g | 30 g | |
| AA15 | | | | | | |
| Resist | AA-16 | B-2 | E-1 | C-1 | C-2 | — |
| composition | 0.79 g | 0.18 g | 0.03 g | 45 g | 30 g | |
| AA16 | | | | | | |
| Resist | AA-17 | B-2 | E-1 | C-1 | C-2 | — |
| composition | 0.79 g | 0.18 g | 0.03 g | 45 g | 30 g | |
| AA17 | | | | | | |
| Resist | AA-18 | B-2 | E-1 | C-1 | C-2 | — |
| composition | 0.79 g | 0.18 g | 0.03 g | 45 g | 30 g | |
| AA18 | | | | | | |

TABLE 24
14^{th} table (Part 2)

| | | Acid | Basic | | | |
|---|---|---|---|---|---|---|
| | Resin | generator | compound | Solvent | | Other |
| | (A) | (B) | (E) | (C) | | additives |
| Resist | AA-16 | AP-1 | E-1 | C-1 | C-2 | — |
| composition | 0.79 g | 0.18 g | 0.03 g | 45 g | 30 g | |
| AA19 | | | | | | |
| Resist | AA-16 | AP-2 | E-1 | C-1 | C-2 | — |
| composition | 0.79 g | 0.18 g | 0.03 g | 45 g | 30 g | |
| AA20 | | | | | | |
| Resist | AA-16 | AP-3 | E-1 | C-1 | C-2 | — |
| composition | 0.79 g | 0.18 g | 0.03 g | 45 g | 30 g | |
| AA21 | | | | | | |
| Resist | AA-16 | AP-4 | E-1 | C-1 | C-2 | — |
| composition | 0.79 g | 0.18 g | 0.03 g | 45 g | 30 g | |
| AA22 | | | | | | |
| Resist | AA-16 | AP-5 | E-1 | C-1 | C-2 | — |
| composition | 0.79 g | 0.18 g | 0.03 g | 45 g | 30 g | |
| AA23 | | | | | | |
| Resist | AA-16 | B-2 | AQ-1 | C-1 | C-2 | — |
| composition | 0.79 g | 0.18 g | 0.03 g | 45 g | 30 g | |
| AA24 | | | | | | |
| Resist | AA-16 | B-2 | AQ-2 | C-1 | C-2 | — |
| composition | 0.79 g | 0.18 g | 0.03 g | 45 g | 30 g | |
| AA25 | | | | | | |
| Resist | AA-16 | B-2 | AQ-3 | C-1 | C-2 | — |
| composition | 0.79 g | 0.18 g | 0.03 g | 45 g | 30 g | |
| AA26 | | | | | | |
| Resist | AA-16 | B-2 | AQ-4 | C-1 | C-2 | — |
| composition | 0.79 g | 0.18 g | 0.03 g | 45 g | 30 g | |
| AA27 | | | | | | |
| Resist | AA-16 | B-2 | AQ-5 | C-1 | C-2 | — |
| composition | 0.79 g | 0.18 g | 0.03 g | 45 g | 30 g | |
| AA28 | | | | | | |
| Resist | AA-2/ | B-2 | AQ-5 | C-1 | C-2 | — |
| composition | AA-16 | 0.18 g | 0.03 g | 45 g | 30 g | |
| AA29 | 0.40 g/ | | | | | |
| | 0.40 g | | | | | |
| Resist | AA-12/ | B-2 | AQ-5 | C-1 | C-2 | — |
| composition | AA-16 | 0.18 g | 0.03 g | 45 g | 30 g | |
| AA30 | 0.40 g/ | | | | | |
| | 0.40 g | | | | | |
| Resist | AA-1/ | B-2 | AQ-5 | C-1 | C-2 | — |
| composition | AA-7 | 0.18 g | 0.03 g | 45 g | 30 g | |
| AA31 | 0.40 g/ | | | | | |
| | 0.40 g | | | | | |
| Resist | AA-16 | B-2/B-3 | AQ-5 | C-1 | C-2 | — |
| composition | 0.80 g | 0.10 g/ | 0.03 g | 45 g | 30 g | |
| AA32 | | 0.10 g | | | | |
| Resist | AA-16 | B-1/B-2 | AQ-5 | C-1 | C-2 | — |
| composition | 0.80 g | 0.10 g/ | 0.03 g | 45 g | 30 g | |
| AA33 | | 0.10 g | | | | |
| Resist | AA-16 | B-2 | E-1/E-4 | C-1 | C-2 | — |
| composition | 0.80 g | 0.18 g | 0.015 g/ | 45 g | 30 g | |
| AA34 | | | 0.015 g | | | |
| Resist | AA-16 | B-2 | AQ-1/ | C-1 | C-2 | — |
| composition | 0.80 g | 0.18 g | AQ-2 | 45 g | 30 g | |
| AA35 | | | 0.015 g/ | | | |
| | | | 0.015 g | | | |
| Resist | AA-2/ | B-1/B-2 | E-1/E-4 | C-1 | C-2 | — |
| composition | AA-16 | 0.10 g/ | 0.015 g/ | 45 g | 30 g | |
| AA36 | 0.40 g/ | 0.10 g | 0.015 g | | | |
| | 0.40 g | | | | | |

<EUV Exposure Evaluation>

Using the resist composition described in the 15^{th} table, a resist pattern was formed in the same manner as in the above-mentioned section “1.EUV and EB exposure”.

In [Development] and [Rinsing], a part of the solutions described in the following 15th table and the developers and the rinsing liquids listed in the section “1. EUV and EB exposure” were used.

TABLE 25
15^{th} table

| Developer | | | | |
|---|---|---|---|---|
| (rinsing | | | | |
| liquid) | Main component | Additives | Content of additives | Content of oxidant |
| SC-1 | isoamyl acetate/2-methylbutyl | — | — | 0.05 mmol/L |
| | acetate = 95/5 | | | |
| SC-2 | isoamyl acetate/2-methylbutyl | — | — | 0.05 mmol/L |
| | acetate = 90/10 | | | |
| SC-3 | isoamyl acetate/2-methylbutyl | — | — | 0.05 mmol/L |
| | acetate = 80/20 | | | |
| SC-4 | isoamyl acetate/2-methylbutyl | — | — | 0.05 mmol/L |
| | acetate = 50/50 | | | |
| SC-5 | isoamyl acetate/2-methylbutyl | — | — | 0.05 mmol/L |
| | acetate = 20/80 | | | |
| SC-6 | isoamyl acetate/pentyl acetate = 20/80 | — | — | 0.05 mmol/L |
| SC-7 | isoamyl acetate/pentyl acetate = 50/50 | — | — | 0.05 mmol/L |
| SC-8 | isoamyl acetate/pentyl acetate = 80/20 | — | — | 0.05 mmol/L |
| SD-1 | decane/2-methylnonane = 80/20 | — | — | 0.05 mmol/L |
| SD-2 | decane/2-methylnonane = 50/50 | — | — | 0.05 mmol/L |
| SD-3 | decane/2-methylnonane = 20/80 | — | — | 0.05 mmol/L |
| SD-4 | undecane/2-methyldecane = 80/20 | — | — | 0.05 mmol/L |
| SD-5 | undecane/2-methyldecane = 50/50 | — | — | 0.05 mmol/L |
| SD-6 | undecane/2-methyldecane = 20/80 | — | — | 0.05 mmol/L |

[Evaluation Test]

Using the obtained resist pattern, the evaluation carried out in the above-mentioned section “1. EUV and EB exposure” was carried out. The details of the results are shown in the 16^{th} table.

TABLE 26
16^{th} table

| | | | | | | 30 nm | Limiting | |
|---|---|---|---|---|---|---|---|---|
| | | PB (60 | PEB (60 | Develop- | | sensitivity | resolution | Defect |
| | | seconds) | seconds) | ment | Rinsing | [mJ/cm²] | (nm) | residue |
| Example AA1 | Resist composition AA1 | 120° C. | 100° C. | S-2 | S-5 | 104 | 18 | A |
| Example AA2 | Resist composition AA2 | 110° C. | 110° C. | SC-1 | S-5 | 90 | 18 | A |
| Example AA3 | Resist composition AA3 | 100° C. | 110° C. | SC-2 | S-5 | 137 | 16 | A |
| Example AA4 | Resist composition AA4 | 90° C. | 110° C. | SC-3 | SD-1 | 95 | 20 | A |
| Example AA5 | Resist composition AA5 | 130° C. | 110° C. | SC-4 | SD-2 | 72 | 19 | A |
| Example AA6 | Resist composition AA6 | 120° C. | 120° C. | SC-5 | SD-3 | 106 | 19 | A |
| Example AA7 | Resist composition AA7 | 110° C. | 90° C. | SC-6 | S-5 | 87 | 16 | A |
| Example AA8 | Resist composition AA8 | 100° C. | 110° C. | SC-7 | S-5 | 87 | 19 | A |
| Example AA9 | Resist composition AA9 | 90° C. | 110° C. | SC-8 | SD-4 | 98 | 19 | A |
| Example AA10 | Resist composition AA10 | 130° C. | 90° C. | S-2 | SD-5 | 102 | 18 | A |
| Example AA11 | Resist composition AA11 | 120° C. | 110° C. | SC-1 | SD-6 | 105 | 20 | A |
| Example AA12 | Resist composition AA12 | 110° C. | 110° C. | SC-2 | S-5 | 100 | 18 | A |
| Example AA13 | Resist composition AA13 | 100° C. | 110° C. | SC-3 | S-5 | 76 | 16 | A |
| Example AA14 | Resist composition AA14 | 90° C. | 110° C. | SC-4 | S-5 | 84 | 18 | A |
| Example AA15 | Resist composition AA15 | 130° C. | 110° C. | SC-5 | S-5 | 74 | 18 | A |
| Example AA16 | Resist composition AA16 | 120° C. | 110° C. | SC-6 | S-5 | 77 | 19 | A |
| Example AA17 | Resist composition AA17 | 110° C. | 110° C. | SC-7 | S-5 | 83 | 17 | A |
| Example AA18 | Resist composition AA18 | 100° C. | 100° C. | SC-8 | S-5 | 99 | 19 | A |
| Example AA19 | Resist composition AA19 | 90° C. | 100° C. | S-2 | S-5 | 88 | 20 | A |
| Example AA20 | Resist composition AA20 | 130° C. | 110° C. | SC-1 | S-5 | 114 | 17 | A |
| Example AA21 | Resist composition AA21 | 120° C. | 100° C. | SC-2 | S-5 | 135 | 17 | A |
| Example AA22 | Resist composition AA22 | 120° C. | 110° C. | SC-3 | S-5 | 134 | 16 | A |
| Example AA23 | Resist composition AA23 | 120° C. | 100° C. | SC-4 | S-5 | 84 | 17 | A |
| Example AA24 | Resist composition AA24 | 100° C. | 110° C. | SC-5 | S-5 | 79 | 17 | A |
| Example AA25 | Resist composition AA25 | 120° C. | 100° C. | SC-6 | S-5 | 133 | 19 | A |
| Example AA26 | Resist composition AA26 | 120° C. | 110° C. | SC-7 | S-5 | 107 | 18 | A |
| Example AA27 | Resist composition AA27 | 120° C. | 100° C. | SC-8 | S-5 | 120 | 19 | A |
| Example AA28 | Resist composition AA28 | 130° C. | 110° C. | S-2 | S-5 | 109 | 17 | A |
| Example AA29 | Resist composition AA29 | 130° C. | 110° C. | S-2 | S-5 | 86 | 19 | A |
| Example AA30 | Resist composition AA30 | 130° C. | 110° C. | S-2 | S-5 | 81 | 16 | A |
| Example AA31 | Resist composition AA31 | 130° C. | 110° C. | S-2 | S-5 | 117 | 18 | A |
| Example AA32 | Resist composition AA32 | 130° C. | 110° C. | S-2 | S-5 | 91 | 16 | A |
| Example AA33 | Resist composition AA33 | 130° C. | 110° C. | S-2 | S-5 | 96 | 17 | A |
| Example AA34 | Resist composition AA34 | 130° C. | 110° C. | S-2 | S-5 | 84 | 17 | A |
| Example AA35 | Resist composition AA35 | 130° C. | 110° C. | S-2 | S-5 | 93 | 18 | A |
| Example AA36 | Resist composition AA36 | 130° C. | 110° C. | S-2 | S-5 | 116 | 18 | A |

As shown in the 16^{th} table, it was found that if the content of the oxidant (peroxide) in at least one of a developer or a rinsing liquid is small, the number of defect residues is small.

1.3.2. EUV Exposure (Part 2)

### Synthesis Example

Resins (AB-1) to (AB-10) having the structure shown in the C5 table were synthesized in the same manner as in Synthesis Example 1, except that the monomer used was changed. The composition ratio (molar ratio) of the resin was calculated by ¹H-NMR measurement. The weight-average molecular weight (Mw: polystyrene conversion) and dispersity (Mw/Mn) of the resin were calculated by GPC (solvent: THF) measurement.

TABLE 27

| | | Composition ratio | | |
|---|---|---|---|---|
| C5 | | (molar ratio) | | |
| table | Structure | from the left | Mw | Mw/Mn |
| Resin AB-1 | 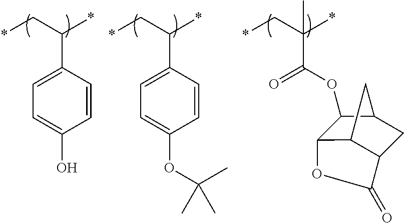 | 30/55/15 | 12,500 | 1.48 |
| Resin AB-2 | 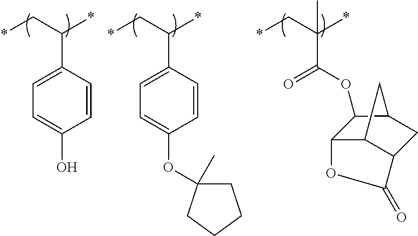 | 40/50/10 | 14,500 | 1.62 |
| Resin AB-3 | 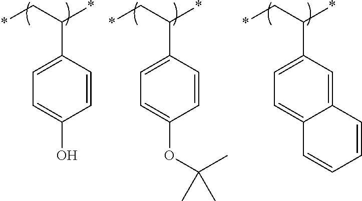 | 30/60/10 | 9,200 | 1.68 |
| Resin AB-4 | 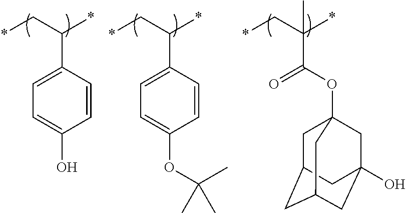 | 20/70/10 | 18,500 | 1.52 |
| Resin AB-5 | 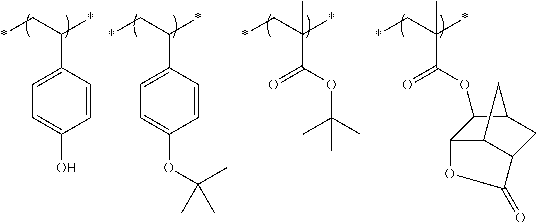 | 30/30/30/10 | 13,000 | 1.56 |
| Resin AB-6 | 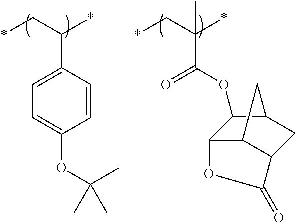 | 70/30 | 12,500 | 1.43 |
| Resin AB-7 | 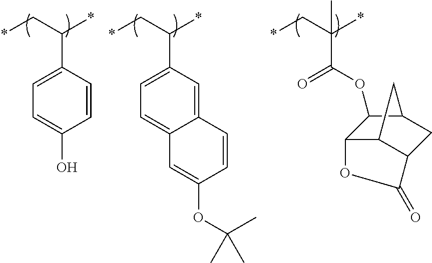 | 35/45/20 | 13,400 | 1.35 |
| Resin AB-8 | 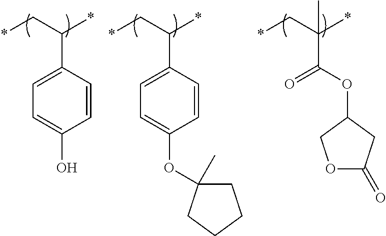 | 25/55/20 | 13,400 | 1.65 |
| Resin AB-9 | 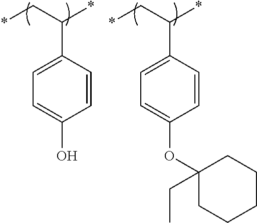 | 50/50 | 12,500 | 1.33 |
| Resin AB-10 | 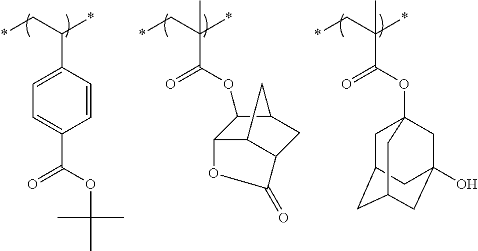 | 60/20/20 | 9,800 | 1.77 |

<Preparation of Resist Composition>

The individual components shown in the following C6 table were dissolved in the solvent shown in the following C6 table, which was then filtered through a polyethylene filter having a pore size of 0.03 μm to obtain resist compositions AB1 to AB10. In the C6 table, the acid generator (B-2), the basic compound (E-1), the solvent (C-1), and the solvent (C-2) are as described in the section “1. EUV and EB exposure”.

TABLE 28
C6 table

| | | Acid | Basic | | | |
|---|---|---|---|---|---|---|
| | Resin | generator | compound | Solvent | | Other |
| | (A) | (B) | (E) | (C) | | additives |
| Resist | AB-1 | B-2 | E-1 | C-1 | C-2 | — |
| composition | 0.79 g | 0.18 g | 0.03 g | 45 g | 30 g | |
| AB1 | | | | | | |
| Resist | AB-2 | B-2 | E-1 | C-1 | C-2 | — |
| composition | 0.79 g | 0.18 g | 0.03 g | 45 g | 30 g | |
| AB2 | | | | | | |
| Resist | AB-3 | B-2 | E-1 | C-1 | C-2 | — |
| composition | 0.79 g | 0.18 g | 0.03 g | 45 g | 30 g | |
| AB3 | | | | | | |
| Resist | AB-4 | B-2 | E-1 | C-1 | C-2 | — |
| composition | 0.79 g | 0.18 g | 0.03 g | 45 g | 30 g | |
| AB4 | | | | | | |
| Resist | AB-5 | B-2 | E-1 | C-1 | C-2 | — |
| composition | 0.79 g | 0.18 g | 0.03 g | 45 g | 30 g | |
| AB5 | | | | | | |
| Resist | AB-6 | B-2 | E-1 | C-1 | C-2 | — |
| composition | 0.79 g | 0.18 g | 0.03 g | 45 g | 30 g | |
| AB6 | | | | | | |
| Resist | AB-7 | B-2 | E-1 | C-1 | C-2 | — |
| composition | 0.79 g | 0.18 g | 0.03 g | 45 g | 30 g | |
| AB7 | | | | | | |
| Resist | AB-8 | B-2 | E-1 | C-1 | C-2 | — |
| composition | 0.79 g | 0.18 g | 0.03 g | 45 g | 30 g | |
| AB8 | | | | | | |
| Resist | AB-9 | B-2 | E-1 | C-1 | C-2 | — |
| composition | 0.79 g | 0.18 g | 0.03 g | 45 g | 30 g | |
| AB9 | | | | | | |
| Resist | AB-10 | B-2 | E-1 | C-1 | C-2 | — |
| composition | 0.79 g | 0.18 g | 0.03 g | 45 g | 30 g | |
| AB10 | | | | | | |

<EUV Exposure Evaluation>

Using the resist composition described in the C6 table and the resist compositions 11, 13 and 14 shown in the section “1. EUV and EB exposure”, a resist pattern was formed in the same manner as in the above-mentioned section “1.3.1. EUV exposure (Part 1)”.

S-2, S-4, and S-5 among the solutions used in [Development] and [Rinsing] are as shown in the section “1. EUV and EB exposure”, and SE-1 to SE-28 are shown in the C7 table below.

TABLE 29
C7 table

| Developer | | | | |
|---|---|---|---|---|
| (rinsing | | | Content of | |
| liquid) | Main component | Additive | additive | Content of oxidant |
| SE-1 | diisobutyl ether | — | | 0.05 mmol/L |
| SE-2 | diisopentyl ether | — | | 0.05 mmol/L |
| SE-3 | diisohexyl ether | — | | 0.05 mmol/L |
| SE-4 | anisole | — | | 0.05 mmol/L |
| SE-5 | di-n-butyl ether | — | | 0.05 mmol/L |
| SE-6 | di-n-pentyl ether | — | | 0.05 mmol/L |
| SE-7 | di-n-hexyl ether | — | | 0.05 mmol/L |
| SE-8 | diisopropyl ether | — | | 0.05 mmol/L |
| SE-9 | diisobutyl ether/undecane = 70/30 | — | | 0.05 mmol/L |
| SE-10 | di-n-butyl ether/undecane = 90/10 | — | | 0.05 mmol/L |
| SE-11 | diisopropyl ether/decane = 50/50 | — | | 0.05 mmol/L |
| SE-12 | diisobutyl ether/undecane = 20/80 | — | | 0.05 mmol/L |
| SE-13 | diisobutyl ketone/undecane = 90/10 | — | | 0.05 mmol/L |
| SE-14 | diisobutyl ketone/undecane = 70/30 | — | | 0.05 mmol/L |
| SE-15 | diisobutyl ketone/undecane = 30/70 | — | | 0.05 mmol/L |
| SE-16 | diisobutyl ketone/decane = 70/30 | — | | 0.05 mmol/L |
| SE-17 | diisobutyl ketone/decane = 30/70 | — | | 0.05 mmol/L |
| SE-18 | diisobutyl ketone | — | | 0.05 mmol/L |
| SE-19 | isobutyl isobutanoate | — | | 0.05 mmol/L |
| SE-20 | diisobutyl ether/diisopentyl ether = 50/50 | — | | 0.05 mmol/L |
| SE-21 | diisopentyl ether/diisohexyl ether = 70/30 | — | | 0.05 mmol/L |
| SE-22 | diisopentyl ether/di-n-butyl ether = 30/70 | — | | 0.05 mmol/L |
| SE-23 | di-n-hexyl ether/di-n-butyl ether = 20/80 | — | | 0.05 mmol/L |
| SE-24 | diisobutyl ether/isoamyl acetate = 60/40 | — | | 0.05 mmol/L |
| SE-25 | di-n-hexyl ether/butyl acetate = 80/20 | — | | 0.05 mmol/L |
| SE-26 | diisopentyl ether/diisobutyl ketone = 70/30 | — | | 0.05 mmol/L |
| SE-27 | diisopropyl ether/2-heptanone = 90/10 | — | | 0.05 mmol/L |
| SE-28 | diisobutyl ether/4-methyl-2-pentanol = 50/50 | — | | 0.05 mmol/L |

[Evaluation Test]

Using the obtained resist pattern, the evaluation carried out in the above-mentioned section “1.3.1. EUV exposure (Part 1)” was carried out. The details of the results are shown in the C8 table.

TABLE 30
C8 table (Part 1)

| | | | | | | 30 nm | Limiting | |
|---|---|---|---|---|---|---|---|---|
| | | PB (60 | PEB (60 | Develop- | | sensitivity | resolution | Defect |
| | | seconds) | seconds) | ment | Rinsing | [mJ/cm²] | (nm) | residue |
| Example AB1 | Resist composition AB1 | 120° C. | 95° C. | SE-18 | S-5 | 107 | 15 | A |
| Example AB2 | Resist composition AB2 | 110° C. | 80° C. | SE 18 | S-5 | 135 | 20 | A |
| Example AB3 | Resist composition AB3 | 100° C. | 100° C. | SE 18 | S-5 | 108 | 16 | A |
| Example AB4 | Resist composition AB4 | 90° C. | 110° C. | SE-18 | S-5 | 119 | 16 | A |
| Example AB5 | Resist composition AB5 | 130° C. | 120° C. | SE 18 | S-5 | 72 | 17 | A |
| Example AB6 | Resist composition AB6 | 120° C. | 110° C. | SE-18 | S-5 | 109 | 16 | A |
| Example AB7 | Resist composition AB7 | 110° C. | 90° C. | SE-18 | S-5 | 93 | 15 | A |
| Example AB8 | Resist composition AB8 | 100° C. | 80° C. | SE-18 | S-5 | 114 | 16 | A |
| Example AB9 | Resist composition AB9 | 90° C. | 80° C. | SE-18 | S-5 | 127 | 18 | A |
| Example AB10 | Resist composition AB10 | 130° C. | 110° C. | SE-18 | S-5 | 102 | 19 | A |
| Example AB11 | Resist composition AB1 | 120° C. | 95° C. | SE-18 | SE-14 | 77 | 18 | A |
| Example AB12 | Resist composition AB2 | 110° C. | 80° C. | SE-18 | S-4 | 134 | 19 | A |
| Example AB13 | Resist composition AB3 | 100° C. | 100° C. | SE-18 | S-4 | 84 | 19 | A |
| Example AB14 | Resist composition AB4 | 90° C. | 110° C. | SE-18 | SE-13 | 108 | 15 | A |
| Example AB15 | Resist composition AB5 | 130° C. | 120° C. | SE-18 | SE-16 | 94 | 20 | A |
| Example AB16 | Resist composition AB6 | 120° C. | 110° C. | SE-18 | SE-1 | 108 | 19 | A |
| Example AB17 | Resist composition AB7 | 110° C. | 90° C. | SE-18 | SE-2 | 68 | 18 | A |
| Example AB18 | Resist composition AB8 | 100° C. | 80° C. | SE-18 | SE-3 | 67 | 20 | A |
| Example AB19 | Resist composition AB9 | 90° C. | 80° C. | SE-18 | SE-4 | 99 | 18 | A |
| Example AB20 | Resist composition AB10 | 130° C. | 110° C. | SE-18 | SE-5 | 73 | 19 | A |
| Example AB21 | Resist composition AB1 | 120° C. | 95° C. | SE-18 | SE-1 | 100 | 16 | A |
| Example AB22 | Resist composition AB1 | 120° C. | 95° C. | SE-18 | SE-2 | 87 | 16 | A |
| Example AB23 | Resist composition AB1 | 120° C. | 95° C. | SE-18 | SE-3 | 77 | 16 | A |
| Example AB24 | Resist composition AB1 | 120° C. | 95° C. | SE-18 | SE-4 | 79 | 20 | A |
| Example AB25 | Resist composition AB1 | 120° C. | 95° C. | SE-18 | SE-5 | 94 | 18 | A |
| Example AB26 | Resist composition AB1 | 120° C. | 95° C. | SE-18 | SE-6 | 71 | 18 | A |
| Example AB27 | Resist composition AB1 | 120° C. | 95° C. | SE-18 | SE-7 | 96 | 18 | A |
| Example AB28 | Resist composition AB1 | 120° C. | 95° C. | SE-18 | SE-8 | 83 | 19 | A |
| Example AB29 | Resist composition AB1 | 120° C. | 95° C. | SE-18 | SE-9 | 95 | 15 | A |
| Example AB30 | Resist composition AB1 | 120° C. | 95° C. | SE-18 | SE-10 | 100 | 15 | A |
| Example AB31 | Resist composition AB1 | 120° C. | 95° C. | SE-18 | SE-11 | 64 | 19 | A |
| Example AB32 | Resist composition AB1 | 120° C. | 95° C. | SE-18 | SE-12 | 119 | 15 | A |

TABLE 31
C8 table (Part 2)

| | | | | | | 30 nm | Limiting | |
|---|---|---|---|---|---|---|---|---|
| | | PB (60 | PEB (60 | Develop- | | sensitivity | resolution | Defect |
| | | seconds) | seconds) | ment | Rinsing | [mJ/cm²] | (nm) | residue |
| Example AB33 | Resist composition AB1 | 120° C. | 95° C. | S-2 | S-5 | 64 | 18 | A |
| Example AB34 | Resist composition AB7 | 120° C. | 90° C. | S-2 | S-5 | 62 | 17 | A |
| Example AB35 | Resist composition AB10 | 120° C. | 110° C. | S-2 | S-5 | 112 | 17 | A |
| Example AB36 | Resist composition AB1 | 120° C. | 95° C. | SE-19 | S-5 | 113 | 18 | A |
| Example AB37 | Resist composition AB7 | 120° C. | 90° C. | SE-19 | S-5 | 118 | 15 | A |
| Example AB38 | Resist composition AB10 | 120° C. | 110° C. | SE-19 | S-5 | 130 | 16 | A |
| Example AB39 | Resist composition AA2 | 120° C. | 110° C. | S-2 | SE-13 | 73 | 18 | A |
| Example AB40 | Resist composition AA2 | 120° C. | 110° C. | S-2 | SE-14 | 63 | 16 | A |
| Example AB41 | Resist composition AA2 | 120° C. | 110° C. | S-2 | SE-15 | 66 | 16 | A |
| Example AB42 | Resist composition AA2 | 120° C. | 110° C. | S-2 | SE-16 | 95 | 20 | A |
| Example AB43 | Resist composition AA2 | 120° C. | 110° C. | S-2 | SE-17 | 73 | 20 | A |
| Example AB44 | Resist composition AA2 | 120° C. | 110° C. | S-2 | SE-1 | 68 | 16 | A |
| Example AB45 | Resist composition AA2 | 120° C. | 110° C. | S-2 | SE-2 | 80 | 16 | A |
| Example AB46 | Resist composition AA2 | 120° C. | 110° C. | S-2 | SE-3 | 94 | 16 | A |
| Example AB47 | Resist composition AA2 | 120° C. | 110° C. | S-2 | SE-4 | 71 | 19 | A |
| Example AB48 | Resist composition AA2 | 120° C. | 110° C. | S-2 | SE-5 | 91 | 18 | A |
| Example AB49 | Resist composition AA2 | 120° C. | 110° C. | S-2 | SE-6 | 73 | 17 | A |
| Example AB50 | Resist composition AA2 | 120° C. | 110° C. | S-2 | SE-7 | 62 | 17 | A |
| Example AB51 | Resist composition AA2 | 120° C. | 110° C. | S-2 | SE-8 | 123 | 19 | A |
| Example AB52 | Resist composition AA2 | 120° C. | 110° C. | S-2 | SE-9 | 123 | 17 | A |
| Example AB53 | Resist composition AA2 | 120° C. | 110° C. | S-2 | SE-10 | 96 | 17 | A |
| Example AB54 | Resist composition AA2 | 120° C. | 110° C. | S-2 | SE-11 | 105 | 20 | A |
| Example AB55 | Resist composition AA2 | 120° C. | 110° C. | S-2 | SE-12 | 131 | 16 | A |
| Example AB56 | Resist composition 11 | 90° C. | 90° C. | SE-18 | SE-1 | 69 | 19 | A |
| Example AB57 | Resist composition 13 | 110° C. | — | SE-18 | SE-1 | 145 | 20 | A |
| Example AB58 | Resist composition 14 | — | — | SE-18 | SE-1 | 125 | 18 | A |
| Example AB59 | Resist composition AA2 | 120° C. | 110° C. | S-2 | SE-20 | 85 | 16 | A |
| Example AB60 | Resist composition AA2 | 120° C. | 110° C. | S-2 | SE-21 | 79 | 16 | A |
| Example AB61 | Resist composition AA2 | 120° C. | 110° C. | S-2 | SE-22 | 109 | 17 | A |
| Example AB62 | Resist composition AA2 | 120° C. | 110° C. | S-2 | SE-23 | 81 | 18 | A |
| Example AB63 | Resist composition AA2 | 120° C. | 110° C. | S-2 | SE-24 | 124 | 19 | A |
| Example AB64 | Resist composition AA2 | 120° C. | 110° C. | S-2 | SE-25 | 108 | 20 | A |
| Example AB65 | Resist composition AA2 | 120° C. | 110° C. | S-2 | SE-26 | 95 | 19 | A |
| Example AB66 | Resist composition AA2 | 120° C. | 110° C. | S-2 | SE-27 | 99 | 20 | A |
| Example AB67 | Resist composition AA2 | 120° C. | 110° C. | S-2 | SE-28 | 131 | 20 | A |

As shown in the C8 table, it was found that if the content of the oxidant (peroxide) in at least one of a developer or a rinsing liquid is small, the number of defect residues is small.

What is claimed is:

1. An organic processing liquid for resist film patterning, which is used to carry out at least one of developing or cleaning of a resist film obtained from an actinic ray-sensitive or radiation-sensitive composition, the liquid comprising:
an organic solvent,
wherein the content of an oxidant in the organic processing liquid is 10 mmol/L or less.

2. The organic processing liquid according to claim 1, wherein the organic processing liquid is a developer.

3. The organic processing liquid according to claim 2, wherein the organic solvent includes an ester-based solvent.

4. The organic processing liquid according to claim 3, wherein the ester-based solvent includes isoamyl acetate.

5. The organic processing liquid according to claim 2, wherein the organic solvent includes a ketone-based solvent.

6. The organic processing liquid according to claim 2, further comprising:
a basic compound.

7. The organic processing liquid according to claim 1, wherein the organic processing liquid is a rinsing liquid.

8. The organic processing liquid according to claim 7, wherein the organic solvent includes a hydrocarbon-based solvent.

9. The organic processing liquid according to claim 7, wherein the organic solvent includes a ketone-based solvent.

10. The organic processing liquid according to claim 7, wherein the organic solvent includes an ether-based solvent.

11. The organic processing liquid according to claim 8, wherein the hydrocarbon-based solvent includes undecane.

12. The organic processing liquid according to claim 1, further comprising:
an antioxidant.

13. The organic processing liquid according to claim 1, further comprising:
a surfactant.

14. A pattern forming method, comprising:
a resist film forming step of forming a resist film using an actinic ray-sensitive or radiation-sensitive composition;
an exposure step of exposing the resist film; and
a treatment step of treating the exposed resist film with the organic processing liquid according to claim 1.

15. The pattern forming method according to claim 14,
wherein the treatment step includes a development step of developing with a developer, wherein the developer is an organic processing liquid including an organic solvent, and the organic solvent includes isoamyl acetate, and
wherein the content of an oxidant in the organic processing processing liquid used as the developer is 10 mmol/L or less.

16. The pattern forming method according to claim 14,
wherein the treatment step includes a development step of developing with a developer, wherein the developer is an organic processing liquid comprising an organic solvent and a basic compound, and
wherein the content of an oxidant in the organic processing processing liquid used as the developer is 10 mmol/L or less.

17. The pattern forming method according to claim 14,
wherein the treatment step includes a rinsing step of cleaning with a rinsing liquid,
wherein the rinsing liquid is an organic processing liquid including an organic solvent and the organic solvent includes a hydrocarbon based solvent, and wherein the content of an oxidant in the organic processing processing liquid used as the rinsing liquid is 10 mmol/L or less.

18. The organic processing liquid according to claim 3, further comprising:
a basic compound.

19. The organic processing liquid according to claim 4, further comprising:
a basic compound.

20. The organic processing liquid according to claim 5, further comprising:
a basic compound.
